(19) United States
(12) Patent Application Publication
(10) Pub. No.: US 2025/0234780 A1
(43) Pub. Date: Jul. 17, 2025

(54) CONDENSED CYCLIC COMPOUND, LIGHT-EMITTING DEVICE INCLUDING THE SAME, AND ELECTRONIC APPARATUS INCLUDING THE LIGHT-EMITTING DEVICE

(71) Applicant: Samsung Electronics Co., Ltd., Suwon-si (KR)

(72) Inventors: Eunkyung LEE, Suwon-si (KR); Sangmo KIM, Suwon-si (KR); Hwang Suk KIM, Suwon-si (KR); Yusuke Maruyama, Suwon-si (KR); Halim LEE, Suwon-si (KR); Soonok JEON, Suwon-si (KR); Jong Soo KIM, Suwon-si (KR); Youngmok SON, Suwon-si (KR); Hwayoung CHO, Suwon-si (KR); Kyeongsik JU, Suwon-si (KR)

(21) Appl. No.: 19/025,033

(22) Filed: Jan. 16, 2025

(30) Foreign Application Priority Data
Jan. 17, 2024 (KR) 10-2024-0007637
Jan. 13, 2025 (KR) 10-2025-0004970

(51) Int. Cl. H10K 85/60; C07F 5/02; C09K 11/06; H10K 50/12; H10K 85/30; H10K 101/20

(52) U.S. Cl. CPC H10K 85/658; C07F 5/027; C09K 11/06; H10K 85/346; H10K 85/6572; C09K 2211/1007; C09K 2211/1014; C09K 2211/1018; H10K 50/121; H10K 2101/20

(57) ABSTRACT

A condensed cyclic compound, a light-emitting device including the same, and an electronic apparatus including the light-emitting device. The condensed cyclic compound is free of metal, and includes a condensed cyclic core having a first condensed ring and a second condensed ring condensed with each other, the condensed cyclic core further including a third condensed ring that is condensed with the first condensed ring and is not condensed with the second condensed ring. The detailed description of the first condensed ring, second condensed ring and third condensed ring is the same as described in the specification.

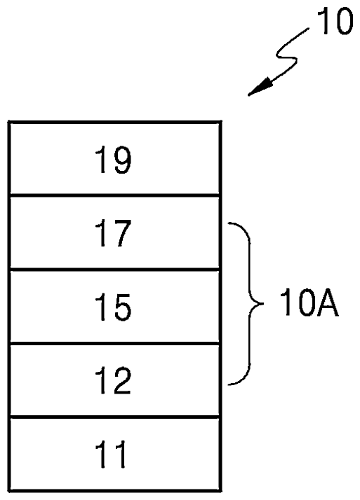

### CROSS-REFERENCE TO RELATED APPLICATION

This application is based on and claims priority to Korean Patent Application No. 10-2024-0007637, filed on Jan. 17, 2024, and Korean Patent Application No. 10-2025-0004970, filed on Jan. 13, 2025, in the Korean Intellectual Property Office, and all the benefits accruing therefrom under 35 U.S.C. § 119, the disclosure of both applications being incorporated by reference herein in their entirety.

### BACKGROUND

### 1. Field

The disclosure relates to a condensed cyclic compound, a light-emitting device including the same, and an electronic apparatus including the light-emitting device.

### 2. Description of the Related Art

From among light-emitting devices, organic light-emitting devices are self-emissive devices that, as compared with devices of the related art, have wide viewing angles, high contrast ratios, short response times, and excellent characteristics in terms of luminance, driving voltage, and response speed, and produce full-color images.

In an example, an organic light-emitting device includes an anode, a cathode, and an interlayer arranged between the anode and the cathode and including an emission layer. A hole transport region may be provided between the anode and the emission layer, and an electron transport region may be provided between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. When the excitons transition from an excited state to a ground state, light is emitted.

### SUMMARY

Provided are a novel condensed cyclic compound, a light-emitting device using the same, and an electronic apparatus including the light-emitting device.

Additional aspects will be set forth in part in the description which follows and, in part, will be apparent from the description, or may be learned by practice of the presented embodiments of the disclosure.

According to an aspect of the disclosure, a condensed cyclic compound
does not include a metal, and
includes a condensed cyclic core, the condensed cyclic core including a first condensed ring and a second condensed ring condensed with each other, wherein
the first condensed ring is a 10-membered ring, an 11-membered ring, a 12-membered ring, or a 13-membered ring, each including nitrogen and carbon as a first ring-forming atom, and a second ring-forming atom including at least one heteroatom selected from oxygen, sulfur, selenium, or nitrogen,
the second condensed ring is a 6-membered ring including nitrogen, carbon, and boron,
the first condensed ring and the second condensed ring are condensed with each other while sharing nitrogen and carbon,
the condensed cyclic core further includes a third condensed ring that is condensed with the first condensed ring and is not condensed with the second condensed ring,
the third condensed ring is a C₅-C₆₀ carbocyclic group or a C₃-C₆₀ heterocyclic group, and
the number of third condensed rings in the condensed cyclic core may be 3 or more.

According to another aspect of the disclosure, a light-emitting device includes a first electrode, a second electrode, and an interlayer which is arranged between the first electrode and the second electrode and includes an emission layer, wherein the interlayer includes at least one type of the condensed cyclic compound.

According to another aspect of the disclosure, an electronic apparatus includes the light-emitting device.

### BRIEF DESCRIPTION OF THE DRAWING

The above and other aspects, features, and advantages of certain embodiments of the disclosure will be more apparent from the following description taken in conjunction with the FIGURE, which shows a schematic cross-sectional view of a light-emitting device according to an embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers, and/or sections should not be limited by these terms. These terms are only used to distinguish one element, component, region, layer or section from another element, component, region, layer, or section. Thus, “a first element,” “component,” “region,” “layer” or “section” discussed below could be termed a second element, component, region, layer, or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the FIGURE.

For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the FIGURE. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded Thus, the regions illustrated in the figures are schematic in nature and their shapes are not intended to illustrate the precise shape of a region and are not intended to limit the scope of the present claims.

### Description of Condensed Cyclic Compound

A condensed cyclic compound does not include a metal and includes a condensed cyclic core in which a first condensed ring and a second condensed ring are condensed with each other. The first condensed ring may be a 10-membered ring, 11-membered ring, 12-membered ring, or 13-membered ring that includes a first ring-forming atom and further includes a second ring-forming atom in addition to the first ring-forming atom. The first ring-forming atom may include nitrogen and carbon. The second ring-forming atom may include at least one heteroatom selected from oxygen, sulfur, selenium, or nitrogen. The second condensed ring is a 6-membered ring including nitrogen, carbon, and boron. The first condensed ring and the second condensed ring are condensed with each other while sharing nitrogen and carbon.

The condensed cyclic core may further include a third condensed ring that is condensed with the first condensed ring and is not condensed with the second condensed ring. The third condensed ring may be selected from a C₅-C₆₀ carbocyclic group and a C₃-C₆₀ heterocyclic group. The number of third condensed rings in the condensed cyclic core may be at least 3.

According to an embodiment, the first condensed ring may be a 10-membered ring. For example, the second ring-forming atom may include one heteroatom selected from oxygen, sulfur, selenium, or nitrogen.

According to an embodiment, the first condensed ring may be an 11-membered ring. For example, the second ring-forming atom may include two heteroatoms selected from oxygen, sulfur, selenium, or nitrogen. The two heteroatoms included in the second ring-forming atom may be the same as or different from each other.

According to an embodiment, the first condensed ring may be a 12-membered ring. For example, the second ring-forming atom may include three heteroatoms selected from oxygen, sulfur, selenium, or nitrogen. The three hetero atoms in the second ring-forming atoms may be the same as or different from each other.

According to an embodiment, the first condensed ring may be a 13-membered ring. For example, the second ring-forming atom may include four heteroatoms selected from oxygen, sulfur, selenium, or nitrogen. The four heteroatoms in the second ring-forming atoms may be the same as or different from each other.

According to an embodiment, the number of third condensed rings may be at least 3 and no more than 10.

According to an embodiment, the number of third condensed rings may be 3 or 4.

According to an embodiment, the number of third condensed rings may be 3.

According to an embodiment, a condensed cyclic compound includes a first condensed cyclic core in which a first condensed ring and a second condensed ring are condensed with each other and a second condensed cyclic core in which a first condensed ring and a second condensed ring are condensed with each other, and wherein the first condensed cyclic core and the second condensed cyclic core are condensed with each other. The second condensed ring of the first condensed cyclic core and the second condensed ring of the second condensed cyclic core may be condensed with each other.

According to an embodiment, a condensed cyclic compound includes a first condensed cyclic core in which a first condensed ring and a second condensed ring are condensed with each other and a second condensed cyclic core in which a first condensed ring and a second condensed ring are condensed with each other include at least nine aromatic rings. For example, the aromatic rings may be benzene rings.

According to an embodiment, a condensed cyclic compound includes a first condensed cyclic core in which a first condensed ring and a second condensed ring are condensed with each other and a second condensed cyclic core in which a first condensed ring and a second condensed ring are condensed with each other include at least nine aromatic rings and at least one carbazole group. For example, the aromatic rings may be benzene rings.

According to an embodiment, the condensed cyclic core may further include a fourth condensed ring that is simultaneously condensed with the first condensed ring and the second condensed ring.

According to an embodiment, the fourth condensed ring may be selected from a C₅-C₆₀ carbocyclic group and a C₃-C₆₀ heterocyclic group.

According to an embodiment, the sum of the numbers of the third condensed rings and the fourth condensed rings may be 4 or more.

According to an embodiment, the number of fourth condensed rings may be 1 or 2.

According to an embodiment, the number of fourth condensed rings may be 1.

According to an embodiment, the condensed cyclic core may be represented by Formula 1(1):

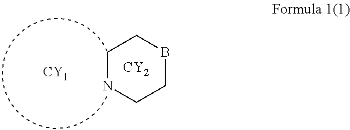

wherein, in Formula 1(1),
ring CY₁ may be the first condensed ring, and
ring CY₂ may be the second condensed ring.

According to an embodiment, the condensed cyclic compound may include a first condensed cyclic core of Formula 1(1) and a second condensed cyclic core of Formula 1(1), where the CY₂ rings of the two cores are condensed with each other.

According to an embodiment, the condensed cyclic core may include a moiety represented by Formula 1(1)-a:

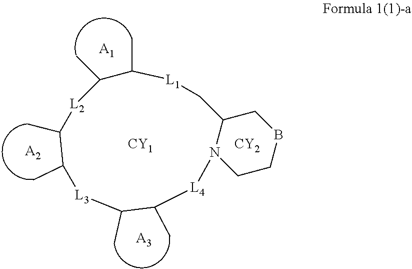

wherein, in Formula 1(1)-a,
ring CY₁ may be a 10-membered ring, an 11-membered ring, a 12-membered ring, or a 13-membered ring, each of which includes nitrogen and carbon as a first ring-forming atom, and at least one heteroatom selected from oxygen, sulfur, selenium, or nitrogen as a second ring-forming atom, in addition to the first ring-forming atom,
ring CY₂ may be a 6-membered ring including nitrogen, carbon, and boron,
L₁ to L₄ may each independently be a single bond or include at least one heteroatom selected from oxygen, sulfur, selenium, or nitrogen,
at least one of L₁ to L₄ may not be a single bond, and
ring A₁ to ring A₃ may each independently be a C₅-C₆₀ carbocyclic group or a C₃-C₆₀ heterocyclic group. Each of ring A₁ and ring A₃, are as described herein. For example, ring A₁ and ring A₃ may independently be a benzene group, a pyridine group, a pyrimidine group, a pyrazine group, or a pyridazine group.

According to an embodiment, the condensed cyclic core may include a moiety represented by Formula 1(1)-b:

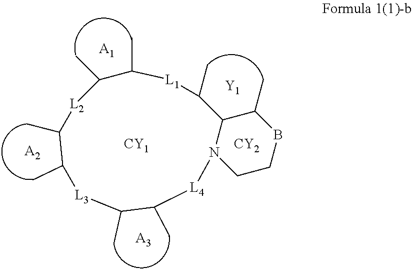

wherein, in Formula 1(1)-b,
ring CY₁ may be a 10-membered ring, an 11-membered ring, a 12-membered ring, or a 13-membered ring, each of which includes nitrogen and carbon as a first ring-forming atom, and at least one heteroatom selected from oxygen, sulfur, selenium, or nitrogen as a second ring-forming atom, in addition to the first ring-forming atom,
ring CY₂ may be a 6-membered ring including nitrogen, carbon, and boron,
L₁ to L₄ may each independently be a single bond or include at least one heteroatom selected from oxygen, sulfur, selenium, or nitrogen,
at least one of L₁ to L₄ may not be a single bond, and
ring A₁ to ring A₃ and ring Y₁ may each independently be a C₅-C₆₀ carbocyclic group or a C₃-C₆₀ heterocyclic group. Each of ring A₁ and ring A₃, are as described herein. For example, ring A₁ and ring A₃ may independently be a benzene group, a pyridine group, a pyrimidine group, a pyrazine group, or a pyridazine group.

According to an embodiment, in ring CY₂ of Formulae 1(1), 1(1)-a, and 1(1)-b, a boron-containing heterocyclic group may be additionally condensed while sharing boron. The boron-containing heterocyclic group may be, for example, a boron-containing 6-membered ring.

The term “boron-containing 6-membered ring” as used herein may include, as a ring-forming element, for example, i) oxygen, carbon, and boron, ii) sulfur, carbon, and boron, iii) nitrogen, carbon, and boron, iv) carbon and boron, or v) silicon, carbon, and boron.

According to an embodiment, the condensed cyclic compound may include two moieties independently represented by Formula 1(1)-a or Formula 1(1)-b where the CY₂ rings of the two moieties are condensed with each other.

According to an embodiment, the condensed cyclic core may include at least one moiety represented by one of Formulae 1(1)-1 to 1(1)-4:

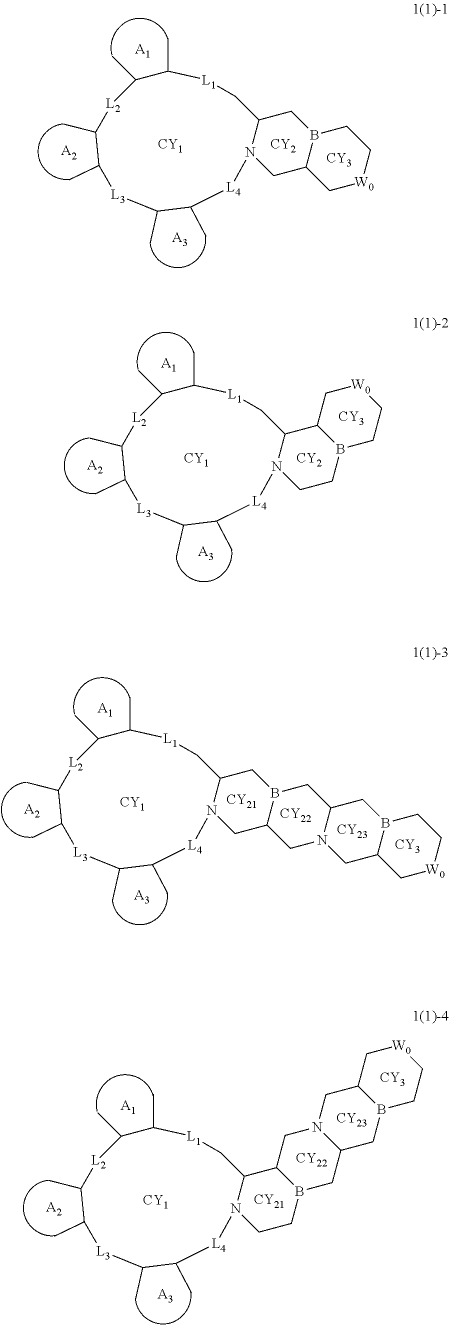

wherein, in Formulae 1(1)-1 to 1(1)-4,
ring CY₁ may be a 10-membered ring, an 11-membered ring, a 12-membered ring, or a 13-membered ring, each of which includes nitrogen and carbon as a first ring-forming atom, and at least one heteroatom selected from oxygen, sulfur, selenium, or nitrogen as a second ring-forming atom, in addition to the first ring-forming atom,
ring CY₂ and rings CY₂₁ to CY₂₃ may each be a 6-membered ring including nitrogen, carbon, and boron,
ring CY₃ may be a 6-membered ring including W₀, carbon and boron (for example, a boron-containing 6-membered ring),
W₀ may include O, S, N, C, or Si, and ring A₁ to ring A₃ may each independently be a C₅-C₆₀ carbocyclic group or a C₃-C₆₀ heterocyclic group. Each of ring A₁ and ring A₃, are as described herein.

According to an embodiment, the condensed cyclic core may include at least one moiety represented by one of Formulae 1(1)-5 to 1(1)-8:

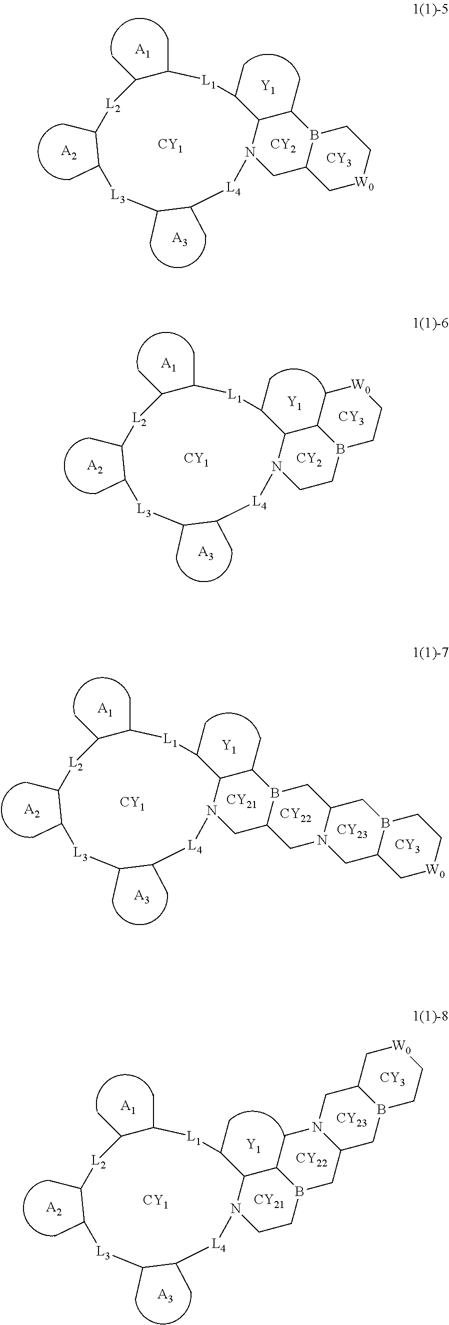

wherein, in Formulae 1(1)-5 to 1(1)-8,
ring CY₁ may be a 10-membered ring, an 11-membered ring, a 12-membered ring, or a 13-membered ring, each of which includes nitrogen and carbon as a first ring-forming atom, and at least one heteroatom selected from oxygen, sulfur, selenium, or nitrogen as a second ring-forming atom, in addition to the first ring-forming atom,
ring CY₂ and rings CY₂₁ to CY₂₃ may each be a 6-membered ring including nitrogen, carbon, and boron,
ring CY₃ may be a 6-membered ring including W₀, carbon and boron (for example, a boron-containing 6-membered ring),
W₀ may include O, S, N, C, or Si, and
ring A₁ to ring A₃ and ring Y₁ may each independently be a C₅-C₆₀ carbocyclic group or a C₃-C₆₀ heterocyclic group. Each of ring A₁ and ring A₃ is as described herein.

According to an embodiment, at least one cyclic group selected from a C₅-C₆₀ carbocyclic group and a C₃-C₆₀ heterocyclic group may be additionally condensed to each of ring CY₂, ring CY₂₁ to CY₂₃ and/or ring CY₃ in Formulae 1(1), 1(1)-a, 1(1)-b, 1(1)-1 to 1(1)-8.

According to an embodiment, at least one of a boron-containing 6-membered ring, an aromatic 6-membered ring (for example, a benzene group, a pyridine group, a pyrimidine group, a pyrazine group, a pyridazine group, etc.), a dibenzofuran group, a dibenzothiophene group, a carbazole group, a fluorene group, and a dibenzosilole group, may be additionally condensed to each of ring CY₂, ring CY₂₁ to CY₂₃ and/or ring CY₃ in Formulae 1(1), 1(1)-a, 1(1)-b, 1(1)-1 to 1(1)-8.

For example, the first condensed ring-containing core of Compound 10 may include a moiety represented by Formula 1(1)-1, and the first condensed ring-containing core of Compound 11 may include a moiety represented by Formula 1(1)-2.

According to an embodiment, the number of first condensed rings in the condensed cyclic compound may be 1, 2, 3, or 4. For example, the number of first condensed rings in the condensed cyclic compound may be 1 or 2. For example, the number of first condensed rings in Compound 1 may be 2, and the number of first condensed rings in Compound 10 may be 1.

According to an embodiment, the number of second condensed rings in the condensed cyclic compound may be 1 to 10. For example, the number of second condensed rings in Compound 1 below is 2, and the number of second condensed rings in Compound 10 below is 1.

According to an embodiment, the number of boron atoms included as ring-forming atoms in the condensed cyclic compound may be 1 to 10. For example, the number of boron atoms included as ring-forming atoms in Compound 1 below is 1.

The condensed cyclic compound may be a delayed fluorescence material. That is, the condensed cyclic compound may emit delayed fluorescent light.

The first condensed ring-containing core may be unsubstituted. Alternatively, the first condensed ring-containing core may be substituted with at least one substituent. The substituent may be understood by referring to the descriptions of R₁ to R₃, R₁₁, R₂₁, R₃₁, R₄₁, Z₁ to Z₃, Z₂₁ to Z₂₃, T₁₁, T₁₂, T₂₁, T₂₂, T₃₁, and T₃₂ in the specification.

For example, the condensed cyclic compound may be a multiple resonance thermally activated delayed fluorescence material.

According to an embodiment, the condensed cyclic compound may be represented by Formulae 1, 2, or 3:

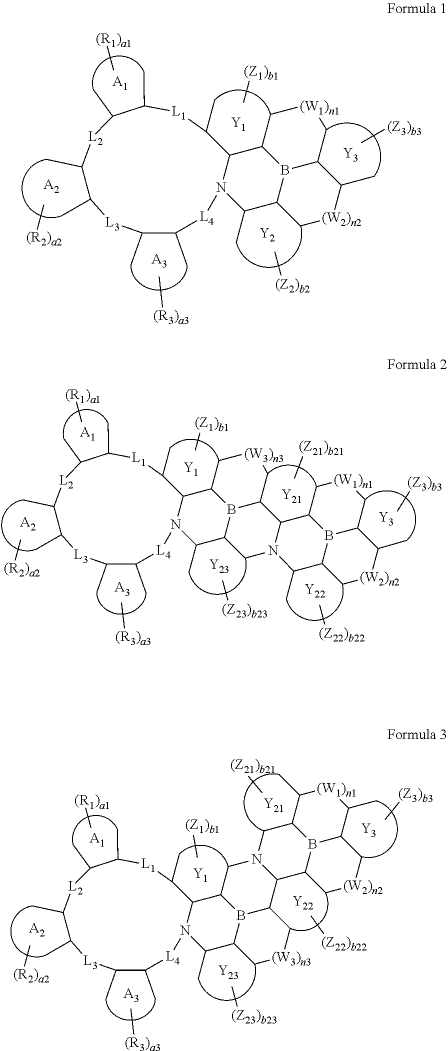

wherein, in Formulae 1, 2, and 3,
ring A₁ to ring A₃, ring Y₁ to ring Y₃ and ring Y₂₁ to ring Y₂₃ may each independently be a C₅-C₆₀ carbocyclic group or a C₃-C₆₀ heterocyclic group,
W₁ may be a single bond, O, S, N(T₁₁), C(T₁₁)(T₁₂), or Si(T₁₁)(T₁₂),
W₂ may be a single bond, O, S, N(T₂₁), C(T₂₁)(T₂₂), or Si(T₂₁)(T₂₂),
W₃ may be a single bond, O, S, N(T₃₁), C(T₃₁)(T₃₂), or Si(T₃₁)(T₃₂),
n1, n2, and n3 may each independently be 0 or 1,
when n1 is 0, *—(W₁)ₙ₁—*′ does not exist,
when n2 is 0, *—(W₂)ₙ₂—*′ does not exist,
when n3 is 0, *—(W₃)ₙ₃—*′ does not exist,
the sum of n1 and n2 may be 1 or more,
L₁ may be a single bond, O, S, Se, or N(R₁₁),
L₂ may be a single bond, O, S, Se, or N(R₂₁),
L₃ may be a single bond, O, S, Se, or N(R₃₁),
L₄ may be a single bond, O, S, Se, or N(R₄₁),
at least one of L₁ to L₄ may not be a single bond, and
R₁ to R₃, R₁₁, R₂₁, R₃₁, R₄₁, Z₁ to Z₃, and Z₂₁ to Z₂₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted non-aromatic condensed heteropolycyclic group, —N(Q₁)(Q₂), —Si(Q₃)(Q₄)(Q₅), —Ge(Q₃)(Q₄)(Q₅), —B(Q₆) (Q₇), —P(═O)(Q₈)(Q₉), or —P(Q₈)(Q₉),
a1 to a3, b1 to b3, and b21 to b23 may each independently be an integer from 0 to 10,
each of T₁₁, T₁₂, T₂₁, T₂₂, T₃₁, and T₃₂ may be i) the same as the definition for Z₁ above, or ii) connected to an adjacent substituent to form the first condensed ring,
two or more of R₁ to R₃, Z₁ to Z₃, and Z₂₁ to Z₂₃, T₁₁, T₁₂, T₂₁, T₂₂, T₃₁, and T₃₂ may optionally be connected to each other, forming a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, Q₁₁ to Q₁₉, Q₂₁ to Q₂₉ and Q₃₁ to Q₃₉ may each independently be: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, a C₁-C₆₀ alkyl group, a C₆-C₆₀ aryl group, or a combination thereof.

According to an embodiment, ring A₁ to ring A₃, ring Y₁ to ring Y₃, and ring Y₂₁ to ring Y₂₃ in Formulae 1 to 3 may each independently be a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

According to an embodiment, ring A₁ to ring A₃, ring Y₁ to ring Y₃, and ring Y₂₁ to ring Y₂₃ in Formulae 1 to 3 may each independently, be a benzene group, a dibenzofuran group, a dibenzothiophene group, a carbazole group, a fluorene group, or a dibenzosilole group.

According to an embodiment, regarding the condensed cyclic compound represented by Formula 1, n1 may be 1, W₁ may be N(T₁₁), and Condition 1A or Condition 1B may be satisfied:
Condition 1A
Z₁ is connected to T₁₁ to form the first condensed ring,
Condition 1B
Z₃ is connected to T₁₁ to form the first condensed ring.

For example, Compound 13 may be a condensed cyclic compound that is represented by Formula 1 wherein n1 is 1 and W₁ is N(T₁₁), and satisfies Condition 1A.

According to an embodiment, regarding the condensed cyclic compound represented by Formula 2 or 3, n1 may be 1, W₁ may be N(T₁₁), and Condition 2A or Condition 2B may be satisfied:
Condition 2A
Z₂₁ is connected to T₁₁ to form the first condensed ring,
Condition 2B
Z₃ is connected to T₁₁ to form the first condensed ring.

According to an embodiment, regarding the condensed cyclic compound represented by Formula 1, n2 may be 1, W₂ may be N(T₂₁), and Condition 1C or Condition 1 D may be satisfied:
Condition 1C
Z₂ is connected to T₂₁ to form the first condensed ring,
Condition 1D
Z₃ is connected to T₂₁ to form the first condensed ring.

For example, Compound 1 may be a condensed cyclic compound that is represented by Formula 1 wherein n2 is 1 and W₂ is N(T₂₁), and satisfies Condition 1D.

According to an embodiment, regarding the condensed cyclic compound represented by Formula 2 or 3, n2 may be 1, W₂ may be N(T₂₁), and Condition 2C or Condition 2D may be satisfied:
Condition 2C
Z₂₂ is connected to T₂₁ to form the first condensed ring,
Condition 2D
Z₃ is connected to T₂₁ to form the first condensed ring.

According to an embodiment, the condensed cyclic compound represented by Formula 1 may satisfy at least one of Condition 1E, Condition 1F, and Condition 1:
Condition 1E
ring Y₁ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring,
are condensed with each other,
Condition 1F
ring Y₂ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring
are condensed with each other,
Condition 1G
ring Y₃ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring
are condensed with each other.

According to an embodiment, the condensed cyclic compound represented by Formula 2 or 3 may satisfy at least one of Condition 2E, Condition 2F, Condition 2G, Condition 2H, and Condition 21:
Condition 2E
ring Y₁ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring are condensed with each other,
Condition 2F
ring Y₂₁ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring are condensed with each other,
Condition 2G
ring Y₂₂ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring are condensed with each other.
Condition 2H
ring Y₂₃ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring are condensed with each other.
Condition 21
ring Y₃ is a C₃-C₆₀ heteropolycyclic group including at least one boron as a ring-forming atom, and
the C₃-C₆₀ heteropolycyclic group is a condensed ring in which
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, and
ii) at least one boron-containing 6-membered ring are condensed with each other.

In an embodiment, in Formula 1,
i) n1 may be 0 and n2 may be 1, or
ii) n1 may be 1 and n2 may be 0, or
iii) n1 and n2 may each be 1.

According to an embodiment, in Formulae 2 and 3,
i) n1 may be 0, n2 may be 1, and n3 may be 0, or
ii) n1 may be 1, n2 may be 0, and n3 may be 0, or
iii) n1 may be 0 and each of n2 and n3 may be 1, or
iv) each of n1 and n3 may be 1 and n2 may be 0, or
v) each of n1 and n2 may be 1 and n3 may be 0, or
vi) each of n1 to n3 may be 1.

According to an embodiment, R₁ to R₃, R₁₁, R₂₁, R₃₁, R₄₁, Z₁ to Z₃ and Z₂₁ to Z₂₃ in Formulae 1 to 3, may each independently be:
hydrogen or deuterium;
a C₁-C₂₀ alkyl group unsubstituted or substituted with deuterium, a phenyl group, a biphenyl group, a carbazolyl group, or a combination thereof;
a phenyl group, a biphenyl group, or a carbazolyl group, unsubstituted or substituted with deuterium, a C₁-C₂₀ alkyl group, a phenyl group, a biphenyl group, a carbazolyl group, or a combination thereof; or
—N(Q₁)(Q₂), and
Q₁ and Q₂ may each independently be a phenyl group, a biphenyl group, or a carbazolyl group, each unsubstituted or substituted with deuterium, a C₁-C₂₀ alkyl group, a phenyl group, a biphenyl group, a carbazolyl group, or a combination thereof.

According to an embodiment, R₁ to R₃, Z₁ to Z₃, Z₂₁ to Z₂₃, T₁₁, T₁₂, T₂₁, T₂₂, T₃₁ and T₃₂ in Formulae 1 to 3 may each independently include:
hydrogen or deuterium;
a C₁-C₂₀ alkyl group unsubstituted or substituted with deuterium, a phenyl group, a biphenyl group, a carbazolyl group, or a combination thereof;
a phenyl group, a biphenyl group, or a carbazolyl group, unsubstituted or substituted with deuterium, a C₁-C₂₀ alkyl group, a phenyl group, a biphenyl group, a carbazolyl group, or a combination thereof; or
—N(Q₁)(Q₂).

The definitions of Q₁ and Q₂ are as described herein.

According to an embodiment, R₁ to R₃, R₁₁, R₂₁, R₃₁, R₄₁, Z₁ to Z₃ and Z₂₁ to Z₂₃ in Formulae 1 to 3, may each independently be:
hydrogen, deuterium, a C₁-C₁₀ alkyl group, or a deuterated C₁-C₁₀ alkyl group;
a phenyl group, a biphenyl group, or an N-carbazolyl group, each unsubstituted or substituted with deuterium, a C₁-C₁₀ alkyl group, a deuterated C₁-C₁₀ alkyl group, a phenyl group, a deuterated phenyl group, a (C₁-C₁₀ alkyl)phenyl group, a deuterated (C₁-C₁₀ alkyl)phenyl group, an N-carbazolyl group, a deuterated N-carbazolyl group, a (C₁-C₁₀ alkyl) N-carbazolyl group, a deuterated (C₁-C₁₀ alkyl) N-carbazolyl group, or a combination thereof; or
—N(Q₁)(Q₂).

According to an embodiment, T₁₁, T₁₂, T₂₁, T₂₂, T₃₁, and T₃₂ in Formulae 1 to 3 may each independently
i) include:
hydrogen, deuterium, a C₁-C₁₀ alkyl group or a deuterated C₁-C₁₀ alkyl group;
a phenyl group, a biphenyl group, or an N-carbazolyl group, each unsubstituted or substituted with deuterium, a C₁-C₁₀ alkyl group, a deuterated C₁-C₁₀ alkyl group, a phenyl group, a deuterated phenyl group, a (C₁-C₁₀ alkyl)phenyl group, a deuterated (C₁-C₁₀ alkyl)phenyl group, an N-carbazolyl group, a deuterated N-carbazolyl group, a (C₁-C₁₀ alkyl) N-carbazolyl group, a deuterated (C₁-C₁₀ alkyl) N-carbazolyl group, or a combination thereof; or
—N(Q₁)(Q₂), wherein Q₁ and Q₂ may each independently be a phenyl group, a biphenyl group, or a carbazolyl group, each unsubstituted or substituted with deuterium, a C₁-C₂₀ alkyl group, a phenyl group, a biphenyl group, a carbazolyl group, or a combination thereof; or
ii) be connected to an adjacent substituent to form the first condensed ring.

According to an embodiment, T₁₁, T₁₂, T₂₁, T₂₂, T₃₁, and T₃₂ in Formulae 1 to 3 may each independently
i) include:
hydrogen, deuterium, a C₁-C₁₀ alkyl group or a deuterated C₁-C₁₀ alkyl group;
a phenyl group, a biphenyl group, or an N-carbazolyl group, each unsubstituted or substituted with deuterium, a C₁-C₁₀ alkyl group, a deuterated C₁-C₁₀ alkyl group, a phenyl group, a deuterated phenyl group, a (C₁-C₁₀ alkyl)phenyl group, a deuterated (C₁-C₁₀ alkyl)phenyl group, an N-carbazolyl group, a deuterated N-carbazolyl group, a (C₁-C₁₀ alkyl) N-carbazolyl group, a deuterated (C₁-C₁₀ alkyl) N-carbazolyl group, or a combination thereof; or
—N(Q₁)(Q₂),
or
ii) be connected to an adjacent substituent to form the first condensed ring.

The definitions of Q₁ and Q₂ are as described herein.

According to an embodiment, T₁₁, T₁₂, T₂₁, T₂₂, T₃₁, and T₃₂ in Formulae 1 to 3 may each independently
i) include:
hydrogen, deuterium, a C₁-C₁₀ alkyl group or a deuterated C₁-C₁₀ alkyl group;
a phenyl group, a biphenyl group, or an N-carbazolyl group, each unsubstituted or substituted with deuterium, a C₁-C₁₀ alkyl group, a deuterated C₁-C₁₀ alkyl group, a phenyl group, a deuterated phenyl group, a (C₁-C₁₀ alkyl)phenyl group, a deuterated (C₁-C₁₀ alkyl)phenyl group, an N-carbazolyl group, a deuterated N-carbazolyl group, a (C₁-C₁₀ alkyl) N-carbazolyl group, a deuterated (C₁-C₁₀ alkyl) N-carbazolyl group, or a combination thereof; or
—N(Q₁)(Q₂), or
ii) be connected to an adjacent substituent to form the first condensed ring.

According to an embodiment, the condensed cyclic compound may include at least one deuterium.

According to an embodiment, a moiety represented by

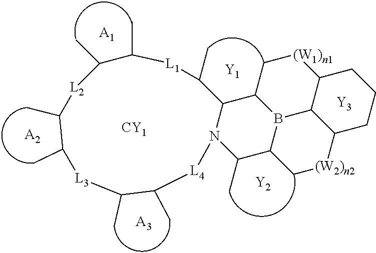

in Formula 1 may be represented by one of Formulae 1A-1 to 1A-3, 1B-1 and 1B-2, 1C-1 to 1C-5, 1D-1 to 1D-5 and 1E-1 to 1E-5:

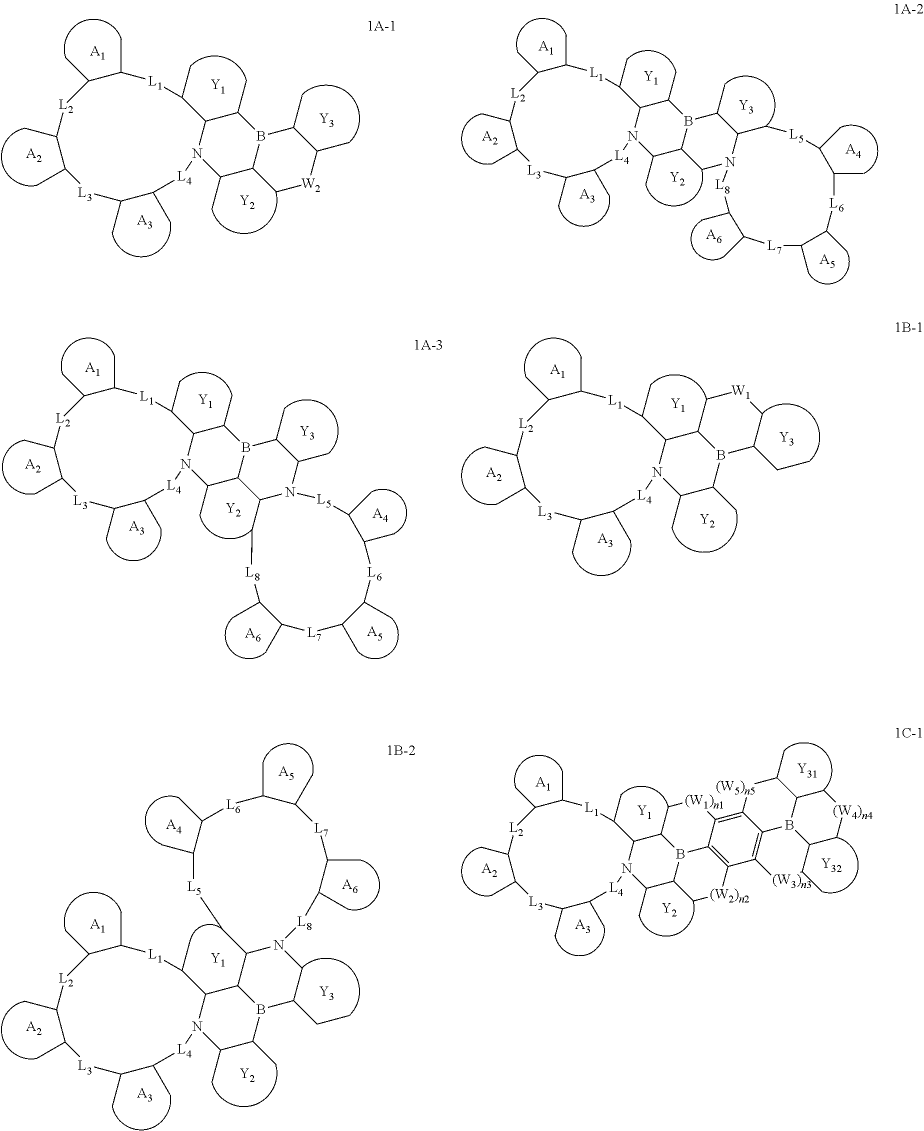

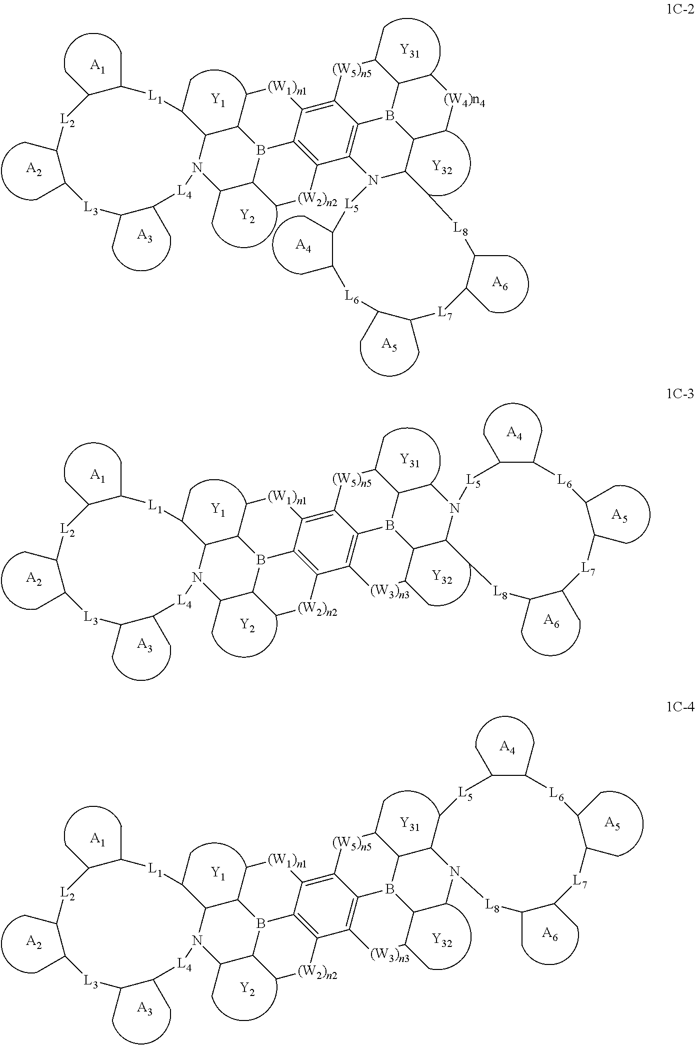

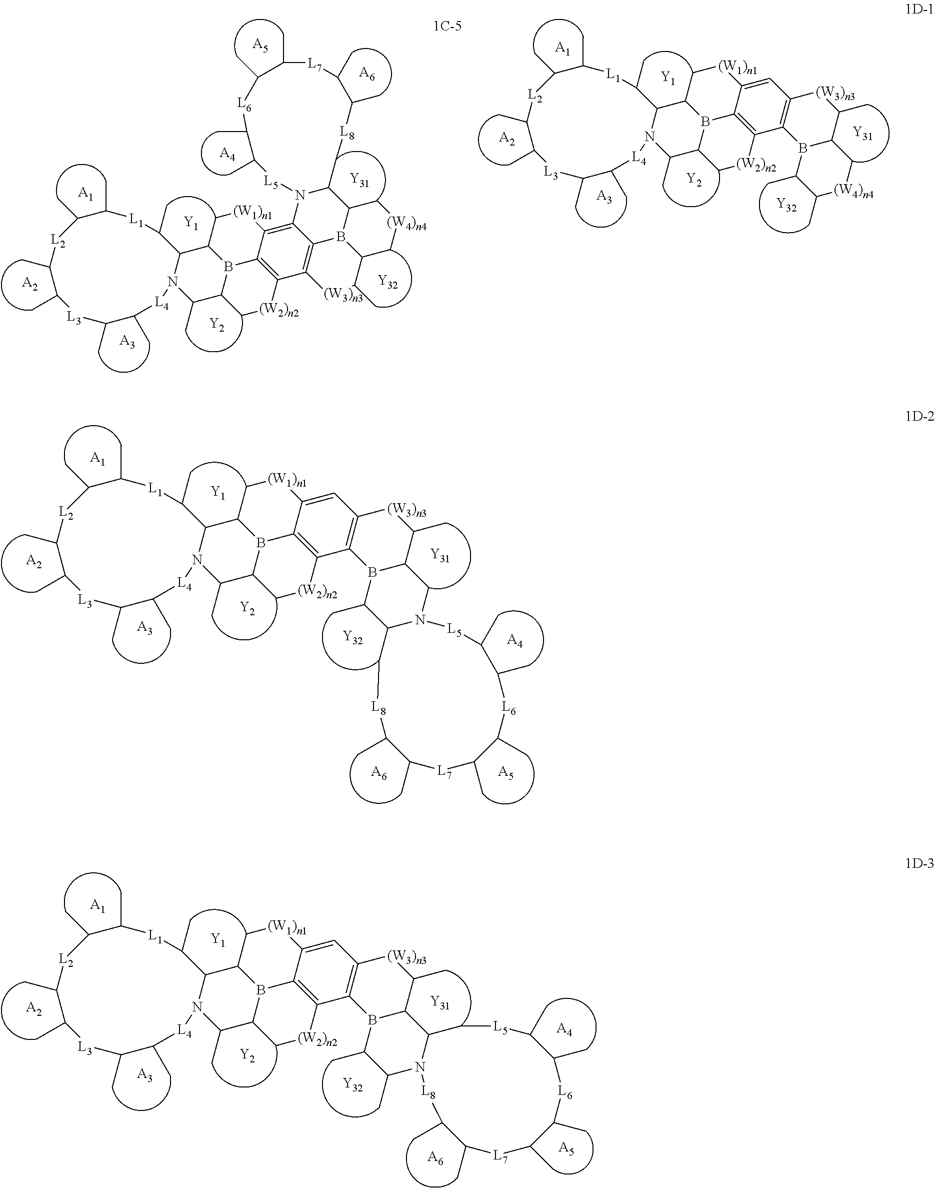

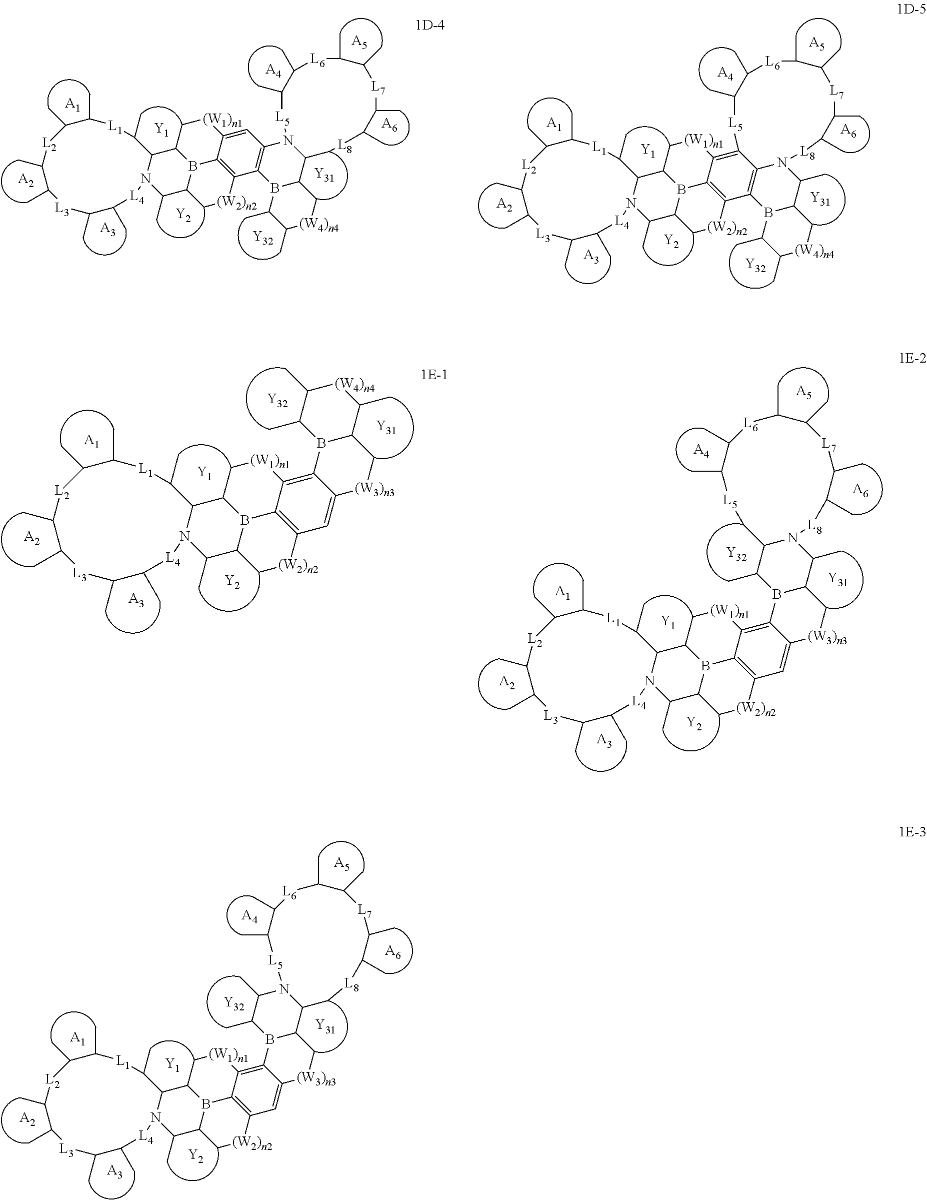

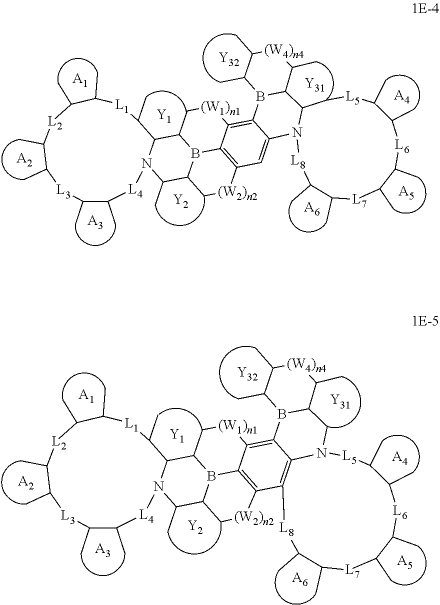

wherein, in Formulae 1A-1 to 1A-3, 1B-1 and 1B-2, 1C-1 to 1C-5, 1D-1 to 1D-5, and 1E-1 to 1E-5,
the definition for each of rings A₁ to ring A₃, rings Y₁ to ring Y₃, L₁ to L₄, W₁, W₂, n1 and n2 is as described herein,
the definition for each of ring A₄ to ring A₆ is the same as the definition for ring A₁,
the definition for each of L₅ to L₈ is the same as the definition for L₁, and at least one of L₅ to L₈ is not a single bond,
the definition for each of ring Y₃₁ and ring Y₃₂ is the same as the definition for ring Y₃,
W₃ may be a single bond, O, S, N(T₃₁), C(T₃₁)(T₃₂), or Si(T₃₁)(T₃₂),
W₄ may be a single bond, O, S, N(T₄₁), C(T₄₁)(T₄₂), or Si(T₄₁)(T₄₂),
W₅ may be a single bond, O, S, N(T₅₁), C(T₅₁)(T₅₂), or Si(T₅₁)(T₅₂),
each of T₃₁, T₃₂, T₄₁, T₄₂, T₅₁, and T₅₂ may be i) the same as the definition for Z₁ above, or ii) connected to an adjacent substituent to form the first condensed ring,
n3 to n5 may each independently be 0 or 1,
when n3 is 0, *—(W₃)ₙ₃—*′ does not exist,
when n4 is 0, *—(W₄)ₙ₄—*′ does not exist,
when n5 is 0, *—(W₅)ₙ₅—*′ does not exist,
the sum of n3, n4, and n5 in Formula 1C-1 may be 2 or more,
the sum of n4 and n5 in Formula 1C-2 may be 1 or more,
the sum of n3 and n5 in Formulae 1C-3 and 1C-4 may be 1 or more,
the sum of n3 and n4 in Formulae 1C-5, 1 D-1 and 1E-1 may be 1 or more,
n3 in Formulae 1 D-2, 1 D-3, 1E-2, and 1E-3 may be 1, and
n4 in Formulae 1 D-4, 1 D-5, 1E-4 and 1E-5 may be 1.

According to an embodiment, the condensed cyclic compound represented by Formula 1 may have an asymmetric structure with respect to the line connecting B and ring Y₂ in Formula 1.

According to an embodiment, the condensed cyclic compound represented by Formula 1 may have a symmetric structure with respect to the line connecting B and ring Y₂ in Formula 1.

The term “N-carbazolyl group” as used herein refers to a monovalent group in which hydrogen is separated from N of the carbazole group and may be combined with another group, and is represented by

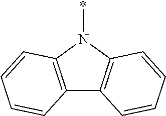 [SMILES: *n1c2ccccc2c2ccccc21]

(where * is a binding site to a neighboring atom).

Various backbones, such as Formulae 1A-1 to 1A-3, 1B-1 and 1B-2, 1C-1 to 1C-5, 1 D-1 to 1 D-5, and 1E-1 to 1E-5, may be unsubstituted or substituted with R₁ to R₃ and Z₁ to Z₃ as described herein according to the definition for Formula 1.

According to an embodiment, the condensed cyclic compound may be one of Compounds 1 to 189:

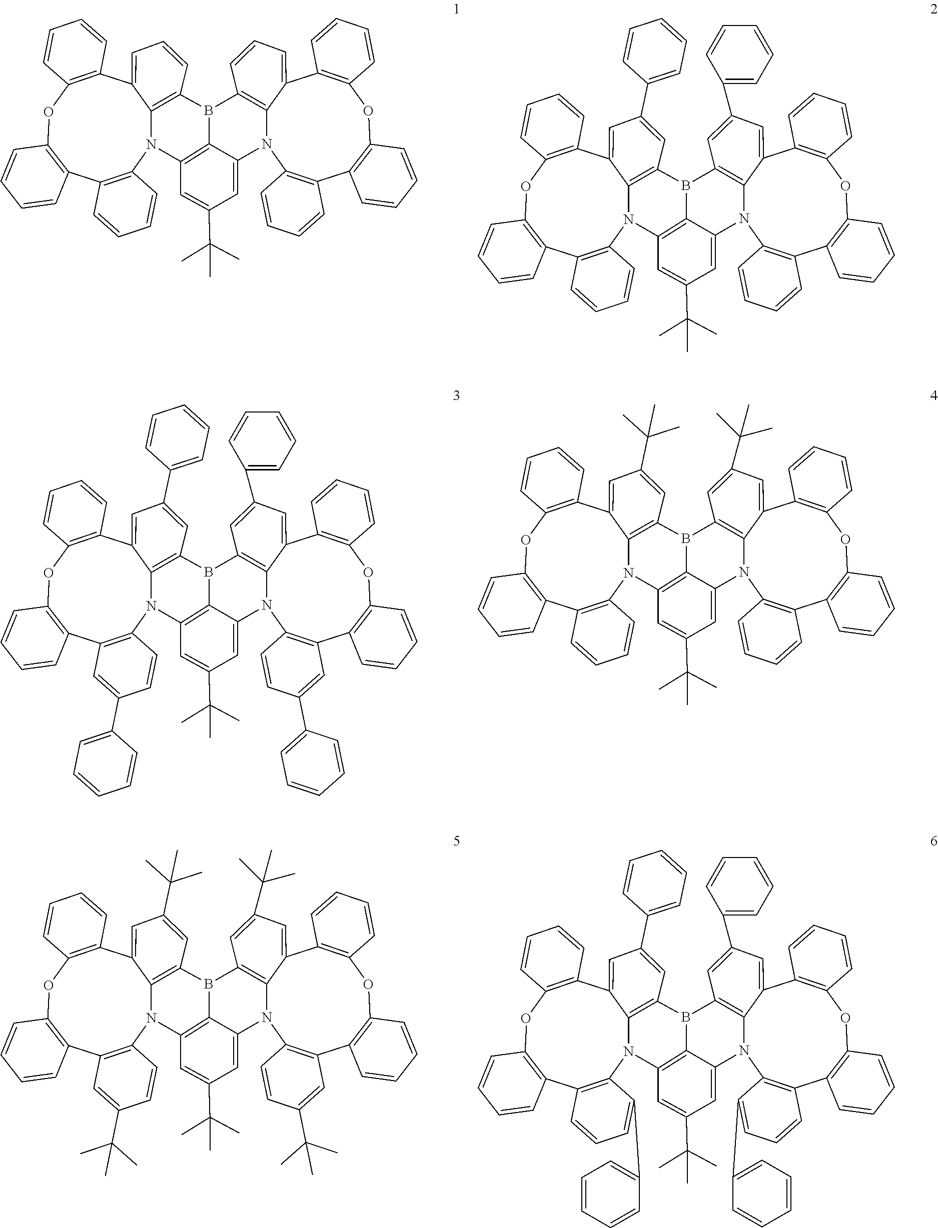

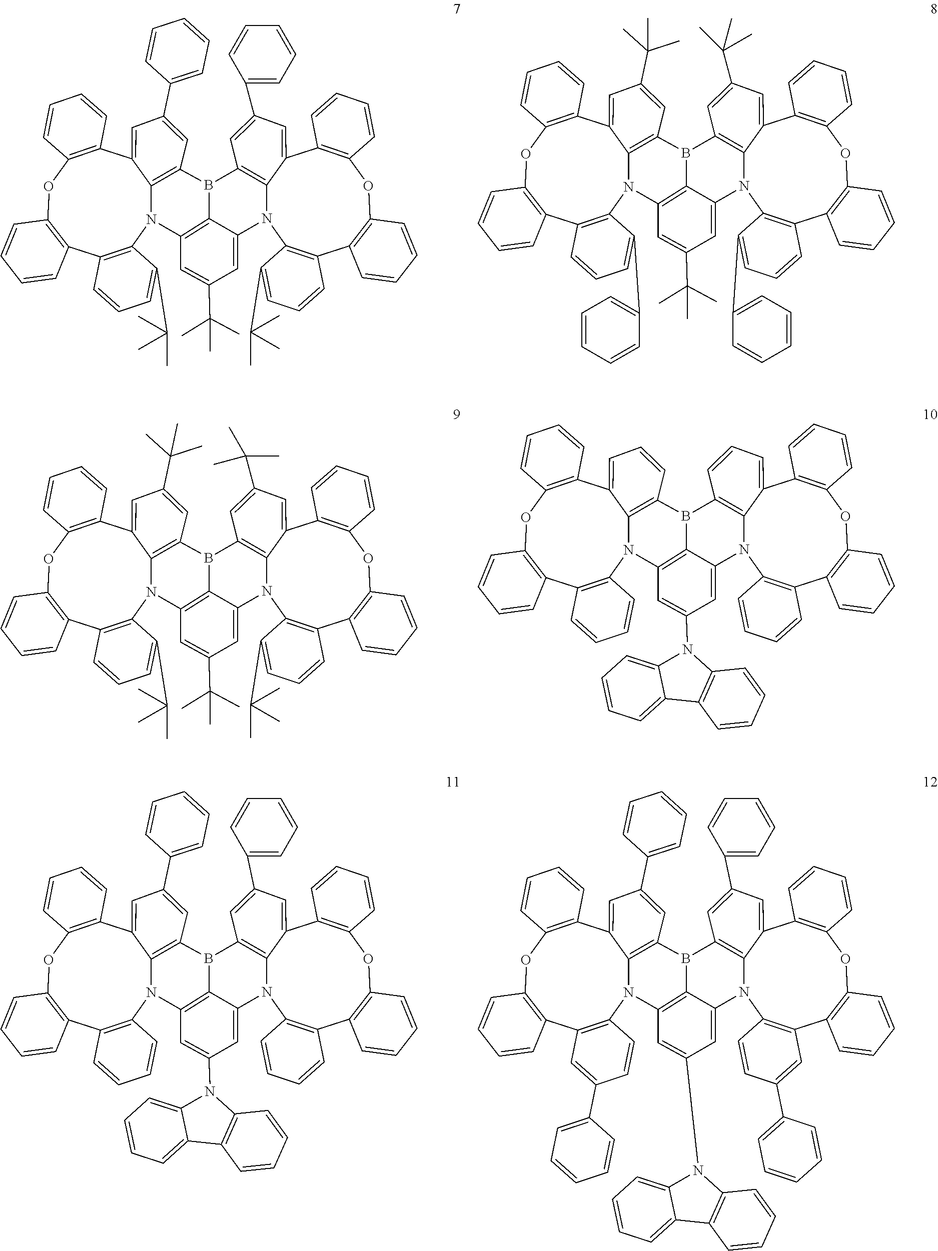

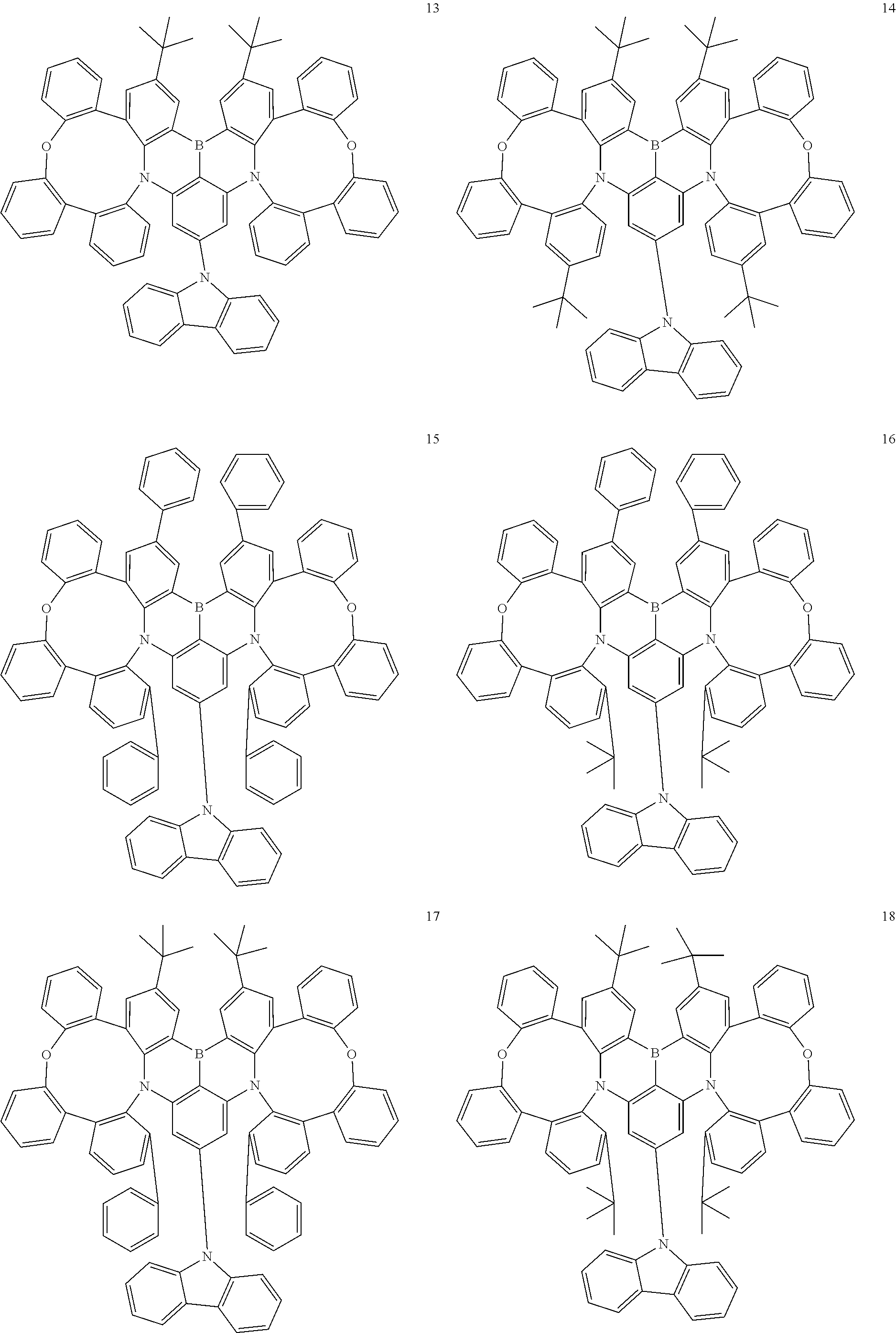

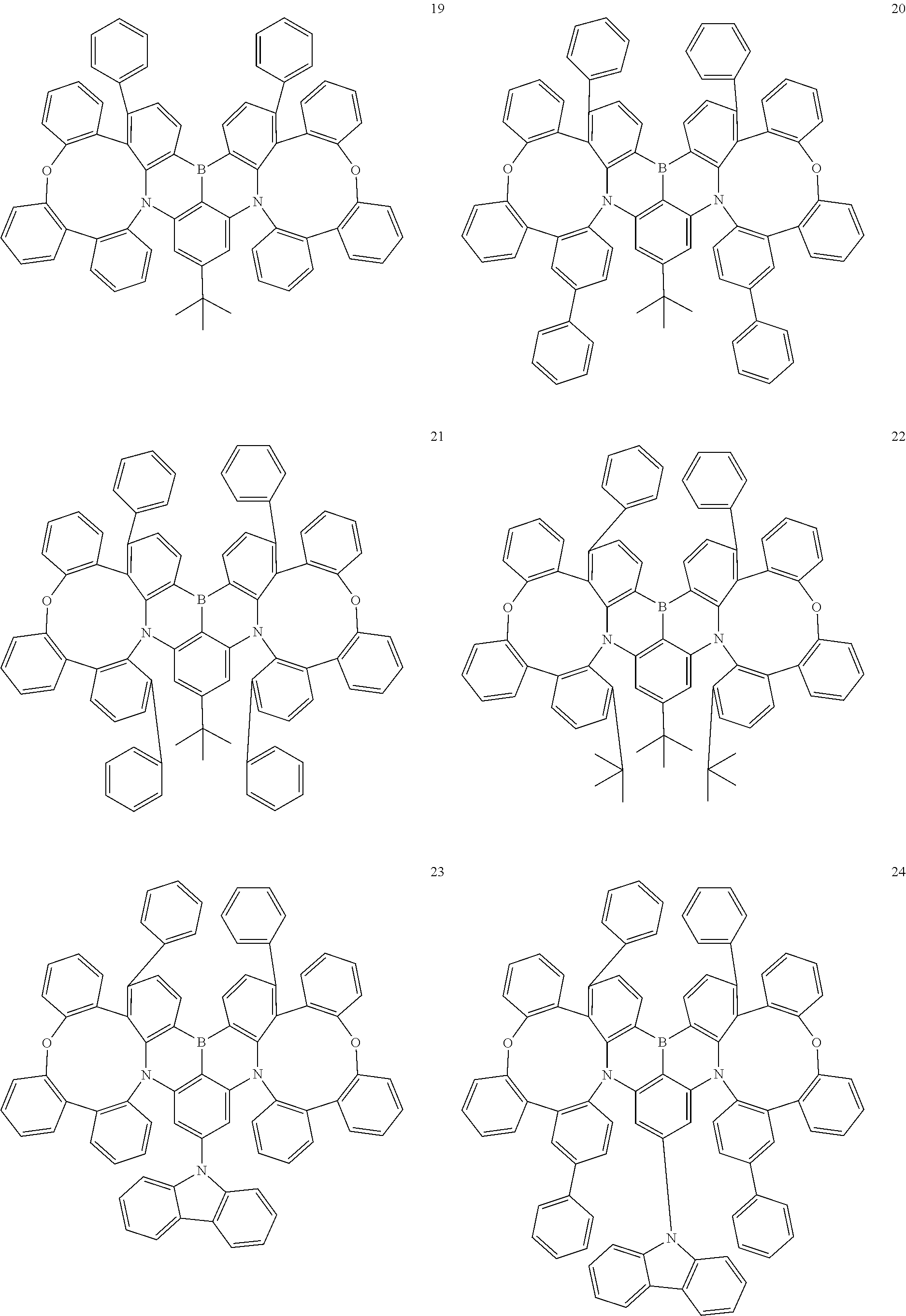

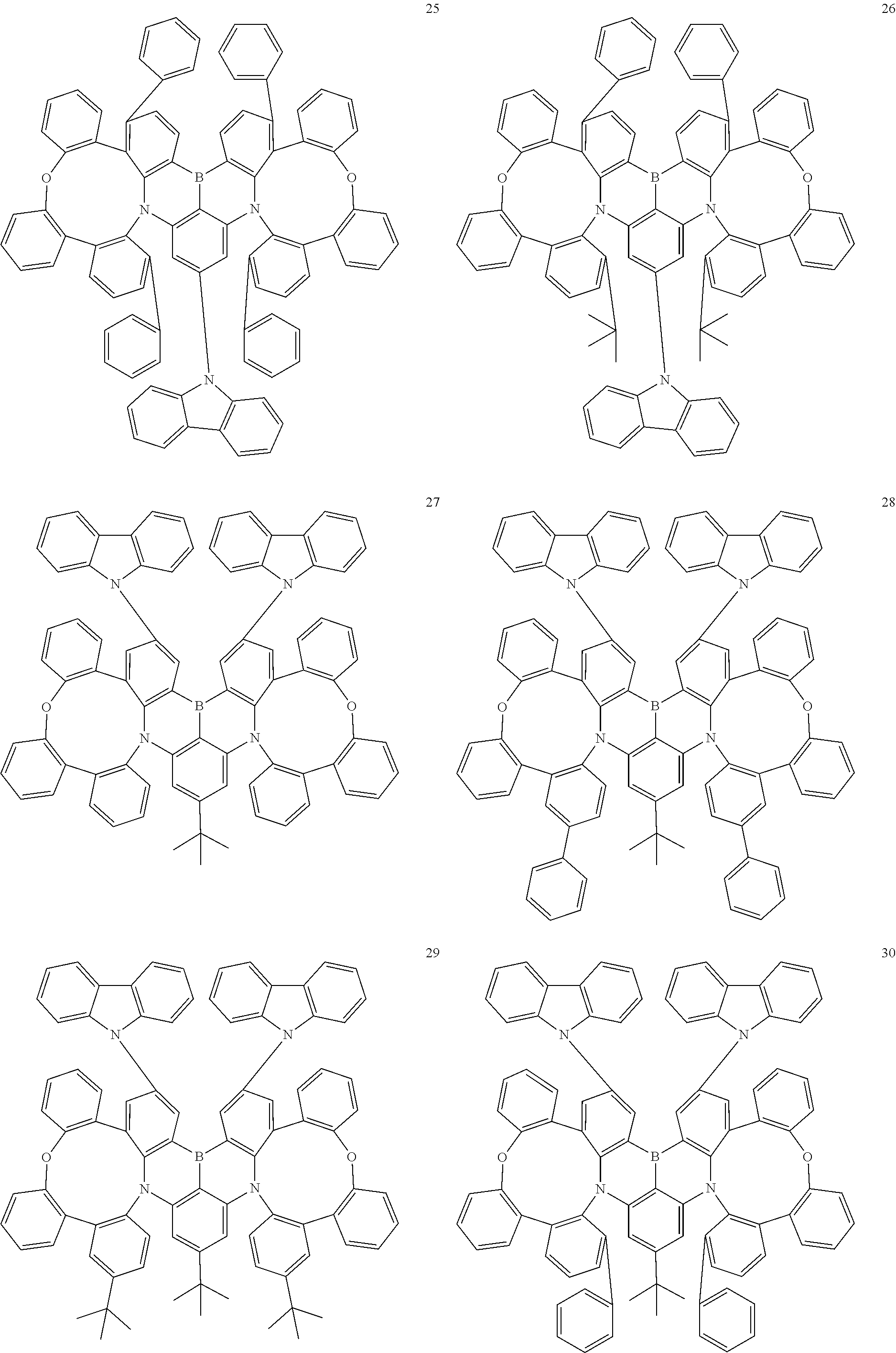

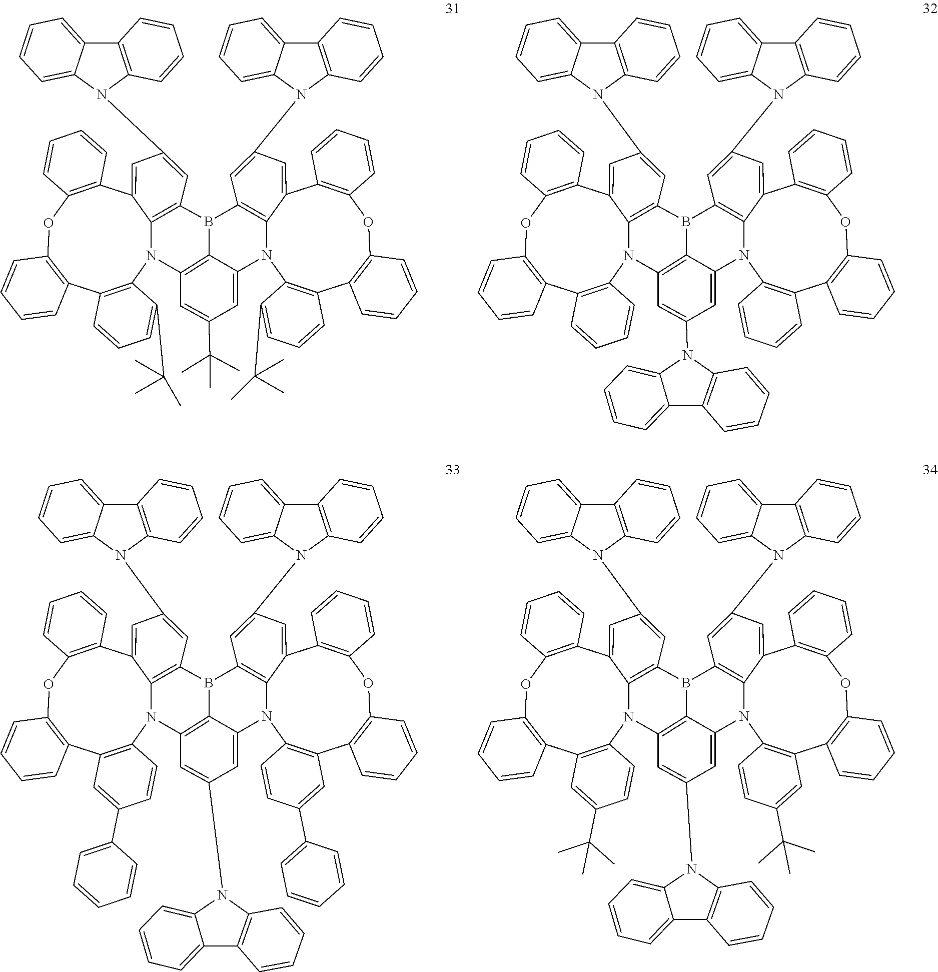

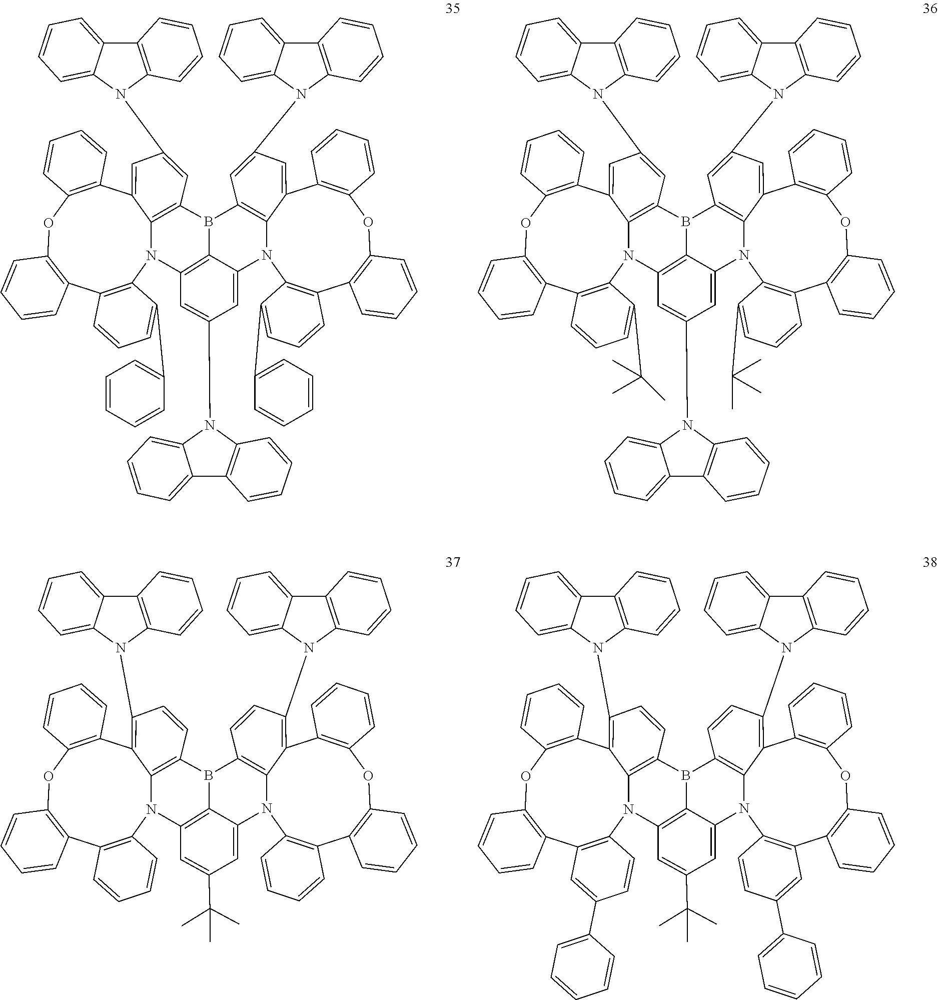

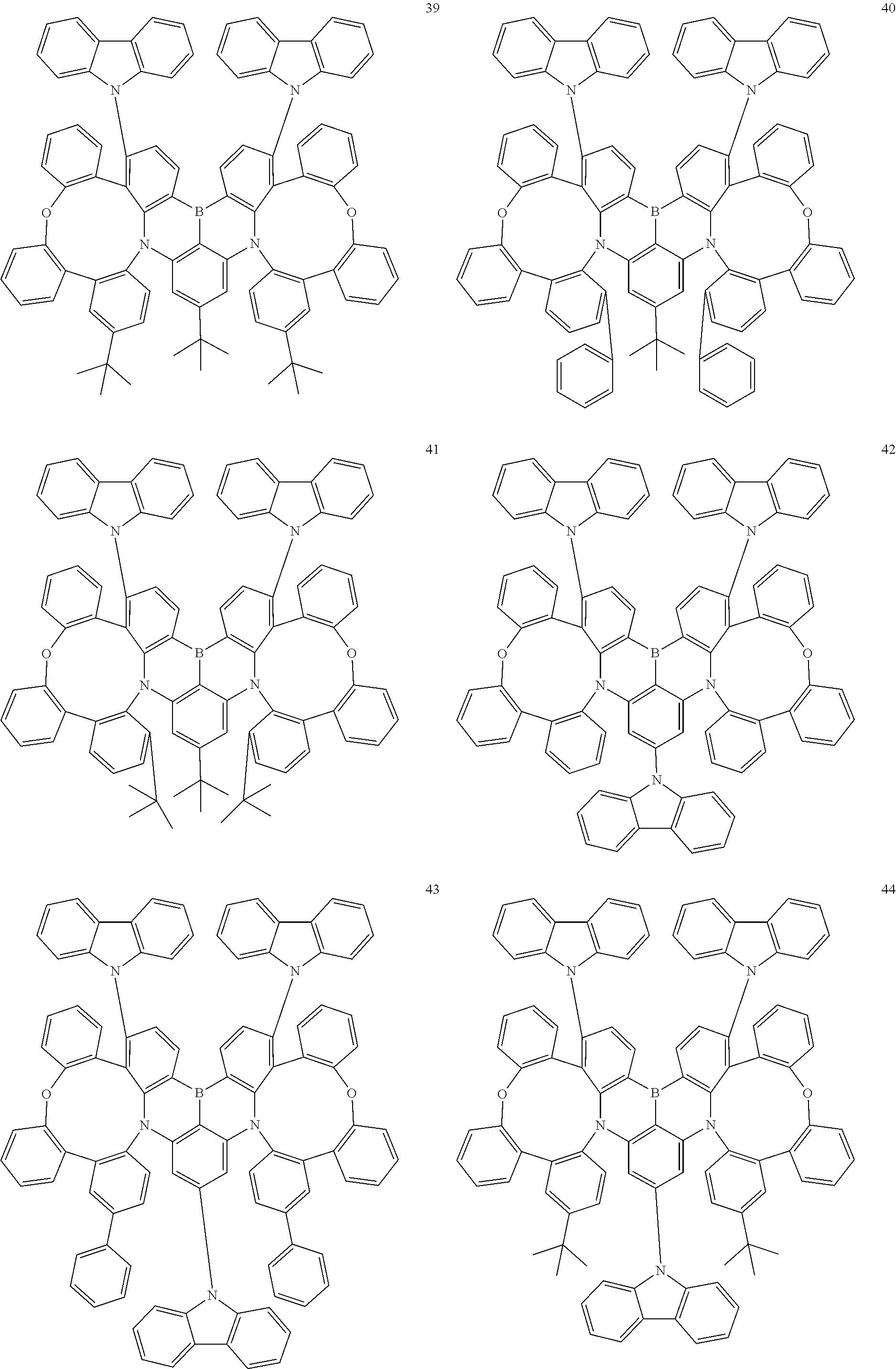

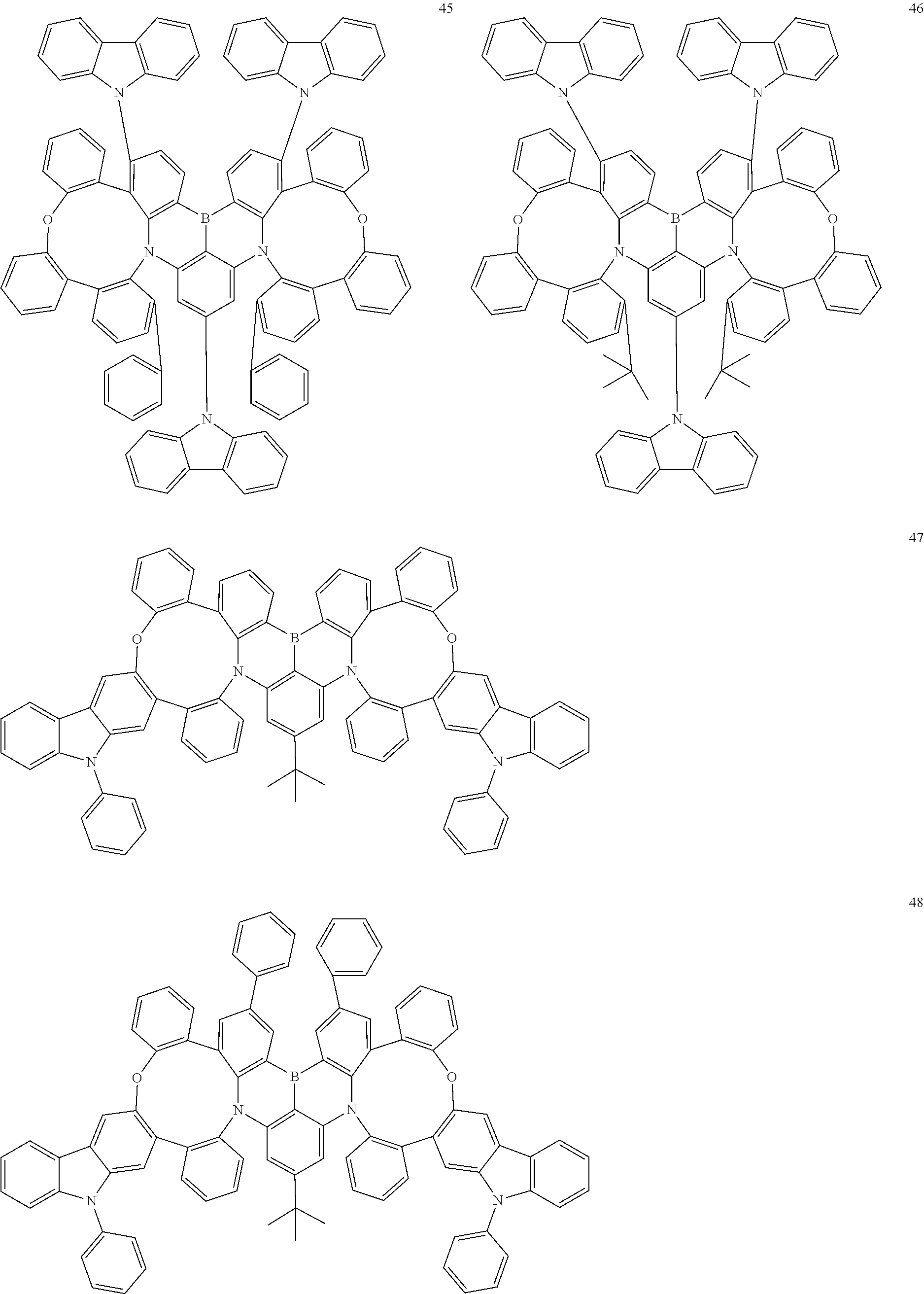

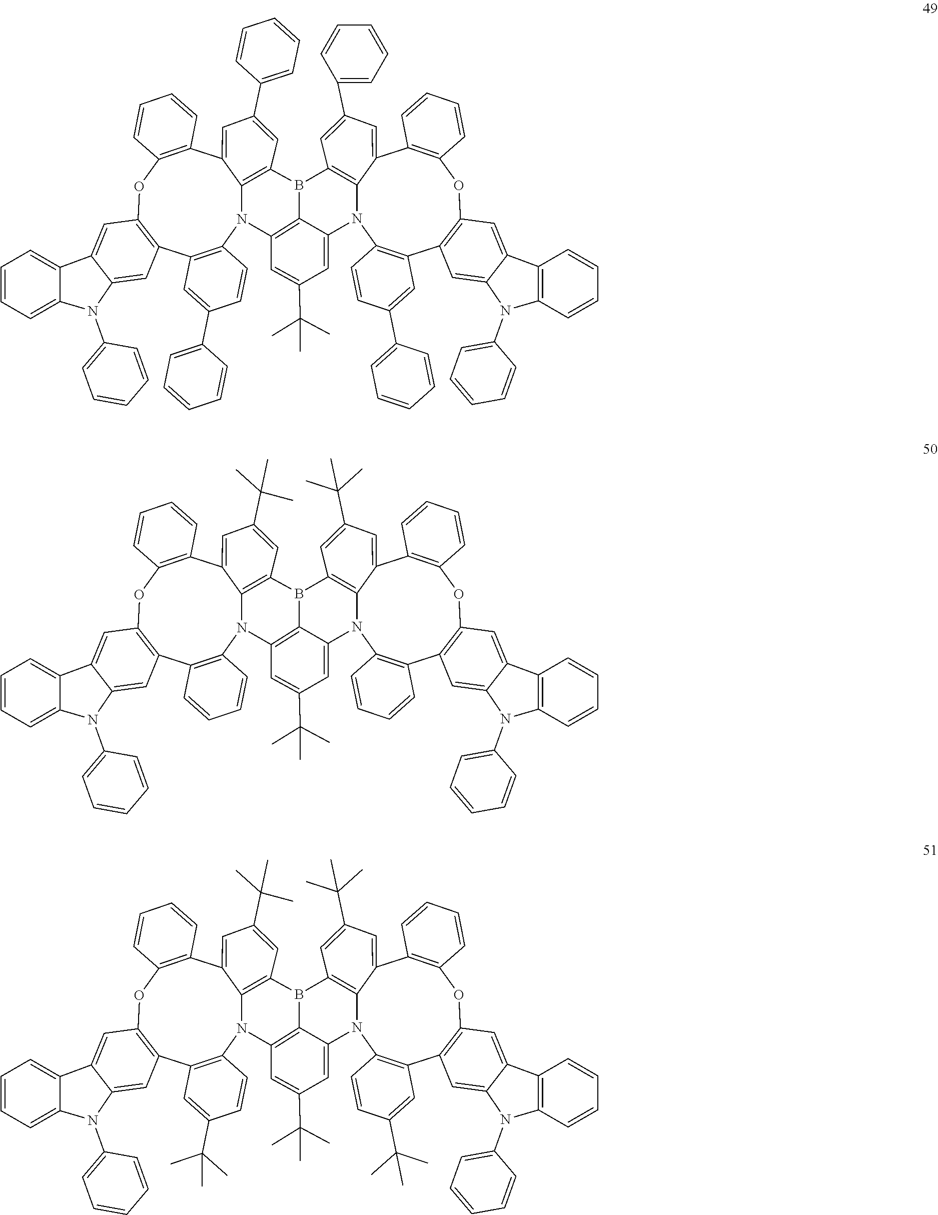

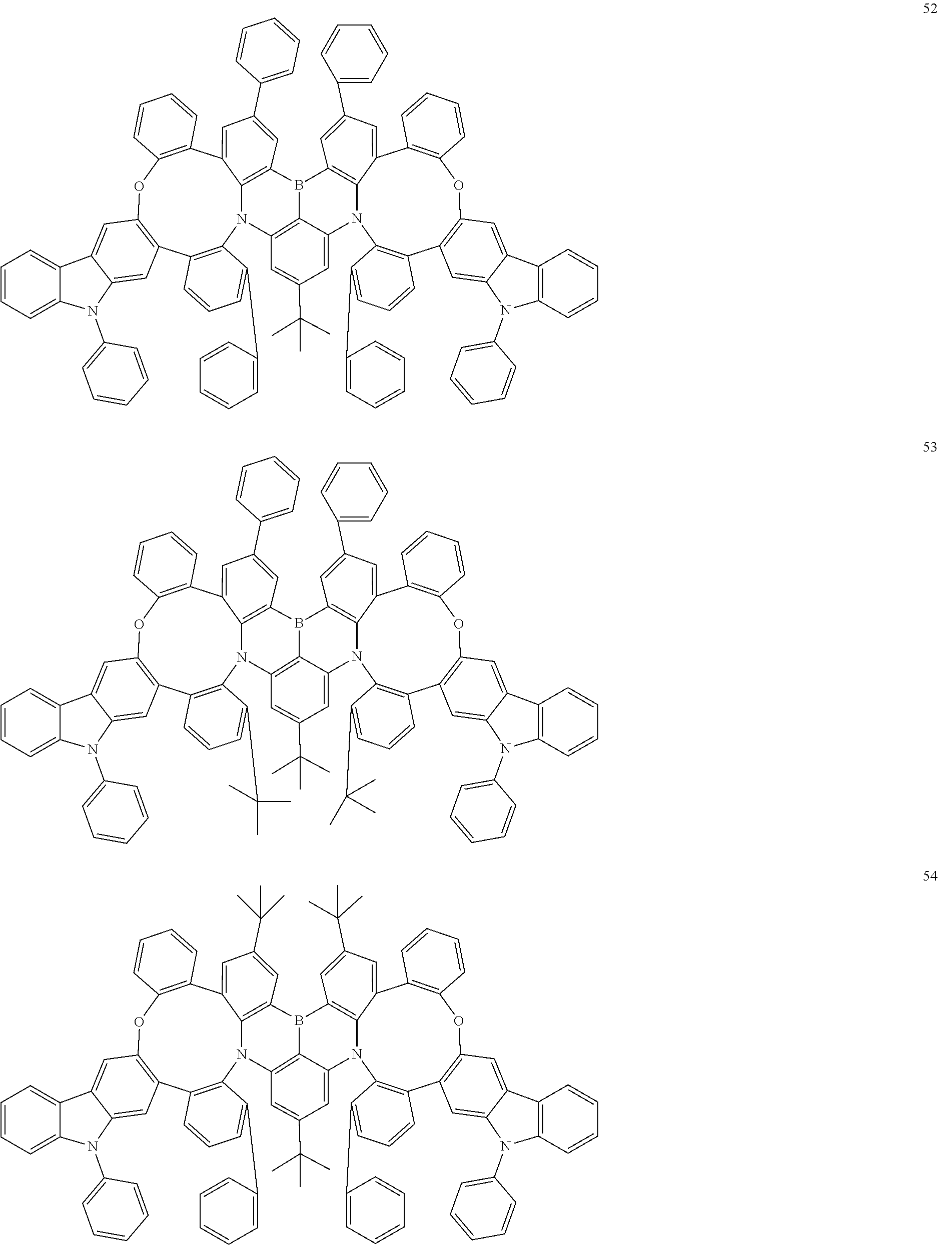

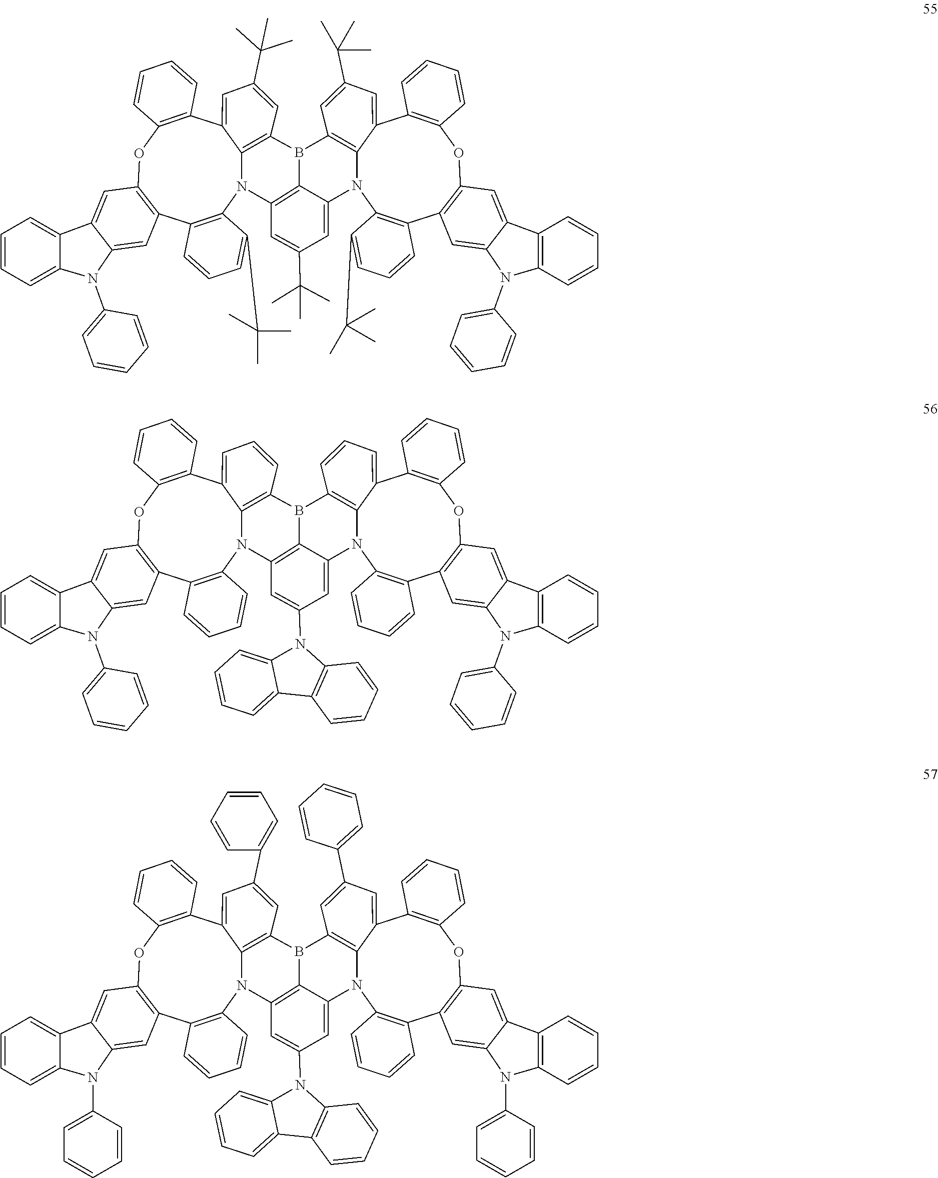

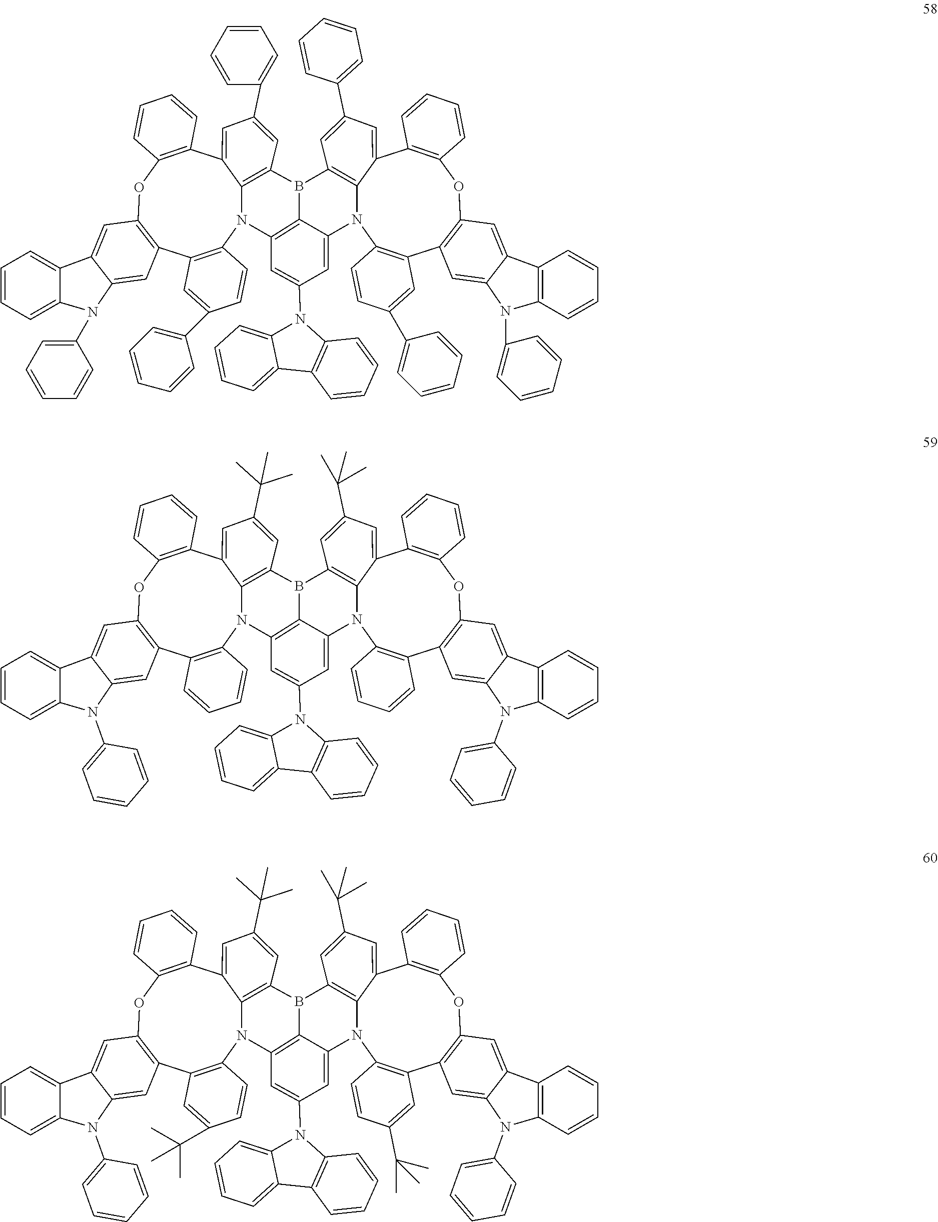

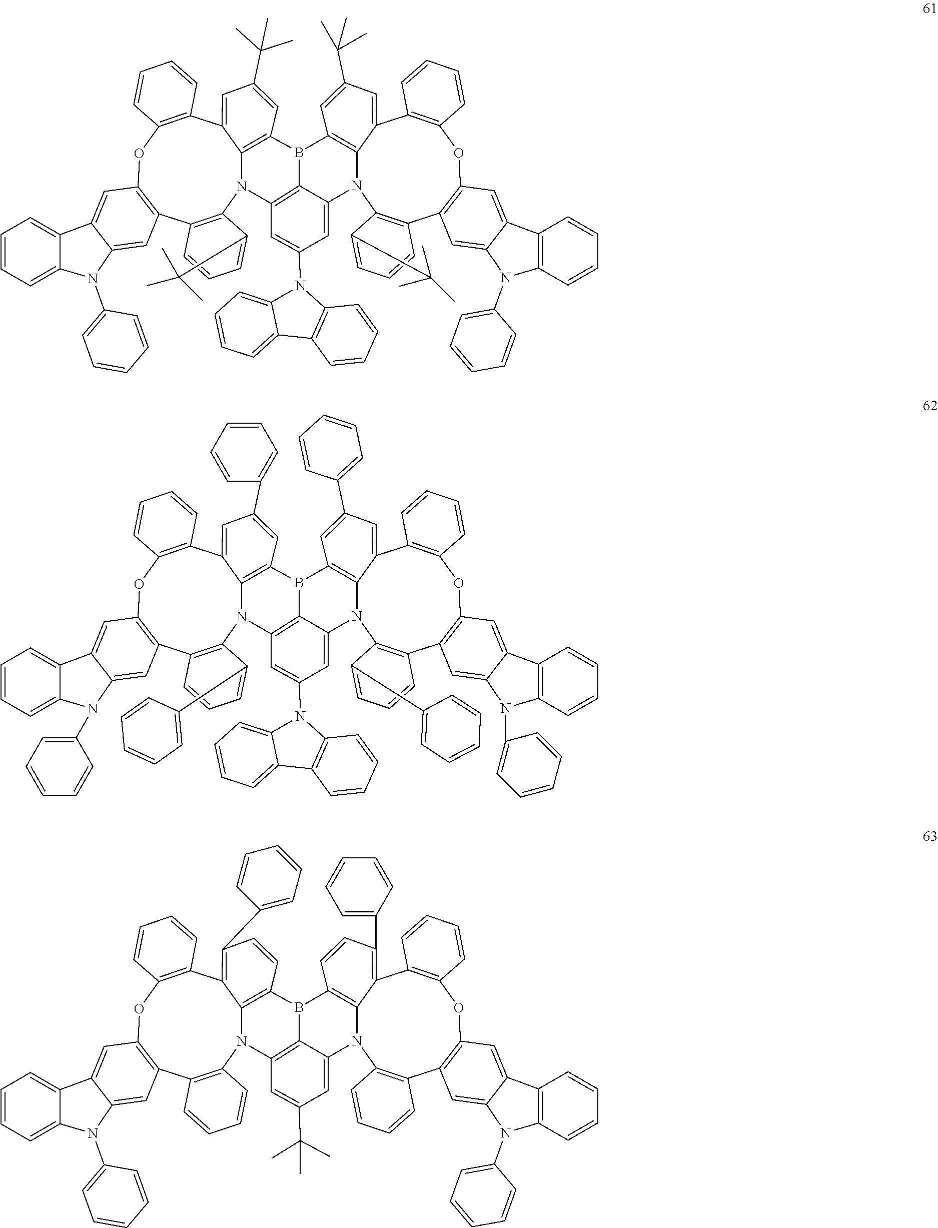

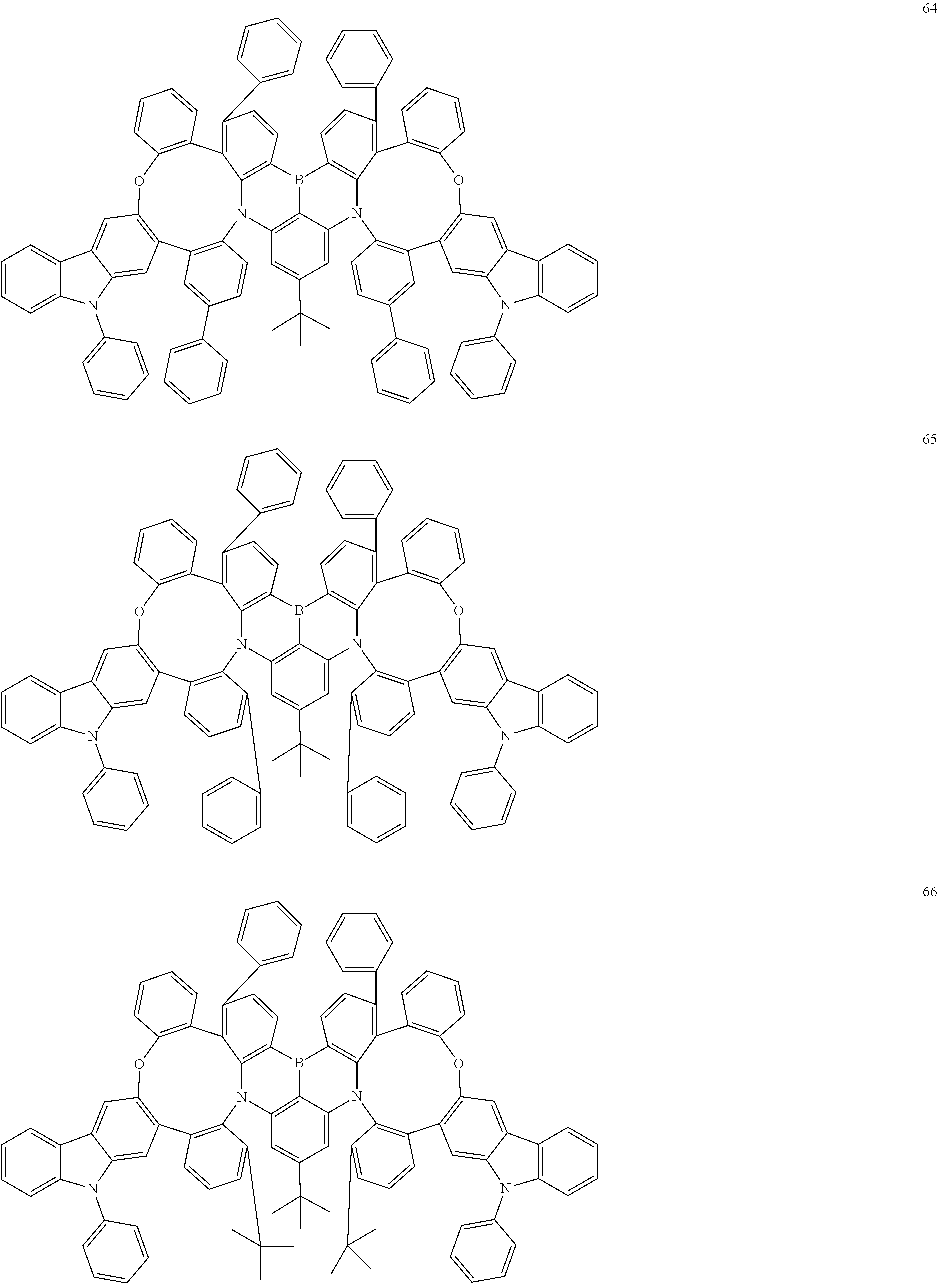

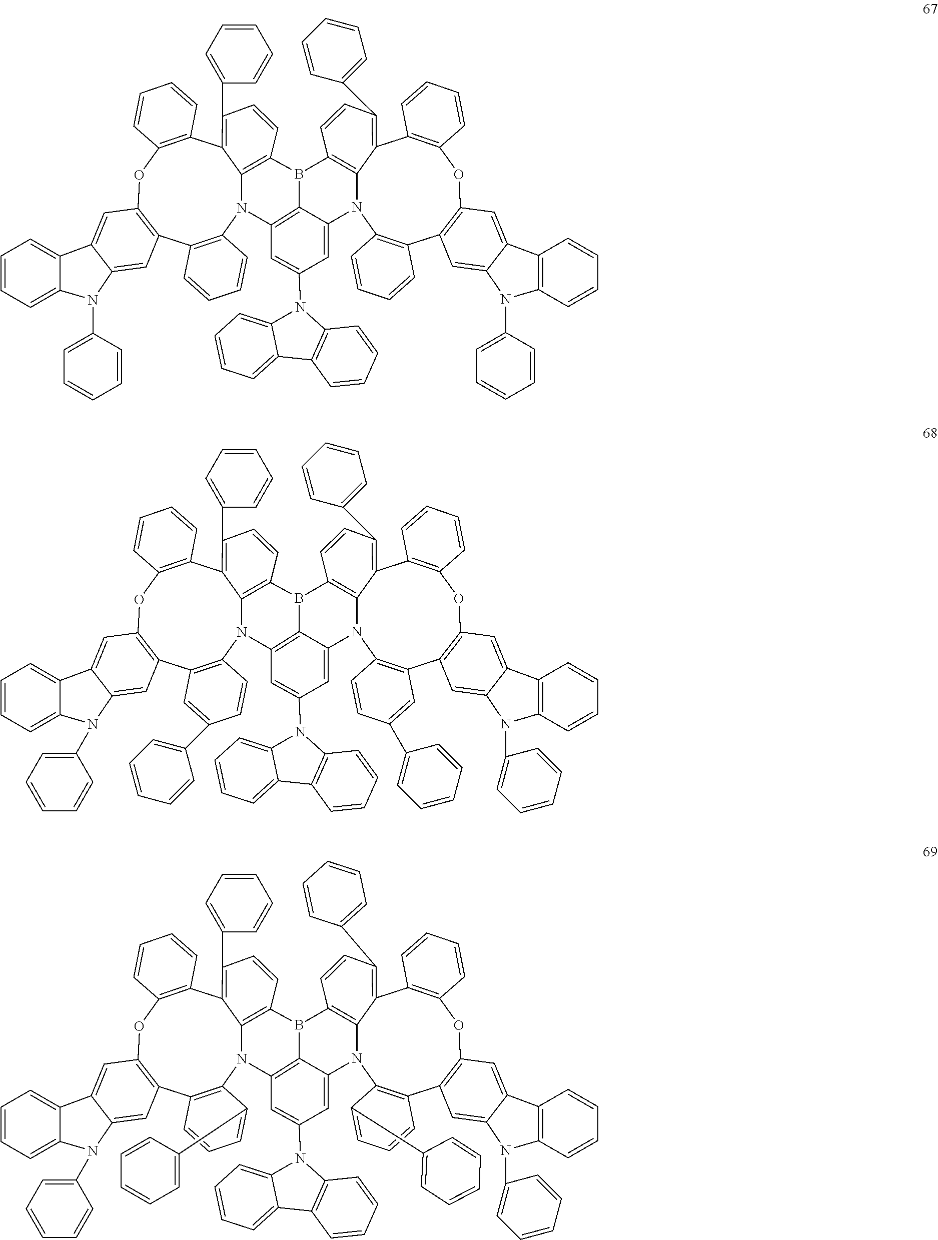

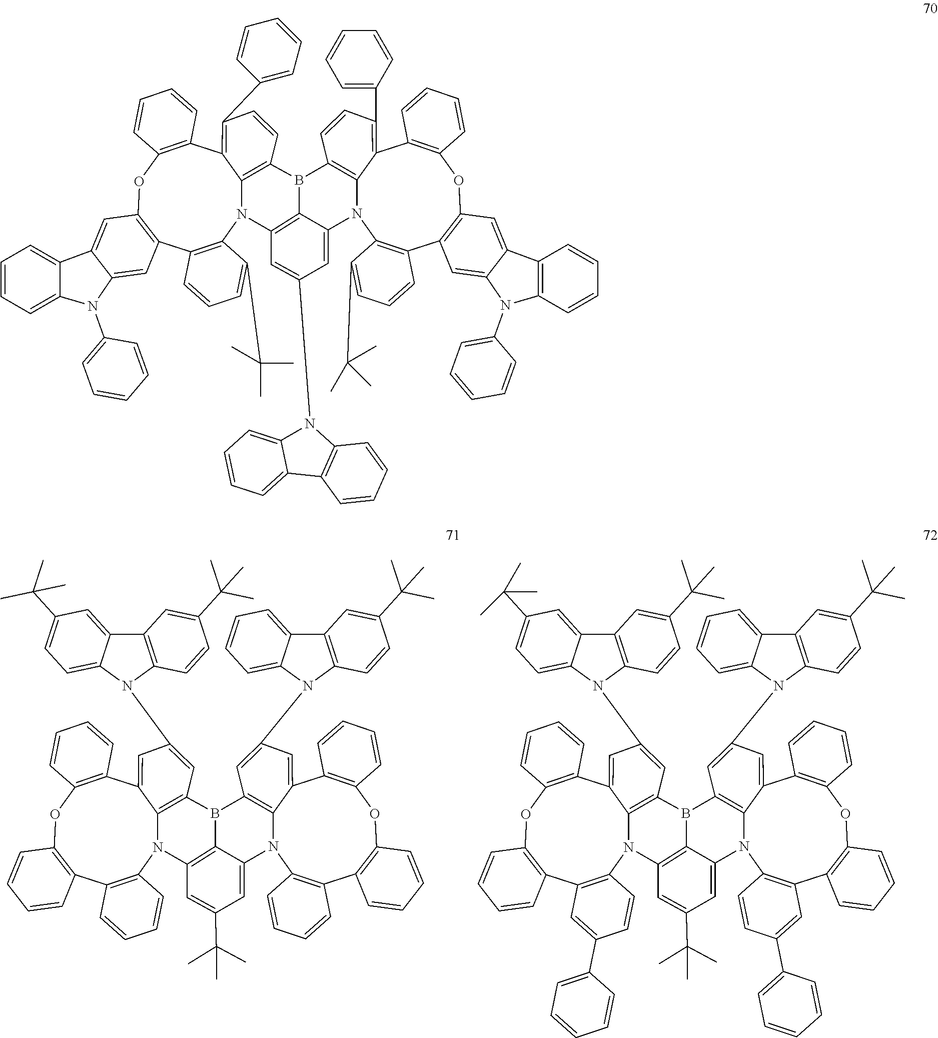

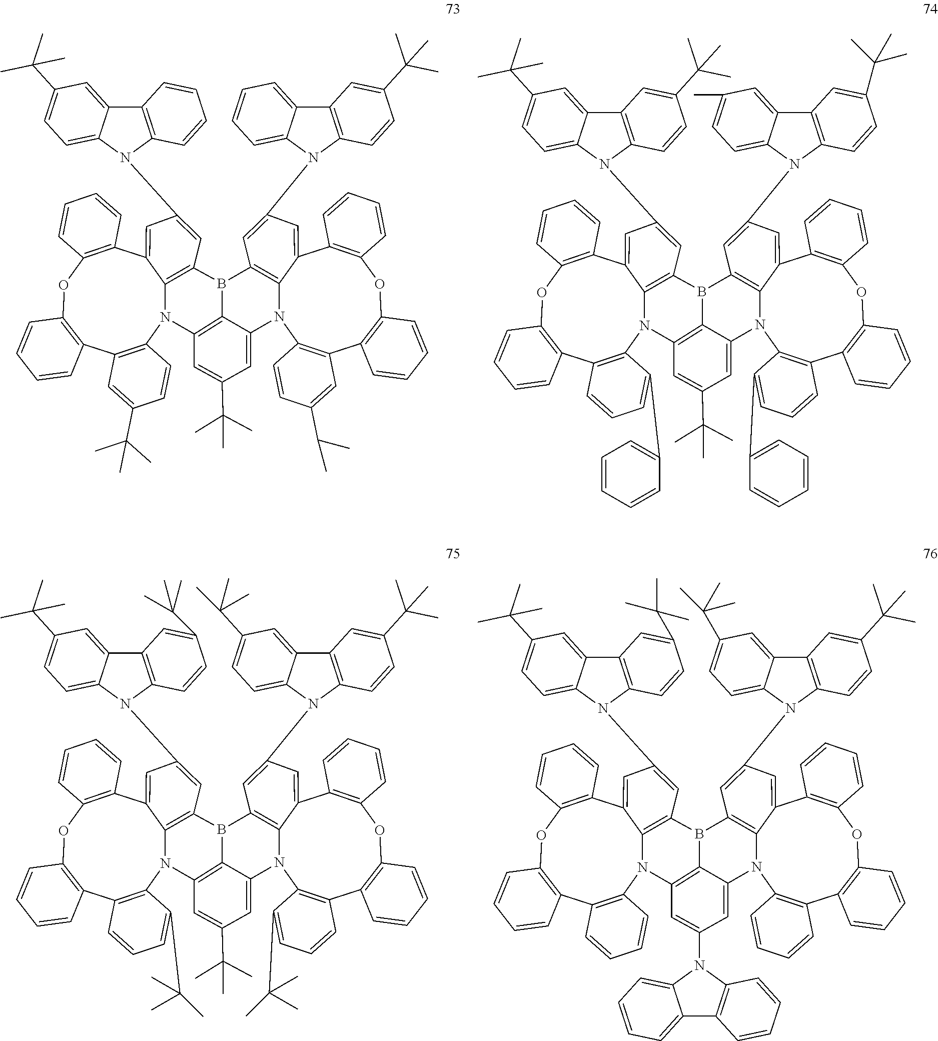

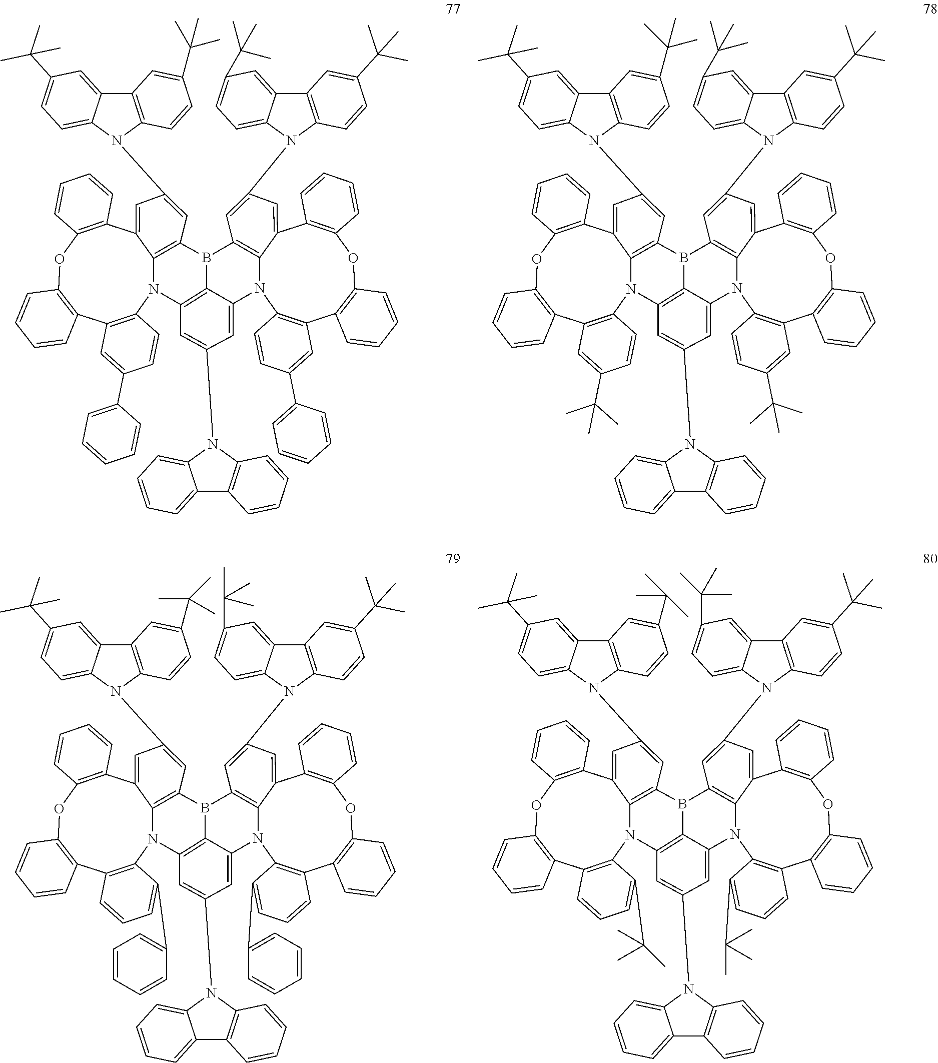

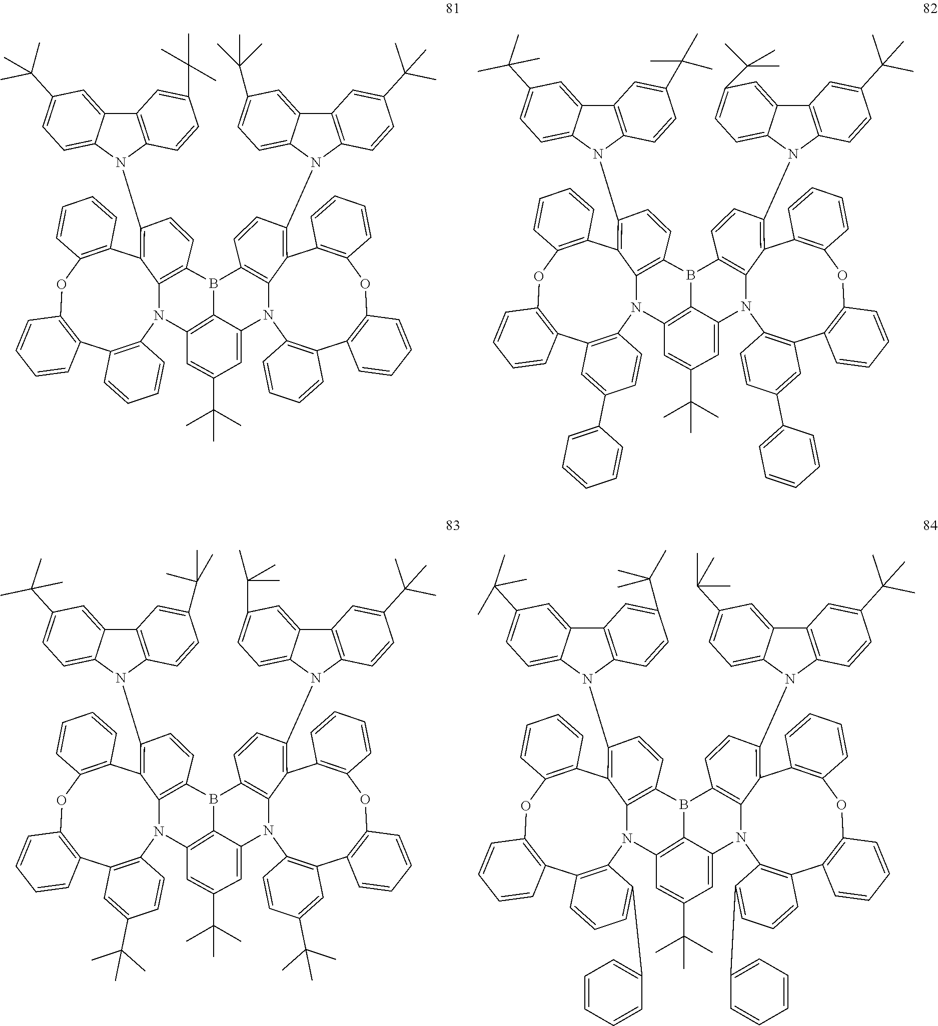

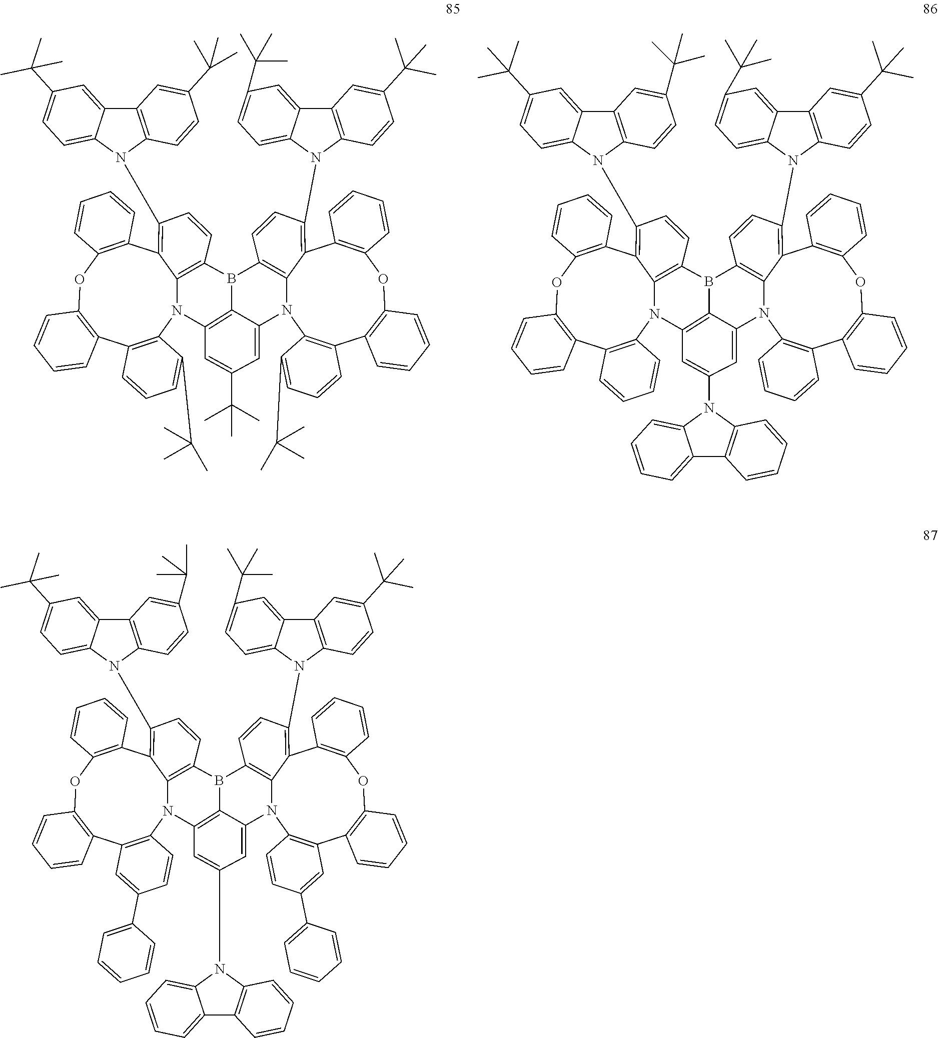

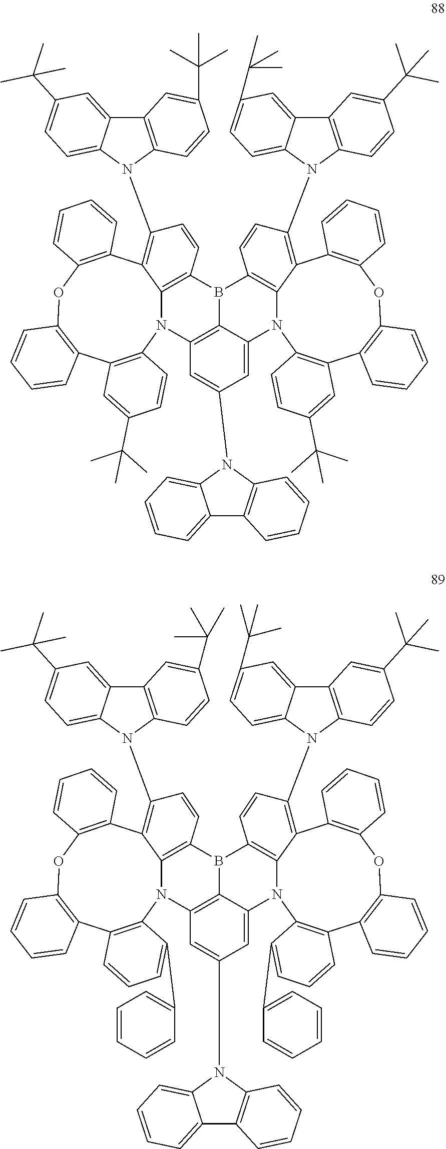

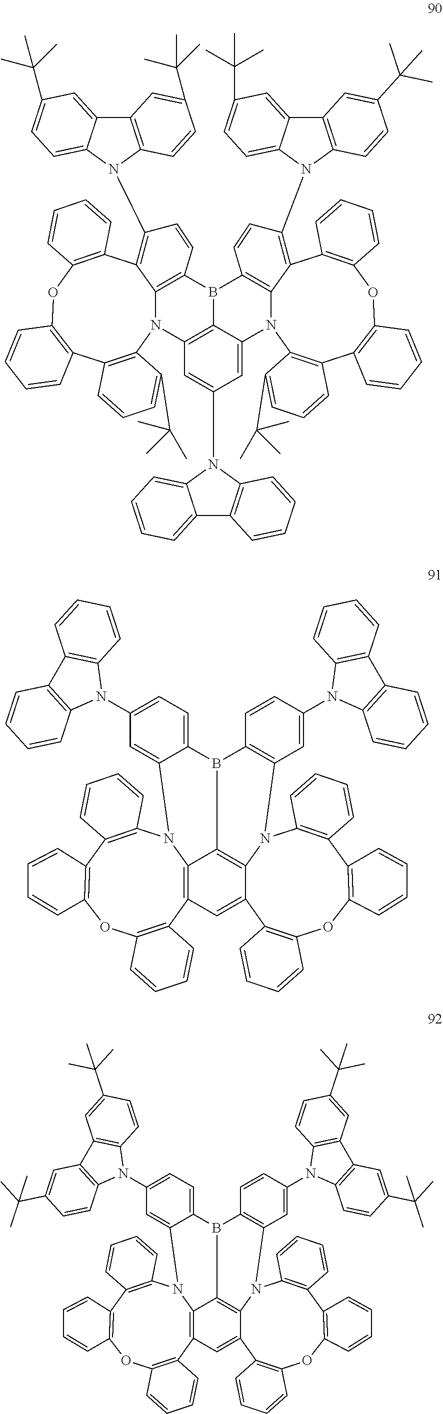

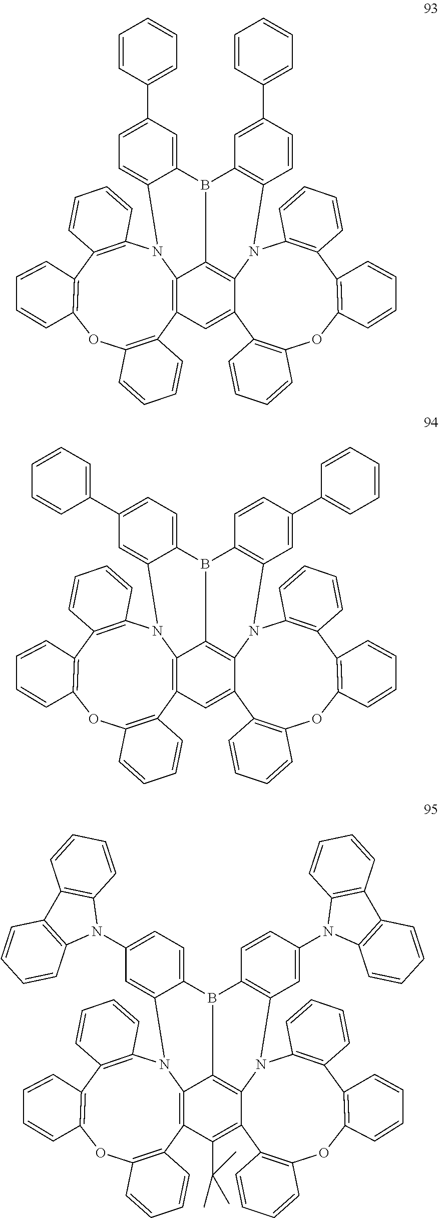 [SMILES: c1ccc(-c2ccc3c(c2)B2c4cc(-c5ccccc5)ccc4N4c5ccccc5-c5ccccc5Oc5ccccc5-c5cc6c(c2c54)N3c2ccccc2-c2ccccc2Oc2ccccc2-6)cc1 ; c1ccc(-c2ccc3c(c2)N2c4ccccc4-c4ccccc4Oc4ccccc4-c4cc5c6c(c42)B3c2ccc(-c3ccccc3)cc2N6c2ccccc2-c2ccccc2Oc2ccccc2-5)cc1 ; CC(C)(C)c1c2c3c4c5c1-c1ccccc1Oc1ccccc1-c1ccccc1N5c1cc(-n5c6ccccc6c6ccccc65)ccc1B4c1ccc(-n4c5ccccc5c5ccccc54)cc1N3c1ccccc1-c1ccccc1Oc1ccccc1-2]

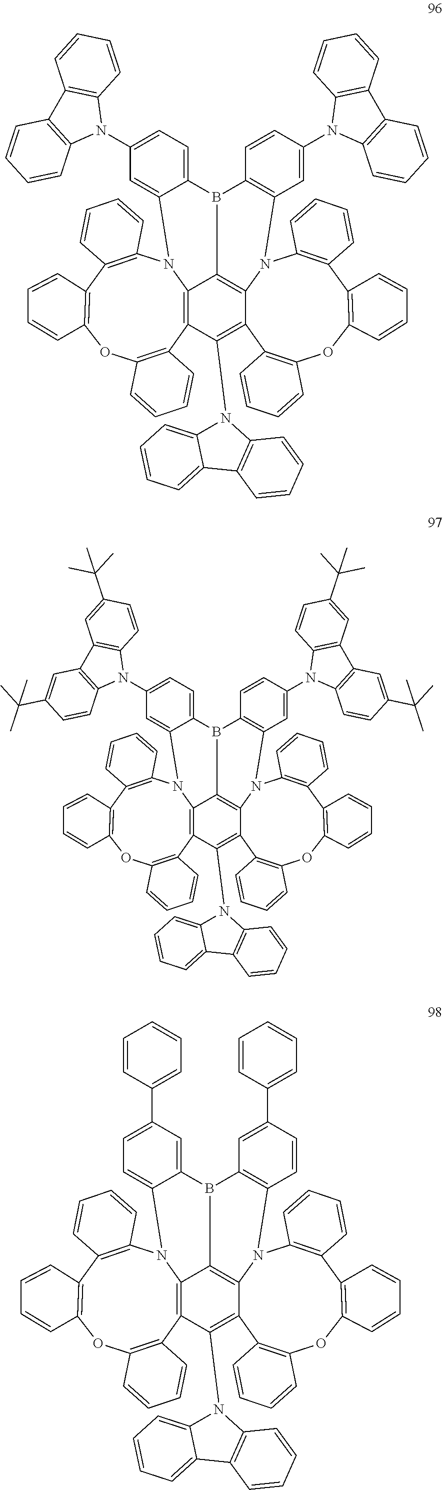 [SMILES: c1ccc2c(c1)Oc1ccccc1-c1c3c4c5c(c1-n1c6ccccc6c6ccccc61)-c1ccccc1Oc1ccccc1-c1ccccc1N5c1cc(-n5c6ccccc6c6ccccc65)ccc1B4c1ccc(-n4c5ccccc5c5ccccc54)cc1N3c1ccccc1-2 ; CC(C)(C)c1ccc2c(c1)c1cc(C(C)(C)C)ccc1n2-c1ccc2c(c1)N1c3ccccc3-c3ccccc3Oc3ccccc3-c3c1c1c4c(c3-n3c5ccccc5c5ccccc53)-c3ccccc3Oc3ccccc3-c3ccccc3N4c3cc(-n4c5ccc(C(C)(C)C)cc5c5cc(C(C)(C)C)ccc54)ccc3B21 ; c1ccc(-c2ccc3c(c2)B2c4cc(-c5ccccc5)ccc4N4c5ccccc5-c5ccccc5Oc5ccccc5-c5c4c2c2c(c5-n4c5ccccc5c5ccccc54)-c4ccccc4Oc4ccccc4-c4ccccc4N32)cc1]

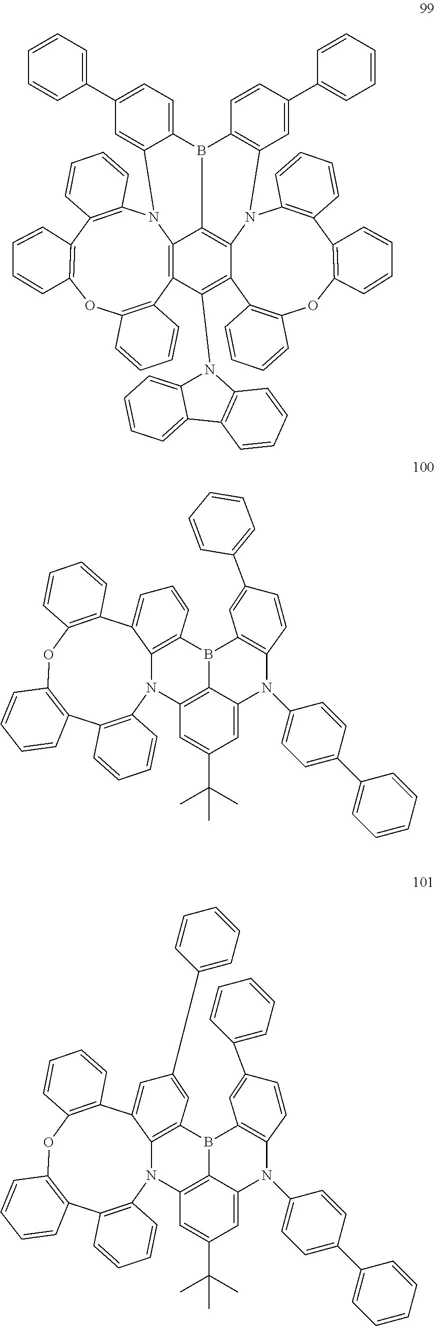 [SMILES: c1ccc(-c2ccc3c(c2)N2c4ccccc4-c4ccccc4Oc4ccccc4-c4c2c2c5c(c4-n4c6ccccc6c6ccccc64)-c4ccccc4Oc4ccccc4-c4ccccc4N5c4cc(-c5ccccc5)ccc4B32)cc1 ; CC(C)(C)c1cc2c3c(c1)N1c4ccccc4-c4ccccc4Oc4ccccc4-c4cccc(c41)B3c1cc(-c3ccccc3)ccc1N2c1ccc(-c2ccccc2)cc1 ; CC(C)(C)c1cc2c3c(c1)N1c4ccccc4-c4ccccc4Oc4ccccc4-c4cc(-c5ccccc5)cc(c41)B3c1cc(-c3ccccc3)ccc1N2c1ccc(-c2ccccc2)cc1]

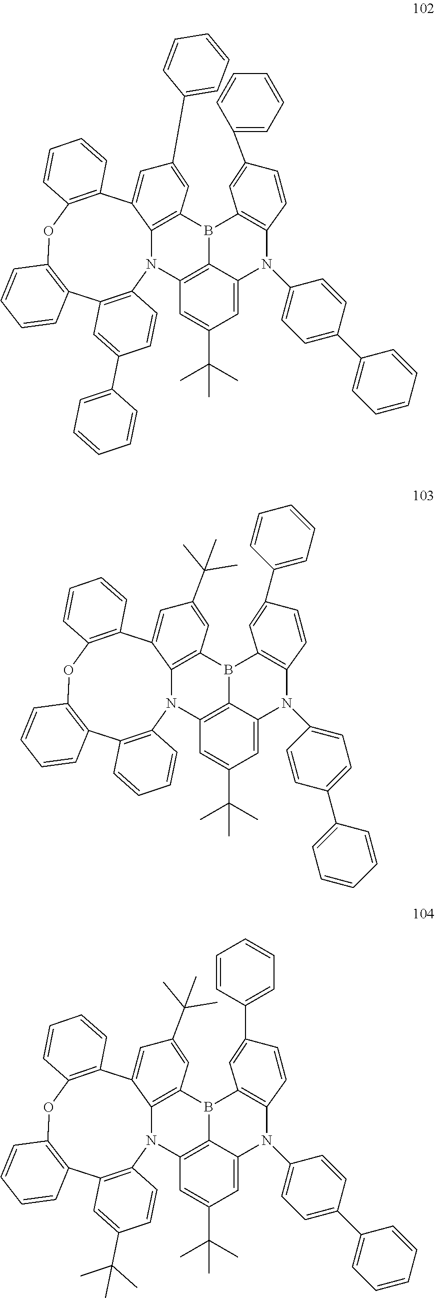 [SMILES: CC(C)(C)c1cc2c3c(c1)N1c4ccc(-c5ccccc5)cc4-c4ccccc4Oc4ccccc4-c4cc(-c5ccccc5)cc(c41)B3c1cc(-c3ccccc3)ccc1N2c1ccc(-c2ccccc2)cc1 ; CC(C)(C)c1cc2c3c(c1)-c1ccccc1Oc1ccccc1-c1ccccc1N3c1cc(C(C)(C)C)cc3c1B2c1cc(-c2ccccc2)ccc1N3c1ccc(-c2ccccc2)cc1 ; CC(C)(C)c1ccc2c(c1)-c1ccccc1Oc1ccccc1-c1cc(C(C)(C)C)cc3c1N2c1cc(C(C)(C)C)cc2c1B3c1cc(-c3ccccc3)ccc1N2c1ccc(-c2ccccc2)cc1]

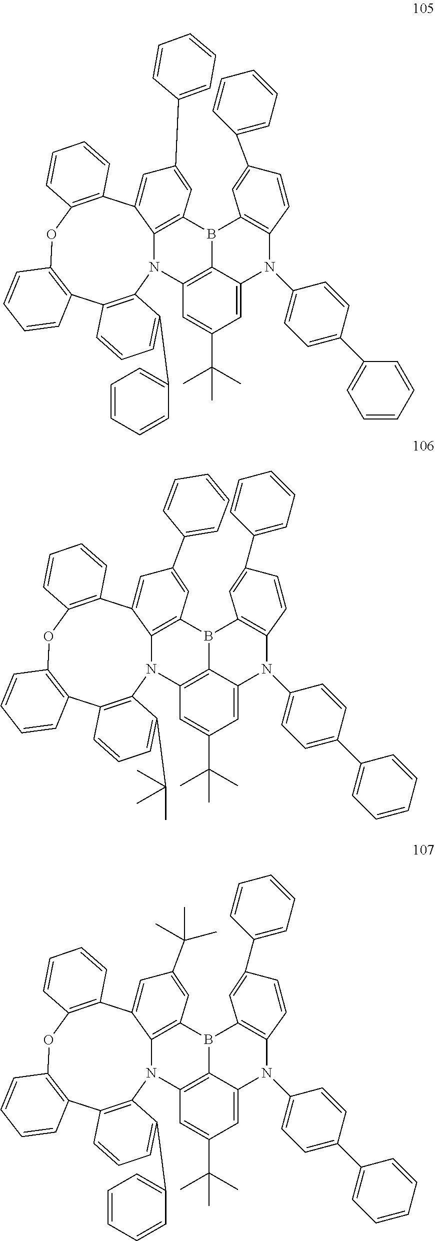 [SMILES: CC(C)(C)c1cc2c3c(c1)N1c4c(cc(-c5ccccc5)cc4-c4ccccc4Oc4ccccc4-c4cccc(-c5ccccc5)c41)B3c1cc(-c3ccccc3)ccc1N2c1ccc(-c2ccccc2)cc1 ; CC(C)(C)c1cc2c3c(c1)N1c4c(cc(-c5ccccc5)cc4-c4ccccc4Oc4ccccc4-c4cccc(C(C)(C)C)c41)B3c1cc(-c3ccccc3)ccc1N2c1ccc(-c2ccccc2)cc1 ; CC(C)(C)c1cc2c3c(c1)-c1ccccc1Oc1ccccc1-c1cccc(-c4ccccc4)c1N3c1cc(C(C)(C)C)cc3c1B2c1cc(-c2ccccc2)ccc1N3c1ccc(-c2ccccc2)cc1]

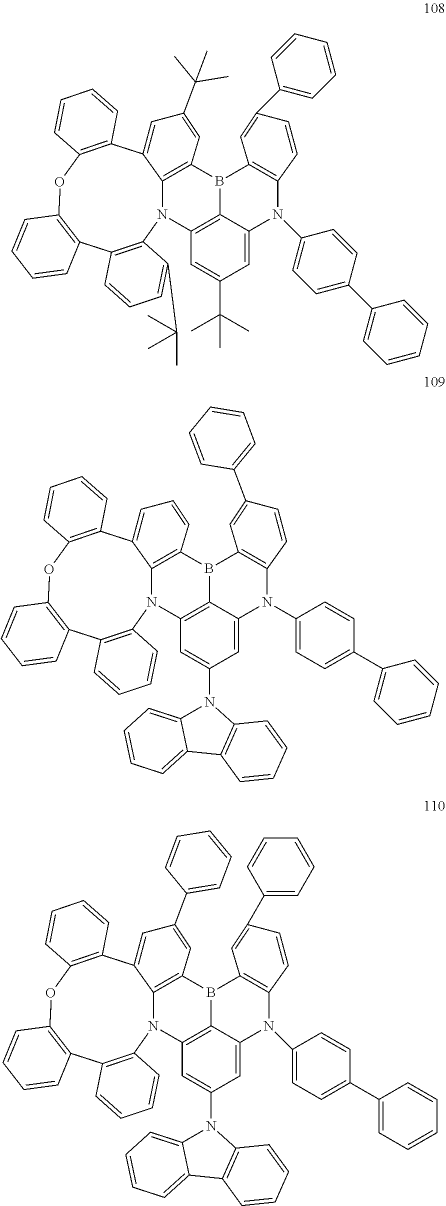 [SMILES: CC(C)(C)c1cc2c3c(c1)-c1ccccc1Oc1ccccc1-c1cccc(C(C)(C)C)c1N3c1cc(C(C)(C)C)cc3c1B2c1cc(-c2ccccc2)ccc1N3c1ccc(-c2ccccc2)cc1 ; c1ccc(-c2ccc(N3c4ccc(-c5ccccc5)cc4B4c5cccc6c5N(c5ccccc5-c5ccccc5Oc5ccccc5-6)c5cc(-n6c7ccccc7c7ccccc76)cc3c54)cc2)cc1 ; c1ccc(-c2ccc(N3c4ccc(-c5ccccc5)cc4B4c5cc(-c6ccccc6)cc6c5N(c5ccccc5-c5ccccc5Oc5ccccc5-6)c5cc(-n6c7ccccc7c7ccccc76)cc3c54)cc2)cc1]

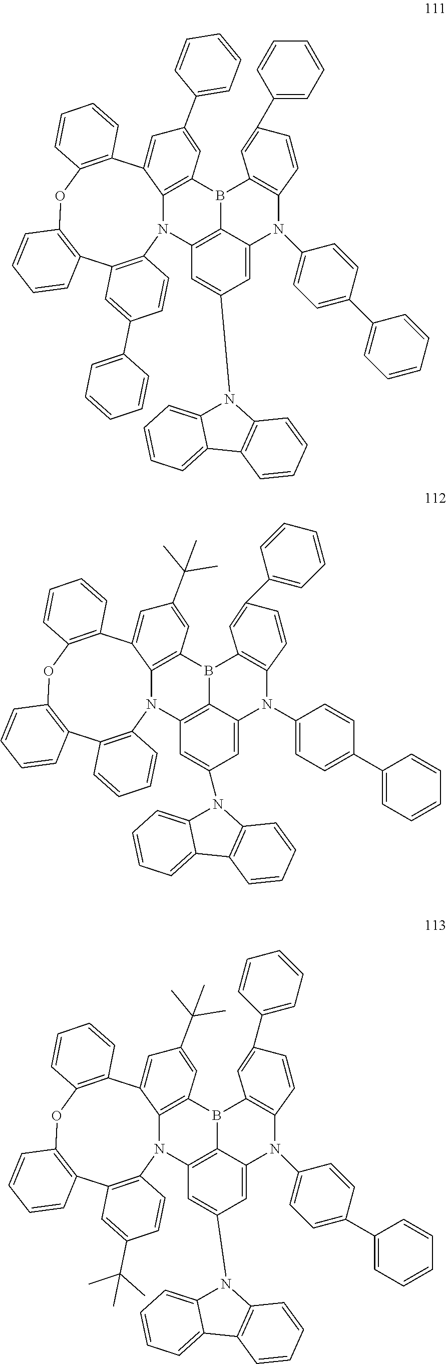 [SMILES: c1ccc(-c2ccc(N3c4ccc(-c5ccccc5)cc4B4c5cc(-c6ccccc6)cc6c5N(c5ccc(-c7ccccc7)cc5-c5ccccc5Oc5ccccc5-6)c5cc(-n6c7ccccc7c7ccccc76)cc3c54)cc2)cc1 ; CC(C)(C)c1cc2c3c(c1)-c1ccccc1Oc1ccccc1-c1ccccc1N3c1cc(-n3c4ccccc4c4ccccc43)cc3c1B2c1cc(-c2ccccc2)ccc1N3c1ccc(-c2ccccc2)cc1 ; CC(C)(C)c1ccc2c(c1)-c1ccccc1Oc1ccccc1-c1cc(C(C)(C)C)cc3c1N2c1cc(-n2c4ccccc4c4ccccc42)cc2c1B3c1cc(-c3ccccc3)ccc1N2c1ccc(-c2ccccc2)cc1]

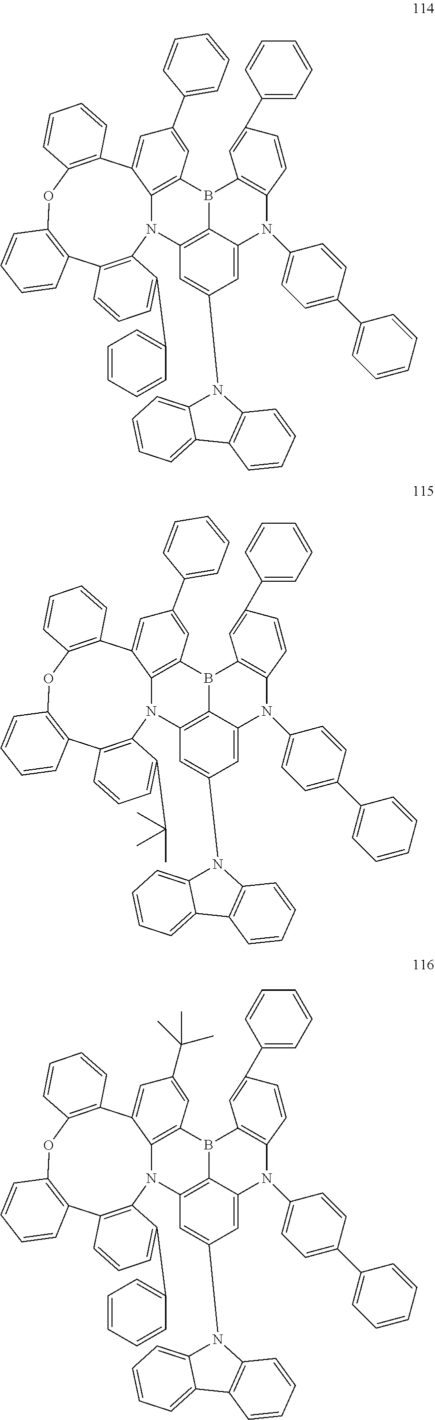 [SMILES: c1ccc(-c2ccc(N3c4ccc(-c5ccccc5)cc4B4c5cc(-c6ccccc6)cc6c5N(c5cc(-n7c8ccccc8c8ccccc87)cc3c54)c3c(-c4ccccc4)cccc3-c3ccccc3Oc3ccccc3-6)cc2)cc1 ; CC(C)(C)c1cccc2c1N1c3cc(-n4c5ccccc5c5ccccc54)cc4c3B(c3cc(-c5ccccc5)ccc3N4c3ccc(-c4ccccc4)cc3)c3cc(-c4ccccc4)cc(c31)-c1ccccc1Oc1ccccc1-2 ; CC(C)(C)c1cc2c3c(c1)-c1ccccc1Oc1ccccc1-c1cccc(-c4ccccc4)c1N3c1cc(-n3c4ccccc4c4ccccc43)cc3c1B2c1cc(-c2ccccc2)ccc1N3c1ccc(-c2ccccc2)cc1]

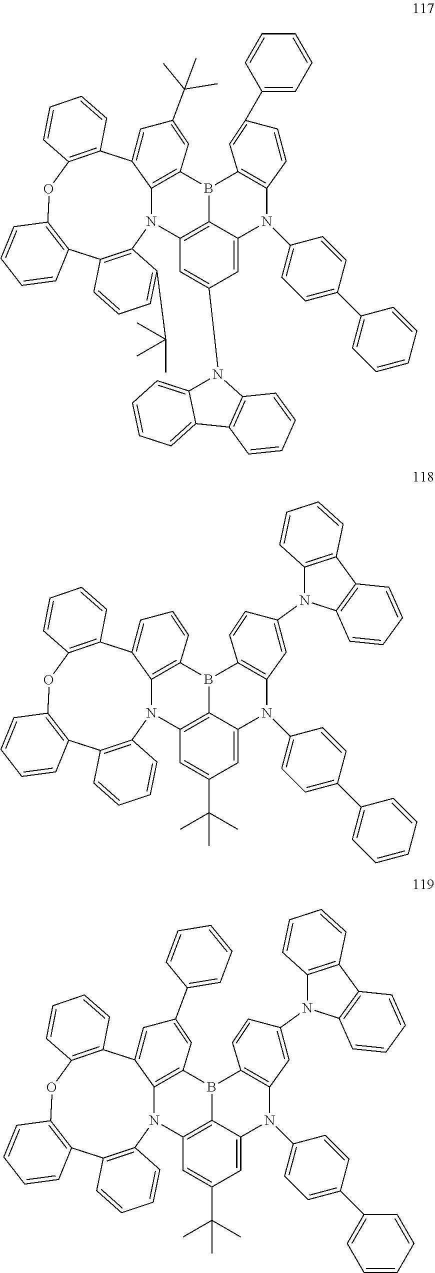 [SMILES: CC(C)(C)c1cc2c3c(c1)-c1ccccc1Oc1ccccc1-c1cccc(C(C)(C)C)c1N3c1cc(-n3c4ccccc4c4ccccc43)cc3c1B2c1cc(-c2ccccc2)ccc1N3c1ccc(-c2ccccc2)cc1 ; CC(C)(C)c1cc2c3c(c1)N1c4ccccc4-c4ccccc4Oc4ccccc4-c4cccc(c41)B3c1ccc(-n3c4ccccc4c4ccccc43)cc1N2c1ccc(-c2ccccc2)cc1 ; CC(C)(C)c1cc2c3c(c1)N1c4ccccc4-c4ccccc4Oc4ccccc4-c4cc(-c5ccccc5)cc(c41)B3c1ccc(-n3c4ccccc4c4ccccc43)cc1N2c1ccc(-c2ccccc2)cc1]

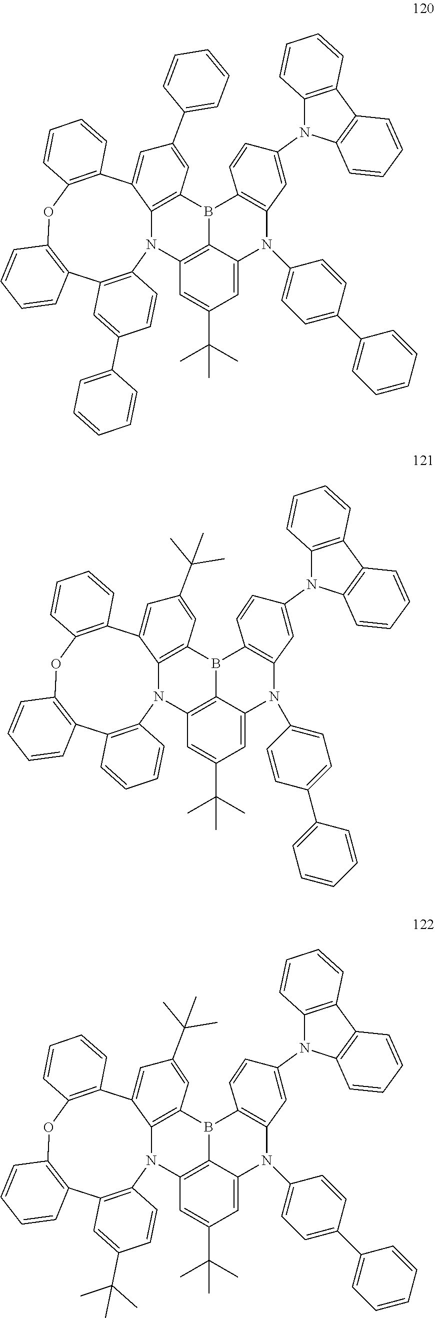 [SMILES: CC(C)(C)c1cc2c3c(c1)N1c4ccc(-c5ccccc5)cc4-c4ccccc4Oc4ccccc4-c4cc(-c5ccccc5)cc(c41)B3c1ccc(-n3c4ccccc4c4ccccc43)cc1N2c1ccc(-c2ccccc2)cc1 ; CC(C)(C)c1cc2c3c(c1)-c1ccccc1Oc1ccccc1-c1ccccc1N3c1cc(C(C)(C)C)cc3c1B2c1ccc(-n2c4ccccc4c4ccccc42)cc1N3c1ccc(-c2ccccc2)cc1 ; CC(C)(C)c1ccc2c(c1)-c1ccccc1Oc1ccccc1-c1cc(C(C)(C)C)cc3c1N2c1cc(C(C)(C)C)cc2c1B3c1ccc(-n3c4ccccc4c4ccccc43)cc1N2c1ccc(-c2ccccc2)cc1]

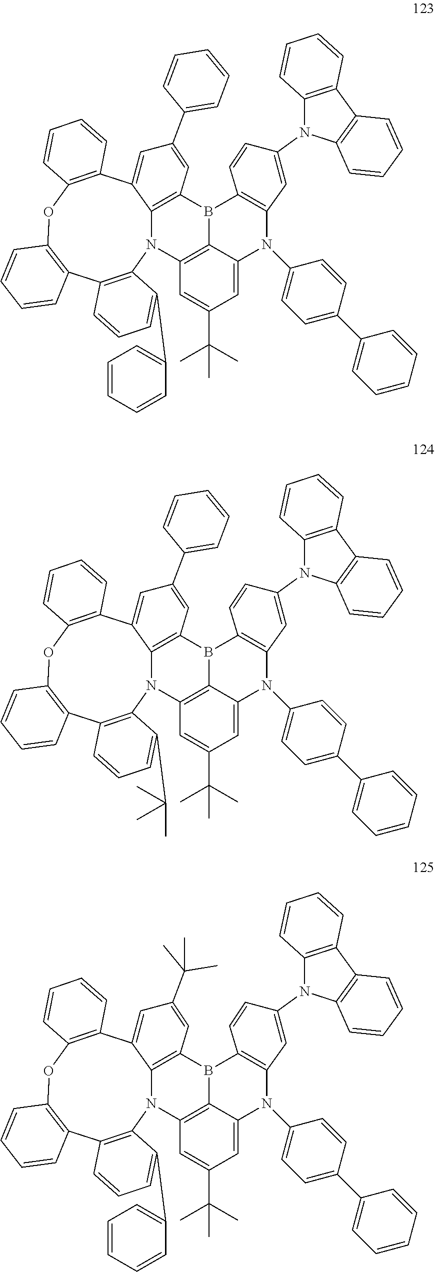 [SMILES: CC(C)(C)c1cc2c3c(c1)N1c4c(cc(-c5ccccc5)cc4-c4ccccc4Oc4ccccc4-c4cccc(-c5ccccc5)c41)B3c1ccc(-n3c4ccccc4c4ccccc43)cc1N2c1ccc(-c2ccccc2)cc1 ; CC(C)(C)c1cc2c3c(c1)N1c4c(cc(-c5ccccc5)cc4-c4ccccc4Oc4ccccc4-c4cccc(C(C)(C)C)c41)B3c1ccc(-n3c4ccccc4c4ccccc43)cc1N2c1ccc(-c2ccccc2)cc1 ; CC(C)(C)c1cc2c3c(c1)-c1ccccc1Oc1ccccc1-c1cccc(-c4ccccc4)c1N3c1cc(C(C)(C)C)cc3c1B2c1ccc(-n2c4ccccc4c4ccccc42)cc1N3c1ccc(-c2ccccc2)cc1]

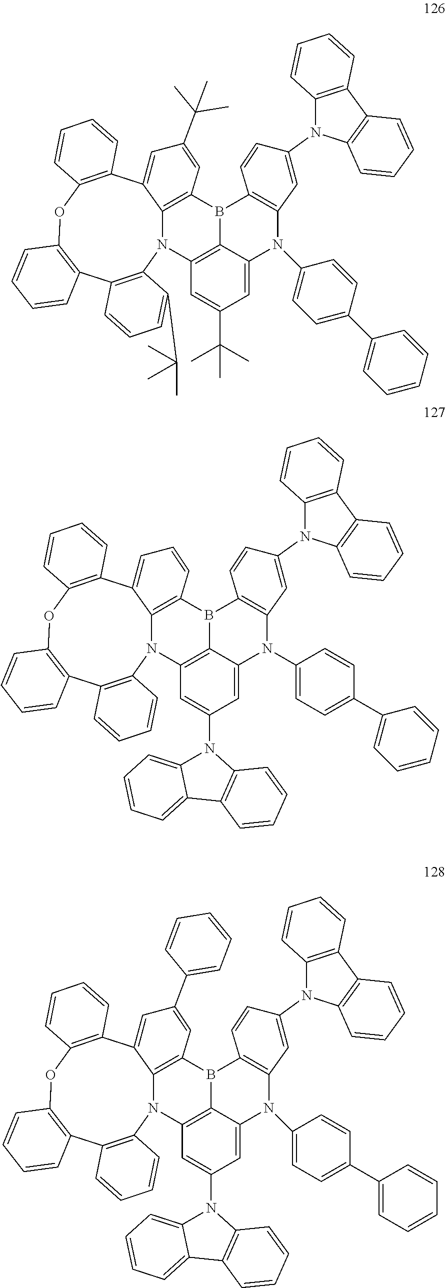 [SMILES: CC(C)(C)c1cc2c3c(c1)-c1ccccc1Oc1ccccc1-c1cccc(C(C)(C)C)c1N3c1cc(C(C)(C)C)cc3c1B2c1ccc(-n2c4ccccc4c4ccccc42)cc1N3c1ccc(-c2ccccc2)cc1 ; c1ccc(-c2ccc(N3c4cc(-n5c6ccccc6c6ccccc65)ccc4B4c5cccc6c5N(c5ccccc5-c5ccccc5Oc5ccccc5-6)c5cc(-n6c7ccccc7c7ccccc76)cc3c54)cc2)cc1 ; c1ccc(-c2ccc(N3c4cc(-n5c6ccccc6c6ccccc65)ccc4B4c5cc(-c6ccccc6)cc6c5N(c5ccccc5-c5ccccc5Oc5ccccc5-6)c5cc(-n6c7ccccc7c7ccccc76)cc3c54)cc2)cc1]

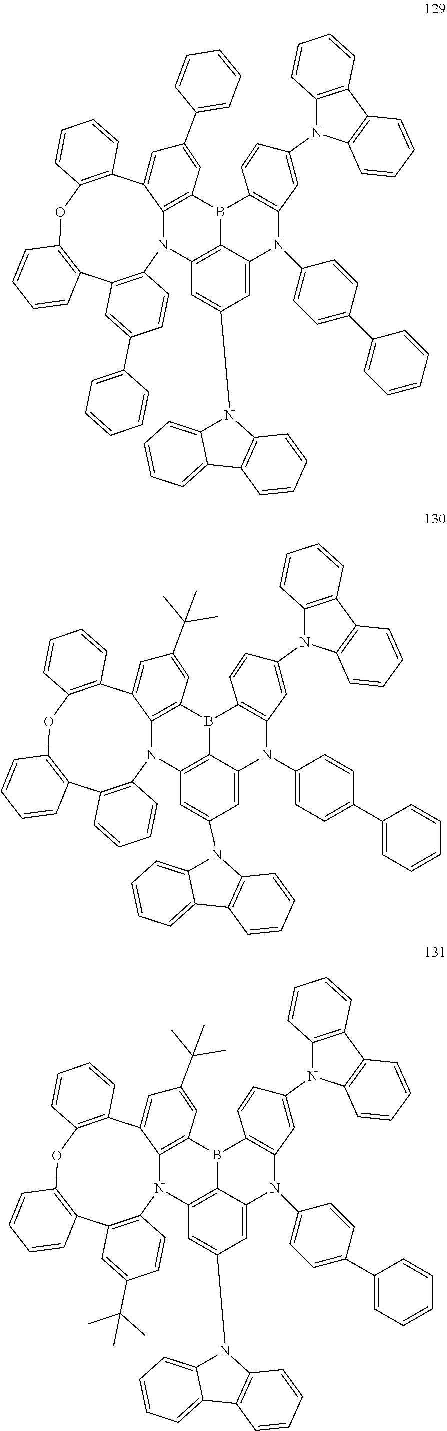 [SMILES: c1ccc(-c2ccc(N3c4cc(-n5c6ccccc6c6ccccc65)ccc4B4c5cc(-c6ccccc6)cc6c5N(c5ccc(-c7ccccc7)cc5-c5ccccc5Oc5ccccc5-6)c5cc(-n6c7ccccc7c7ccccc76)cc3c54)cc2)cc1 ; CC(C)(C)c1cc2c3c(c1)-c1ccccc1Oc1ccccc1-c1ccccc1N3c1cc(-n3c4ccccc4c4ccccc43)cc3c1B2c1ccc(-n2c4ccccc4c4ccccc42)cc1N3c1ccc(-c2ccccc2)cc1 ; CC(C)(C)c1ccc2c(c1)-c1ccccc1Oc1ccccc1-c1cc(C(C)(C)C)cc3c1N2c1cc(-n2c4ccccc4c4ccccc42)cc2c1B3c1ccc(-n3c4ccccc4c4ccccc43)cc1N2c1ccc(-c2ccccc2)cc1]

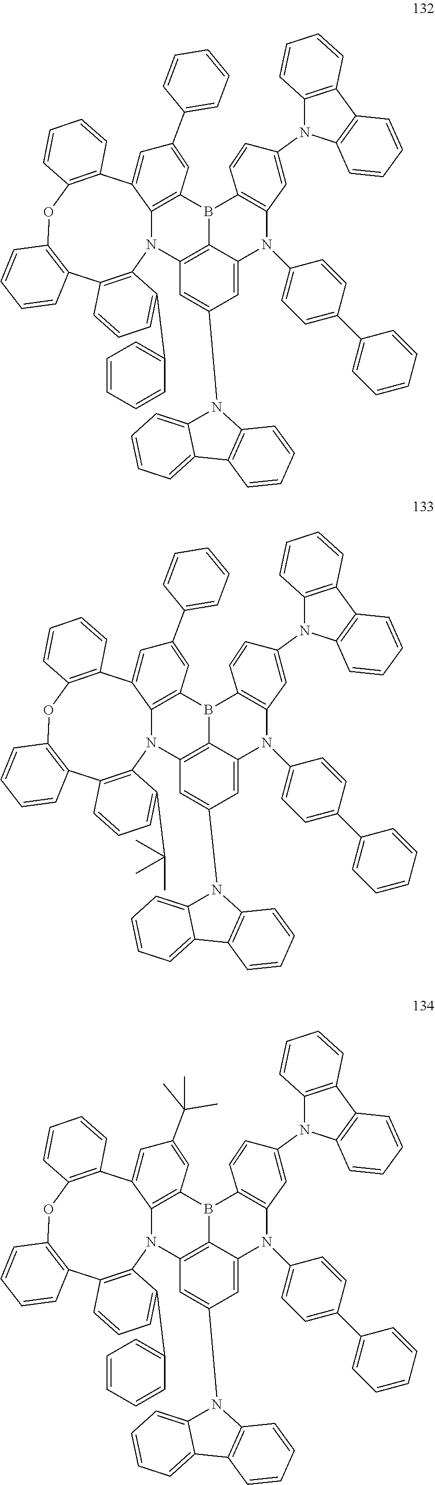 [SMILES: c1ccc(-c2ccc(N3c4cc(-n5c6ccccc6c6ccccc65)ccc4B4c5cc(-c6ccccc6)cc6c5N(c5cc(-n7c8ccccc8c8ccccc87)cc3c54)c3c(-c4ccccc4)cccc3-c3ccccc3Oc3ccccc3-6)cc2)cc1 ; CC(C)(C)c1cccc2c1N1c3cc(-n4c5ccccc5c5ccccc54)cc4c3B(c3ccc(-n5c6ccccc6c6ccccc65)cc3N4c3ccc(-c4ccccc4)cc3)c3cc(-c4ccccc4)cc(c31)-c1ccccc1Oc1ccccc1-2 ; CC(C)(C)c1cc2c3c(c1)-c1ccccc1Oc1ccccc1-c1cccc(-c4ccccc4)c1N3c1cc(-n3c4ccccc4c4ccccc43)cc3c1B2c1ccc(-n2c4ccccc4c4ccccc42)cc1N3c1ccc(-c2ccccc2)cc1]

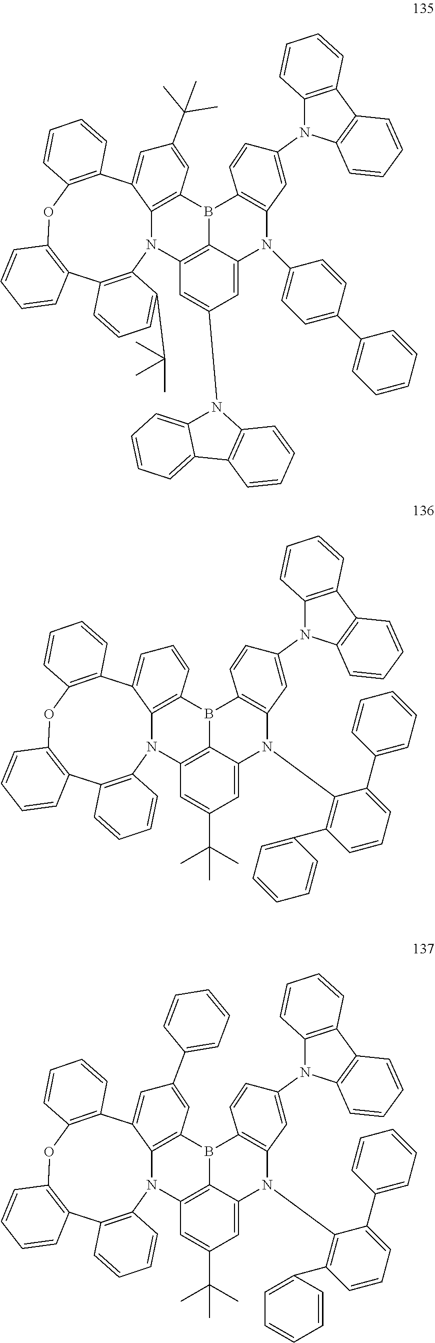 [SMILES: CC(C)(C)c1cc2c3c(c1)-c1ccccc1Oc1ccccc1-c1cccc(C(C)(C)C)c1N3c1cc(-n3c4ccccc4c4ccccc43)cc3c1B2c1ccc(-n2c4ccccc4c4ccccc42)cc1N3c1ccc(-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1cccc3c1N2c1ccccc1-c1ccccc1Oc1ccccc1-3 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)cc3c1N2c1ccccc1-c1ccccc1Oc1ccccc1-3]

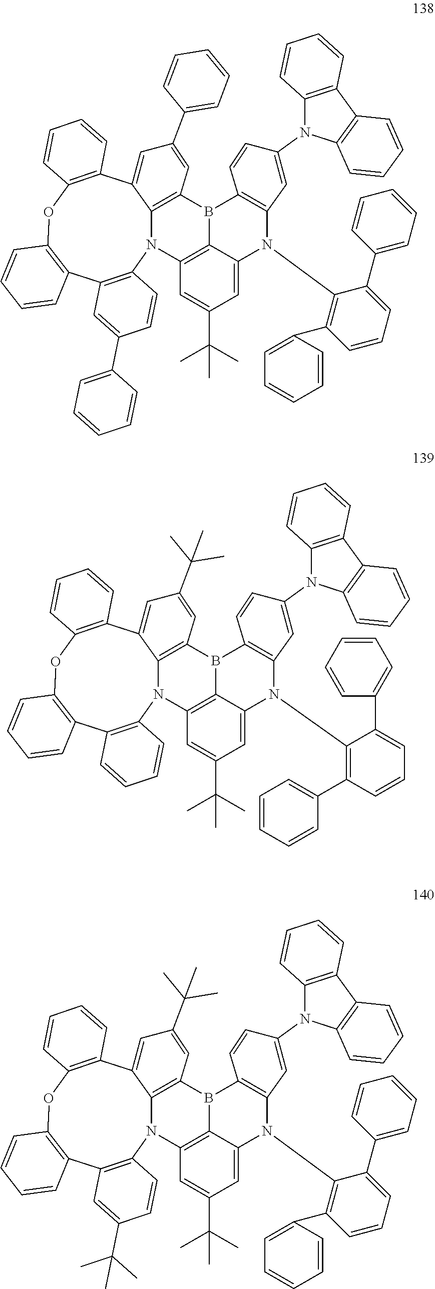 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)cc3c1N2c1ccc(-c2ccccc2)cc1-c1ccccc1Oc1ccccc1-3 ; CC(C)(C)c1cc2c3c(c1)-c1ccccc1Oc1ccccc1-c1ccccc1N3c1cc(C(C)(C)C)cc3c1B2c1ccc(-n2c4ccccc4c4ccccc42)cc1N3c1c(-c2ccccc2)cccc1-c1ccccc1 ; CC(C)(C)c1ccc2c(c1)-c1ccccc1Oc1ccccc1-c1cc(C(C)(C)C)cc3c1N2c1cc(C(C)(C)C)cc2c1B3c1ccc(-n3c4ccccc4c4ccccc43)cc1N2c1c(-c2ccccc2)cccc1-c1ccccc1]

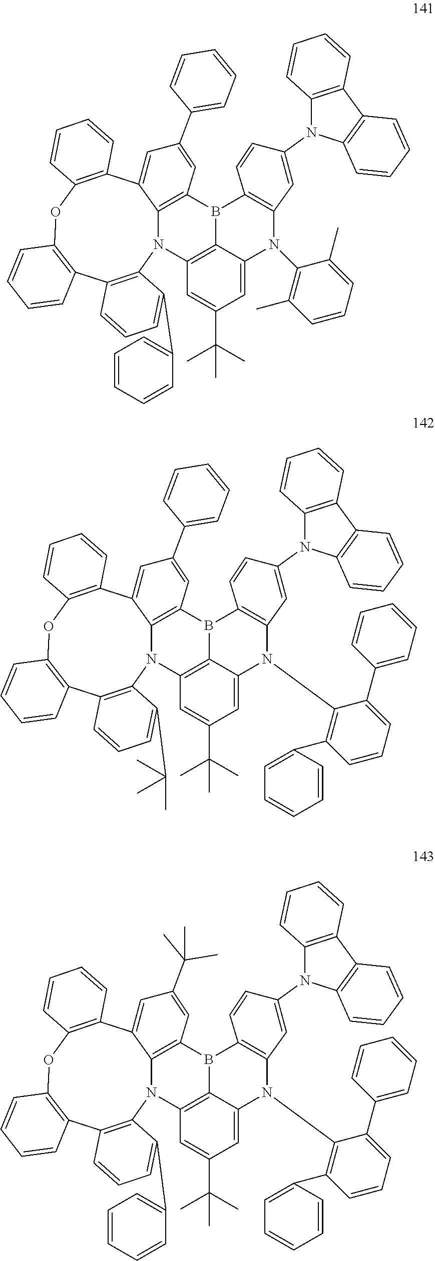 [SMILES: Cc1cccc(C)c1N1c2cc(-n3c4ccccc4c4ccccc43)ccc2B2c3cc(-c4ccccc4)cc4c3N(c3cc(C(C)(C)C)cc1c32)c1c(-c2ccccc2)cccc1-c1ccccc1Oc1ccccc1-4 ; CC(C)(C)c1cc2c3c(c1)N1c4c(cc(-c5ccccc5)cc4-c4ccccc4Oc4ccccc4-c4cccc(C(C)(C)C)c41)B3c1ccc(-n3c4ccccc4c4ccccc43)cc1N2c1c(-c2ccccc2)cccc1-c1ccccc1 ; CC(C)(C)c1cc2c3c(c1)-c1ccccc1Oc1ccccc1-c1cccc(-c4ccccc4)c1N3c1cc(C(C)(C)C)cc3c1B2c1ccc(-n2c4ccccc4c4ccccc42)cc1N3c1c(-c2ccccc2)cccc1-c1ccccc1]

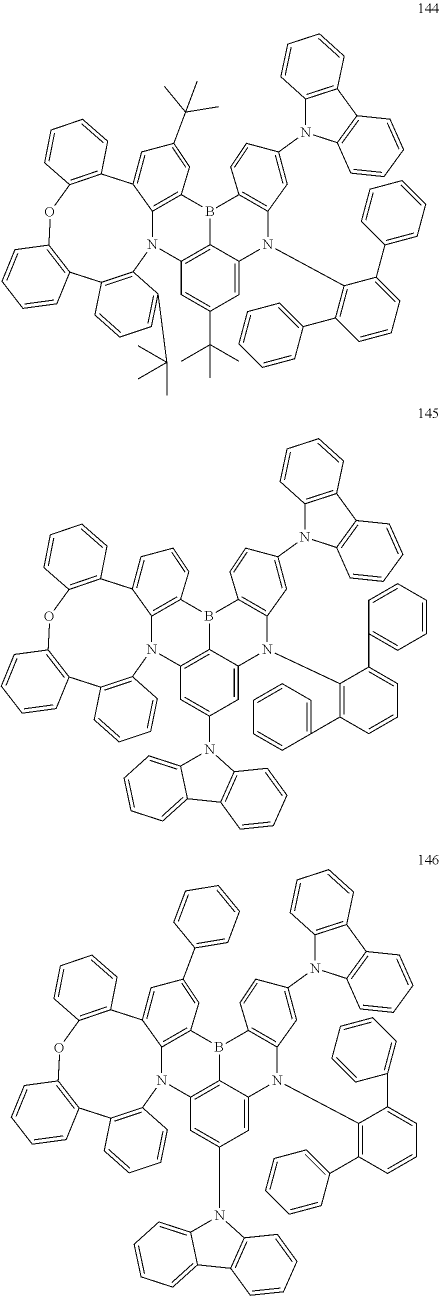 [SMILES: CC(C)(C)c1cc2c3c(c1)-c1ccccc1Oc1ccccc1-c1cccc(C(C)(C)C)c1N3c1cc(C(C)(C)C)cc3c1B2c1ccc(-n2c4ccccc4c4ccccc42)cc1N3c1c(-c2ccccc2)cccc1-c1ccccc1 ; c1ccc(-c2cccc(-c3ccccc3)c2N2c3cc(-n4c5ccccc5c5ccccc54)ccc3B3c4cccc5c4N(c4ccccc4-c4ccccc4Oc4ccccc4-5)c4cc(-n5c6ccccc6c6ccccc65)cc2c43)cc1 ; c1ccc(-c2cc3c4c(c2)-c2ccccc2Oc2ccccc2-c2ccccc2N4c2cc(-n4c5ccccc5c5ccccc54)cc4c2B3c2ccc(-n3c5ccccc5c5ccccc53)cc2N4c2c(-c3ccccc3)cccc2-c2ccccc2)cc1]

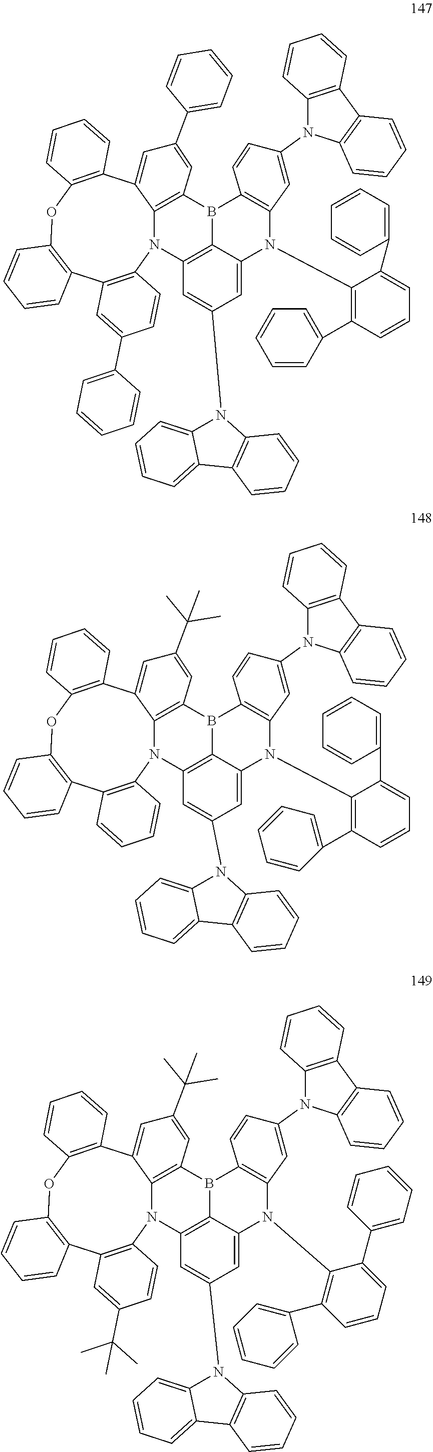 [SMILES: c1ccc(-c2ccc3c(c2)-c2ccccc2Oc2ccccc2-c2cc(-c4ccccc4)cc4c2N3c2cc(-n3c5ccccc5c5ccccc53)cc3c2B4c2ccc(-n4c5ccccc5c5ccccc54)cc2N3c2c(-c3ccccc3)cccc2-c2ccccc2)cc1 ; CC(C)(C)c1cc2c3c(c1)-c1ccccc1Oc1ccccc1-c1ccccc1N3c1cc(-n3c4ccccc4c4ccccc43)cc3c1B2c1ccc(-n2c4ccccc4c4ccccc42)cc1N3c1c(-c2ccccc2)cccc1-c1ccccc1 ; CC(C)(C)c1ccc2c(c1)-c1ccccc1Oc1ccccc1-c1cc(C(C)(C)C)cc3c1N2c1cc(-n2c4ccccc4c4ccccc42)cc2c1B3c1ccc(-n3c4ccccc4c4ccccc43)cc1N2c1c(-c2ccccc2)cccc1-c1ccccc1]

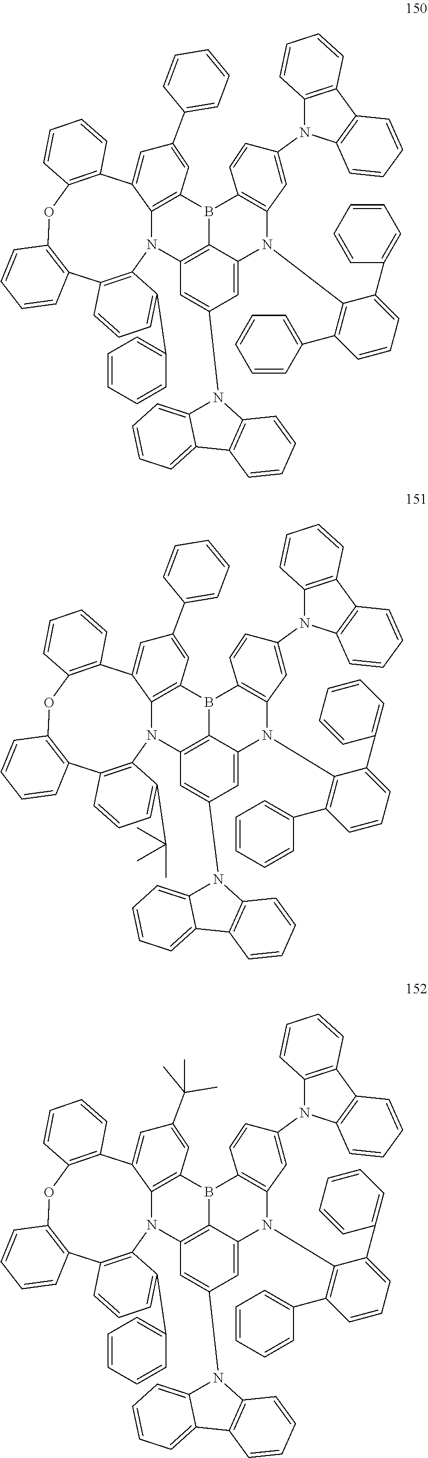 [SMILES: c1ccc(-c2cc3c4c(c2)-c2ccccc2Oc2ccccc2-c2cccc(-c5ccccc5)c2N4c2cc(-n4c5ccccc5c5ccccc54)cc4c2B3c2ccc(-n3c5ccccc5c5ccccc53)cc2N4c2c(-c3ccccc3)cccc2-c2ccccc2)cc1 ; CC(C)(C)c1cccc2c1N1c3cc(-n4c5ccccc5c5ccccc54)cc4c3B(c3ccc(-n5c6ccccc6c6ccccc65)cc3N4c3c(-c4ccccc4)cccc3-c3ccccc3)c3cc(-c4ccccc4)cc(c31)-c1ccccc1Oc1ccccc1-2 ; CC(C)(C)c1cc2c3c(c1)-c1ccccc1Oc1ccccc1-c1cccc(-c4ccccc4)c1N3c1cc(-n3c4ccccc4c4ccccc43)cc3c1B2c1ccc(-n2c4ccccc4c4ccccc42)cc1N3c1c(-c2ccccc2)cccc1-c1ccccc1]

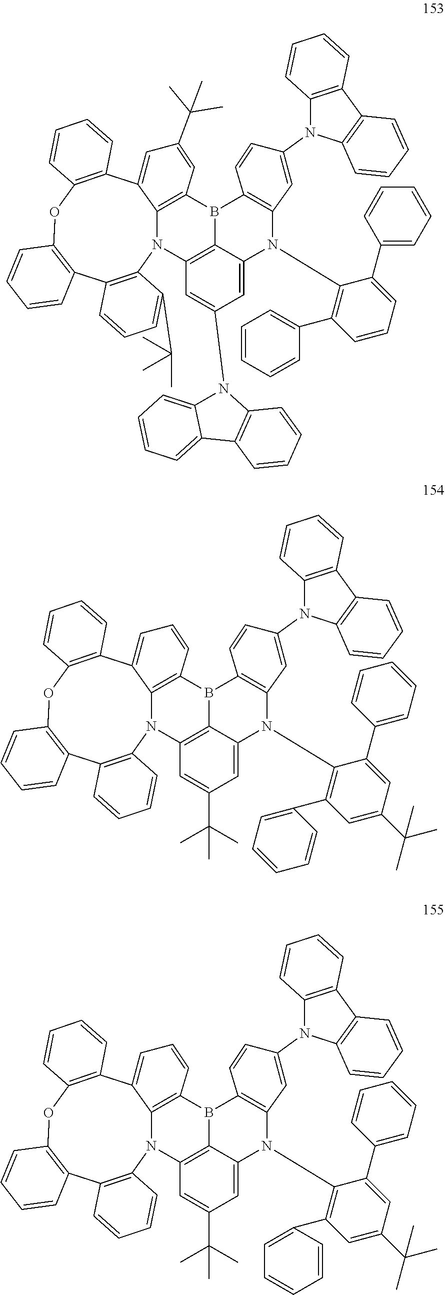 [SMILES: CC(C)(C)c1cc2c3c(c1)-c1ccccc1Oc1ccccc1-c1cccc(C(C)(C)C)c1N3c1cc(-n3c4ccccc4c4ccccc43)cc3c1B2c1ccc(-n2c4ccccc4c4ccccc42)cc1N3c1c(-c2ccccc2)cccc1-c1ccccc1 ; CC(C)(C)c1cc(-c2ccccc2)c(N2c3cc(-n4c5ccccc5c5ccccc54)ccc3B3c4cccc5c4N(c4ccccc4-c4ccccc4Oc4ccccc4-5)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cccc5c4N(c4ccccc4-c4ccccc4Oc4ccccc4-5)c4cc(C(C)(C)C)cc2c43)c(-c2ccccc2)c1]

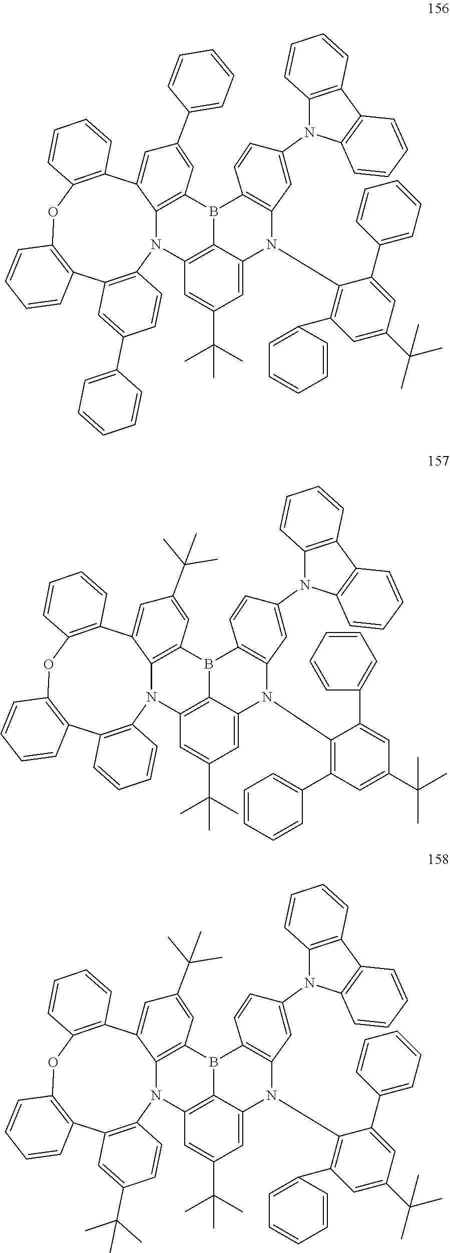 [SMILES: CC(C)(C)c1cc(-c2ccccc2)c(N2c3cc(-n4c5ccccc5c5ccccc54)ccc3B3c4cc(-c5ccccc5)cc5c4N(c4ccc(-c6ccccc6)cc4-c4ccccc4Oc4ccccc4-5)c4cc(C(C)(C)C)cc2c43)c(-c2ccccc2)c1 ; CC(C)(C)c1cc2c3c(c1)-c1ccccc1Oc1ccccc1-c1ccccc1N3c1cc(C(C)(C)C)cc3c1B2c1ccc(-n2c4ccccc4c4ccccc42)cc1N3c1c(-c2ccccc2)cc(C(C)(C)C)cc1-c1ccccc1 ; CC(C)(C)c1ccc2c(c1)-c1ccccc1Oc1ccccc1-c1cc(C(C)(C)C)cc3c1N2c1cc(C(C)(C)C)cc2c1B3c1ccc(-n3c4ccccc4c4ccccc43)cc1N2c1c(-c2ccccc2)cc(C(C)(C)C)cc1-c1ccccc1]

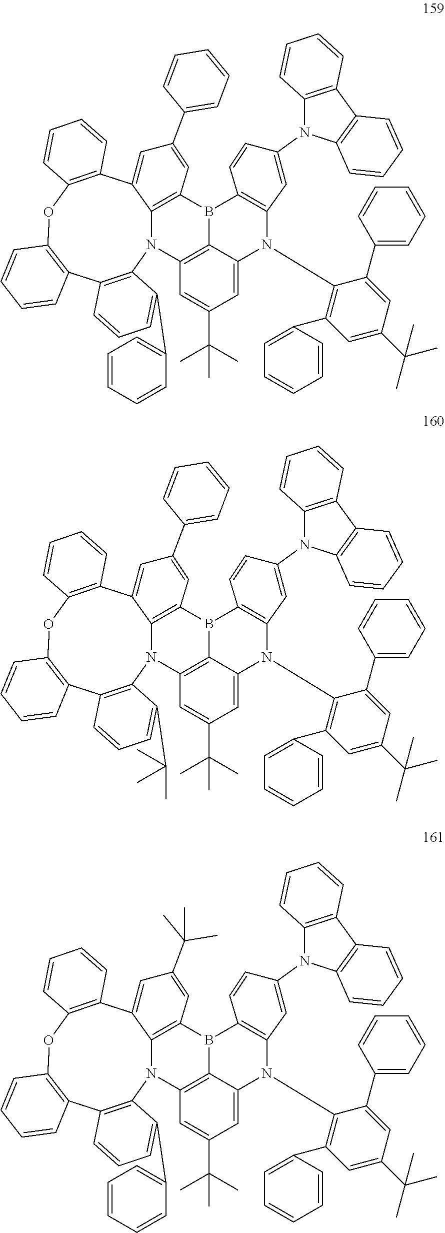 [SMILES: CC(C)(C)c1cc(-c2ccccc2)c(N2c3cc(-n4c5ccccc5c5ccccc54)ccc3B3c4cc(-c5ccccc5)cc5c4N(c4cc(C(C)(C)C)cc2c43)c2c(-c3ccccc3)cccc2-c2ccccc2Oc2ccccc2-5)c(-c2ccccc2)c1 ; CC(C)(C)c1cc(-c2ccccc2)c(N2c3cc(-n4c5ccccc5c5ccccc54)ccc3B3c4cc(-c5ccccc5)cc5c4N(c4cc(C(C)(C)C)cc2c43)c2c(cccc2C(C)(C)C)-c2ccccc2Oc2ccccc2-5)c(-c2ccccc2)c1 ; CC(C)(C)c1cc2c3c(c1)-c1ccccc1Oc1ccccc1-c1cccc(-c4ccccc4)c1N3c1cc(C(C)(C)C)cc3c1B2c1ccc(-n2c4ccccc4c4ccccc42)cc1N3c1c(-c2ccccc2)cc(C(C)(C)C)cc1-c1ccccc1]

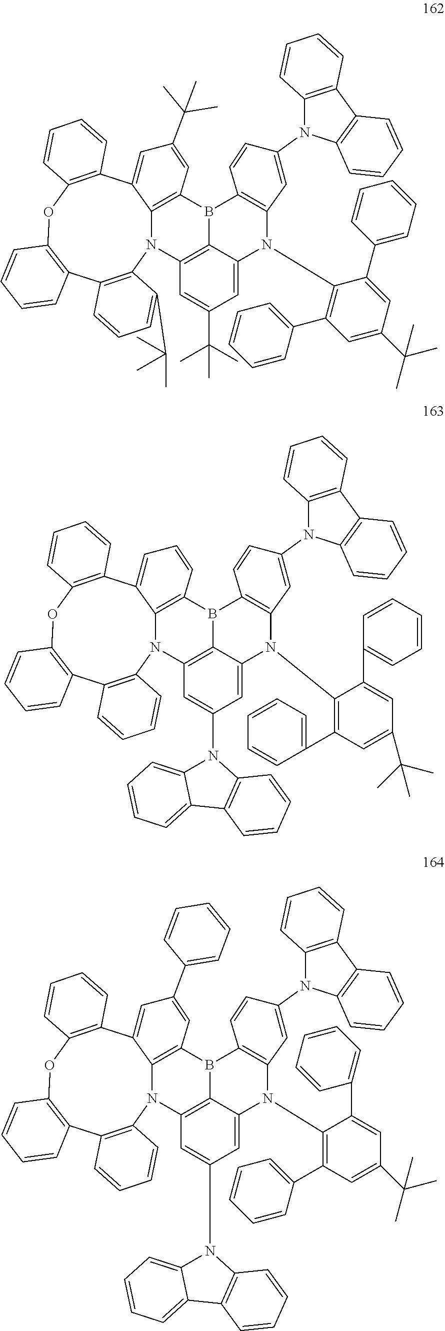 [SMILES: CC(C)(C)c1cc2c3c(c1)-c1ccccc1Oc1ccccc1-c1cccc(C(C)(C)C)c1N3c1cc(C(C)(C)C)cc3c1B2c1ccc(-n2c4ccccc4c4ccccc42)cc1N3c1c(-c2ccccc2)cc(C(C)(C)C)cc1-c1ccccc1 ; CC(C)(C)c1cc(-c2ccccc2)c(N2c3cc(-n4c5ccccc5c5ccccc54)ccc3B3c4cccc5c4N(c4ccccc4-c4ccccc4Oc4ccccc4-5)c4cc(-n5c6ccccc6c6ccccc65)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)cc5c4N(c4ccccc4-c4ccccc4Oc4ccccc4-5)c4cc(-n5c6ccccc6c6ccccc65)cc2c43)c(-c2ccccc2)c1]

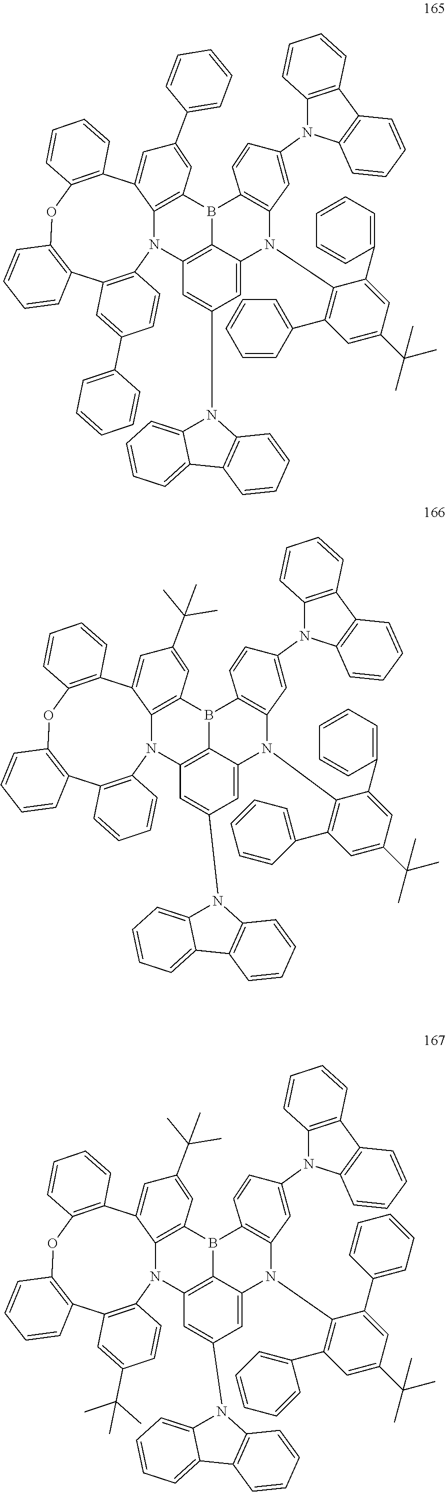 [SMILES: CC(C)(C)c1cc(-c2ccccc2)c(N2c3cc(-n4c5ccccc5c5ccccc54)ccc3B3c4cc(-c5ccccc5)cc5c4N(c4ccc(-c6ccccc6)cc4-c4ccccc4Oc4ccccc4-5)c4cc(-n5c6ccccc6c6ccccc65)cc2c43)c(-c2ccccc2)c1 ; CC(C)(C)c1cc2c3c(c1)-c1ccccc1Oc1ccccc1-c1ccccc1N3c1cc(-n3c4ccccc4c4ccccc43)cc3c1B2c1ccc(-n2c4ccccc4c4ccccc42)cc1N3c1c(-c2ccccc2)cc(C(C)(C)C)cc1-c1ccccc1 ; CC(C)(C)c1ccc2c(c1)-c1ccccc1Oc1ccccc1-c1cc(C(C)(C)C)cc3c1N2c1cc(-n2c4ccccc4c4ccccc42)cc2c1B3c1ccc(-n3c4ccccc4c4ccccc43)cc1N2c1c(-c2ccccc2)cc(C(C)(C)C)cc1-c1ccccc1]

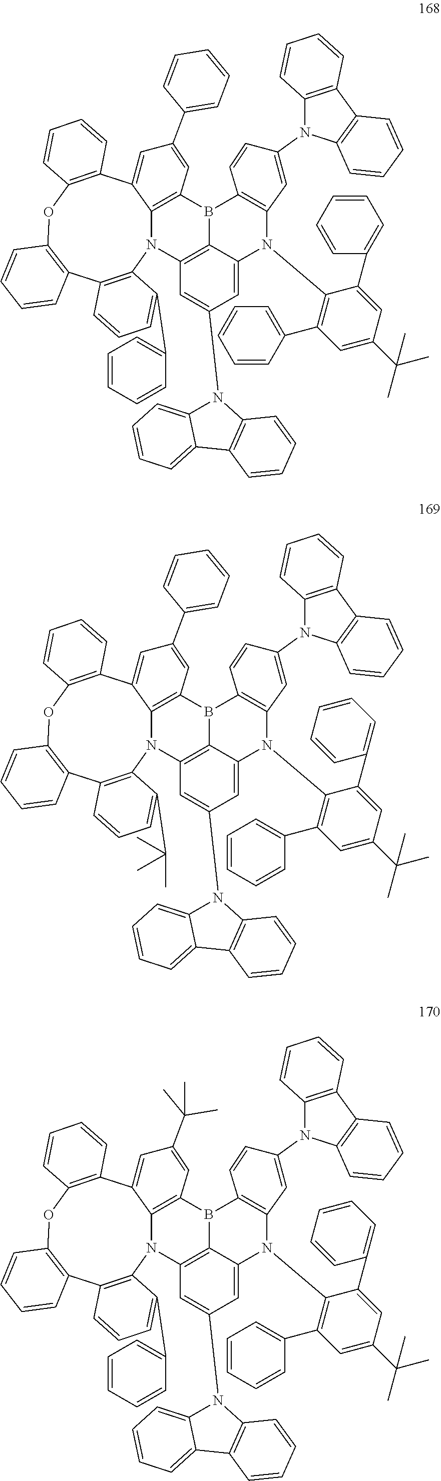

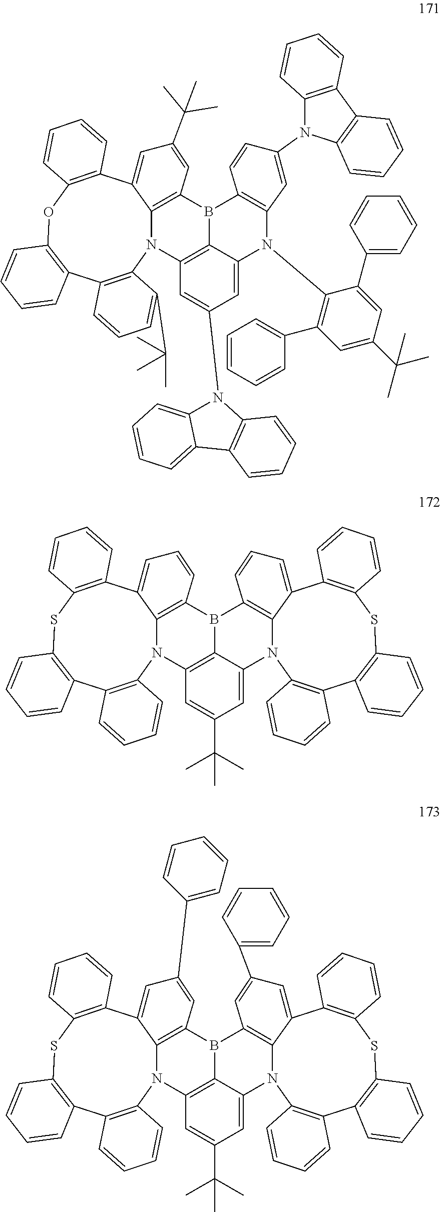 [SMILES: CC(C)(C)c1cc2c3c(c1)-c1ccccc1Oc1ccccc1-c1cccc(C(C)(C)C)c1N3c1cc(-n3c4ccccc4c4ccccc43)cc3c1B2c1ccc(-n2c4ccccc4c4ccccc42)cc1N3c1c(-c2ccccc2)cc(C(C)(C)C)cc1-c1ccccc1 ; CC(C)(C)c1cc2c3c(c1)N1c4ccccc4-c4ccccc4Sc4ccccc4-c4cccc(c41)B3c1cccc3c1N2c1ccccc1-c1ccccc1Sc1ccccc1-3 ; CC(C)(C)c1cc2c3c(c1)N1c4ccccc4-c4ccccc4Sc4ccccc4-c4cc(-c5ccccc5)cc(c41)B3c1cc(-c3ccccc3)cc3c1N2c1ccccc1-c1ccccc1Sc1ccccc1-3]

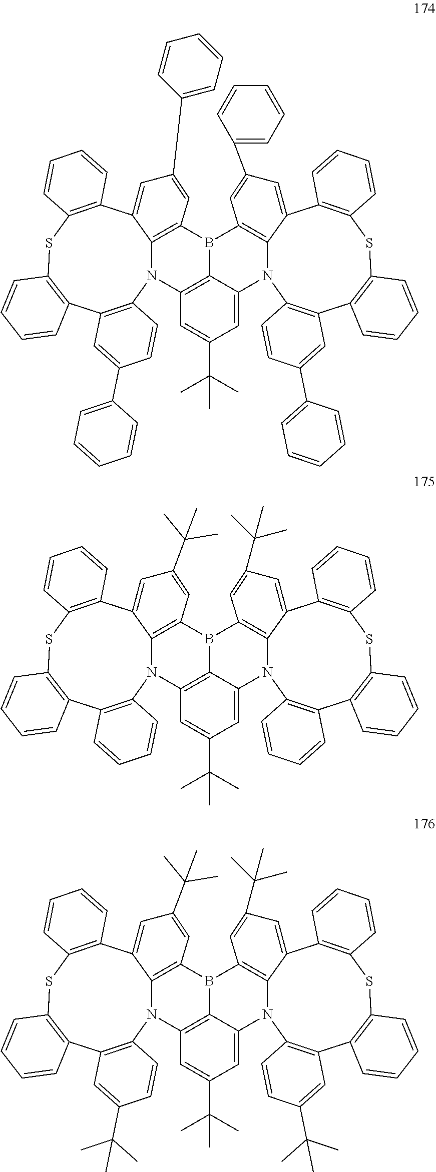 [SMILES: CC(C)(C)c1cc2c3c(c1)N1c4ccc(-c5ccccc5)cc4-c4ccccc4Sc4ccccc4-c4cc(-c5ccccc5)cc(c41)B3c1cc(-c3ccccc3)cc3c1N2c1ccc(-c2ccccc2)cc1-c1ccccc1Sc1ccccc1-3 ; CC(C)(C)c1cc2c3c(c1)-c1ccccc1Sc1ccccc1-c1ccccc1N3c1cc(C(C)(C)C)cc3c1B2c1cc(C(C)(C)C)cc2c1N3c1ccccc1-c1ccccc1Sc1ccccc1-2 ; CC(C)(C)c1ccc2c(c1)-c1ccccc1Sc1ccccc1-c1cc(C(C)(C)C)cc3c1N2c1cc(C(C)(C)C)cc2c1B3c1cc(C(C)(C)C)cc3c1N2c1ccc(C(C)(C)C)cc1-c1ccccc1Sc1ccccc1-3]

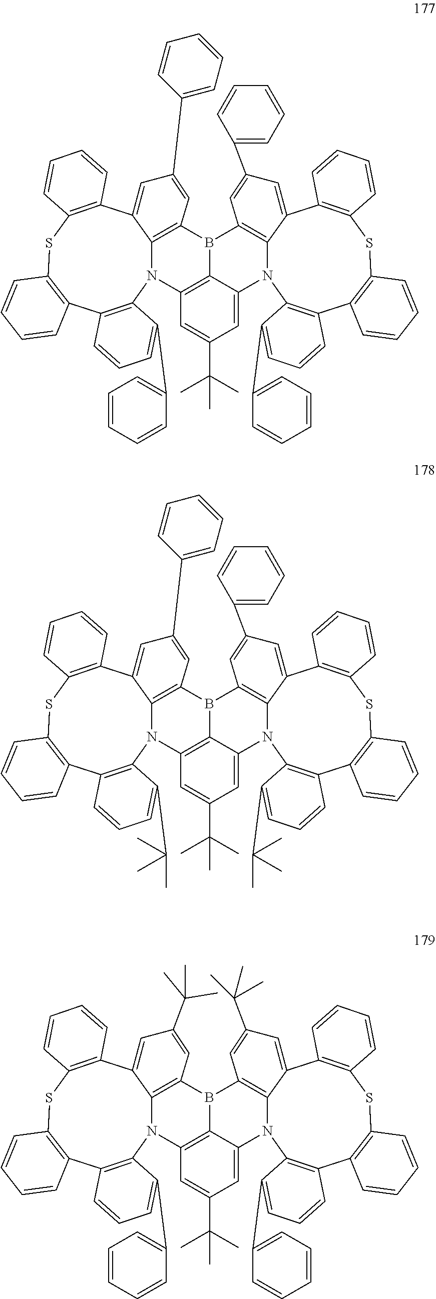 [SMILES: CC(C)(C)c1cc2c3c(c1)N1c4c(cc(-c5ccccc5)cc4-c4ccccc4Sc4ccccc4-c4cccc(-c5ccccc5)c41)B3c1cc(-c3ccccc3)cc3c1N2c1c(-c2ccccc2)cccc1-c1ccccc1Sc1ccccc1-3 ; CC(C)(C)c1cc2c3c(c1)N1c4c(cc(-c5ccccc5)cc4-c4ccccc4Sc4ccccc4-c4cccc(C(C)(C)C)c41)B3c1cc(-c3ccccc3)cc3c1N2c1c(cccc1C(C)(C)C)-c1ccccc1Sc1ccccc1-3 ; CC(C)(C)c1cc2c3c(c1)-c1ccccc1Sc1ccccc1-c1cccc(-c4ccccc4)c1N3c1cc(C(C)(C)C)cc3c1B2c1cc(C(C)(C)C)cc2c1N3c1c(-c3ccccc3)cccc1-c1ccccc1Sc1ccccc1-2]

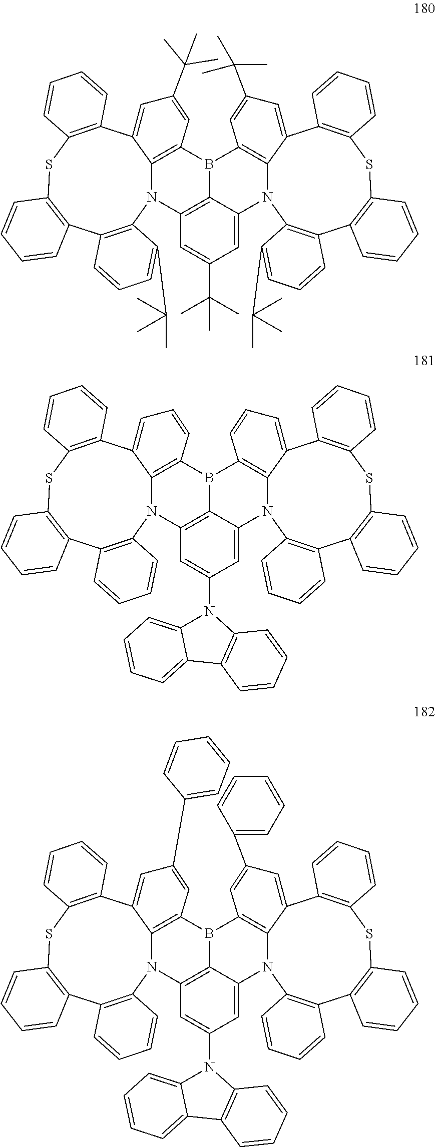 [SMILES: CC(C)(C)c1cc2c3c(c1)-c1ccccc1Sc1ccccc1-c1cccc(C(C)(C)C)c1N3c1cc(C(C)(C)C)cc3c1B2c1cc(C(C)(C)C)cc2c1N3c1c(cccc1C(C)(C)C)-c1ccccc1Sc1ccccc1-2 ; c1ccc2c(c1)Sc1ccccc1-c1cccc3c1N(c1ccccc1-2)c1cc(-n2c4ccccc4c4ccccc42)cc2c1B3c1cccc3c1N2c1ccccc1-c1ccccc1Sc1ccccc1-3 ; c1ccc(-c2cc3c4c(c2)-c2ccccc2Sc2ccccc2-c2ccccc2N4c2cc(-n4c5ccccc5c5ccccc54)cc4c2B3c2cc(-c3ccccc3)cc3c2N4c2ccccc2-c2ccccc2Sc2ccccc2-3)cc1]

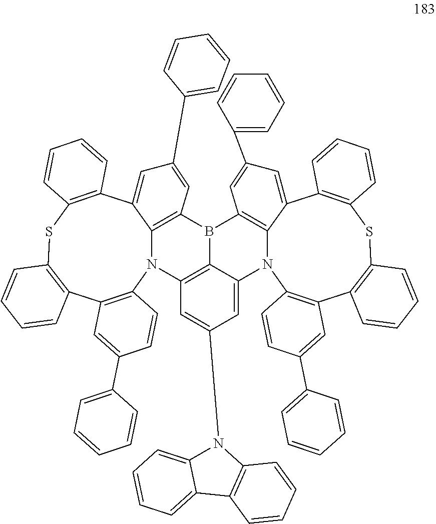 [SMILES: c1ccc(-c2ccc3c(c2)-c2ccccc2Sc2ccccc2-c2cc(-c4ccccc4)cc4c2N3c2cc(-n3c5ccccc5c5ccccc53)cc3c2B4c2cc(-c4ccccc4)cc4c2N3c2ccc(-c3ccccc3)cc2-c2ccccc2Sc2ccccc2-4)cc1]

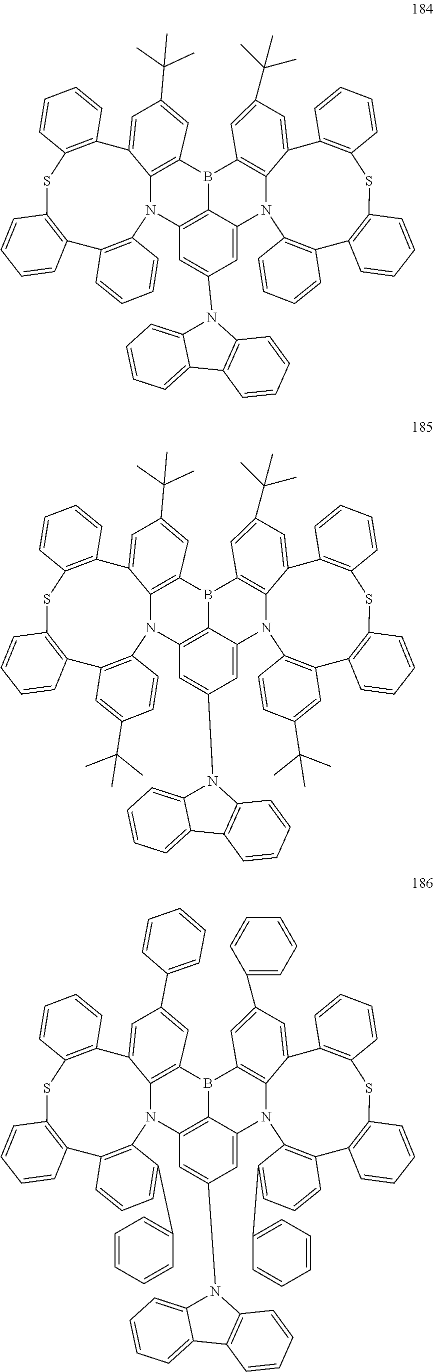 [SMILES: CC(C)(C)c1cc2c3c(c1)-c1ccccc1Sc1ccccc1-c1ccccc1N3c1cc(-n3c4ccccc4c4ccccc43)cc3c1B2c1cc(C(C)(C)C)cc2c1N3c1ccccc1-c1ccccc1Sc1ccccc1-2 ; CC(C)(C)c1ccc2c(c1)-c1ccccc1Sc1ccccc1-c1cc(C(C)(C)C)cc3c1N2c1cc(-n2c4ccccc4c4ccccc42)cc2c1B3c1cc(C(C)(C)C)cc3c1N2c1ccc(C(C)(C)C)cc1-c1ccccc1Sc1ccccc1-3 ; c1ccc(-c2cc3c4c(c2)-c2ccccc2Sc2ccccc2-c2cccc(-c5ccccc5)c2N4c2cc(-n4c5ccccc5c5ccccc54)cc4c2B3c2cc(-c3ccccc3)cc3c2N4c2c(-c4ccccc4)cccc2-c2ccccc2Sc2ccccc2-3)cc1]

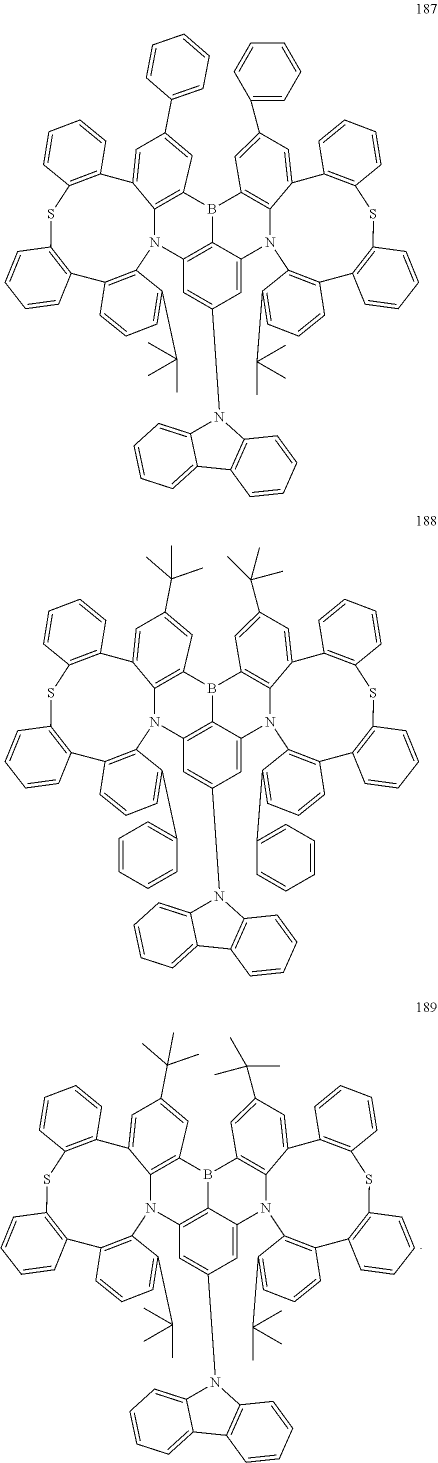 [SMILES: CC(C)(C)c1cccc2c1N1c3cc(-n4c5ccccc5c5ccccc54)cc4c3B(c3cc(-c5ccccc5)cc(c31)-c1ccccc1Sc1ccccc1-2)c1cc(-c2ccccc2)cc2c1N4c1c(cccc1C(C)(C)C)-c1ccccc1Sc1ccccc1-2 ; CC(C)(C)c1cc2c3c(c1)-c1ccccc1Sc1ccccc1-c1cccc(-c4ccccc4)c1N3c1cc(-n3c4ccccc4c4ccccc43)cc3c1B2c1cc(C(C)(C)C)cc2c1N3c1c(-c3ccccc3)cccc1-c1ccccc1Sc1ccccc1-2 ; CC(C)(C)c1cc2c3c(c1)-c1ccccc1Sc1ccccc1-c1cccc(C(C)(C)C)c1N3c1cc(-n3c4ccccc4c4ccccc43)cc3c1B2c1cc(C(C)(C)C)cc2c1N3c1c(cccc1C(C)(C)C)-c1ccccc1Sc1ccccc1-2]

The condensed cyclic compound does not include a metal. Therefore, the condensed cyclic compound is clearly distinguished from various organometallic compounds including a central metal such as platinum, palladium, gold, etc. and an organic ligand bound thereto.

In addition, the condensed cyclic compound includes a condensed cyclic core in which a first condensed ring and a second condensed ring are condensed with each other; the first condensed ring may be a 10-membered ring, an 11-membered ring, a 12-membered ring, or a 13-membered ring, each of which includes nitrogen and carbon as a first ring-forming atom, and at least one heteroatom selected from oxygen, sulfur, selenium, or nitrogen as a second ring-forming atom, in addition to the first ring-forming atom; and the second condensed ring may be a 6-membered ring including nitrogen, carbon, and boron; and the first condensed ring and the second condensed ring are condensed with each other while sharing nitrogen and carbon. In addition, the condensed cyclic core may further include a third condensed ring that is condensed with the first condensed ring and is not condensed with the second condensed ring, and the third condensed ring is selected from a C₅-C₆₀ carbocyclic group and a C₃-C₆₀ heterocyclic group, and the number of the third condensed ring in the condensed cyclic core is 3 or more. As a result, the condensed cyclic compound may have excellent thermal and electrical stability and a relatively small steric hindrance effect, due to the shielding effect, and emits a relatively narrow full-width-at-half-maximum (FWHM) and short-wavelength shifted blue light (for example, delayed fluorescence blue light). Accordingly, an electronic device for example, a light-emitting device, using the condensed cyclic compound, may have improved driving voltage, improved external quantum efficiency, improved luminescence efficiency, and/or improved lifetime characteristics.

According to an embodiment, the FWHM of the emission spectrum of the condensed cyclic compound may be about 10 nm to about 30 nm, for example, about 10 nm to about 25 nm.

In some embodiments, the emission peak wavelength in the emission spectrum of the condensed cyclic compound may be about 400 nm to about 500 nm, for example, about 440 nm to about 470 nm.

In some embodiments, the singlet (Si) energy level of the condensed cyclic compound may be about 2.4 eV to about 3.1 eV.

In some embodiments, the absolute value of the difference between the singlet (S₁) energy and the triplet (T₁) energy of the condensed cyclic compound may be about 0 eV to about 1 eV.

In some embodiments, the absolute value of the highest occupied molecular orbital (HOMO) energy level of the condensed cyclic compound may be about 4.0 eV to about 6.5 eV.

With respect to Compounds 1, 5, 10, 11, 12, 29, 48, 57 and 91, the HOMO energy level, the lowest unoccupied molecular orbital (LUMO) energy level, the S₁ energy level, the T₁ energy level, and ΔE_{ST} (absolute value of difference between the S₁ energy level and the T₁ energy level) were evaluated using the Gaussian 09 program involving molecular structure optimization by density functional theory (DFT) based on B3LYP. Results are shown in Table 1.

TABLE 1

| Compound | HOMO | LUMO | S₁ | T₁ | ΔEₛₜ |
|---|---|---|---|---|---|
| No. | (eV) | (eV) | (eV) | (eV) | (eV) |
| 1 | −4.70 | −1.18 | 2.76 | 2.66 | 0.1 |
| 5 | −4.67 | −1.12 | 2.68 | 2.59 | 0.09 |
| 10 | −5.031 | −1.356 | 2.78 | 2.69 | 0.08 |
| 11 | −4.97 | −1.42 | 2.70 | 2.59 | 0.11 |
| 12 | −4.93 | −1.37 | 2.74 | 2.62 | 0.12 |
| 29 | −4.84 | −1.46 | 2.61 | 2.51 | 0.1 |
| 48 | −4.73 | −1.21 | 2.63 | 2.59 | 0.04 |
| 57 | −4.92 | −1.38 | 2.64 | 2.60 | 0.04 |
| 91 | −5.00 | −1.48 | 2.64 | 2.59 | 0.05 |

The method for synthesizing the condensed cyclic compound may be recognized by those skilled in the art by referring to the synthesis examples described later.

### Light-Emitting Device

The condensed cyclic compound may be suitable for use in an interlayer of a light-emitting device, for example, as a material for an emission layer in the interlayer. Another aspect of the present disclosure provides a light-emitting device including a first electrode, a second electrode, and an interlayer which is arranged between the first electrode and the second electrode and includes an emission layer, wherein the interlayer includes at least one type of the condensed cyclic compounds.

Since the light-emitting device includes an interlayer including at least one type of the condensed cyclic compound as described above, the light-emitting device can emit blue light with a relatively small FWHM and a short wavelength shift, and has improved driving voltage, improved external quantum efficiency, improved luminescence efficiency, and/or improved lifetime characteristics.

The condensed cyclic compound may be used between a pair of electrodes of a light-emitting device. For example, the condensed cyclic compound may be included in the emission layer. In this regard, the emission layer may further include a host. The amount of the host may be greater than the amount of the condensed cyclic compound.

The emission layer may emit red light, green light, or blue light. For example, the emission layer may emit blue light.

According to an embodiment, the CIEy value of the light emitted from the emission layer may be about 0.040 to about 0.170, about 0.050 to about 0.170, about 0.060 to about 0.170, about 0.040 to about 0.165, about 0.050 to about 0.165, or about 0.060 to about 0.165.

In some embodiments, the emission peak wavelength of light emitted from the emission layer may be about 440 nm to about 470 nm, about 445 nm to about 470 nm, about 450 nm to about 470 nm, about 455 nm to about 470 nm, about 460 nm to about 470 nm, about 440 nm to about 465 nm, about 445 nm to about 465 nm, about 450 nm to about 465 nm, about 455 nm to about 465 nm, or about 460 nm to about 465 nm.

The emission layer may further include a host. The host may be as described herein.

The first electrode may be an anode, which is a hole injection electrode, and the second electrode may be a cathode, which is an electron injection electrode, or the first electrode may be a cathode, which is an electron injection electrode, and the second electrode may be an anode, which is a hole injection electrode.

For example, in the organic light-emitting device, the first electrode may be an anode, the second electrode may be a cathode, and the interlayer may further include a hole transport region between the first electrode and the emission layer and an electron transport region between the emission layer and the second electrode, wherein the hole transport region may include a hole injection layer, a hole transport layer, an electron-blocking layer, an auxiliary layer, or a combination thereof, and the electron transport region may include a buffer layer, a hole-blocking layer, an electron transport layer, an electron injection layer, or a combination thereof.

The term “interlayer” as used herein refers to a single and/or multiple layers disposed between a first electrode and a second electrode in an organic light-emitting device. The “interlayer” may include, in addition to an organic compound, an organometallic complex including a metal.

In some embodiments, the emission layer may include a first Embodiment or a second Embodiment:

### First Embodiment

The emission layer includes at least one condensed cyclic compound, and the condensed cyclic compound may function as an emitter, for example, a delayed fluorescence emitter. That is, the condensed cyclic compound may be an emitter. For example, the light emitted from the condensed cyclic compound may be at least 80%, at least 85%, at least 90%, or at least 95% of the total light-emitting components of the emission layer. The light emitted from the condensed cyclic compound may be blue light. The emission layer may further include a sensitizer, and the sensitizer and the condensed cyclic compound may be different from each other. The sensitizer may be an organometallic compound, a delayed fluorescence material, a prompt fluorescence material, or a combination thereof. The amount (weight) of the sensitizer may be about 0.01 parts by weight to about 10 parts by weight per 100 parts by weight of the emission layer.

### Second Embodiment

The emission layer includes at least one condensed cyclic compound, and the condensed cyclic compound may function as a sensitizer or an auxiliary dopant. That is, the condensed cyclic compound may be a sensitizer or an auxiliary dopant. The sensitizer may effectively transmit excitons from the host to the emitter. The emission layer may further include an emitter, and the emitter may be different from the condensed cyclic compound. The emitter may be an organometallic compound, a prompt fluorescence material, a delayed fluorescence material, or a combination thereof.

In this specification, an emitter is a host, a sensitizer, and/or an auxiliary dopant, which is a material that receives excitons and emits light through transition to the ground state.

The amount of the condensed cyclic compound in the first embodiment and the second embodiment may be about 0.01 parts by weight to about 40 parts by weight, about 0.1 parts by weight to about 20 parts by weight, about 1 part by weight to about 20 parts by weight, based on 100 parts by weight of the emission layer.

The organometallic compound in the first embodiment and the second embodiment includes a transition metal and n ligands bonded to the transition metal, and n may be an integer from 1 to 4.

According to an embodiment, regarding the organometallic compound, the transition metal may be platinum (Pt) or palladium (Pd), n may be 1, and the ligand may be a tetradentate ligand. The tetradentate ligand may include, for example, a carbene moiety bonded to the transition metal.

In some embodiments, the organometallic compound includes a transition metal and a tetradentate ligand bonded to the transition metal, the transition metal may be platinum or palladium, and the tetradentate ligand may be a carbene moiety bonded to the transition metal.

In some embodiments, regarding the organometallic compound, the transition metal may be iridium (Ir) or osmium (Os), n may be 3, and at least one of the n ligands may be a bidentate ligand including —F, a cyano group, or a combination thereof, or a bidentate ligand including a carbene moiety bonded to the transition metal. For example, the bidentate ligand may further include an imidazole group or a triazole group.

In some embodiments, the organometallic compound may be an organometallic compound represented by Formula 3 and/or an organometallic compound represented by Formula 5 described herein. Details of Formulae 3 and 5 are provided below.

The delayed fluorescence material in the first embodiment and the second embodiment may be, for example, a heat-activated delayed fluorescence material. As another example, the delayed fluorescence material may be a multiple resonance thermally activated delayed fluorescence material.

The multiple resonance thermally activated delayed fluorescence may be a polycyclic compound which that i) does not include a transition metal, and ii) has a core in which two or more C₃-C₆₀ cyclic groups are condensed with each other. In this regard, two C₃-C₆₀ cyclic groups of the core may be condensed with each other while sharing boron (B) or nitrogen (N).

According to an embodiment, the delayed fluorescence material may be a polycyclic compound represented by Formula 4 below. Details of Formula 4 will be provided below.

The prompt fluorescence material in the first embodiment and the second embodiment may be an amino group-containing compound, a styryl group-containing compound, etc. For example, the prompt fluorescence material may include a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group (a tetracene group), a picene group, a perylene group, a pentaphene group, an indenoanthracene group, a group represented by one of Formulae 501-1 to 501-21 below, or a combination thereof:

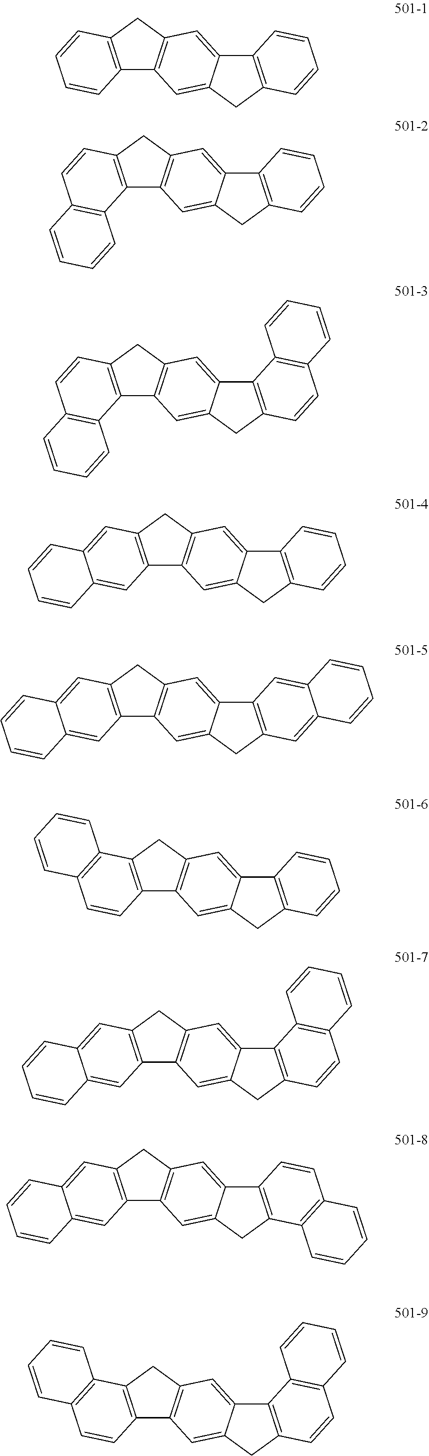

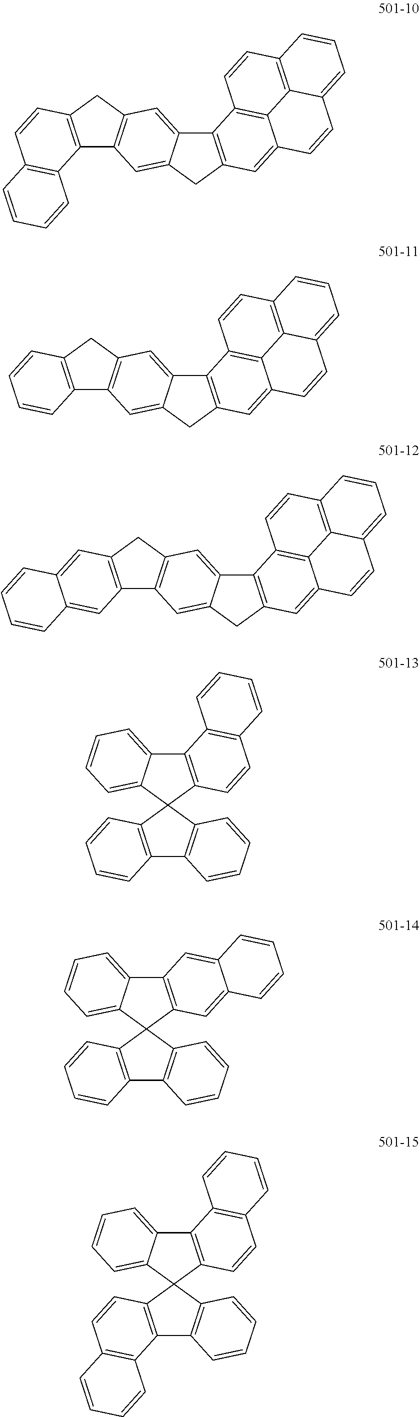

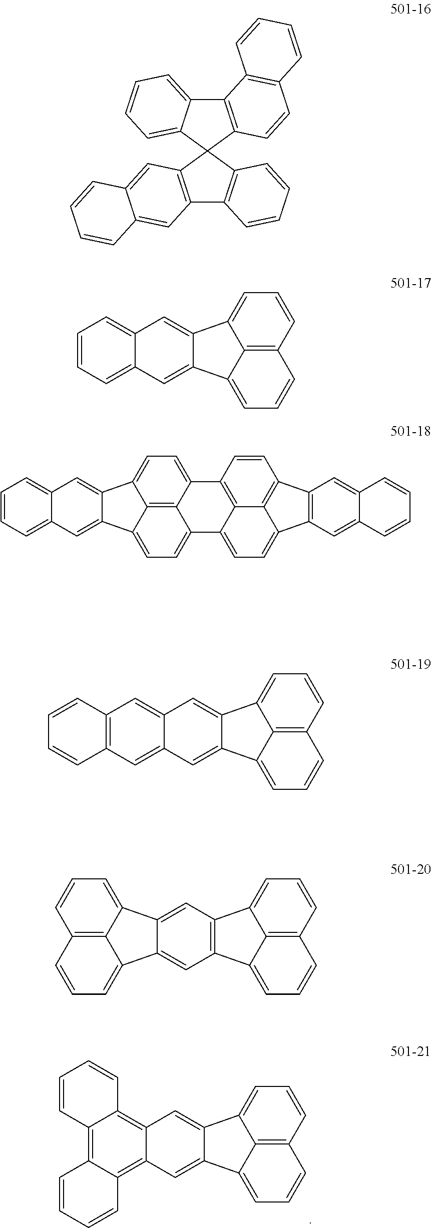

In some embodiments, the prompt fluorescence material may include a compound represented by Formula 501A or 501B:

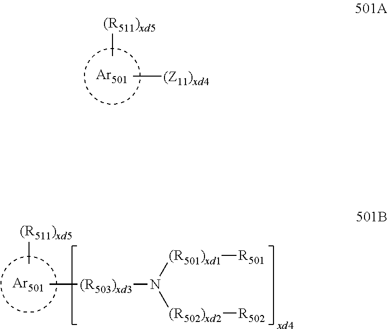

wherein, in Formulae 501A and 501B,
Ar₅₀₁ may be a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group, a picene group, a perylene group, a pentaphene group, an indenoanthracene group, a bisanthracene group, or a group represented by one of Formulae 501-1 to 501-21,
R₅₁₁ may be hydrogen, deuterium, —F, —Cl, —Br, —I, a hydroxyl group, a nitro group, an amino group, a amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed polycyclic group, or —Si(Q₅₀₁)(Q₅₀₂)(Q₅₀₃),
xd5 may be an integer from 0 to 10,
L₅₀₁ to L₅₀₃ may each independently be:
a single bond; and
a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, or a divalent non-aromatic condensed heteropolycyclic group, each unsubstituted or substituted with deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₅₀₁)(Q₅₀₂) (Q₅₀₃), or a combination thereof,
xd1 to xd3 may each independently be 1, 2, or 3,
R₅₀₁ and R₅₀₂ may each independently be a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, or a dibenzosilolyl group, each unsubstituted or substituted with deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₅₀₁)(Q₅₀₂)(Q₅₀₃), or a combination thereof,
Z₁₁ may be a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, an a monovalent non-aromatic condensed polycyclic group, or a monovalent non-aromatic condensed heteropolycyclic group, each unsubstituted or substituted with deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed polycyclic group, —Si(Q₅₀₁)(Q₅₀₂)(Q₅₀₃), or a combination thereof,
xd4 may be 1, 2, 3, 4, 5, or 6, and
Q₅₀₁ to Q₅₀₃ may each independently selected from hydrogen, a C₁-C₆₀ alkyl group, a C₁-C₆₀ alkoxy group, a C₆-C₆₀ aryl group, a C₁-C₆₀ heteroaryl group, a monovalent non-aromatic condensed polycyclic group, or a monovalent non-aromatic condensed heteropolycyclic group.

In some embodiments, the prompt fluorescence material includes a compound represented by Formula 501A or 501B, wherein xd4 in Formula 501A may be 1, 2, 3, 4, 5, or 6, and xd4 in Formula 501B may be 2, 3, or 4.

### Description of Host

m1 hosts in the emission layer may include a hole-transporting compound, an electron-transporting compound, an anodic compound, or a combination thereof. Each of the first host and the second host may not include a transition metal.

For example, m1 in the emission layer is 2, two hosts in the emission layer each include a hole-transporting compound and an electron-transporting compound, and the hole-transporting compound and the electron-transporting compound may be different from each other.

According to an embodiment, the hole-transporting compound may be a compound that includes at least one π electron-rich C₃-C₆₀ cyclic group and does not include an electron-transporting group. Examples of the electron-transporting group are a cyano group, a fluoro group, a π-electron-deficient nitrogen-including cyclic group, a phosphine oxide group, a sulfoxide group, and the like.

The term “π-electron deficient nitrogen-including cyclic group” as used herein may be a C₁-C₆₀ heterocyclic group having at least one *—N═*′ moiety as a ring-forming moiety. Examples of the π-electron deficient nitrogen-including cyclic group are a triazine group, an imidazole group, and the like.

The term “π electron-rich C₃-C₆₀ cyclic group” as used herein may be a C₃-C₆₀ cyclic group that does not include the *—N═*′ moiety as a ring-forming moiety. Examples of the π electron-rich C₃-C₆₀ cyclic group are a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group.

For example, the hole-transporting compound may include two or more carbazole groups.

In some embodiments, the electron-transporting compound may be a compound including at least one electron-transporting group. The electron-transporting group may be a cyano group, a fluoro group, a π electron-deficient nitrogen-including C₁-C₆₀ cyclic group, a phosphine oxide group, a sulfoxide group, or a combination thereof. According to an embodiment, the electron-transporting compound may include a triazine group.

For example, the electron-transporting compound may include: at least one electron-transporting group (for example, a triazine group); and at least one π electron-rich C₃-C₆₀ cyclic group (for example, a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, a dibenzocarbazole group, or a combination thereof).

According to an embodiment, the hole-transporting compound may be a compound represented by Formula 6:

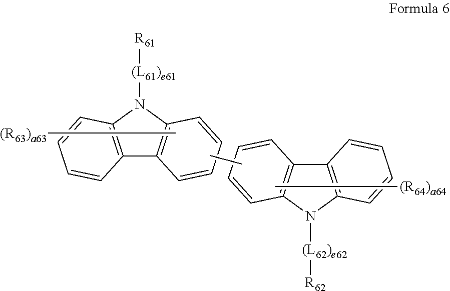

wherein, in Formula 6,
L₆₁ and L₆₂ may each independently be a π electron-rich C₃-C₆₀ cyclic group, unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, or a (C₁-C₂₀ alkyl)biphenyl group, —Si(Q₃₃) (Q₃₄) (Q₃₅),
e61 and e62 may each independently be an integer from 1 to 6,
R₆₁ to R₆₄ may each independently be:
hydrogen, deuterium, a C₁-C₂₀ alkyl group, or a deuterated C₁-C₂₀ alkyl group;
a π electron rich C₃-C₆₀ cyclic group that is unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, a (C₁-C₂₀alkyl)biphenyl group, —Si(Q₃₃)(Q₃₄)(Q₃₅), or a combination thereof,
—Si(Q₃)(Q₄)(Q₅), and
a63 and a64 may each independently be an integer from 0 to 7.

Descriptions of each of Q₃ to Q₅ and Q₃₃ to Q₃₅ are as described herein.

In some embodiments, the hole-transporting compound may be a compound represented by Formulae 6-1, 6-2, or 6-3:

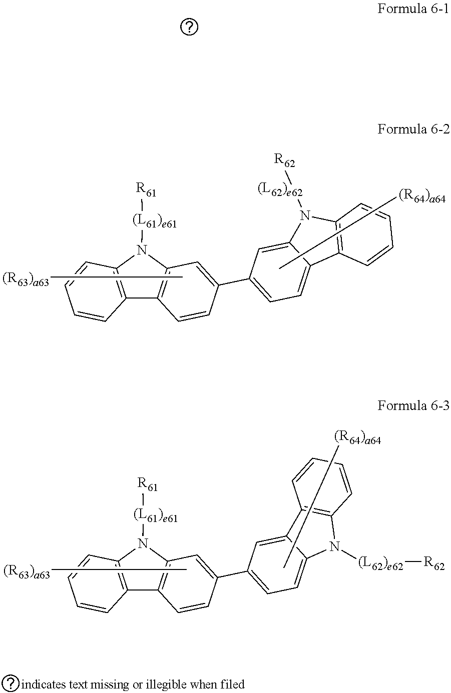

wherein, in Formulae 6-1 to 6-3, L₆₁, L₆₂, R₆₁ to R₆₄, e61, e62, a63, and a64 are respectively the same as those described herein.

In some embodiments, the hole-transporting compound may be one of Compounds HTH1 to HTH6:

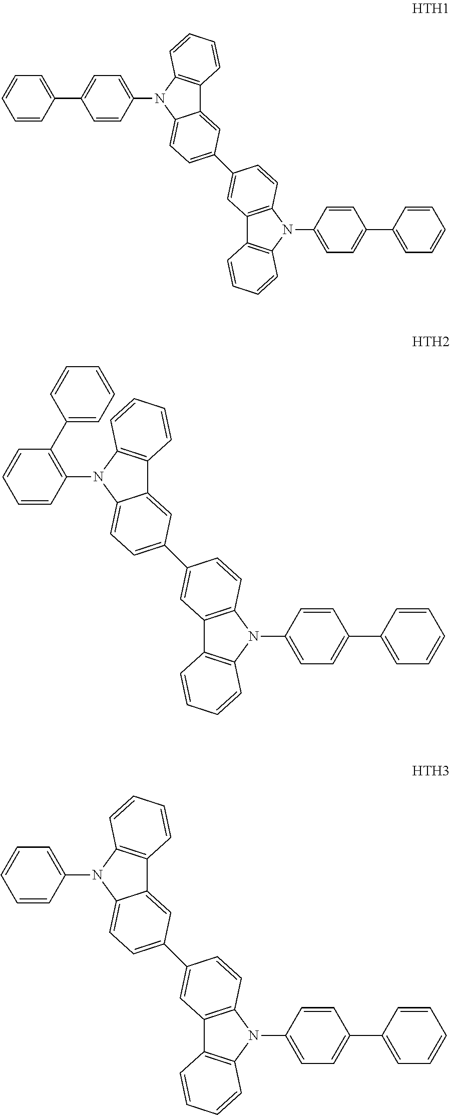 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccccc5)ccc43)cc2)cc1]

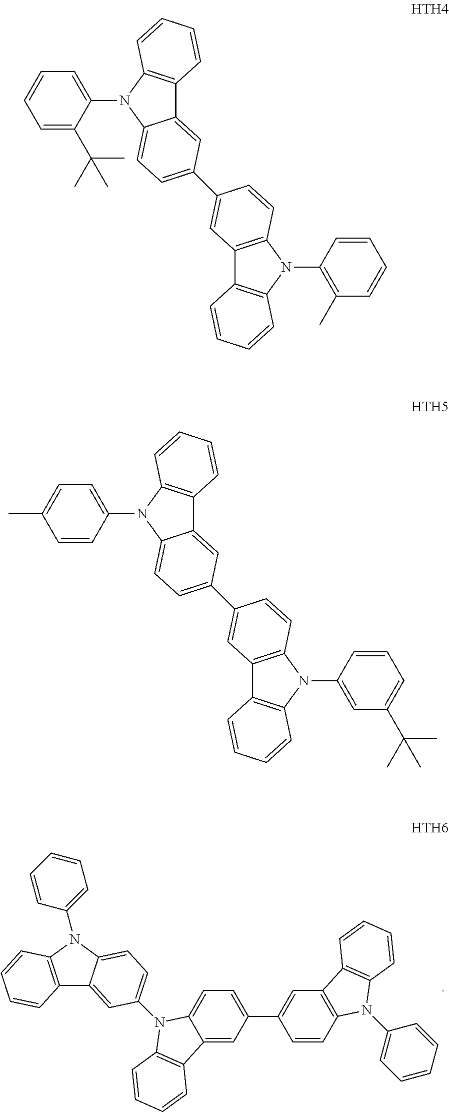 [SMILES: Cc1ccccc1-n1c2ccccc2c2cc(-c3ccc4c(c3)c3ccccc3n4-c3ccccc3C(C)(C)C)ccc21 ; Cc1ccc(-n2c3ccccc3c3cc(-c4ccc5c(c4)c4ccccc4n5-c4cccc(C(C)(C)C)c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

In some embodiments, the electron-transporting compound may be a compound represented by Formula 7:

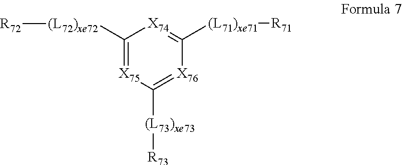

wherein, in Formula 7,
X₇₄ may be C(R₇₄) or N, X₇₅ may be C(R₇₅) or N, X₇₆ may be C(R₇₆) or N, and at least one of X₇₄ to X₇₆ may be N,
L₇₁ to L₇₃ may each independently be a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated phenyl group, a (C₁-C₂₀ alkyl)biphenyl group, —Si(Q₃₃)(Q₃₄)(Q₃₅), or a combination thereof,
e71 to e73 may each independently be an integer from 1 to 10,
R₇₁ to R₇₆ may each independently be:
hydrogen, deuterium, —F, or a cyano group;
a C₁-C₂₀ alkyl group that is unsubstituted or substituted with deuterium, —F, a cyano group, or a combination thereof;
a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated phenyl group, a (C₁-C₂₀ alkyl)biphenyl group, a —Si(Q₃₃)(Q₃₄)(Q₃₅), or a combination thereof; or
—Si(Q₃)(Q₄)(Q₅).

Descriptions of each of Q₃ to Q₅ and Q₃₃ to Q₃₅ are as described herein.

In some embodiments, each of X₇₄ to X₇₆ in Formula 7 may be N.

In some embodiments, L₇₁ to L₇₃ in Formula 7 may each independently be a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl) phenyl group, a biphenyl group, a deuterated biphenyl group, a fluorinated phenyl group, a (C₁-C₂₀ alkyl) biphenyl group, —Si(Q₃₃)(Q₃₄)(Q₃₅), or a combination thereof.

In some embodiments, in Formula 7, at least one L₇₁, at least one L₇₂, at least one of L₇₃, or a combination thereof may each independently be a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated phenyl group, a (C₁-C₂₀alkyl) biphenyl group, a —Si(Q₃₃) (Q₃₄) (Q₃₅), or a combination thereof.

In some embodiments, in Formula 7, at least one L₇₁, at least one L₇₂, at least one L₇₃, or a combination thereof may be a carbazole group, an indolocarbazole group, a benzocarbazole group, a naphthocarbazole group, or a dibenzocarbazole group, each of which has a nitrogen atom connected to a carbon atom of a 6-membered ring including X₇₄ to X₇₆ in Formula 7 via a single bond or neighboring L₇₁, L₇₂ and/or L₇₃ therebetween.

In some embodiments, e71 to e73 in Formula 7 represent the number of L₇₁ to the number of L₇₃, respectively, and may each independently be, for example, 1, 2, 3, 4, or 5.

In some embodiments, R₇₁ to R₇₆ in Formula 7 may each independently be:
hydrogen, deuterium, —F, or a cyano group;
a C₁-C₂₀ alkyl group that is unsubstituted or substituted with deuterium, —F, a cyano group, or a combination thereof;
a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated phenyl group, a (C₁-C₂₀alkyl)biphenyl group, —Si(Q₃₃)(Q₃₄)(Q₃₅), or a combination thereof; or
—Si(Q₃)(Q₄)(Q₅).

In some embodiments, the electron-transporting compound may be one of Compounds ETH1 to ETH7:

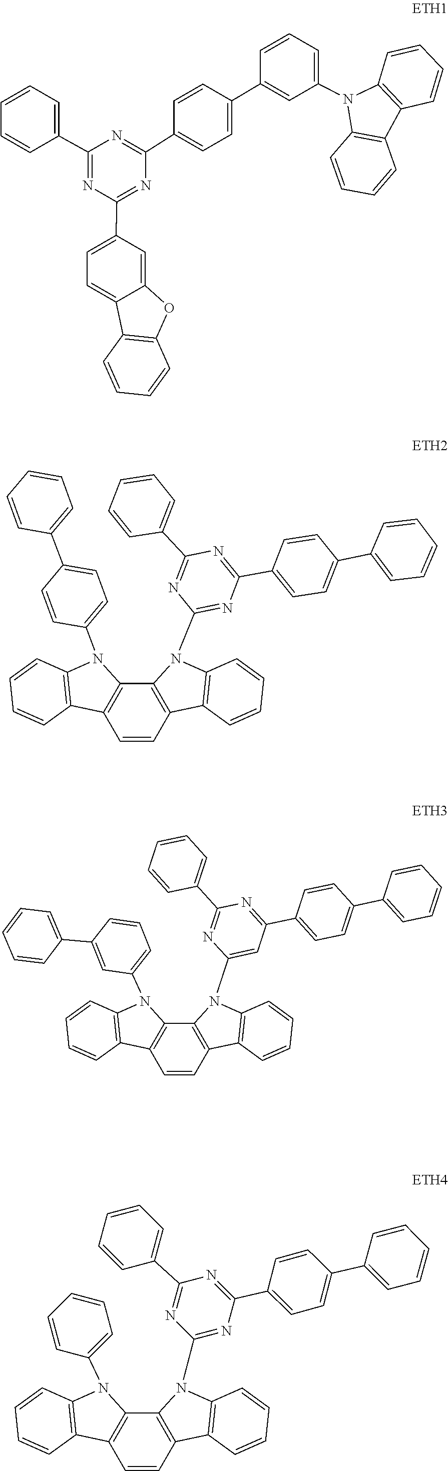 [SMILES: c1ccc(-c2nc(-c3ccc(-c4cccc(-n5c6ccccc6c6ccccc65)c4)cc3)nc(-c3ccc4c(c3)oc3ccccc34)n2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-c3cc(-n4c5ccccc5c5ccc6c7ccccc7n(-c7cccc(-c8ccccc8)c7)c6c54)nc(-c4ccccc4)n3)cc2)cc1 ; c1ccc(-c2ccc(-c3nc(-c4ccccc4)nc(-n4c5ccccc5c5ccc6c7ccccc7n(-c7ccccc7)c6c54)n3)cc2)cc1]

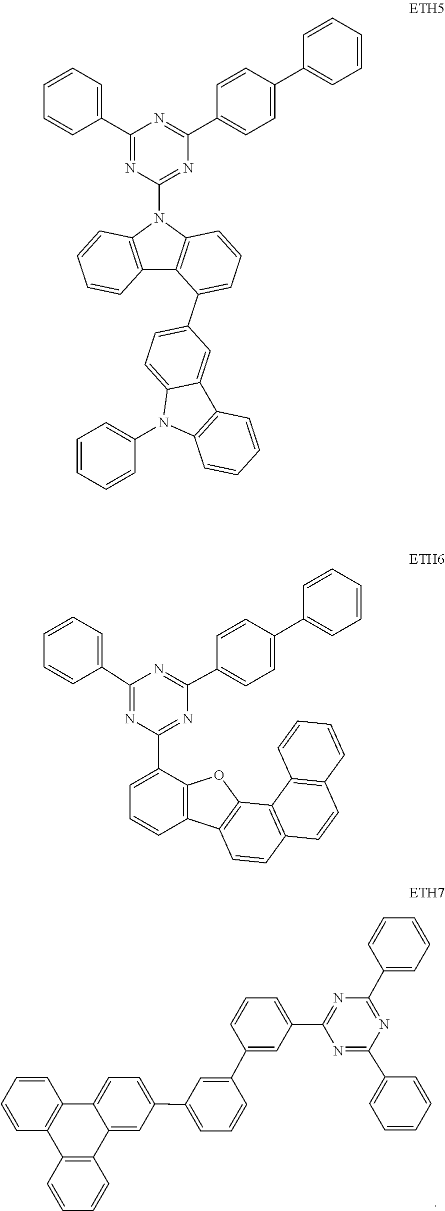 [SMILES: c1ccc(-c2ccc(-c3nc(-c4ccccc4)nc(-n4c5ccccc5c5c(-c6ccc7c(c6)c6ccccc6n7-c6ccccc6)cccc54)n3)cc2)cc1 ; c1ccc(-c2ccc(-c3nc(-c4ccccc4)nc(-c4cccc5c4oc4c5ccc5ccc6ccccc6c54)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1]

### Description of Formula 3

The organometallic compound in the first embodiment and the second embodiment may be an organometallic compound represented by Formula 3:

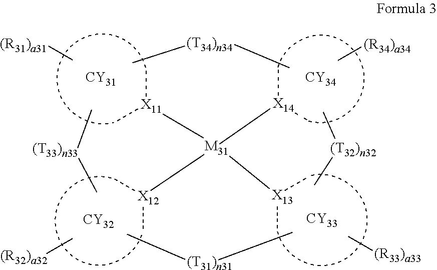

wherein, in Formula 3,
M₃₁ may be a transition metal,
X₁₁ to X₁₄ may each independently be C or N, two bonds of a bond between X₁₁ and M₃₁, a bond between X₁₂ and M₃₁, a bond between X₁₃ and M₃₁, and a bond between X₁₄ and M₃₁ may each be a coordinate bond, and the other two bonds may each be a covalent bond,
ring CY₃₁ to ring CY₃₄ may each independently be a C₅-C₃₀ carbocyclic group or a C₁-C₃₀ heterocyclic group,
T₃₁ may be a single bond, a double bond, *—N(R₃₅ₐ)—*′, *—B(R₃₅ₐ)—*′, *—P(R₃₅ₐ)—*′, *—C(R₃₅ₐ)(R_{35b})—*′, *—Si(R₃₅ₐ)(R_{35b})—*′, *—Ge(R₃₅ₐ)(R_{35b})—*′, *—S—*′, *—Se—*′, *—O—*′, *—C(═O)—*′, *—S(═O)—*′, *—S(═O)₂—*′, *—C(R₃₅ₐ)═*′, *═C(R₃₅ₐ)—*′, *—C(R₃₅ₐ)═C(R_{35b})—*′, *—C(═S)—*′, *C≡C—*, a C₅-C₃₀ carbocyclic group unsubstituted or substituted with at least one R₁₀ₐ, or a C₁-C₆₀ heterocyclic group unsubstituted or substituted with at least one R₁₀ₐ,
T₃₂ may be a single bond, a double bond, *—N(R₃₆ₐ)—*′, *—B(R₃₆ₐ)—*′, *—P(R₃₆ₐ)—*′, *—C(R₃₆ₐ)(R_{36b})—*′, *—Si(R₃₆ₐ)(R_{36b})—*′, *—Ge(R₃₆ₐ)(R_{36b})—*′, *—S—*′, *—Se—*′, *—O—*′, *—C(═O)—*′, *—S(═O)—*′, *—S(═O)₂—*′, *—C(R₃₆ₐ)═*′, *═C(R₃₆ₐ)—*′, *—C(R₃₆ₐ)═C(R_{36b})—*′, *—C(═S)—*′, *—C≡C—*,
a C₅-C₃₀ carbocyclic group unsubstituted or substituted with at least one R₁₀ₐ, or a C₁-C₆₀ heterocyclic group unsubstituted or substituted with at least one R₁₀ₐ,
T₃₃ may be a single bond, a double bond, *—N(R₃₇ₐ)—*′, *—B(R₃₇ₐ)—*′, *—P(R₃₇ₐ)—*′, *—C(R₃₇ₐ)(R_{37b})—*′, *—Si(R₃₇ₐ)(R_{37b})—*′, *—Ge(R₃₇ₐ)(R_{37b})—*′, *—S—*′, *—Se—*′, *—O—*′, *—C(═O)—*′, *—S(═O)—*′, *—S(═O)₂—*′, *—C(R₃₇ₐ)═*′, *═C(R₃₇ₐ)—*′, *—C(R₃₇ₐ)═C(R_{37b})—*′, *—C(═S)—*′, *—C≡C—*′, a C₅-C₃₀ carbocyclic group unsubstituted or substituted with at least one R₁₀ₐ, or a C₁-C₆₀ heterocyclic group unsubstituted or substituted with at least one R₁₀ₐ,
T₃₄ may be a single bond, a double bond, *—N(R₃₈ₐ)—*′, *—B(R₃₈ₐ)—*′, *—P(R₃₈ₐ)—*′, *—C(R₃₈ₐ)(R_{38b})—*′, *—Si(R₃₈ₐ)(R_{38b})—*′, *—Ge(R₃₈ₐ)(R_{38b})—*′, *—S—*′, *—Se—*′, *—O—*′, *—C(═O)—*′, *—S(═O)—*′, *—S(═O)₂—*′, *—C(R₃₈ₐ)═*′, *═C(R₃₈ₐ)—*′, *—C(R₃₈ₐ)═C(R_{38b})—*′, *—C(═S)—*′, *—C≡C—*, a C₅-C₃₀ carbocyclic group unsubstituted or substituted with at least one R₁₀ₐ, or a C₁-C₃₀ heterocyclic group unsubstituted or substituted with at least one R₁₀ₐ,
n31 to n34 may each independently be an integer from 0 to 5, and three or more of n31 to n34 may each independently be an integer from 1 to 5,
when n31 is 0, T₃₁ may not be present, when n32 is 0, T₃₂ may not be present, when n33 is 0, T₃₃ may not be present, and when n34 is 0, T₃₄ may not be present,
when n31 is 2 or more, two or more of T₃₁(s) may be identical to or different from each other, when n32 is 2 or more, two or more of T₃₂(s) may be identical to or different from each other, when n33 is 2 or more, two or more of T₃₃(s) may be identical to or different from each other, and when n34 is 2 or more, two or more of T₃₄(s) may be identical to or different from each other,
R₃₁ to R₃₄, R₃₅ₐ, R_{35b}, R₃₆ₐ, R_{36b}, R₃₇ₐ, R_{37b}, R₃₈ₐ, and R_{38b} may each independently be hydrogen, deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a31 to a34 may each independently be an integer from 0 to 20,
two or more of a31 R₃₁ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more R₃₂ groups may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more R₃₃ groups may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more R₃₄ groups may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₁ to R₃₄, R₃₅ₐ, R_{35b}, R₃₆ₐ, R_{36b}, R₃₇ₐ, R_{37b}, R₃₈ₐ, and R_{38b} may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ is as described in connection with R₃₁,
* and *′ each indicate a binding site to a neighboring atom,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ heteroaryl alkyl group, the substituted monovalent non-aromatic condensed polycyclic group, and the substituted monovalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, a Q₁₁ to Q₁₉, a Q₂₁ to Q₂₉ and Q₃₁ to Q₃₉ may each independently be hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₂-C₁₀ heterocycloalkenyl group; a C₆-C₆₀ aryl group unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

According to an embodiment, M₃₁ in Formula 3 may be Pt, Pd, or Au.

In some embodiments, M₃₁ in Formula 3 may be Pt or Pd.

In some embodiments, the bond between X₁₁ and M₃₁ in Formula 3 may be a coordinate bond.

In some embodiments, in Formula 3, X₁₁ may be C, and a bond between X₁₁ and M₃₁ may be a coordinate bond. That is, X₁₁ in Formula 3 may be C in a carbene moiety.

In some embodiments, ring CY₃₁ to ring CY₃₄ in Formula 3 may each independently be i) a first ring, ii) a second ring, iii) a condensed ring in which two or more first rings are condensed with each other, iv) a condensed ring in which two or more second rings are condensed with each other, or v) a condensed ring in which at least one first ring is condensed with at least one second ring,
wherein the first ring may be a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornane group, a norbornene group, a cyclohexane group, a cyclohexene group, a benzene group, a pyridine group, a pyrimidine group, a pyrazine group, a pyridazine group, a triazine group, an oxazine group, a thiazine group, a dihydropyrazine group, a dihydropyridine group, or a dihydroazasilane group.

According to an embodiment, R₃₁ to R₃₄, R₃₅ₐ, R_{35b}, R₃₆ₐ, R_{36b}, R₃₇ₐ, R_{37b}, R₃₈ₐ, and R_{38b} may each independently be:
hydrogen, deuterium, —F, —Cl, —Br, —I, —CD₃, —CD₂H, —CDH₂, —CF₃, —CF₂H, —CFH₂, a cyano group (CN), a nitro group, an amino group, a C₁-C₂₀ alkyl group, or a C₁-C₂₀ alkoxy group;
a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a cyano group (CN), a nitro group, an amino group, a phenyl group, or a combination thereof; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, or an anthracenyl group, each unsubstituted or substituted with at least one of deuterium, —F, —Cl, —Br, —I, —CD₃, —CD₂H, —CDH₂, —CF₃, —CF₂H, —CFH₂, a cyano group (CN), a nitro group, an amino group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, or a combination thereof.

According to an embodiment, the organometallic compound represented by Formula 3 may be an organometallic compound represented by Formula 3-1 or an organometallic compound represented by Formula 3-2:

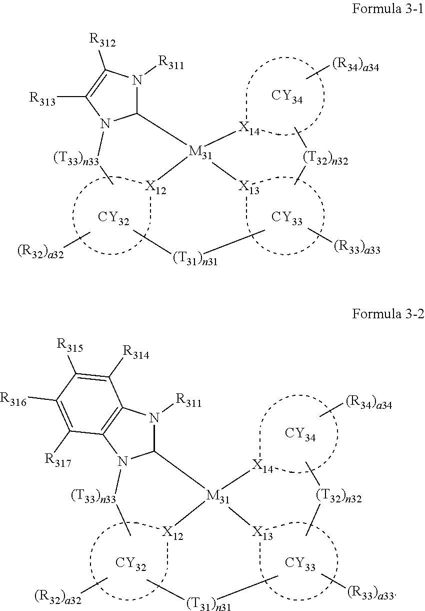

The bond between the carbon of the imidazole group and M₃₁ in Formula 3-1 may be a coordinate bond. That is, the imidazole group in Formula 3-1 may include a carbene moiety bonded to M₃₁.

The bond between the carbon of the benzimidazole group and M₃₁ in Formula 3-2 may be a coordinate bond. That is, the benzimidazole group in Formula 3-2 includes a carbene moiety bonded to M₃₁.

In Formulae 3-1 and 3-2,
M₃₁, CY₃₂, CY₃₃, CY₃₄, X₁₂, X₁₃, X₁₄, T₃₁, T₃₂, T₃₃, n31, n32, n33, R₃₂, R₃₃, R₃₄, a32, a33, and a34 may respectively be understood by referring to the descriptions of M₃₁, CY₃₂, CY₃₃, CY₃₄, X₁₂, X₁₃, X₁₄, T₃₁, T₃₂, T₃₃, n31, n32, n33, R₃₂, R₃₃, R₃₄, a32, a33, and a34 provided herein, and
R₃₁₁ to R₃₁₇ may each be understood by referring to the description of R₃₁ provided herein.

In an embodiment, in Formulae 3-1 and 3-2,
R₃₁₁ to R₃₁₇ may each independently be:
hydrogen, deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a carboxylic acid group or a salt thereof, a sulfonic acid group or a salt thereof, or a phosphoric acid group or a salt thereof;
a C₁-C₂₀ alkyl group or a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, or a combination thereof;
a C₃-C₁₀ cycloalkyl group, a C₁-C₁₀ heterocycloalkyl group, a C₆-C₆₀ aryl group, a C₇-C₆₀ arylalkyl group, a C₆-C₆₀ aryloxy group, a C₆-C₆₀ arylthio group, a C₁-C₆₀ heteroaryl group, a substituted or unsubstituted C₂-C₆₀ heteroaryl alkyl group, a monovalent non-aromatic condensed polycyclic group, a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a C₁-C₂₀ alkyl group, a C₁-C₂₀ alkoxy group, or a combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

For example, in Formulae 3-1 and 3-2,
at least one of R₃₁₁ to R₃₁₇ may be
a C₁-C₂₀ alkyl group, a C₆-C₆₀ aryl group, or a C₇-C₆₀ arylalkyl group, each unsubstituted or substituted with at least one of a methyl group, an ethyl group, an n-propyl group, an isopropyl group, an n-butyl group, an isobutyl group, a sec-butyl group, a tert-butyl group, a phenyl group, a cumyl group, or a combination thereof.

### Description of Formula 5

The organometallic compound in the first embodiment and the second embodiment may be an organometallic compound represented by Formula 5:

M₅₁(L₅₁)ₙ₅₁(L₅₂)ₙ₅₂ Formula 5

wherein M₅₁ in Formula 5 may be a transition metal.

In an embodiment, M₅₁ may be a first-row transition metal, a second-row transition metal, or a third-row transition metal of the Periodic Table of Elements.

In some embodiments, M₅₁ may be iridium (Ir), platinum (Pt), osmium (Os), titanium (Ti), zirconium (Zr), hafnium (Hf), europium (Eu), terbium (Tb), thulium (Tm), or rhodium (Rh).

In some embodiments, M₅₁ may be Ir, Pt, Os, or Rh.

In some embodiments, M₅₁ may be Ir or Os.

In Formula 5, L₅₁ may be a ligand represented by Formula 5A, and L₅₂ may be a ligand represented by Formula 5B:

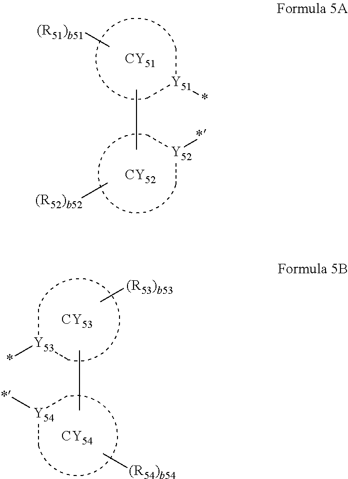

wherein Formulae 5A and 5B are each as described in the herein.

In an embodiment, n51 in Formula 5 may be 1, 2, or 3, wherein, when n51 is 2 or more, two or more of L₅₁(s) may be identical to or different from each other.

In an embodiment, n52 in Formula 5 may be 0, 1, or 2, wherein, when n52 is 2, two L₅₂(s) may be identical to or different from each other.

The sum of n51 and n52 in Formula 5 may be 2 or 3. For example, the sum of n51 and n52 may be 3.

In an embodiment, in Formula 5, i) M may be Ir, and n51+n52=3; or ii) M may be Pt, and n51+n52=2.

In some embodiments, in Formula 5, M may be Ir, and i) n51 may be 1, and n52 may be 2, or ii) n51 may be 2, and n52 may be 1.

L₅₁ and L₅₂ in Formula 5 may be different from each other.

Y₅₁ to Y₅₄ in Formulae 5A to 5B may each independently be C or N. For example, Y₅₁ and Y₅₃ may each be N, and Y₅₂ and Y₅₄ may each be C.

Ring CY₅₁ to ring CY₅₄ in Formulae 5A and 5B may each independently be a C₅-C₃₀ carbocyclic group or a C₁-C₃₀ heterocyclic group.

For example, ring CY₅₁ to ring CY₅₄ in Formulae 5A and 5B may each independently include i) a third ring, ii) a fourth ring, iii) a condensed ring in which two or more third rings are condensed with each other, iv) a condensed ring in which two or more fourth rings are condensed with each other, or v) a condensed ring in which at least one third ring is condensed with at least one fourth ring,
wherein the third ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and
the fourth ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In some embodiments, in Formulae 5A and 5B, ring CY₁ to ring CY₄ may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, an imidazole group, a triazole group, an oxazole group, an isooxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

For example, ring CY₅₁ and ring CY₅₃ in Formulae 5A and 5B may be different from each other.

In some embodiments, ring CY₅₂ and ring CY₅₄ in Formulae 5A and 5B may be different from each other.

In some embodiments, ring CY₅₁ to ring CY₅₄ in Formulae 5A and 5B may be different from each other.

R₅₁ to R₅₄ in Formulae 5A and 5B may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₅₁)(Q₅₂), —Si(Q₅₃)(Q₅₄)(Q₅₅), —Ge(Q₅₃)(Q₅₄)(Q₅₅), —B(Q₅₆)(Q₅₇), —P(═O)(Q₅₈)(Q₅₉), or —P(Q₅₈)(Q₅₉). Q₅₁ to Q₅₉ are each as described in the present specification.

In an embodiment, R₅₁ to R₅₄ in Formulae 5A and 5B may each independently be: hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group or azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a (phenyl)C₁-C₁₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₅₁)(Q₅₂), —Ge(Q₅₃)(Q₅₄)(Q₅₅), —B(Q₅₆)(Q₅₇), —P(═O)(Q₅₈)(Q₅₉), or —P(Q₅₈)(Q₅₉),
wherein Q₅₁ to Q₅₉ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

In some embodiments, R₅₁ to R₅₄ may each independently be:
hydrogen, deuterium, —F, or a cyano group;
a C₁-C₂₀ alkyl group unsubstituted or substituted with deuterium, a cyano group, a C₃-C₁ cycloalkyl group, a deuterated C₃-C₁ cycloalkyl group, a fluorinated C₃-C₁ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated a phenyl group, a fluorinated a phenyl group, a (C₁-C₂₀ alkyl)phenyl group, a biphenyl group, a deuterated a biphenyl group, a fluorinated a biphenyl group, a (C₁-C₂₀ alkyl)biphenyl group, a dibenzofuranyl group, a deuterated a dibenzofuranyl group, a fluorinated a dibenzofuranyl group, a (C₁-C₂₀ alkyl)dibenzofuranyl group, a dibenzothiophenyl group, a deuterated a dibenzothiophenyl group, a fluorinated a dibenzothiophenyl group, a (C₁-C₂₀ alkyl)dibenzothiophenyl group, or a combination thereof;
a C₃-C₁ cycloalkyl group, a C₁-C₁₀ heterocycloalkyl group, a phenyl group, or a biphenyl group, each unsubstituted or substituted with deuterium, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated a biphenyl group, a (C₁-C₂₀ alkyl)biphenyl group, a dibenzofuranyl group, a deuterated dibenzofuranyl group, a fluorinated a dibenzofuranyl group, a (C₁-C₂₀ alkyl)dibenzofuranyl group, a dibenzothiophenyl group, a deuterated dibenzothiophenyl group, a fluorinated a dibenzothiophenyl group, a (C₁-C₂₀ alkyl)dibenzothiophenyl group, or a combination thereof; or
—Si(Q₅₃)(Q₅₄)(Q₅₅) or —Ge(Q₅₃)(Q₅₄)(Q₅₅).
b51 to b54 in Formulae 5A and 5B indicate the numbers of R₅₁ to R₅₄, respectively, and may each independently be an integer from 0 to 20. When b51 is 2 or more, two or more of R₅₁ may be identical to or different from each other, when b52 is 2 or more, two or more of R₅₂ may be identical to or different from each other, when b53 is 2 or more, two or more of R₅₃ may be identical to or different from each other, and when b54 is 2 or more, two or more of R₅₄ may be identical to or different from each other. For example, b51 to b54 may each independently be an integer from 0 to 8.

According to an embodiment, in Formula 5A, Y₅₂ may be C, the bond between Y₅₂ and M₅₁ may be a covalent bond, and at least one of b52 R₅₂ may be a cyano group or —F.

In some embodiments, in Formula 5A, Y₅₁ may be N, the bond between Y₅₁ and M₅₁ may be a coordination bond, CY₅₁ may be an imidazole group, a triazole group, a benzimidazole group, or a triazolopyridine group, and at least one of b52 R₅₂ may be a cyano group or —F.

In some embodiments, in Formula 5A, Y₅₁ may be C, and the bond between Y₅₁ and M₅₁ may be a coordinate bond.

In some embodiments, in Formula 5A, Y₅₁ may be C, the bond between Y₅₁ and M₅₁ may be a coordinate bond, and CY₅₁ may be a benzimidazole group or an imidazopyrazine group.

Specific examples of organometallic compounds represented by Formula 3 or Formula 5

For example, the organometallic compound represented by Formula 3 or Formula 5 may be one of Compounds P1 to P52:

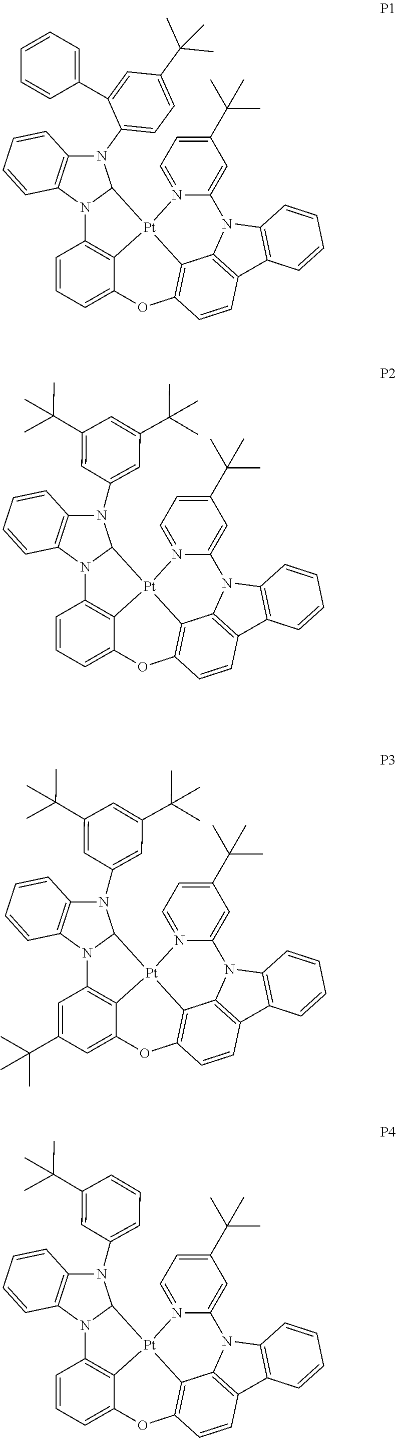

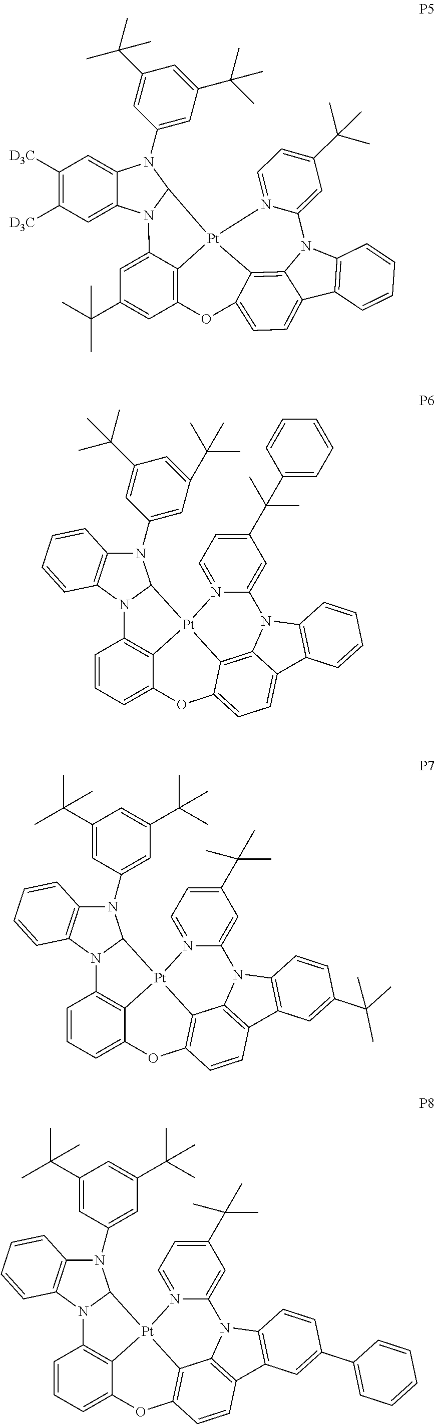

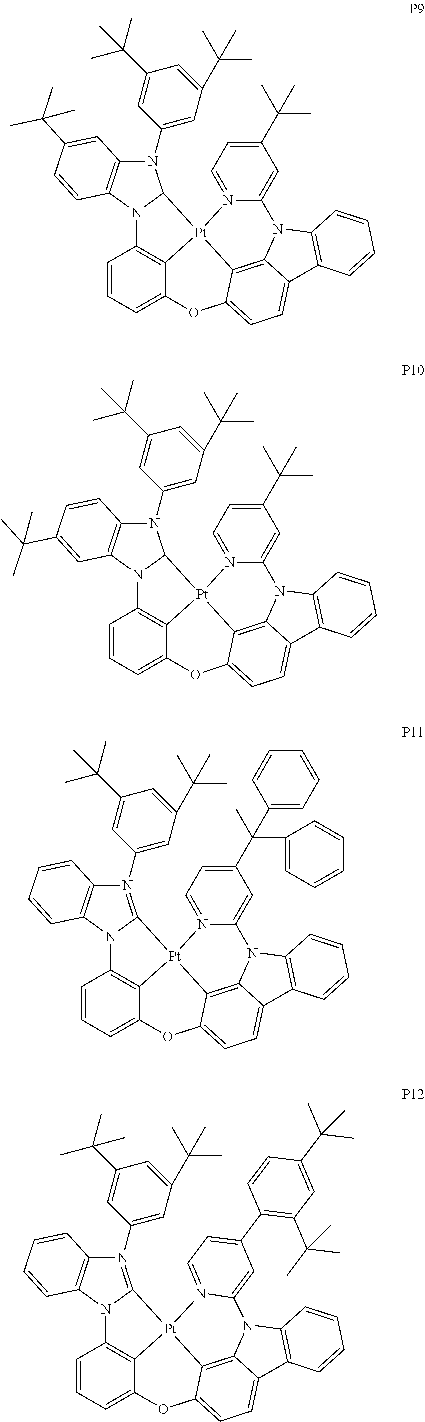

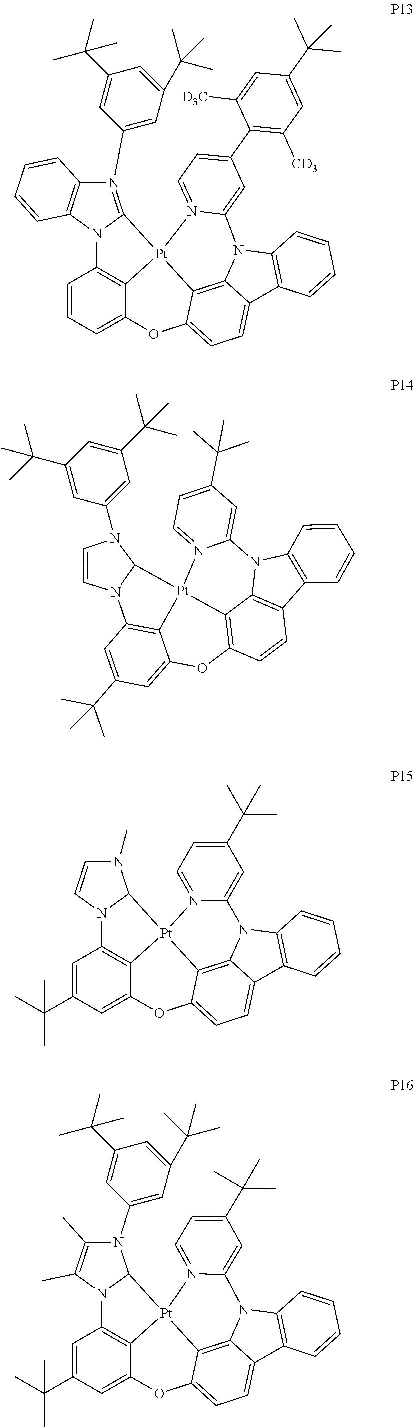

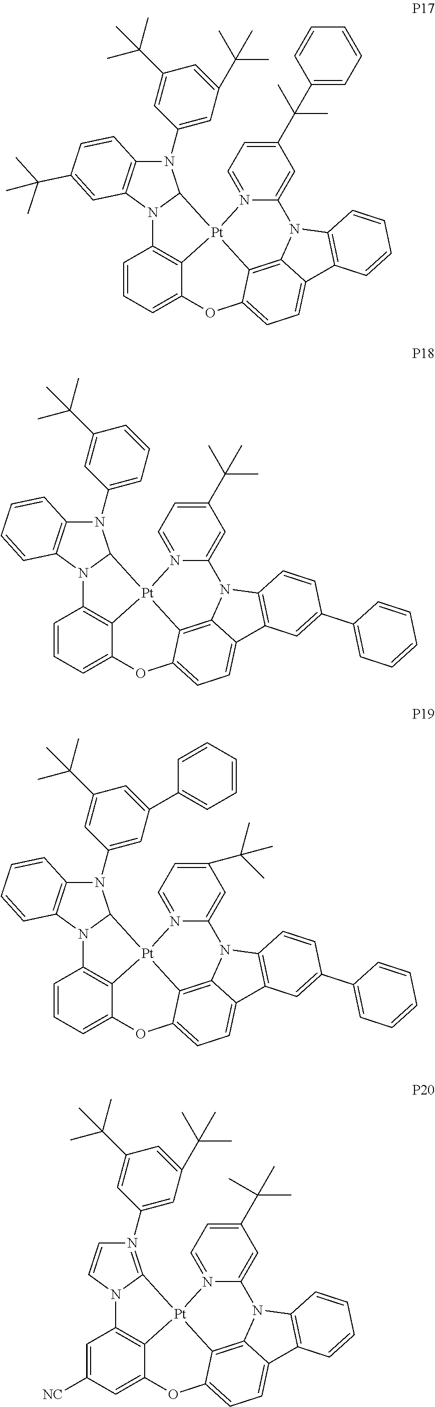

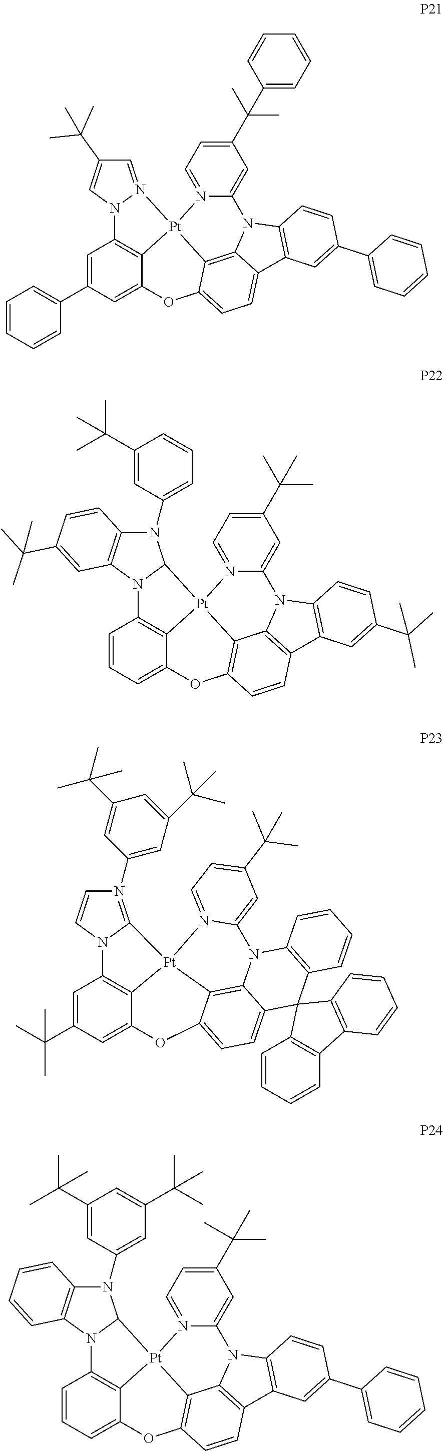

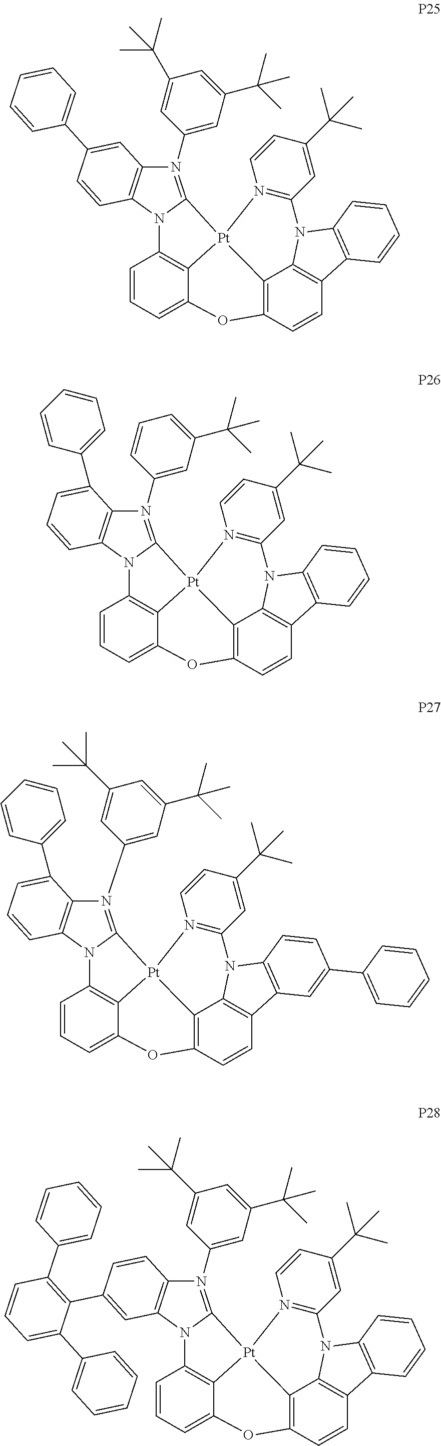

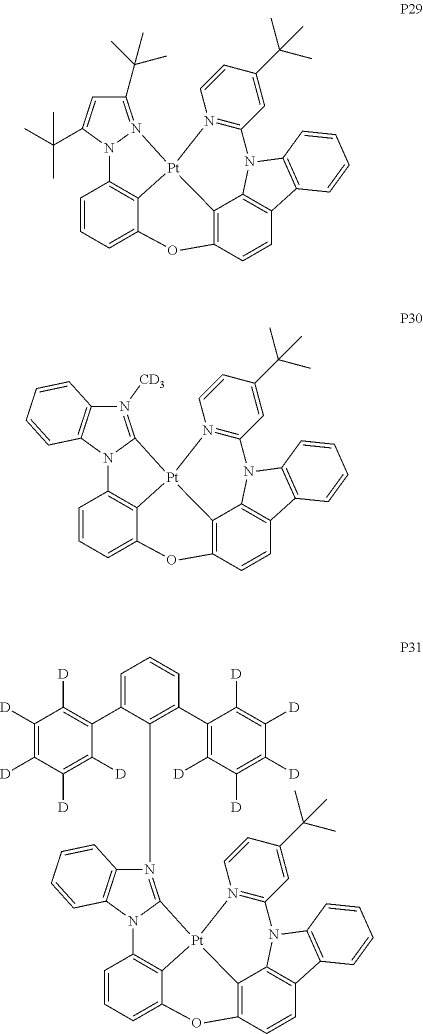

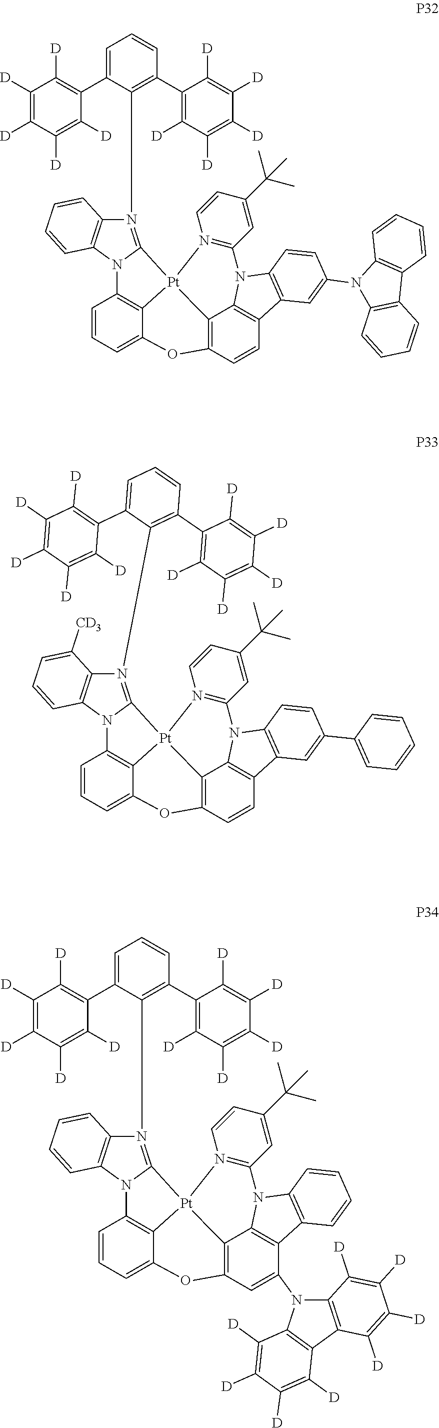

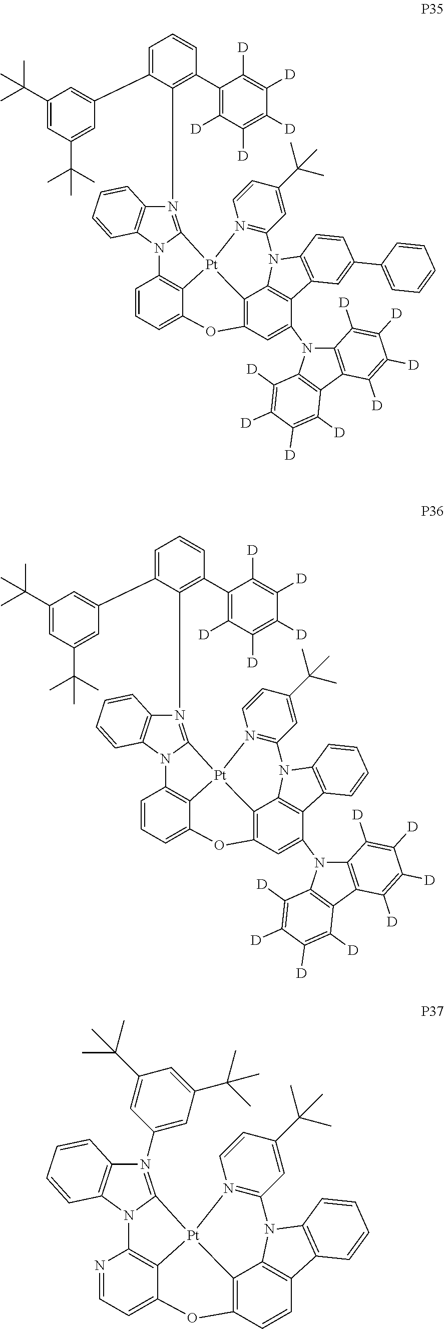

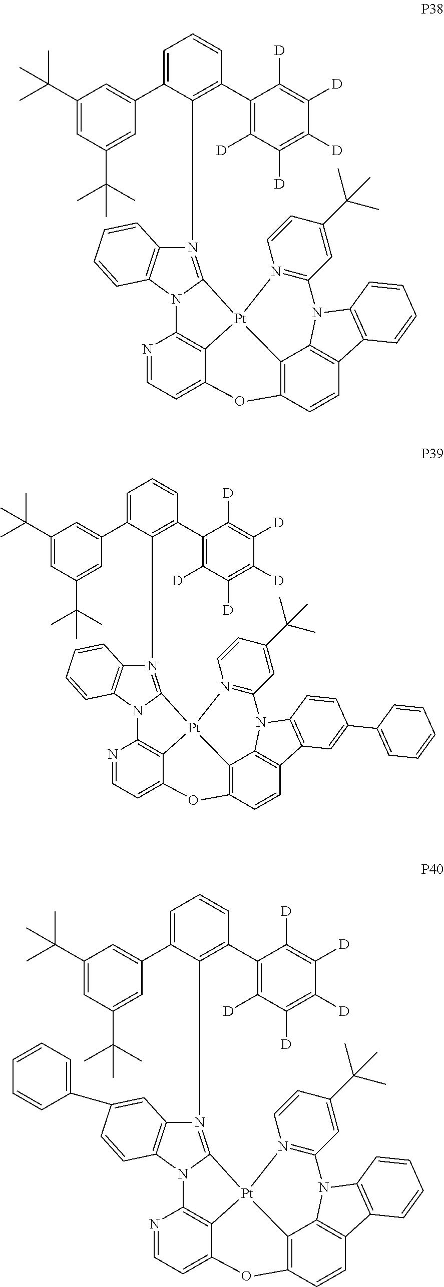

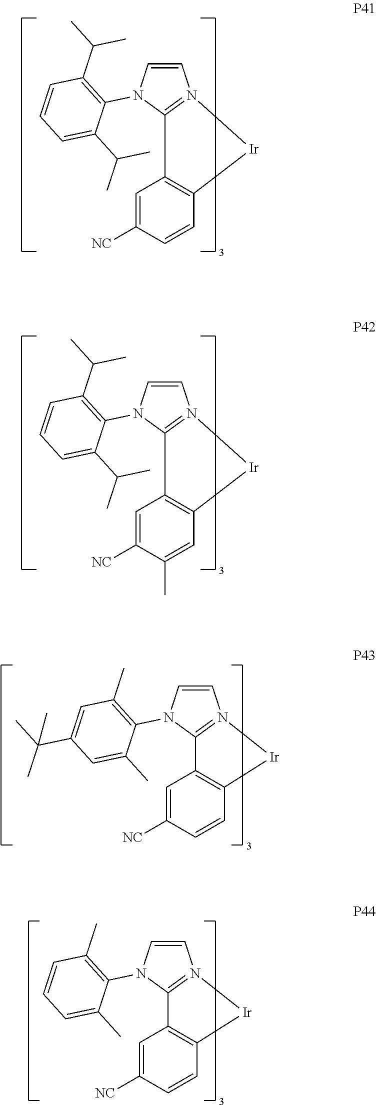

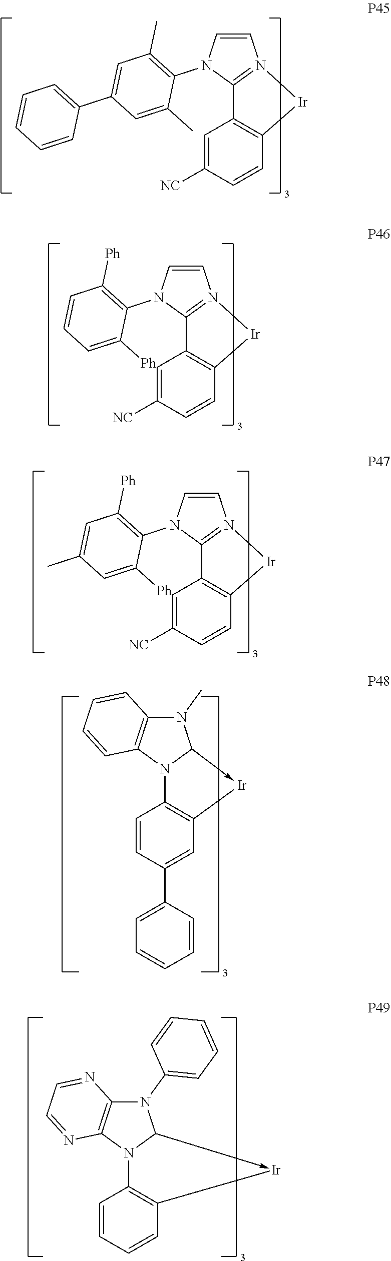

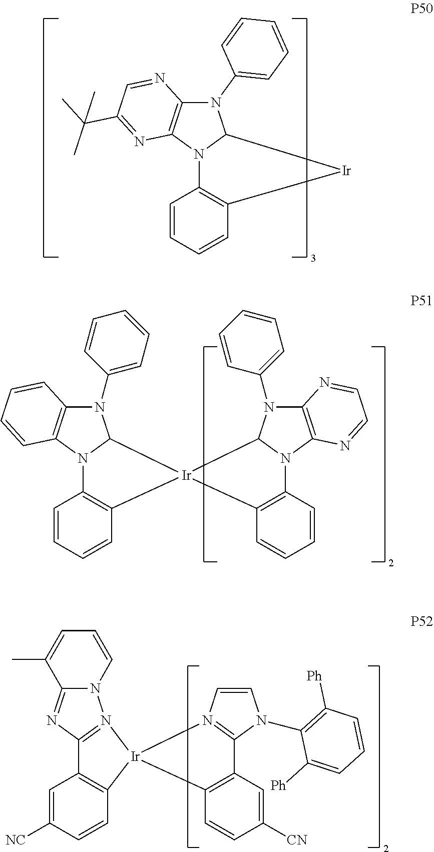

### Description of Formula 4

The delayed fluorescence material in the first embodiment and the second embodiment may be a polycyclic compound represented by Formula 4:

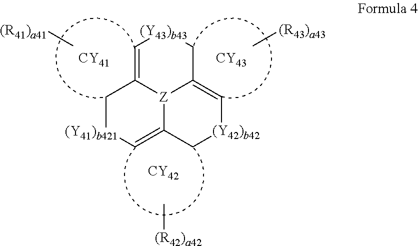

wherein, in Formula 4,
Z may be B or N,
ring CY₄₁ to ring CY₄₃ may each independently be a C₅-C₃₀ carbocyclic group or a C₁-C₃₀ heterocyclic group, Y₄₁ may be a single bond, *—N(R₄₄)—*′, *—B(R₄₄)—*′, *—P(R₄₄)—*′, *—C(R₄₄)(R₄₅)—*′, *—Si(R₄₄)(R₄₅)—*′, *—Ge(R₄₄)(R₄₅)—*′, *—O—*′, *—S—*′, *—Se—*′, *—C(═O)—*′, or *—S(═O)₂—*′, Y₄₂ may be a single bond, *—N(R₄₆)—*′, *—B(R₄₆)—*′, *—P(R₄₆)—*′, *—C(R₄₆)(R₄₇)—*′, *—Si(R₄₆)(R₄₇)—*′, *—Ge(R₄₆)(R₄₇)—*′, *—O—*′, *—S—*′, *—Se—*′, *—C(═O)—*′, or *—S(═O)₂—*′, Y₄₃ may be a single bond, *—N(R₄₈)—*′, *—B(R₄₈)—*′, *—P(R₄₈)—*′, *—C(R₄₈)(R₄₉)—*′, *—Si(R₄₈)(R₄₉)—*′, *—Ge(R₄₈)(R₄₉)—*′, *—O—*′, *—S—*′, *—Se—*′, *—C(═O)—*′, or *—S(═O)₂—*′,
b41 to b43 may each independently be 0 or 1,
when b41 is 0, Y₄₁ may not be present, when b42 is 0, Y₄₂ may not be present, and when b43 is 0, Y₄₃ may not be present,
R₄₁ to R₄₉ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a41 to a43 may each independently be an integer from 0 to 20,
two or more R₄₁ groups may optionally be bonded to each other to form a C₅-C₃₀ carbocyclic group unsubstituted or substituted with at least one R_{10b} or a C₁-C₃₀ heterocyclic group unsubstituted or substituted with at least one R_{10b},
two or more R₄₂ groups may optionally be bonded to each other to form a C₅-C₃₀ carbocyclic group unsubstituted or substituted with at least one R_{10b} or a C₁-C₃₀ heterocyclic group unsubstituted or substituted with at least one R_{10b},
two or more R₄₃ groups may optionally be bonded to each other to form a C₅-C₃₀ carbocyclic group unsubstituted or substituted with at least one R_{10b} or a C₁-C₃₀ heterocyclic group unsubstituted or substituted with at least one R_{10b},
two or more of R₄₁ to R₄₉ may optionally be bonded to each other to form a C₅-C₃₀ carbocyclic group unsubstituted or substituted with at least one R_{10b} or a C₁-C₃₀ heterocyclic group unsubstituted or substituted with at least one R_{10b},
R_{10b} is as described in connection with R₄₁,
* and *′ each indicate a binding site to a neighboring atom,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ heteroaryl alkyl group, the substituted monovalent non-aromatic condensed polycyclic group, and the substituted monovalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, a Q₁₁ to Q₁₉, a Q₂₁ to Q₂₉ and Q₃₁ to Q₃₉ may each independently be hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₂-C₁₀ heterocycloalkenyl group; a C₆-C₆₀ aryl group unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

According to an embodiment, ring CY₄₁ to ring CY₄₃ may be each independently, i) a benzene group, or ii) a polycyclic group in which two or more C₃-C₆₀ cyclic groups are condensed with each other. Two C₃-C₆₀ cyclic groups in the polycyclic group may be condensed with each other while sharing boron (B) or nitrogen (N).

In some embodiments, at least one of b41 to b43, or at least two of b41 to b43, may each be 1. In some embodiments, two of b41 to b43 may be 1, and the remaining one may be 0.

In some embodiments, R₄₁ to R₄₉ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₆₀ alkyl group or a C₁-C₆₀ alkoxy group, each substituted with at least one of deuterium, —F, —Cl, —Br, —I, a hydroxyl group, a cyano group, a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, and a chrysenyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each unsubstituted or substituted with at least one of deuterium, —F, —Cl, —Br, —I, a hydroxyl group, a cyano group, a nitro group, an amino group, a C₁-C₆₀ alkyl group, a C₁-C₆₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, and a carbazolyl group.

In some embodiments, the polycyclic compound represented by Formula 4 may be a polycyclic compound represented by one of Formulae 4-1 to 4-9:

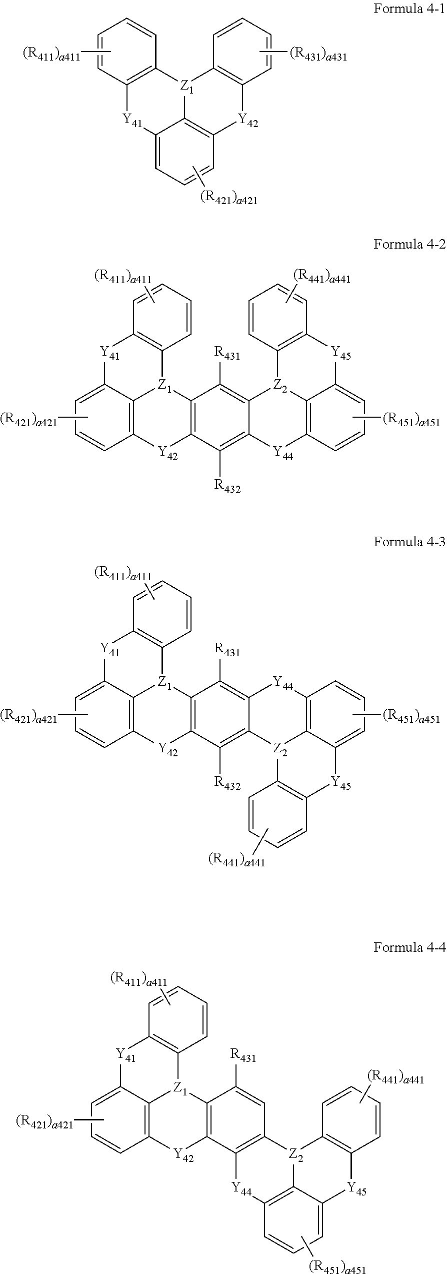

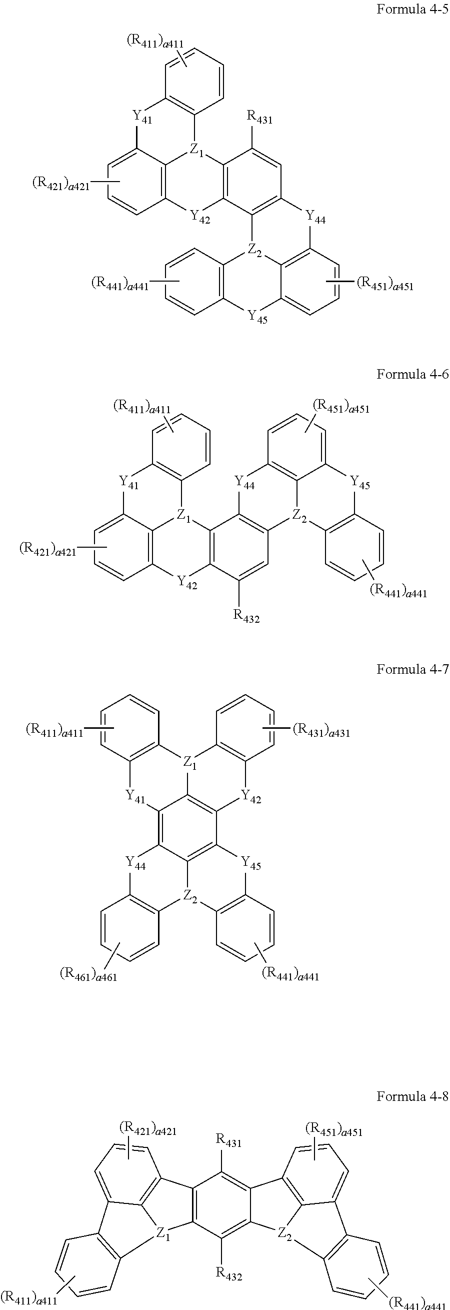

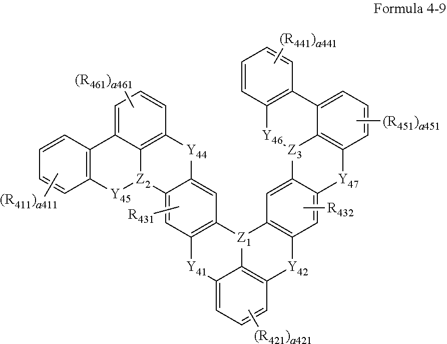

wherein, in Formulae 4-1 to 4-9,
each of Z₁ to Z₃ is as described in connection with Z in this specification,
Y₄₁ and Y₄₂ are as described in the present specification,
Y₄₄ to Y₄₇ refer to the description of Y₄₁ and Y₄₂ in the present specification, respectively,
R₄₁₁ is as described in connection with R₄₁, R₄₂₁ is as described in connection with R₄₂, R₄₃₁ and R₄₃₂ are each as described in connection with R₄₃, R₄₄₁ is as described in connection with R₄₁, R₄₅₁ is as described in connection with R₄₂, and R₄₆₁ is as described in connection with R₄₃,
a411 may be an integer from 0 to 4, a421 may be an integer from 0 to 3,
a431 may be an integer from 0 to 4,
a441 may be an integer from 0 to 4,
a451 may be an integer from 0 to 3, and
a461 may be an integer from 0 to 3.

The polycyclic compound represented by Formula 4 may be selected from Compounds D1 to D30:

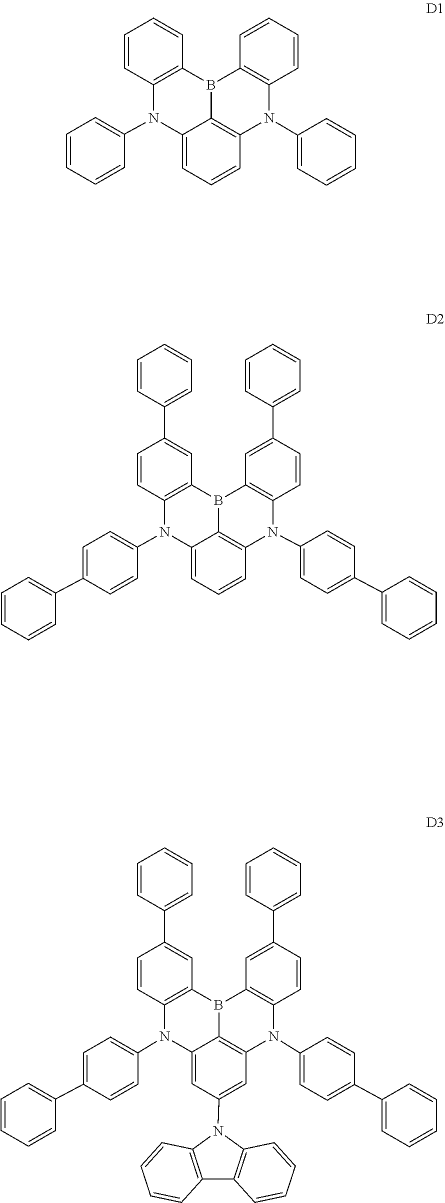 [SMILES: c1ccc(N2c3ccccc3B3c4ccccc4N(c4ccccc4)c4cccc2c43)cc1 ; c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1]

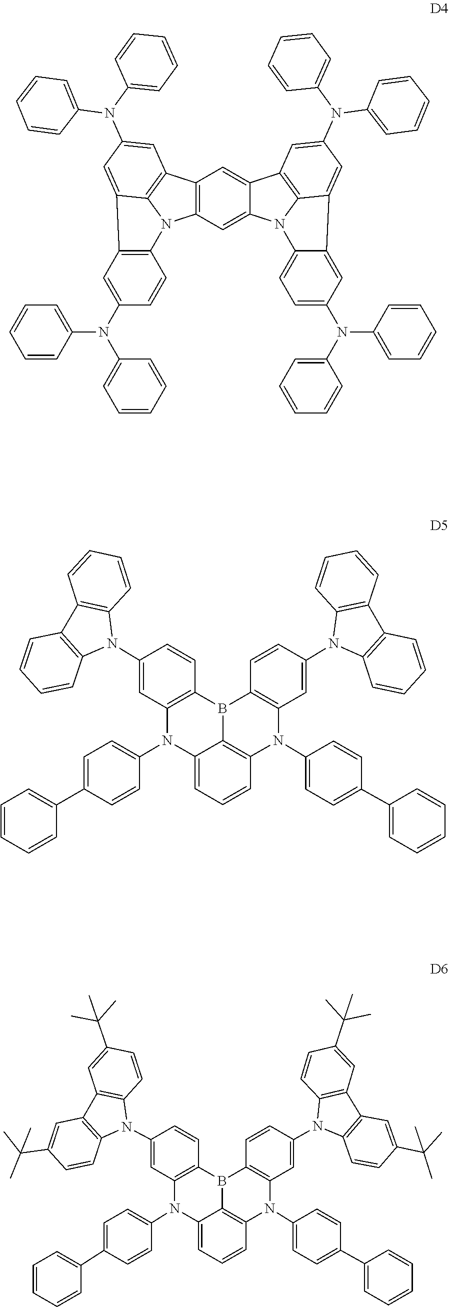 [SMILES: c1ccc(N(c2ccccc2)c2ccc3c(c2)c2cc(N(c4ccccc4)c4ccccc4)cc4c5cc6c7cc(N(c8ccccc8)c8ccccc8)cc8c9cc(N(c%10ccccc%10)c%10ccccc%10)ccc9n(c6cc5n3c24)c87)cc1 ; c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cccc3c54)cc2)cc1 ; CC(C)(C)c1ccc2c(c1)c1cc(C(C)(C)C)ccc1n2-c1ccc2c(c1)N(c1ccc(-c3ccccc3)cc1)c1cccc3c1B2c1ccc(-n2c4ccc(C(C)(C)C)cc4c4cc(C(C)(C)C)ccc42)cc1N3c1ccc(-c2ccccc2)cc1]

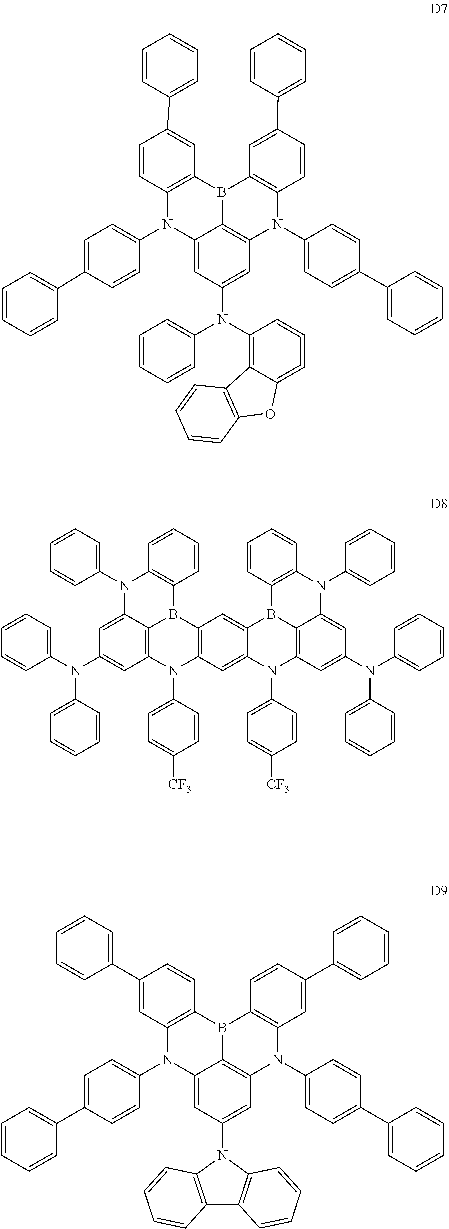 [SMILES: C1=C=c2oc3ccccc3c2=C(N(c2ccccc2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)C=1 ; FC(F)(F)c1ccc(N2c3cc4c(cc3B3c5ccccc5N(c5ccccc5)c5cc(N(c6ccccc6)c6ccccc6)cc2c53)B2c3ccccc3N(c3ccccc3)c3cc(N(c5ccccc5)c5ccccc5)cc(c32)N4c2ccc(C(F)(F)F)cc2)cc1 ; c1ccc(-c2ccc(N3c4cc(-c5ccccc5)ccc4B4c5ccc(-c6ccccc6)cc5N(c5ccc(-c6ccccc6)cc5)c5cc(-n6c7ccccc7c7ccccc76)cc3c54)cc2)cc1]

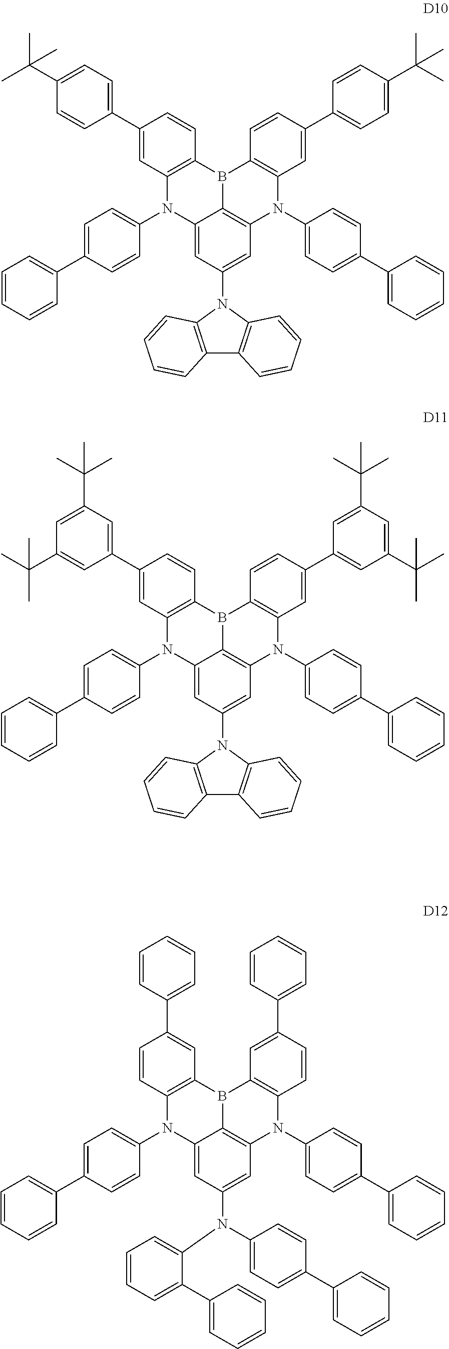 [SMILES: CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1 ; CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1 ; c1ccc(-c2ccc(N(c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)c3ccccc3-c3ccccc3)cc2)cc1]

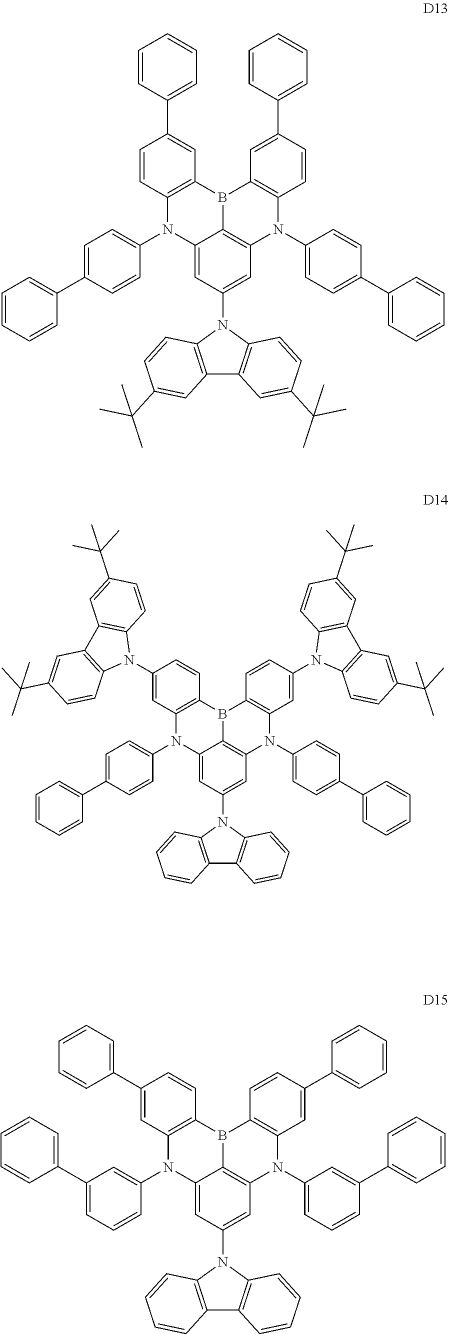 [SMILES: CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc2c(c1)c1cc(C(C)(C)C)ccc1n2-c1ccc2c(c1)N(c1ccc(-c3ccccc3)cc1)c1cc(-n3c4ccccc4c4ccccc43)cc3c1B2c1ccc(-n2c4ccc(C(C)(C)C)cc4c4cc(C(C)(C)C)ccc42)cc1N3c1ccc(-c2ccccc2)cc1 ; c1ccc(-c2cccc(N3c4cc(-c5ccccc5)ccc4B4c5ccc(-c6ccccc6)cc5N(c5cccc(-c6ccccc6)c5)c5cc(-n6c7ccccc7c7ccccc76)cc3c54)c2)cc1]

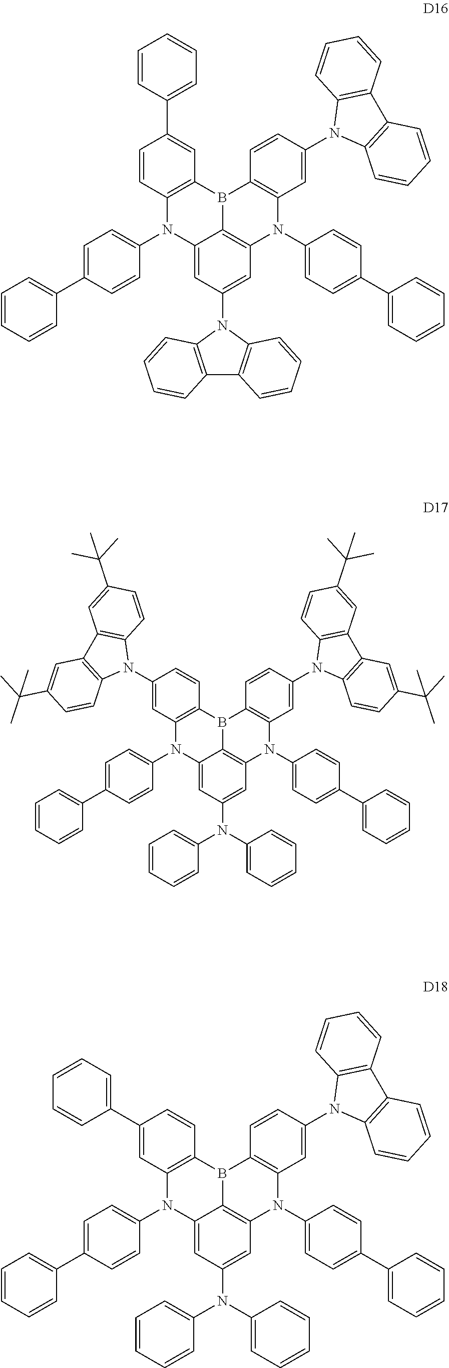 [SMILES: c1ccc(-c2ccc(N3c4ccc(-c5ccccc5)cc4B4c5ccc(-n6c7ccccc7c7ccccc76)cc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1ccc2c(c1)N(c1ccc(-c3ccccc3)cc1)c1cc(N(c3ccccc3)c3ccccc3)cc3c1B2c1ccc(-n2c4ccc(C(C)(C)C)cc4c4cc(C(C)(C)C)ccc42)cc1N3c1ccc(-c2ccccc2)cc1 ; c1ccc(-c2ccc(N3c4cc(-c5ccccc5)ccc4B4c5ccc(-n6c7ccccc7c7ccccc76)cc5N(c5ccc(-c6ccccc6)cc5)c5cc(N(c6ccccc6)c6ccccc6)cc3c54)cc2)cc1]

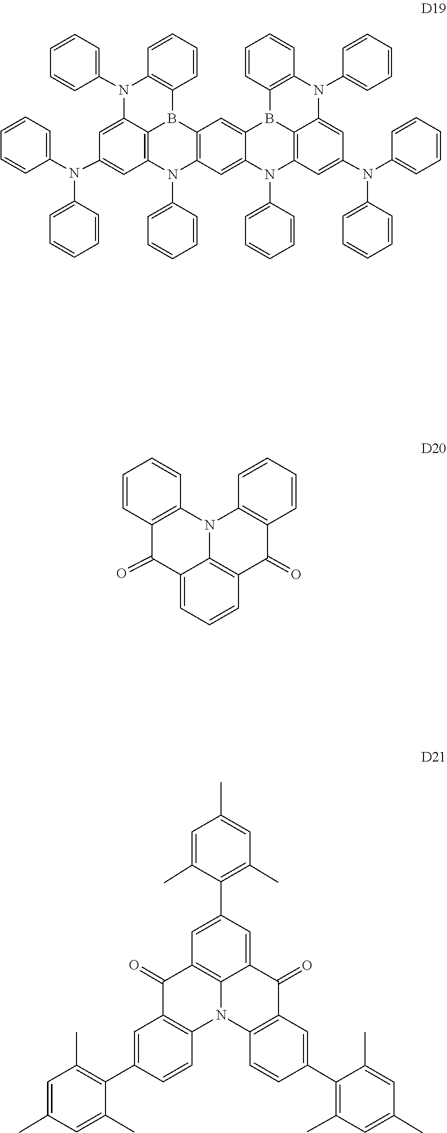

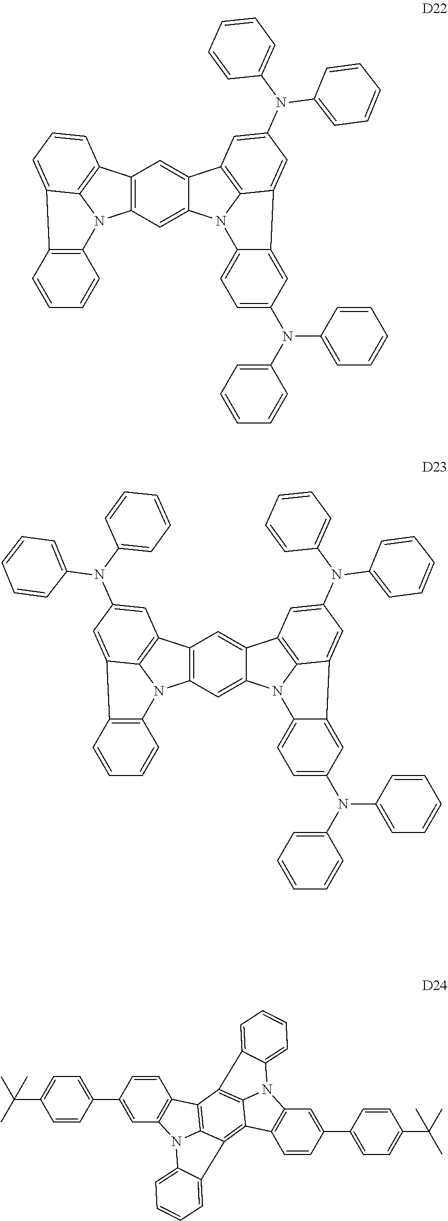 [SMILES: c1ccc(N(c2ccccc2)c2ccc3c(c2)c2cc(N(c4ccccc4)c4ccccc4)cc4c5cc6c7cccc8c9ccccc9n(c6cc5n3c24)c87)cc1 ; c1ccc(N(c2ccccc2)c2ccc3c(c2)c2cc(N(c4ccccc4)c4ccccc4)cc4c5cc6c7cc(N(c8ccccc8)c8ccccc8)cc8c9ccccc9n(c6cc5n3c24)c87)cc1 ; CC(C)(C)c1ccc(-c2ccc3c4c5c6ccccc6n6c7cc(-c8ccc(C(C)(C)C)cc8)ccc7c(c7c8ccccc8n(c3c2)c74)c56)cc1]

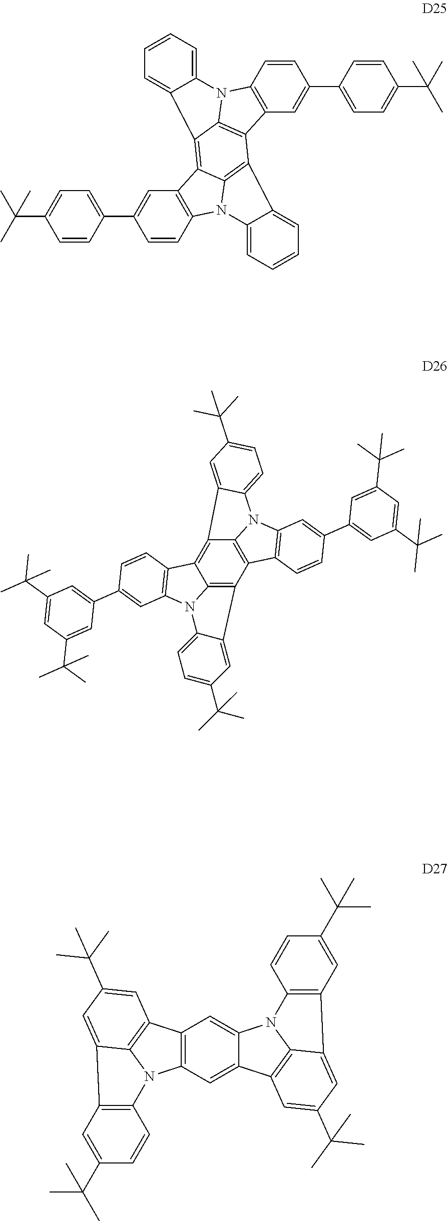

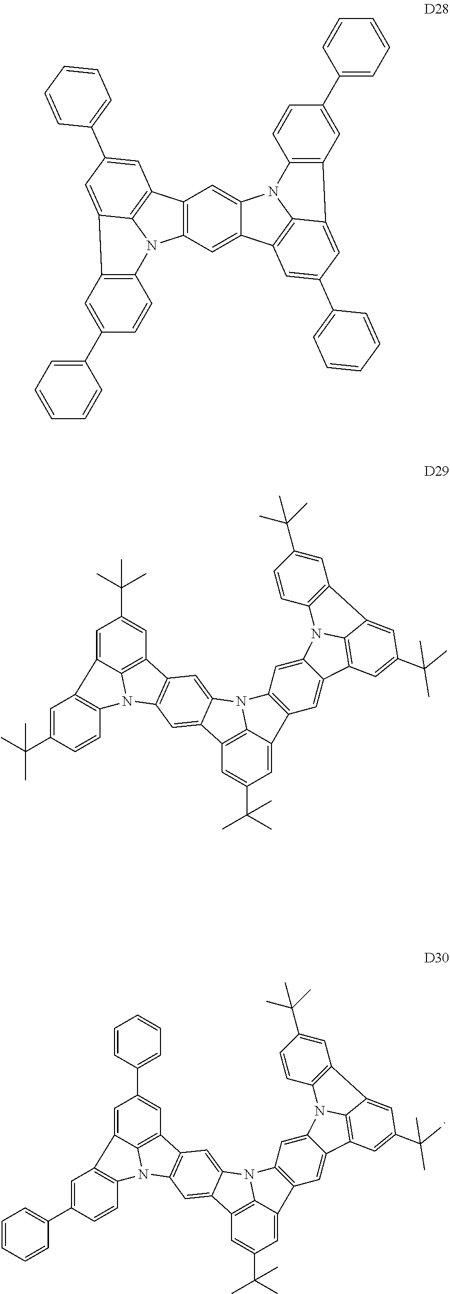 [SMILES: c1ccc(-c2ccc3c(c2)c2cc(-c4ccccc4)cc4c5cc6c(cc5n3c24)c2cc(-c3ccccc3)cc3c4cc(-c5ccccc5)ccc4n6c32)cc1 ; CC(C)(C)c1ccc2c(c1)c1cc(C(C)(C)C)cc3c4cc5c(cc4n2c13)c1cc(C(C)(C)C)cc2c3cc4c6cc(C(C)(C)C)cc7c8cc(C(C)(C)C)ccc8n(c4cc3n5c12)c76 ; CC(C)(C)c1ccc2c(c1)c1cc(C(C)(C)C)cc3c4cc5c6cc(C(C)(C)C)cc7c8cc9c(cc8n(c5cc4n2c13)c76)c1cc(-c2ccccc2)cc2c3cc(-c4ccccc4)ccc3n9c21]

### DESCRIPTION OF THE FIGURE

The FIGURE is a schematic cross-sectional view of an organic light-emitting device 10 according to an embodiment. Hereinafter, the structure and manufacturing method of the organic light-emitting device 10 according to an embodiment will be described with reference to the FIGURE.

The organic light-emitting device 10 of the FIGURE includes a first electrode 11, a second electrode 19 facing the first electrode 11, and an interlayer 10A between the first electrode 11 and the second electrode 19.

The interlayer 10A includes an emission layer 15, a hole transport region 12 is between the first electrode 11 and an emission layer 15, and an electron transport region 17 is between the emission layer 15 and the second electrode 19.

A substrate may be further disposed under the first electrode 11 or on the second electrode 19. The substrate may be a substrate commonly used in organic light-emitting devices, for example, a glass substrate or a transparent plastic substrate, which have excellent mechanical strength, thermal stability, transparency, surface smoothness, ease of handling, and water repellency.

### First Electrode 11

The first electrode 11 may be formed by, for example, depositing or sputtering, onto the substrate, a material for forming the first electrode 11. The first electrode 11 may be an anode. The material for forming the first electrode 11 may include materials with a high work function to facilitate hole injection.

The first electrode 11 may be a reflective electrode, a transflective electrode, or a transmissive electrode. In an embodiment, when the first electrode 11 is a transmissive electrode, the material for forming the first electrode 11 may include indium tin oxide (ITO), indium zinc oxide (IZO), tin oxide (SnO₂), zinc oxide (ZnO), or a combination thereof. In some embodiments, when the first electrode 11 is a semi-transmissive electrode or a reflective electrode, the material for forming the first electrode 11 may include magnesium (Mg), silver (Ag), aluminum (Al), aluminum-lithium (Al—Li), calcium (Ca), magnesium-indium (Mg—In), magnesium-silver (Mg—Ag), or a combination thereof.

The first electrode 11 may have a single-layered structure or a multi-layered structure including two or more layers.

### Emission Layer 15

A thickness of the emission layer 15 may be in a range of about 100 Angstrom (Å) to about 1,000 Å, for example, about 200 Å to about 600 Å. When the thickness of the emission layer is within the range described above, excellent luminescence characteristics may be obtained without a substantial increase in driving voltage.

According to an embodiment, the emission layer 15 may include a condensed cyclic compound as described herein. The emission layer 15 may follow the first embodiment or the second embodiment described in this specification.

The emission layer 15 may further include a host as described herein in addition to the condensed cyclic compound, the sensitizer, and the emitter as described herein.

### Hole Transport Region 12

The hole transport region 12 may be arranged between the first electrode 11 and the emission layer 15 of the organic light-emitting device 10.

The hole transport region 12 may have a single-layer structure or a multi-layer structure.

For example, the hole transport region 12 may have a hole injection layer, a hole transport layer, a hole injection layer/hole transport layer structure, a hole injection layer/first hole transport layer/second hole transport layer structure, a hole injection layer/first hole transport layer/second hole transport layer/electron-blocking layer structure, a hole transport layer/interlayer structure, a hole injection layer/hole transport layer/interlayer structure, a hole transport layer/electron-blocking layer structure, or a hole injection layer/hole transport layer/electron-blocking layer structure.

The hole transport region 12 may include any compound having hole-transporting properties.

For example, the hole transport region 12 may include an amine-based compound.

In an embodiment, the hole transport region 12 may include, for example, m-MTDATA, TDATA, 2-TNATA, NPB, β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), one of a compound represented by Formula 201 to a compound represented by Formula 205, or a combination thereof:

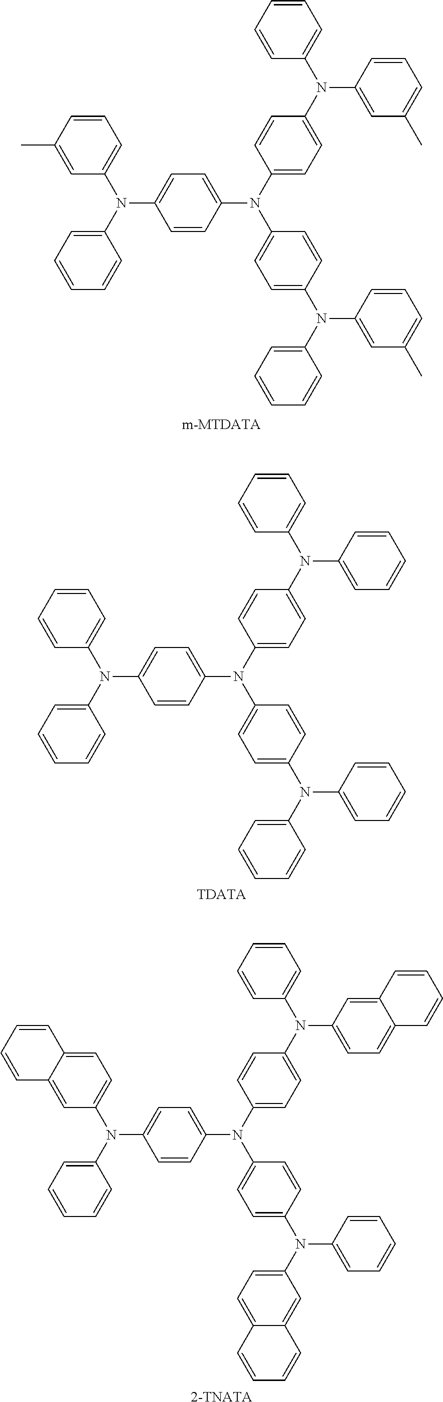

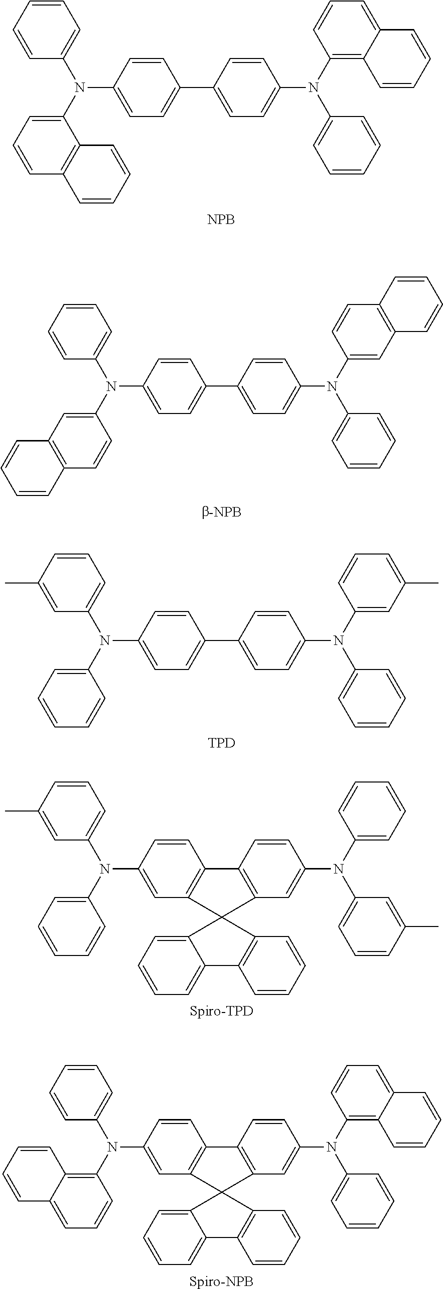

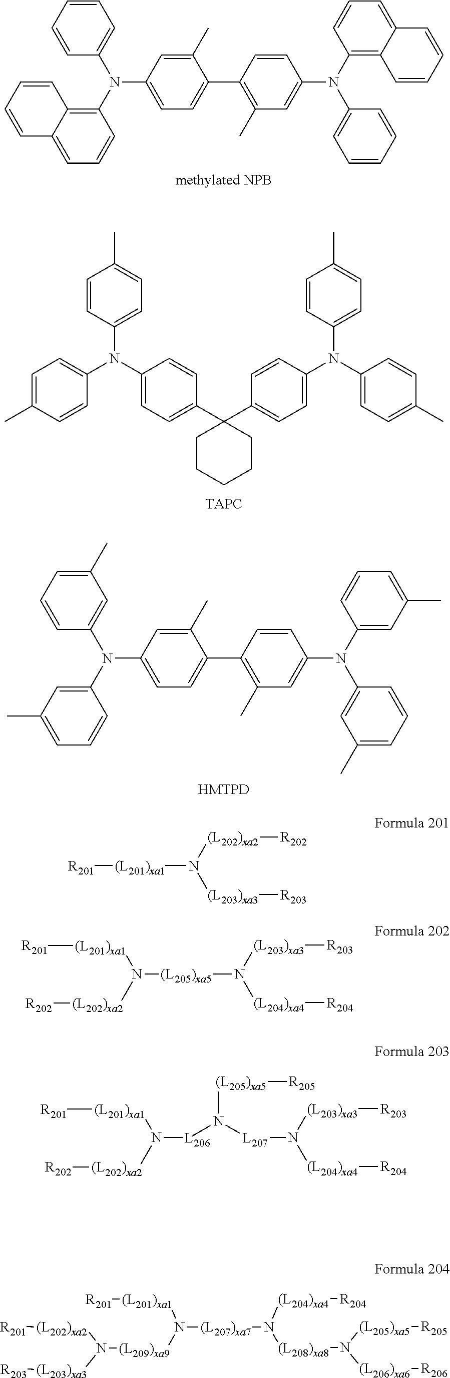

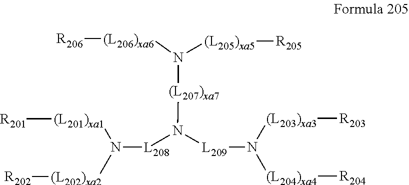

wherein, in Formulae 201 to 205,
L₂₀₁ to L₂₀₉ may each independently be *—O—*′, *—S—*′, a substituted or unsubstituted C₅-C₆₀ carbocyclic group, or a substituted or unsubstituted C₁-C₆₀ heterocyclic group,
xa1 to xa9 may each independently be an integer from 0 to 5, and
R₂₀₁ to R₂₀₆ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein neighboring two groups of R₂₀₁ to R₂₀₆ may optionally be linked to each other via a single bond, a dimethyl-methylene group, or a diphenyl-methylene group.

In an embodiment,
L₂₀₁ to L₂₀₉ may be a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a corogen group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, —Si(Q₁₁)(Q₁₂)(Q₁₃), or a combination thereof,
xa1 to xa9 may each independently be 0, 1, or 2, and
R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indeno carbazolyl group, an indolocarbazolyl group, a benzofurocarbazolyl group, or a benzothienocarbazolyl group, each unsubstituted or substituted with deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), —N(Q₃₁)(Q₃₂), or a combination thereof.

Q₁₁ to Q₁₃ and Q₃₁ to Q₃₃ may each independently be a C₁-C₁₀ alkyl group, a C₁-C₁₀ alkoxy group, a phenyl group, a biphenyl group, a terphenyl group, or a naphthyl group.

In some embodiments, the hole transport region 12 may include a carbazole-including amine-based compound.

In some embodiments, the hole transport region 12 may include a carbazole-including amine-based compound and a carbazole-free amine-based compound.

The carbazole-including amine-based compound may include, for example, compounds represented by Formula 201 including a carbazole group and further including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

The carbazole-free amine-based compound may include, for example, compounds represented by Formula 201 not including a carbazole group and including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

In some embodiments, the hole transport region 12 may include a compound represented by Formula 201, a compound represented by Formula 202, or a combination thereof.

In some embodiments, the hole transport region 12 may include a compound represented by Formula 201-1, 202-1, or 201-2, or a combination thereof:

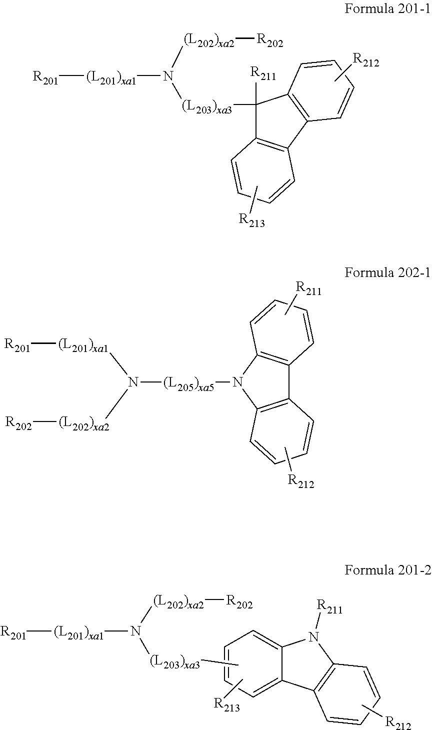

wherein, in Formulae 201-1, 202-1, and 201-2,
L₂₀₁ to L₂₀₃, L₂₀₅, xa1 to xa3, xa5, R₂₀₁ and R₂₀₂ are each as described herein, and
R₂₁₁ to R₂₁₃ may each independently be hydrogen, deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a dimethylfluorenyl group, a diphenylfluorenyl group, a triphenylenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

In an embodiment, the hole transport region 12 may include one of Compounds HT1 to HT39 or a combination thereof:

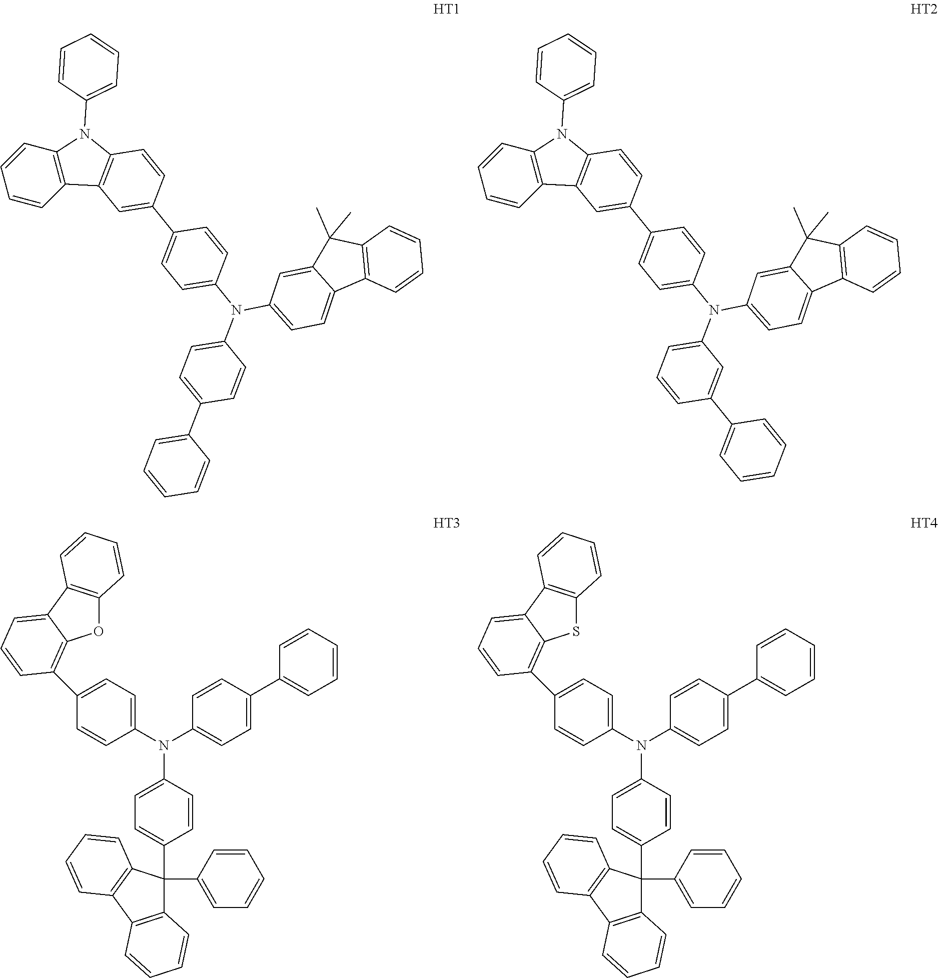 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; c1ccc(-c2ccc(N(c3ccc(-c4cccc5c4sc4ccccc45)cc3)c3ccc(C4(c5ccccc5)c5ccccc5-c5ccccc54)cc3)cc2)cc1]

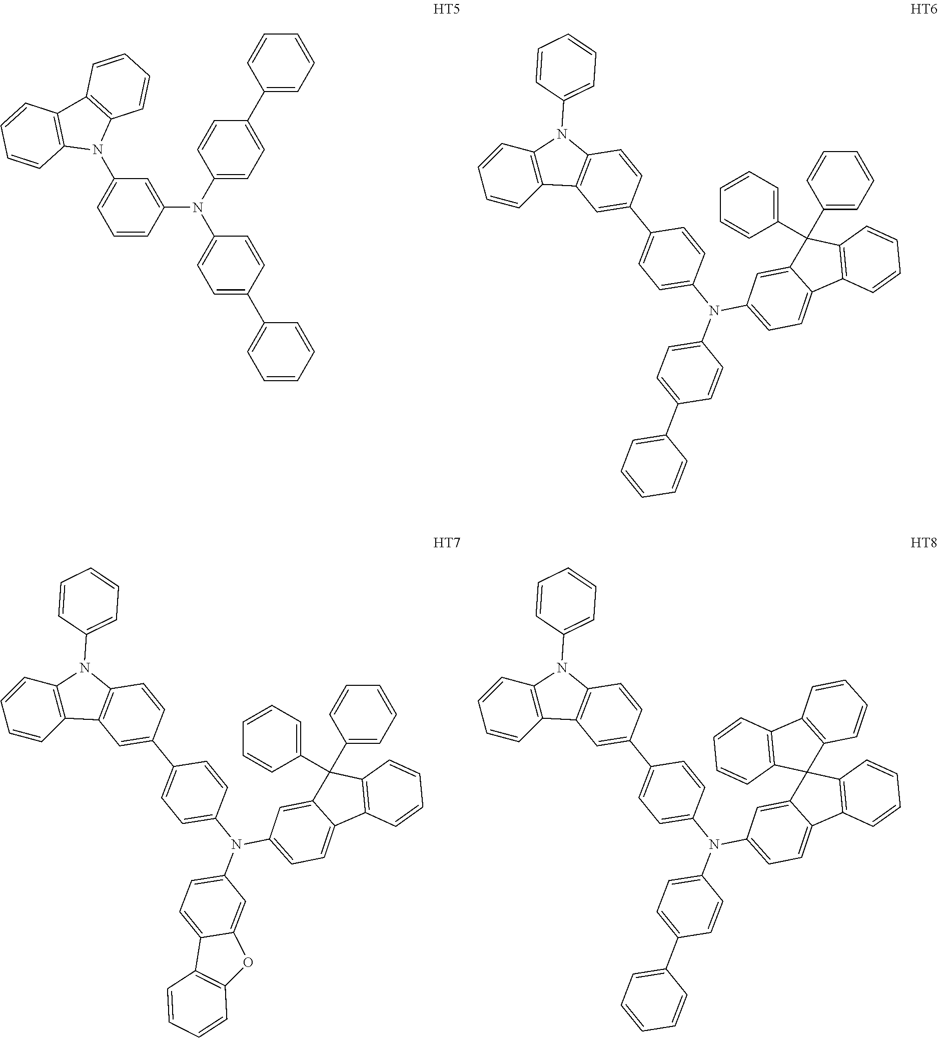 [SMILES: c1ccc(-c2ccc(N(c3ccc(-c4ccccc4)cc3)c3cccc(-n4c5ccccc5c5ccccc54)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

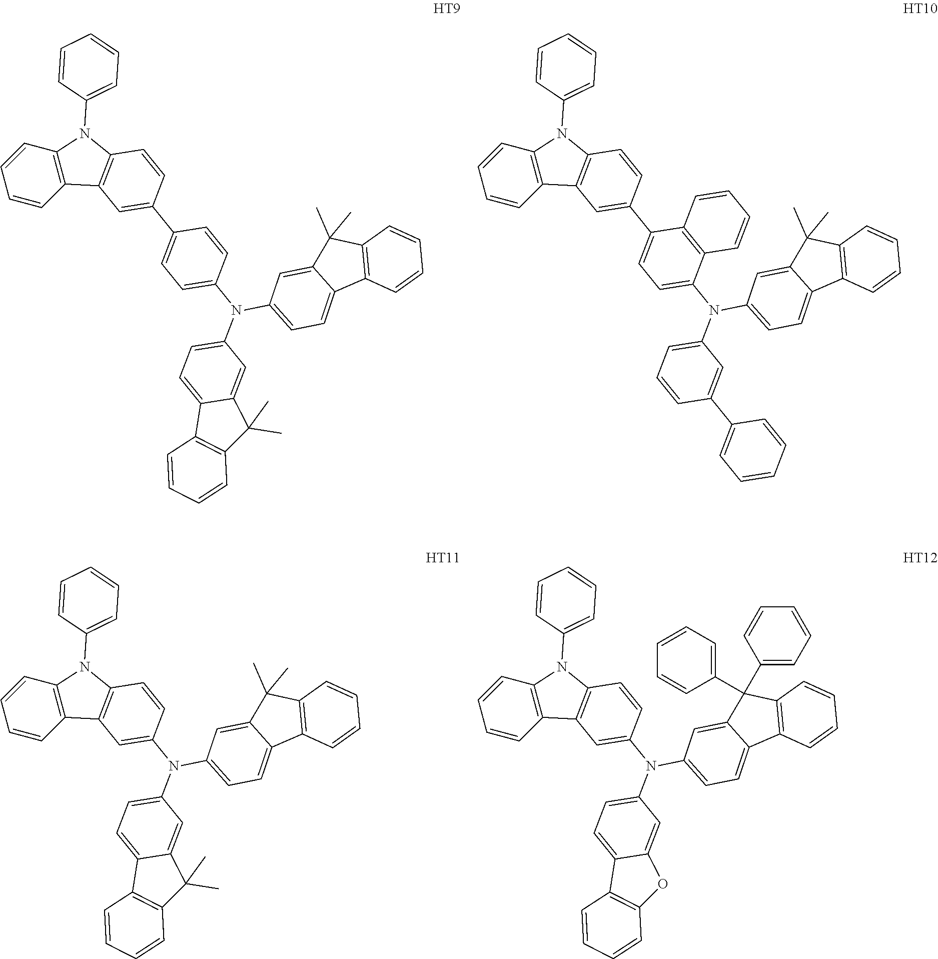 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

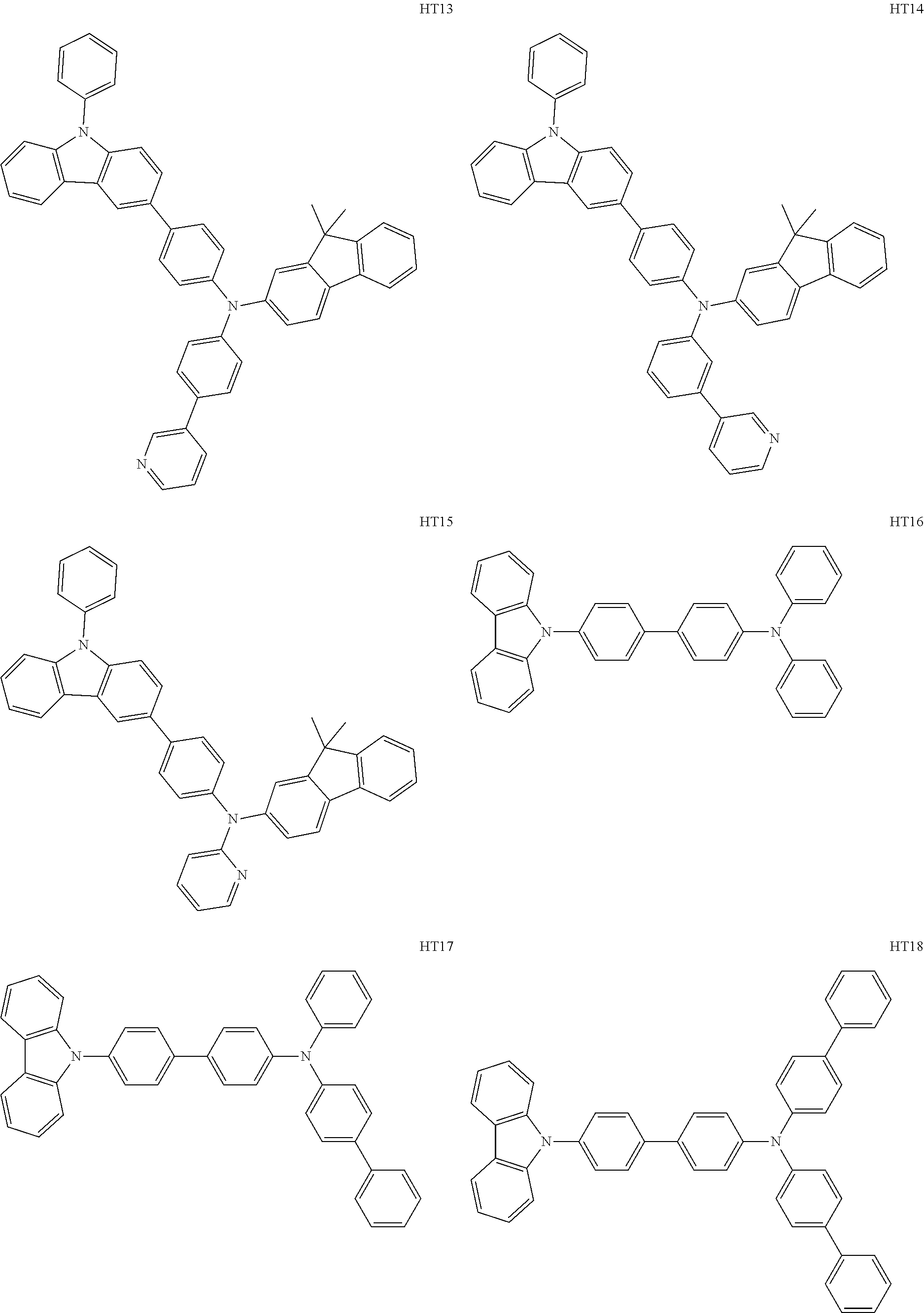 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

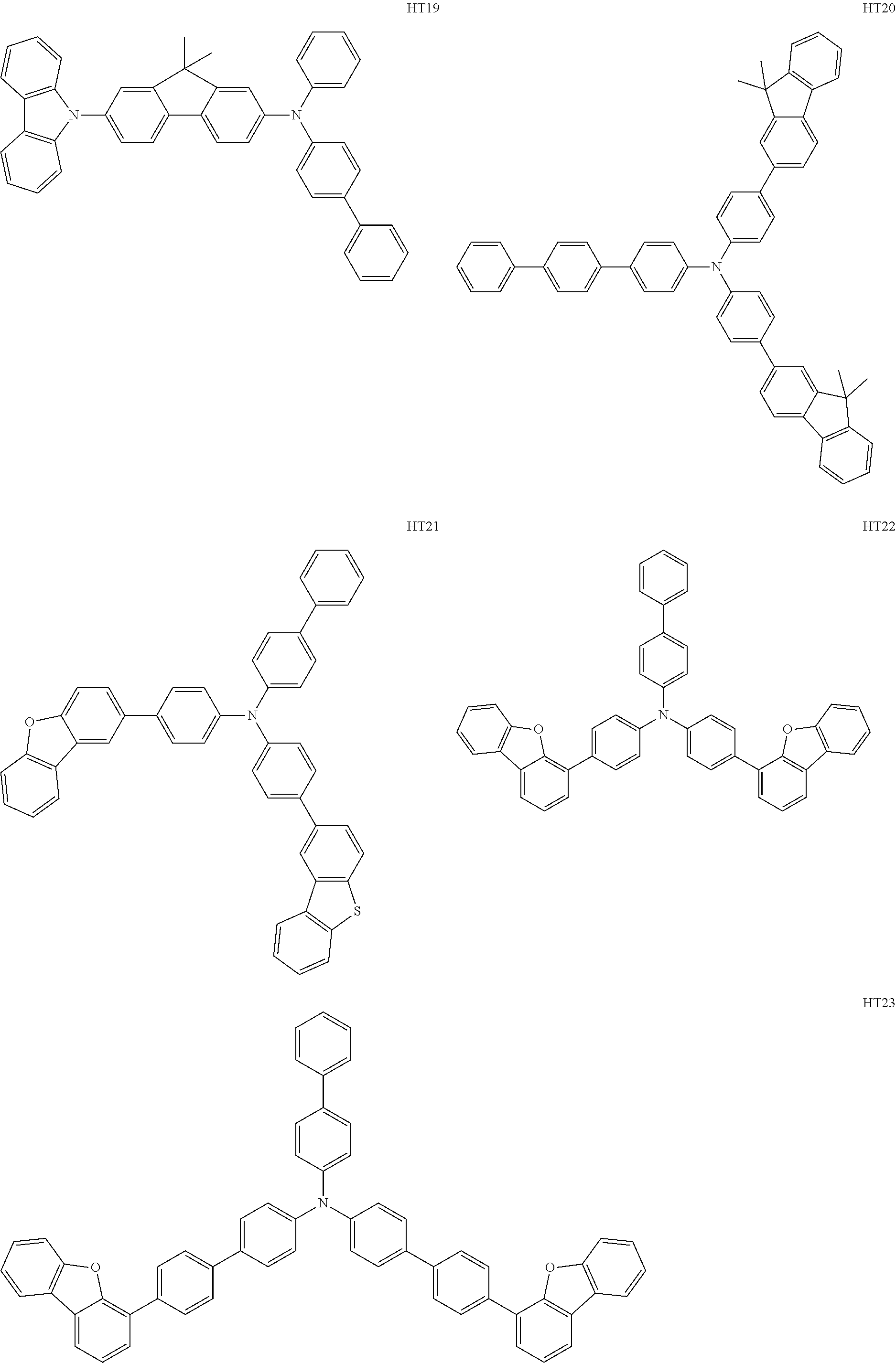

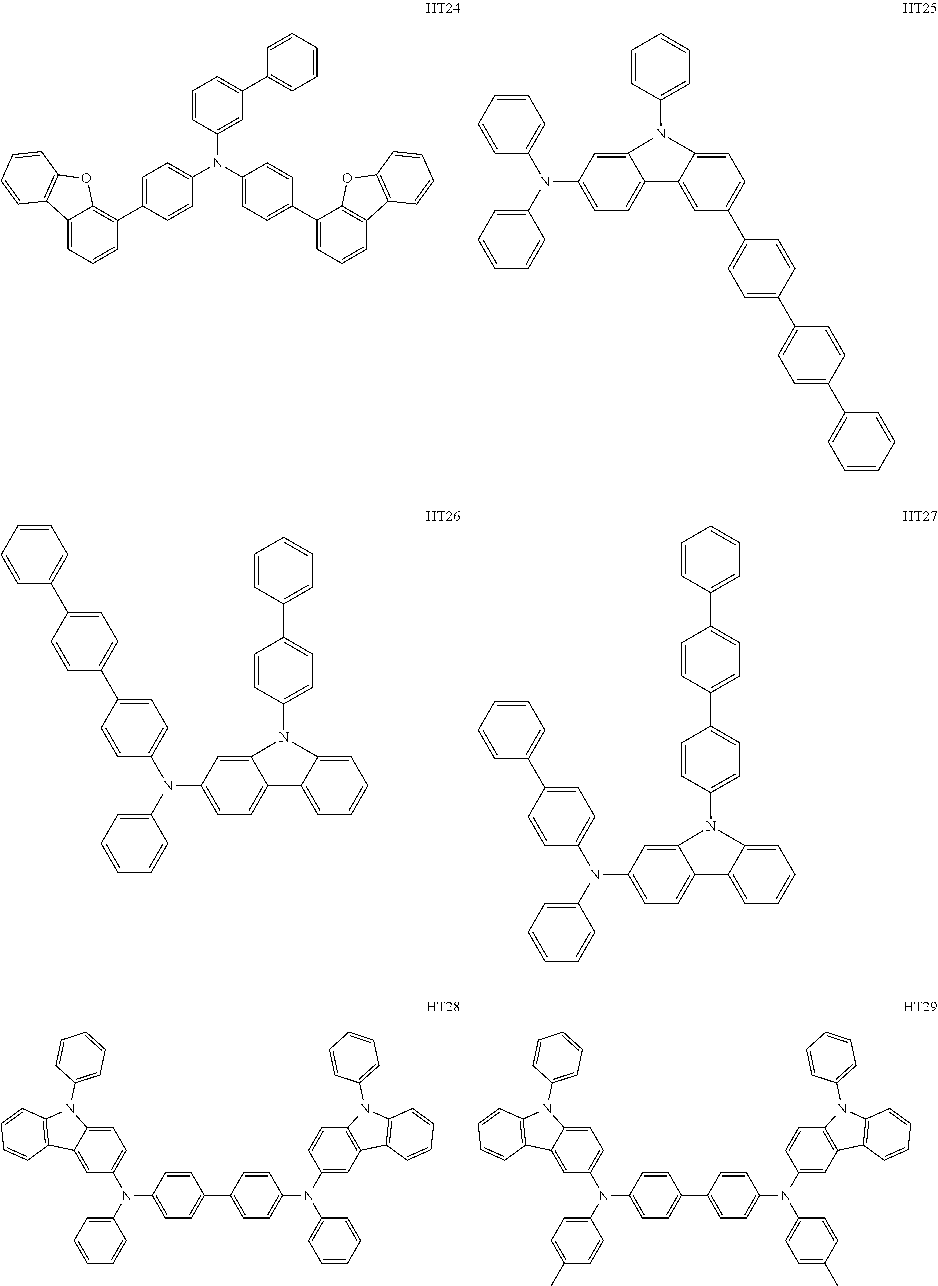

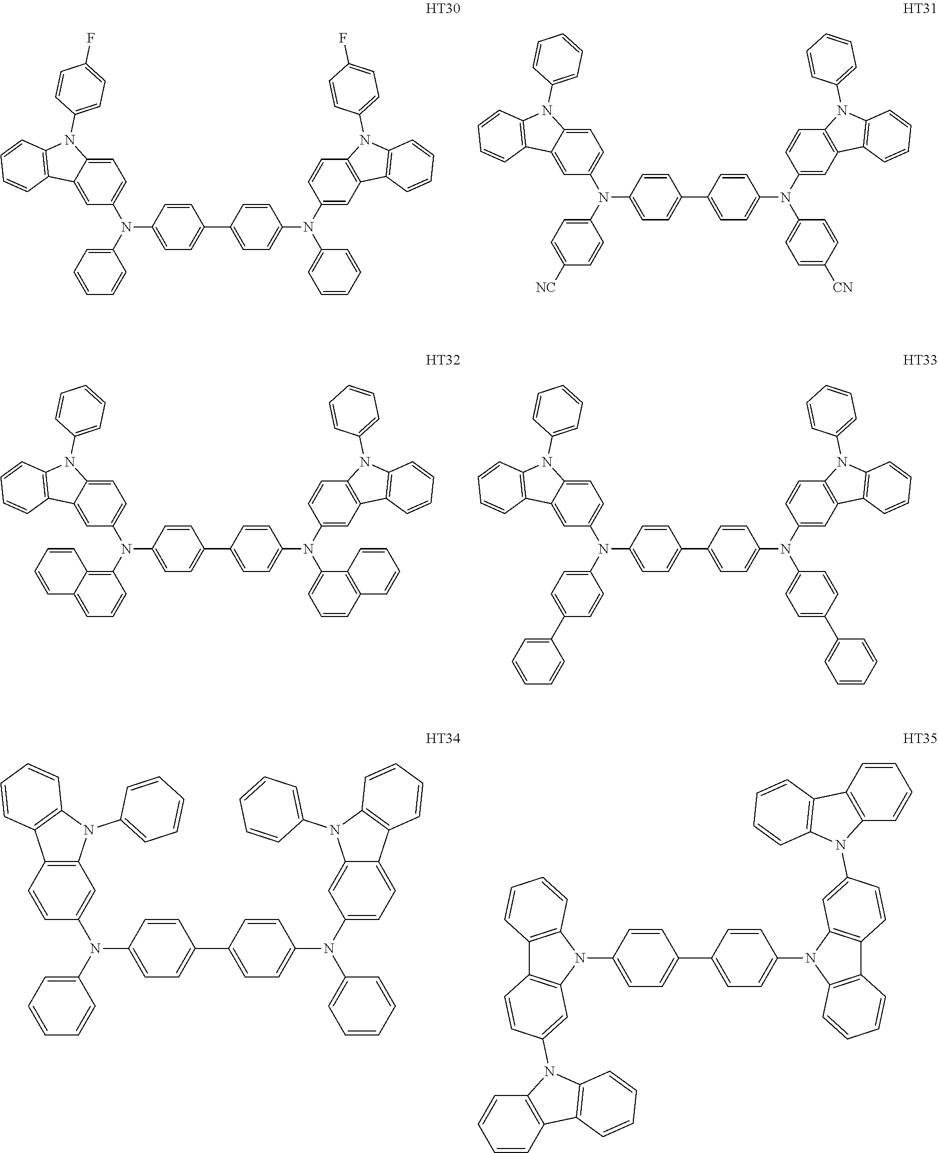

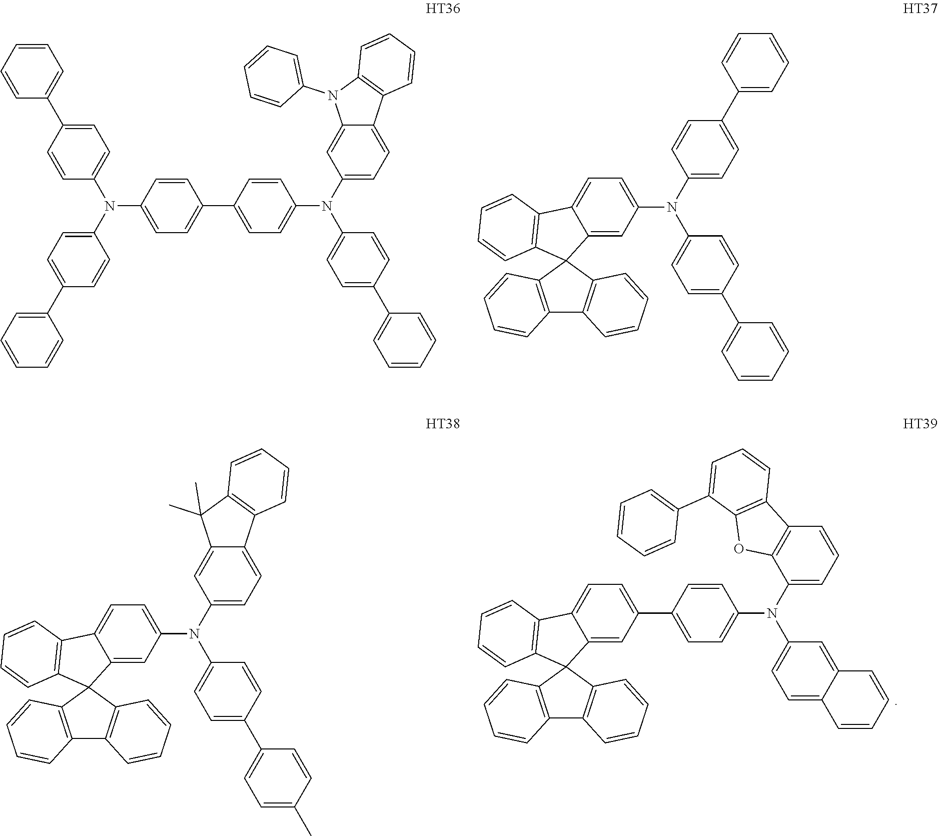 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

In some embodiments, the hole transport region 12 of the organic light-emitting device 10 may further include a p-dopant. When the hole transport region 12 further includes a p-dopant, the hole transport region 12 may have a matrix (for example, at least one of compounds represented by Formulae 201 to 205) and a p-dopant included in the matrix. The p-dopant may be uniformly or non-uniformly doped in the hole transport region 12.

In an embodiment, the LUMO energy level of the p-dopant may be less than or equal to about −3.5 eV.

The p-dopant may include a quinone derivative, a metal oxide, a cyano group-including compound, or a combination thereof.

For example, the p-dopant may include:
a quinone derivative, such as tetracyanoquinodimethane (TCNQ), 2,3,5,6-tetrafluoro-7,7,8,8-tetracyanoquinodimethane (F4-TCNQ), and F6-TCNNQ;
a metal oxide, such as tungsten oxide or molybdenum oxide;
1,4,5,8,9,12-hexaazatriphenylene-hexacarbonitrile (HAT-CN);
a compound represented by Formula 221; or
a combination thereof:

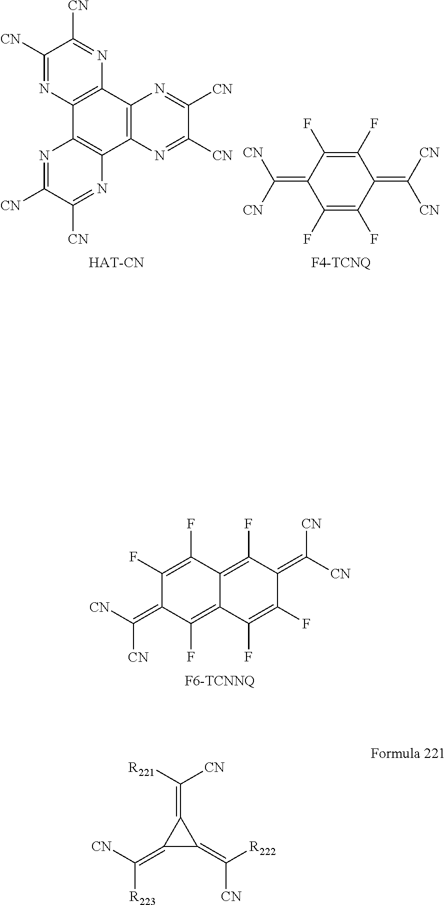

wherein, in Formula 221,
R₂₂₁ to R₂₂₃ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein at least one substituent of R₂₂₁ to R₂₂₃ may be: a cyano group; —F; —Cl; —Br; —I; a C₁-C₂₀ alkyl group substituted with —F; a C₁-C₂₀ alkyl group substituted with —Cl; a C₁-C₂₀ alkyl group substituted with —Br; a C₁-C₂₀ alkyl group substituted with —I; or a combination thereof.

The compound represented by Formula 221 may include, for example, Compound HT-D2:

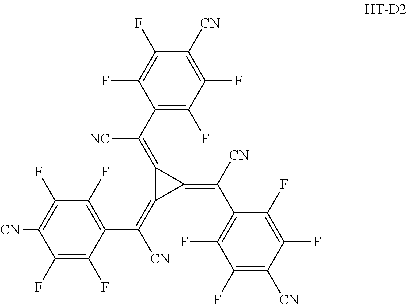 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

The hole transport region 12 may have a thickness in a range about 100 Å to about 10,000 Å, for example, about 400 Å to about 2,000 Å, and the emission layer 15 may have a thickness in a range of about 100 Å to about 3,000 Å, for example, about 300 Å to about 1,000 Å. When the thickness of each of the hole transport region 12 and the emission layer 15 is within these ranges, satisfactory hole transportation characteristics and/or luminescence characteristics may be obtained without a substantial increase in driving voltage.

The hole transport region 12 may further include a buffer layer.

The buffer layer may compensate for an optical resonance distance according to a wavelength of light emitted from the emission layer 15, and thus, efficiency of a formed organic light-emitting device may be improved.

The hole transport region 12 may further include an electron-blocking layer. The electron-blocking layer may include a known material, for example, mCP or DBFPO:

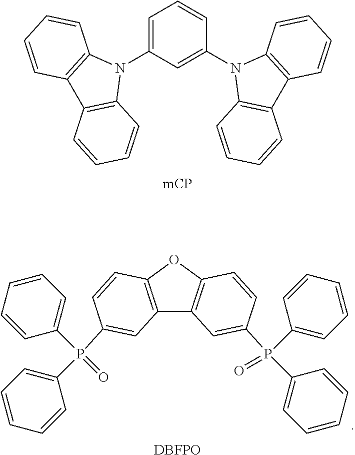

### Electron Transport Region 17

The electron transport region 17 is arranged between the emission layer 15 and the second electrode 19 of the organic light-emitting device 10.

The electron transport region 17 may have a single-layer structure or a multi-layer structure.

For example, the electron transport region 17 may have an electron transport layer, an electron transport layer/electron injection layer structure, a buffer layer/electron transport layer structure, hole-blocking layer/electron transport layer structure, a buffer layer/electron transport layer/electron injection layer structure, or a hole-blocking layer/electron transport layer/electron injection layer structure. The electron transport region 17 may further include an electron control layer.

The electron transport region 17 may include known electron-transporting materials.

The electron transport region 17 (for example, a buffer layer, a hole-blocking layer, an electron control layer, or an electron transport layer in the electron transport region) may include a metal-free compound including at least one π electron-deficient nitrogen-including C₁-C₆₀ cyclic group. The π electron-deficient nitrogen-including C₁-C₆₀ cyclic group is as described herein.

For example, the electron transport region 17 may include a compound represented by Formula 601.

[Ar₆₀₁]ₓₑ₁₁-[(L₆₀₁)ₓₑ₁-R₆₀₁]ₓₑ₂₁ Formula 601

In Formula 601,
Ar₆₀₁ and L₆₀₁ may each independently be a C₅-C₆₀ carbocyclic group unsubstituted or substituted with at least one R₆₀₁ₐ or a C₁-C₆₀ heterocyclic group unsubstituted or substituted with at least one R₆₀₁ₐ,
xe11 may be 1, 2, or 3,
xe1 may be an integer from 0 to 5,
R₆₀₁ₐ and R₆₀₁ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and
xe21 may be an integer from 1 to 5.

In an embodiment, at least one of xe11 Ar₆₀₁ and xe21 R₆₀₁ may include the π electron-deficient nitrogen-including C₁-C₆₀ cyclic group.

In an embodiment, Ar₆₀₁ and L₆₀₁ in Formula 601 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), —P(═O)(Q₃₁)(Q₃₂), or a combination thereof, and
Q₃₁ to Q₃₃ may each independently be a C₁-C₁₀ alkyl group, a C₁-C₁₀ alkoxy group, a phenyl group, a biphenyl group, a terphenyl group, or a naphthyl group.

When xe11 in Formula 601 is 2 or more, two or more of Ar₆₀₁ may be linked to each other via a single bond.

In some embodiments, Ar₆₀₁ in Formula 601 may be an anthracene group.

In some embodiments, the compound represented by Formula 601 may be represented by Formula 601-1:

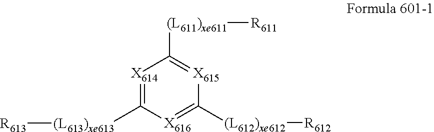

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ are each independently as described in connection with L₆₀₁,
xe611 to xe613 are each independently as described in connection with xe1,
R₆₁₁ to R₆₁₃ are each independently as described in connection with R₆₀₁, and
R₆₁₄ to R₆₁₆ may each independently be hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, or a naphthyl group.

In some embodiments, xe1 and xe611 to xe613 in Formulae 601 and 601-1 may each independently be 0, 1, or 2.

In some embodiments, R₆₀₁ and R₆₁₁ to R₆₁₃ in Formulae 601 and 601-1 may each independently be a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, or an azacarbazolyl group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, an azacarbazolyl group, or a combination thereof; or
—S(═O)₂(Q₆₀₁), or —P(═O)(Q₆₀₁)(Q₆₀₂), wherein Q₆₀₁ and Q₆₀₂ are as described herein.

The electron transport region 17 may include one of Compounds ET1 to ET36 or a combination thereof:

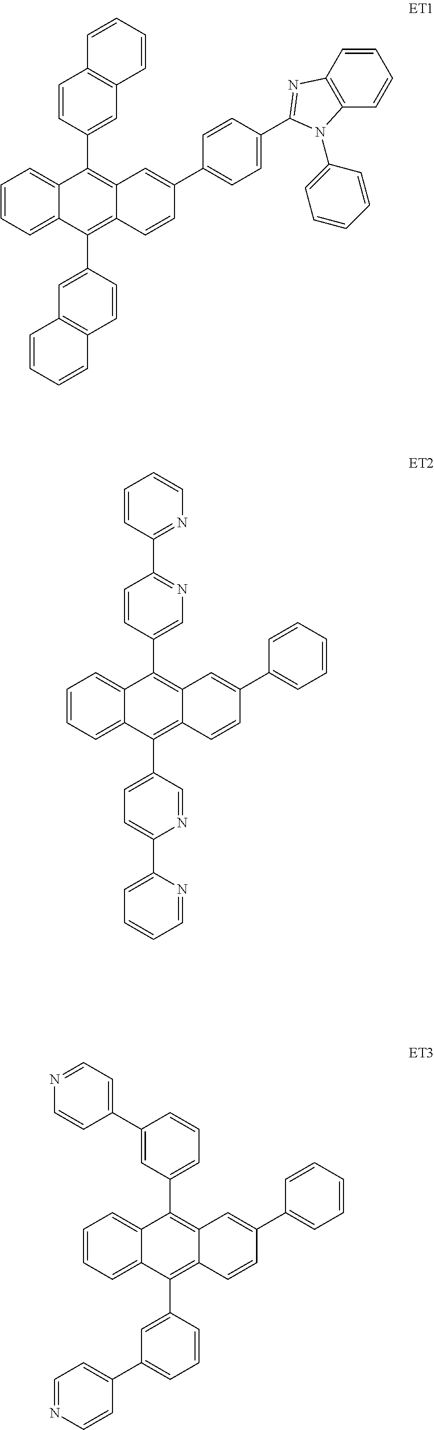 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

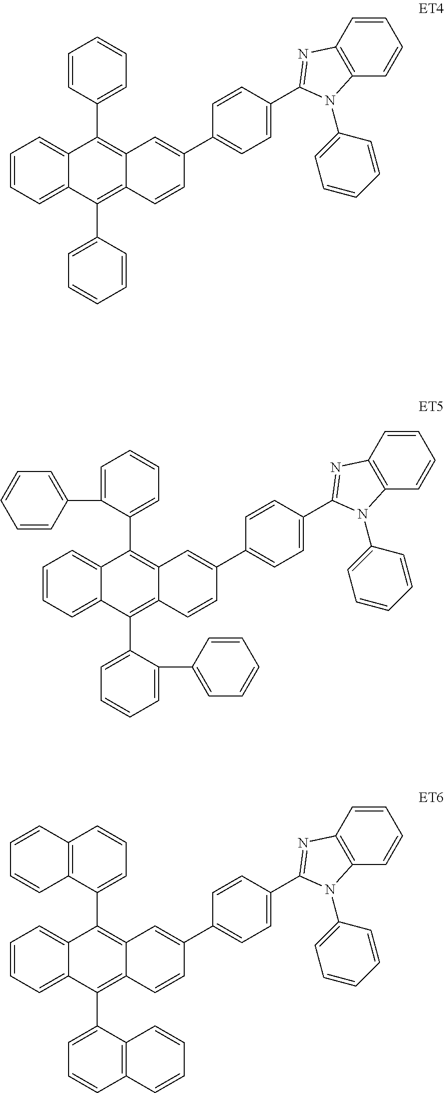 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

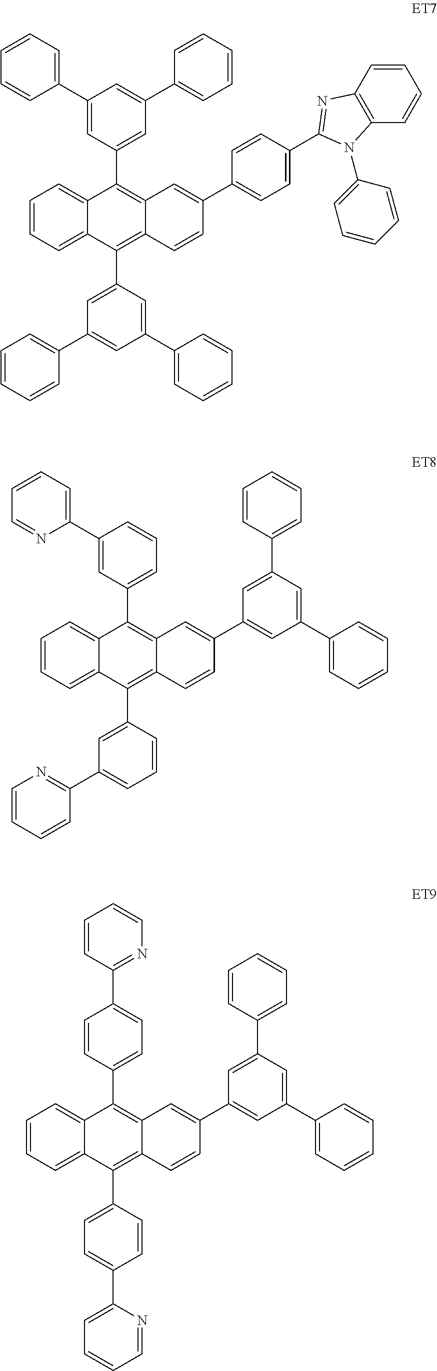 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

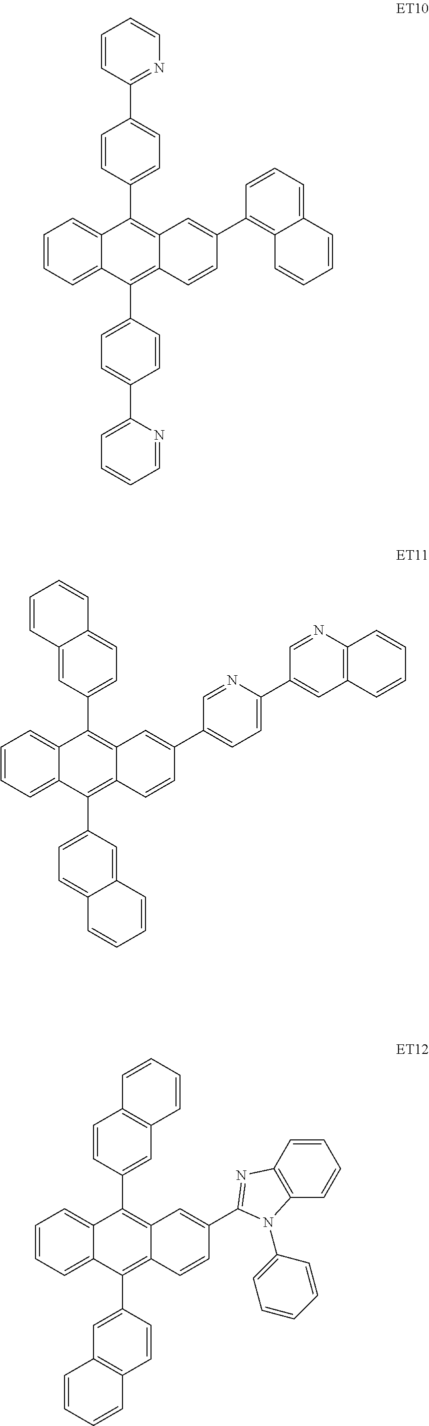 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

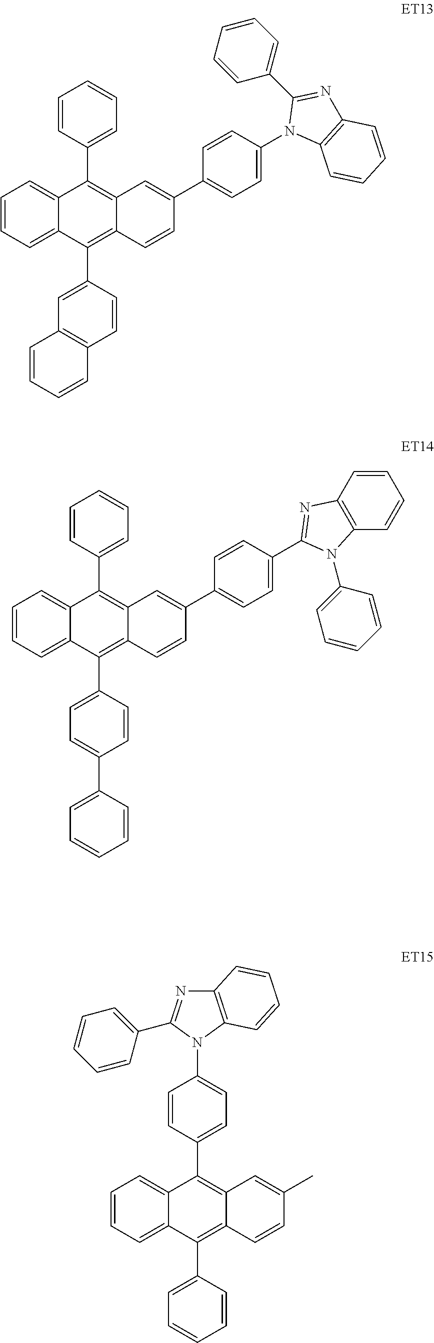 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

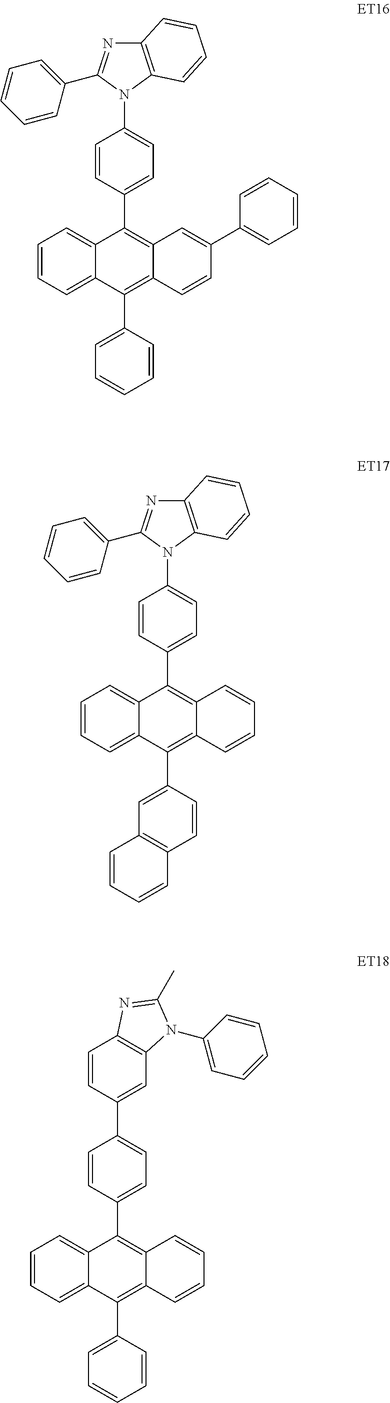 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

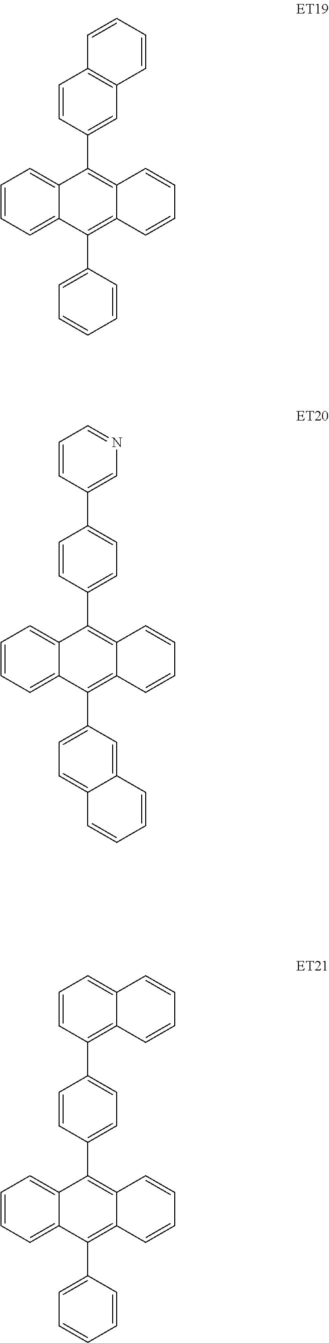

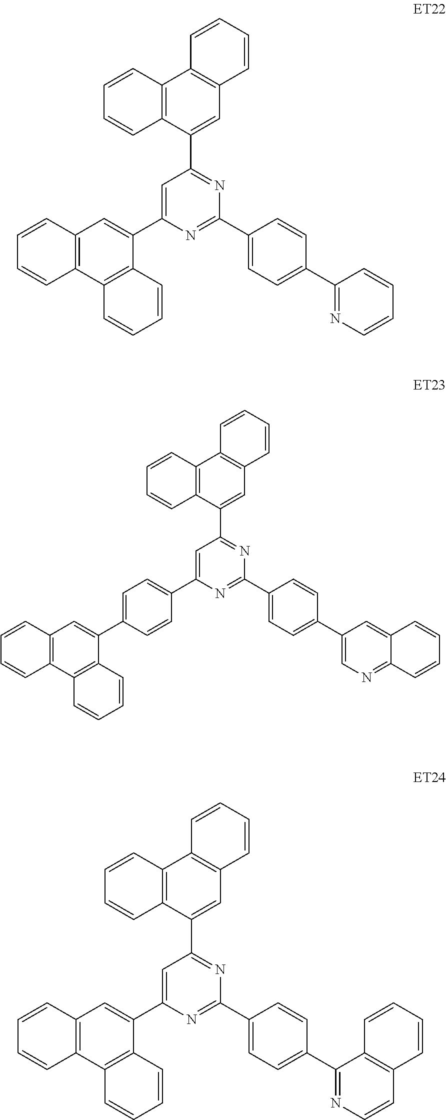 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

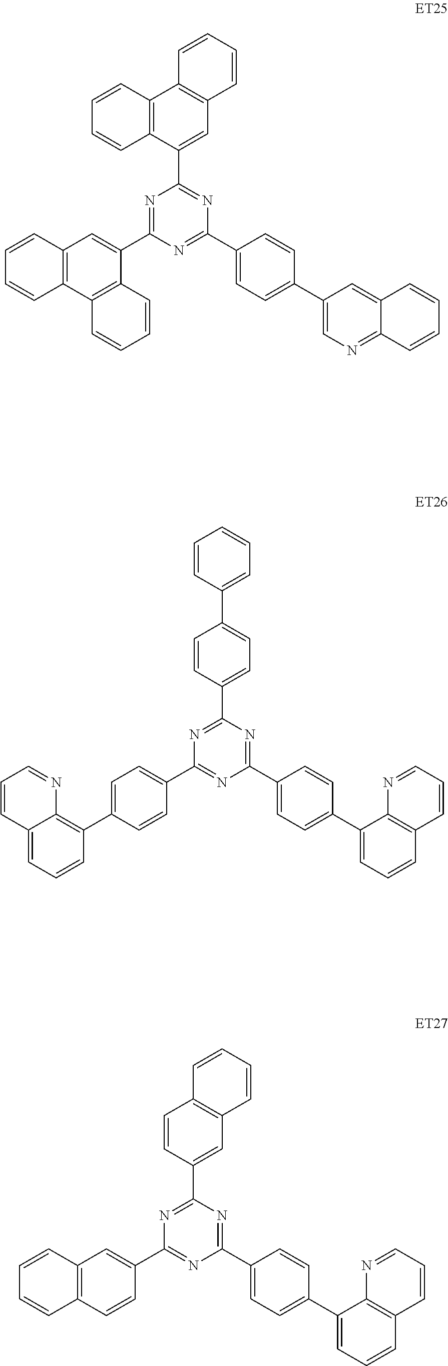 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

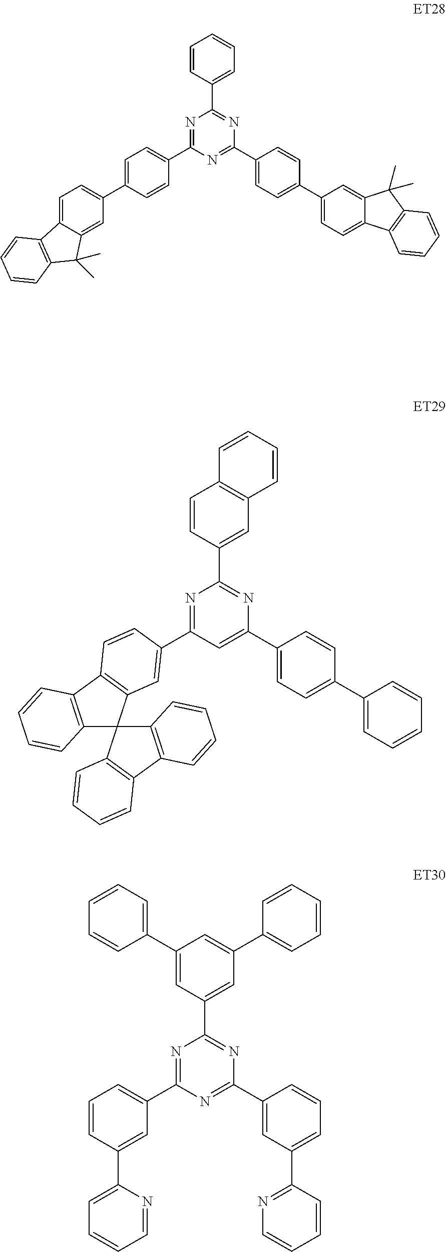 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

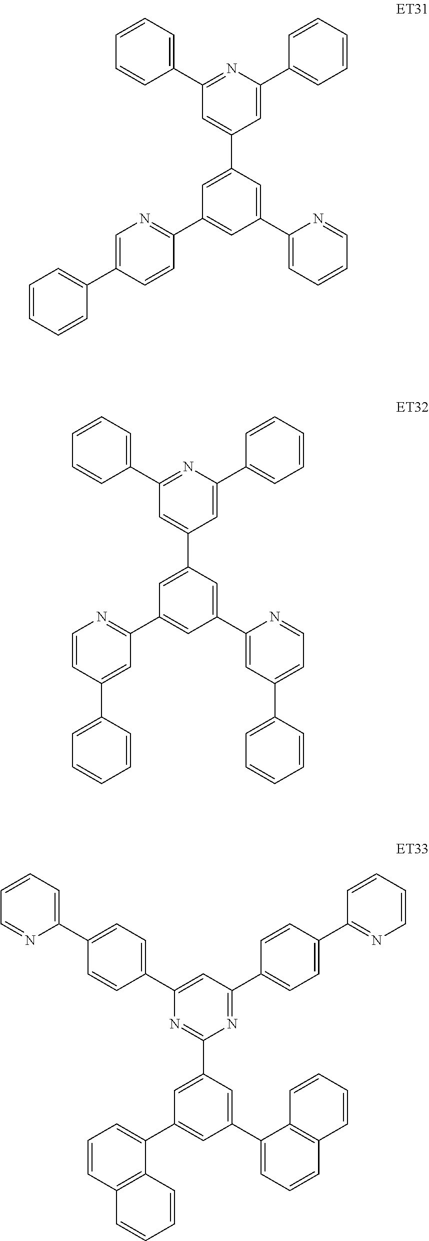 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

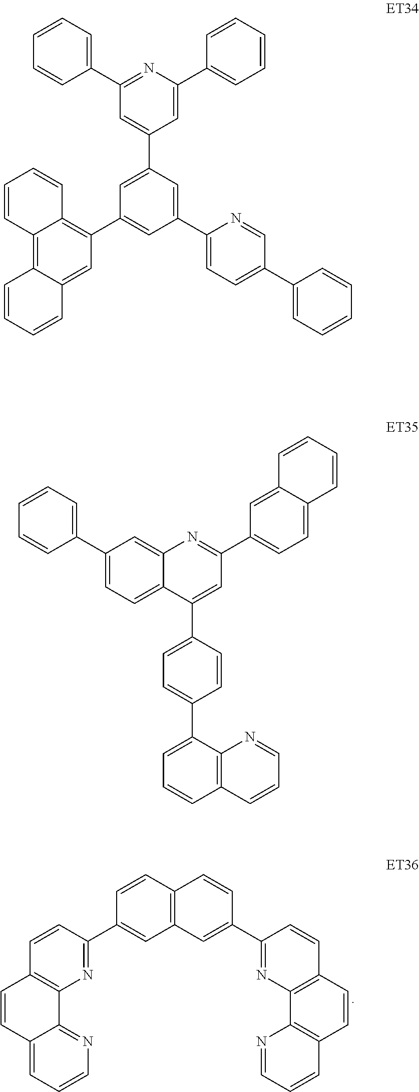 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region 17 may include 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), NTAZ, DBFPO, or a combination thereof. For example, when the electron transport region 17 includes a hole-blocking layer, the hole-blocking layer may include BCP or Bphen:

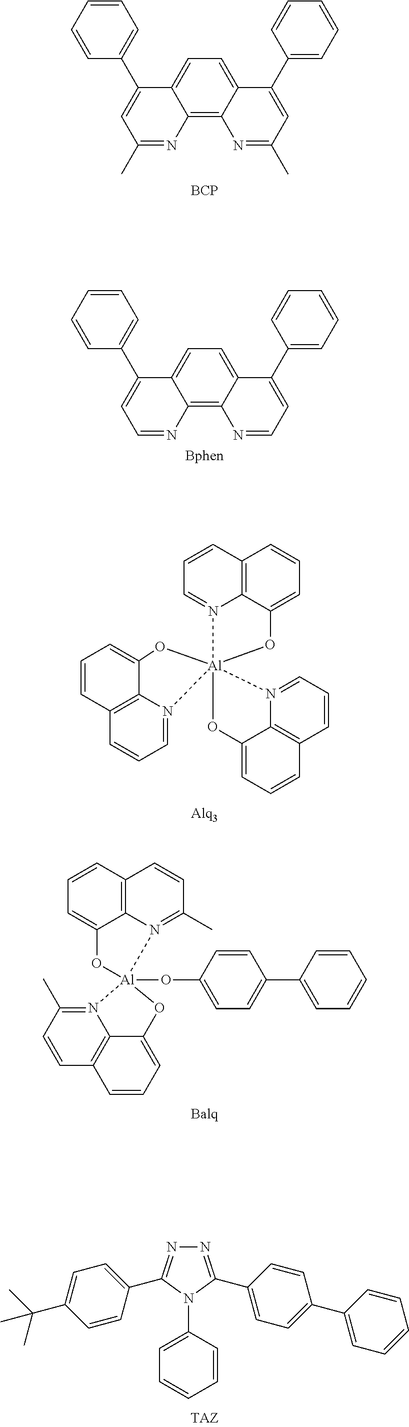

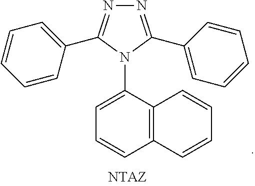 [SMILES: c1ccc(-c2nnc(-c3ccccc3)n2-c2cccc3ccccc23)cc1]

Thicknesses of the buffer layer, the hole-blocking layer, and the electron control layer may each independently be in a range of about 20 angstrom to about 1,000 angstrom, for example, about 30 angstrom to about 300 angstrom. When the thicknesses of the buffer layer, the hole-blocking layer, and the electron control layer are within these ranges, excellent hole blocking characteristics or excellent electron control characteristics may be obtained without a substantial increase in driving voltage.

The thickness of the electron transport layer may be about 100 angstrom to about 1,000 angstrom, for example, about 150 angstrom to about 500 angstrom. When the thickness of the electron transport layer is within these ranges, satisfactory electron-transporting characteristics may be obtained without a substantial increase in driving voltage.

The electron transport region 17 (for example, the electron transport layer in the electron transport region 17) may further include, in addition to the aforementioned materials, a metal-including material.

The metal-including material may include an alkali metal complex, an alkaline earth metal complex, or a combination thereof. A metal ion of the alkali metal complex may include a Li ion, a Na ion, a K ion, a Rb ion, a Cs ion, or a combination thereof, and a metal ion of the alkaline earth metal complex may include a Be ion, a Mg ion, a Ca ion, a Sr ion, a Ba ion, or a combination thereof. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxydiphenyloxadiazole, a hydroxydiphenylthiadiazole, a hydroxyphenylpyridine, a hydroxyphenylbenzimidazole, a hydroxyphenylbenzothiazole, a bipyridine, a phenanthroline, a cyclopentadiene, or a combination thereof.

In an embodiment, the metal-including material may include a L₁ complex. The Li complex may include, for example, Compound ET-D1 (LiQ) or ET-D2:

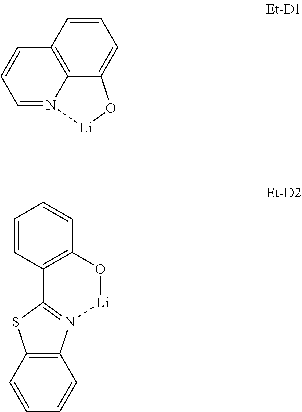

The electron transport region 17 may include an electron injection layer that facilitates the injection of electrons from the second electrode 19. The electron injection layer may directly contact the second electrode 19.

The electron injection layer may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The electron injection layer may include an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof.

The alkali metal may include Li, Na, K, Rb, Cs, or a combination thereof. In an embodiment, the alkali metal may be Li, Na, or Cs. In some embodiments, the alkali metal may be Li or Cs.

The alkaline earth metal may include Mg, Ca, Sr, Ba, or a combination thereof.

The rare earth metal may include Sc, Y, Ce, Tb, Yb, Gd, or a combination thereof.

The alkali metal compound, the alkaline earth metal compound, and the rare earth metal compound may include oxides and halides (for example, fluorides, chlorides, bromides, or iodides) of the alkali metal, the alkaline earth metal, and the rare earth metal, or a combination thereof.

The alkali metal compound may include: one of alkali metal oxides such as Li₂O, Cs₂O, K₂O, and the like; one of alkali metal halides such as LiF, NaF, CsF, KF, LiI, NaI, CsI, KI, and the like; or a combination thereof. In an embodiment, the alkali metal compound may include LiF, Li₂O, NaF, LiI, NaI, CsI, KI, or a combination thereof.

The alkaline earth-metal compound may include one of alkaline earth-metal compounds, such as BaO, SrO, CaO, BaₓSr₁₋ₓO (wherein 0<x<1), or BaₓCa₁₋ₓO (wherein 0<x<1), or a combination thereof. In an embodiment, the alkaline earth metal compound may include BaO, SrO, CaO, or a combination thereof.

The rare earth metal compound may include YbF₃, ScF₃, ScO₃, Y₂O₃, Ce₂O₃, GdF₃, TbF₃, or a combination thereof. In an embodiment, the rare earth metal compound may include YbF₃, ScF₃, TbF₃, YbI₃, ScI₃, TbI₃, or a combination thereof.

The alkali metal complex, the alkaline earth metal complex, and the rare earth metal complex may include an ion of alkali metal, alkaline earth metal, and rare earth metal as described above, and a ligand coordinated with a metal ion of the alkali metal complex, the alkaline earth metal complex, or the rare earth metal complex may include hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, cyclopentadiene, or a combination thereof.

The electron injection layer may consist of an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof, as described above. In some embodiments, the electron injection layer may further include an organic material. When the electron injection layer further includes an organic material, an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or a combination thereof may be homogeneously or non-homogeneously dispersed in a matrix including the organic material.

The thickness of the electron injection layer may be about 1 Å to about 100 Å, and, for example, about 3 Å to about 90 Å. When the thickness of the electron injection layer is within the range as described above, satisfactory electron injection characteristics may be obtained without a substantial increase in driving voltage.

### Second Electrode 19

The second electrode 19 is disposed on the interlayer 10A as described above.

The second electrode 19 may be a cathode which is an electron injection electrode, and in this regard, a material for forming the second electrode 19 may be selected from a metal, an alloy, an electrically conductive compound, and a combination thereof, which have a relatively low work function.

The second electrode 19 may include Li, Ag, Mg, Al, Al—Li, Ca, Mg—In, Mg—Ag, ITO, IZO, or a combination thereof. The second electrode 19 may be a transmissive electrode, a semi-transmissive electrode, or a reflective electrode.

The second electrode 19 may have a single-layer structure having a single layer or a multi-layer structure including two or more layers.

### Explanation of Terms

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₂-C₆₀ alkenyl group” as used herein refers to a structure including at least one carbon-carbon double bond in the middle or at the end of the C₂-C₆₀ alkyl group, and examples thereof include an ethenyl group, a propenyl group, and a butenyl group.

The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof are an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group are a cyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a monovalent monocyclic group that includes at least one heteroatom selected from N, O, P, Si, S, Se, Ge, and B as a ring-forming atom and 1 to 10 carbon atoms, and the term “the C₁-C₁₀ heterocycloalkylene group” as used herein refers to a divalent group having the same structure as the C₁-C₁₀ heterocycloalkyl group.

Examples of the C₁-C₁₀ heterocycloalkyl group are a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent cyclic group that has 3 to 10 carbon atoms, and at least one carbon-carbon double bond in the ring thereof and has no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₂-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one carbon-carbon double bond in the ring thereof. Examples of the C₂-C₁₀ heterocycloalkenyl group include a 2,3-dihydrofuranyl group and a 2,3-dihydrothiophenyl group. The term “C₁-C₁₀ heterocycloalkenylene group” as used herein refers to a divalent group having the same structure as the C₂-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused with each other.

The term “C₁-C₆₀ heteroaryl group” as used herein refers to a monovalent group that includes at least one heteroatom selected from N, O, P, Si, S, Se, Ge, and B as a ring-forming atom and a heterocyclic aromatic system having 1 to 60 carbon atoms, and the term “C₁-C₆₀ heteroarylene group” as used herein refers to a divalent group that includes at least one heteroatom selected from N, O, P, Si, S, Se, Ge, and B as a ring-forming atom and a heterocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused with each other.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “monovalent non-aromatic condensed polycyclic group” as used herein refers to a monovalent group in which two or more rings are condensed with each other, only carbon is used as a ring-forming atom (for example, the number of carbon atoms may be 8 to 60), and the whole molecule is a non-aromaticity group. An example of the monovalent non-aromatic condensed polycyclic group is a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, a heteroatom selected from N, O, P, Si, S, Se, Ge, and B, other than carbon atoms (for example, having 1 to 60 carbon atoms), as a ring-forming atom, and no aromaticity in the entire molecular structure thereof. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “π electron-deficient nitrogen-including C₁-C₆₀ cyclic group” as used herein refers to a cyclic group having 1 to 60 carbon atoms and including at least one *—N═*′ (wherein * and *′ each indicate a binding site to an adjacent atom) as a ring-forming moiety. For example, the π electron-deficient nitrogen-including C₁-C₆₀ cyclic group may be a) a first ring, b) a condensed ring in which at least two first rings are condensed, or c) a condensed ring in which at least one first ring and at least one second ring are condensed.

The term “π electron-rich C₃-C₆₀ cyclic group” as used herein refers to a cyclic group having 3 to 60 carbon atoms and not including at least one *—N═*′ (wherein * and *′ each indicate a binding site to an adjacent atom) as a ring-forming moiety. For example, the π electron-rich C₃-C₆₀ cyclic group may be a) a second ring or b) a condensed ring in which at least two second rings are condensed.

The term “C₅-C₆₀ cyclic group” as used herein refers to a monocyclic or polycyclic group having 5 to 60 carbon atoms, and may be, for example, a) a third ring or b) a condensed ring in which two or more third rings are condensed with each other.

The term “C₁-C₆₀ heterocyclic group” as used herein refers to a monocyclic or polycyclic group that has 1 to 60 carbon atoms and includes at least one heteroatom, and may be, for example, a) a fourth ring, b) a condensed ring in which two or more fourth rings are condensed with each other, or c) a condensed ring in which at least one third ring is condensed with at least one fourth ring.

The “first ring” as used herein may be an imidazole group, a pyrazole group, a thiazole group, an isothiazole group, an oxazole group, an isoxazole group, a pyridine group, a pyrazine group, a pyridazine group, a pyrimidine group, a triazole group, a tetrazole group, an oxadiazole group, a triazine group, or a thiadiazole group.

The “second ring” as used herein may be a benzene group, a cyclopentadiene group, a pyrrole group, a furan group, a thiophene group, or a silole group.

The “third ring” as used herein may be a cyclopentane group, a cyclopentadiene group, an indene group, an adamantane group, a norbornene group, a bicyclo[1.1.1]pentane group, a bicyclo[2.1.1]hexane group, a bicyclo[2.2.1]heptane group (a norbornane group), a bicyclo[2.2.2]octane group, a cyclohexane group, a cyclohexene group, or a benzene group.

The “fourth ring” as used herein may be a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, a triazasilole group, a pyridine group, a pyrimidine group, a pyrazine group, a pyridazine group, or a triazine group.

For example, the π electron-deficient nitrogen-including C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

For example, the π electron-rich C₃-C₆₀ cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonapthothiophene group, an (indolo)phenanthrene group, a (benzofurano)phenanthrene group, or a (benzothieno)phenanthrene group.

For example, the C₅-C₆₀ carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, a 5,6,7,8-tetrahydroisoquinoline group, a 5,6,7,8-tetrahydroquinoline group, an adamantane group, a norbornane group, or a norbornene group.

For example, the C₁-C₆₀ heterocyclic group may be a thiophene group, a furan group, a pyrrole group, a cyclopentadiene group, a silole group, a borole group, a phosphole group, a selenophene group, a germole group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

The terms “a π electron-deficient nitrogen-including C₁-C₆₀ cyclic group, a π electron-rich C₃-C₆₀ cyclic group, a C₅-C₆₀ cyclic group, and a C₁-C₆₀ heterocyclic group” as used herein each refer to a part of a condensed ring or a monovalent, a divalent, a trivalent, a tetravalent, a pentavalent, or a hexavalent group, depending on the formula structure.

Substituents of the substituted π electron-deficient nitrogen-including C₁-C₆₀ cyclic group, the substituted π electron-rich C₃-C₆₀ cyclic group, the substituted C₅-C₆₀ cyclic group, the substituted C₁-C₆₀ heterocyclic group, the substituted C₁-C₆₀ alkylene group, the substituted C₂-C₆₀ alkenylene group, the substituted C₂-C₆₀ alkynylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof.

Q₁ to Q₉, Q₁₁ to Q₁₉, Q₂₁ to Q₂₉, and Q₃₁ to Q₃₉ described herein may each independently be: hydrogen; deuterium; —F; —Cl; —Br; —I; a hydroxyl group; a cyano group; a nitro group; an amidino group; a hydrazine group; a hydrazone group; a carboxylic acid or a salt thereof; a sulfonic acid or a salt thereof; a phosphoric acid or a salt thereof; a C₁-C₆₀ alkyl group which is unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₂-C₁₀ heterocycloalkenyl group; a C₆-C₆₀ aryl group which is unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉, and Q₃₁ to Q₃₉ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

The term “room temperature” as used herein refers to a temperature of about 25° C.

The terms “a biphenyl group, a terphenyl group, and a tetraphenyl group” used herein respectively refer to monovalent groups in which two, three, or four phenyl groups which are linked together via a single bond.

Hereinafter, a compound and an organic light-emitting device according to embodiments are described in detail with reference to Synthesis Examples and Examples. However, the organic light-emitting device is not limited thereto. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Example 1: Synthesis of Compound 10

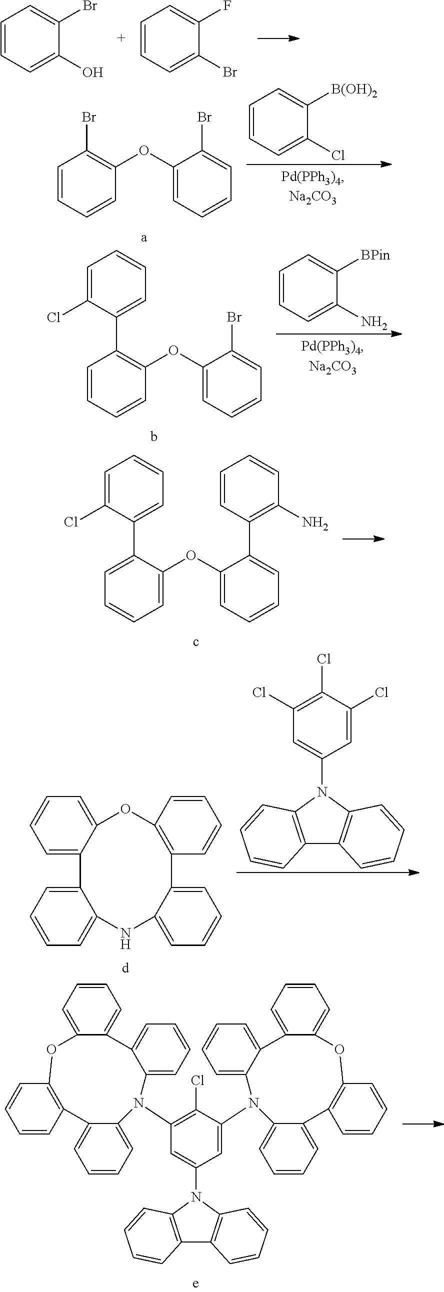

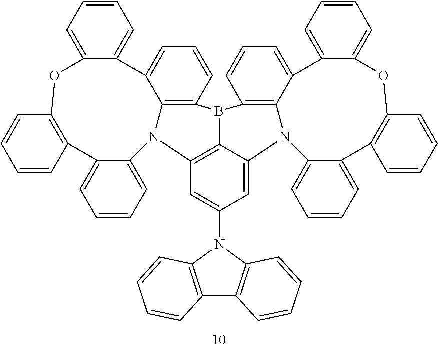 [SMILES: c1ccc2c(c1)Oc1ccccc1-c1cccc3c1N(c1ccccc1-2)c1cc(-n2c4ccccc4c4ccccc42)cc2c1B3c1cccc3c1N2c1ccccc1-c1ccccc1Oc1ccccc1-3]

### Synthesis of Intermediate 1(a)

2-bromo-phenol (50.0 g, 289 mmol), 1-bromo-2-fluorobenzene (55.63 g, 318 mmol), potassium carbonate (59.914 g, 434 mmol), and 500 ml of triethylene glycol dimethyl ether (triglyme) were placed in a round flask and stirred under reflux at 190° C. under a nitrogen atmosphere. After completion of the reaction, the organic solvent layer was concentrated and purified by column chromatography to obtain Intermediate 1(a) (85 g, yield of 90%).

LC-Mass (calculated: 328 g/mol, found: 325.89 (M⁺¹))

### Synthesis of Intermediate 1(b)

Intermediate 1(a) (70 g, 213 mmol), 2-chlorophenylboronic acid (50.1 g, 320 mmol), tetrakis(triphenylphosphine)palladium (0) (Pd(PPh₃)₄) (33.2 g, 21.3 mmol), and sodium carbonate (45.15 g, 426 mmol) were mixed with 1.2 L of a mixture of toluene and ethanol and stirred at 80° C. After completion of the reaction, a result which had been cooled to room temperature was subjected to an extraction process using distilled water and dichloromethane, and the remaining water was removed therefrom with anhydrous magnesium sulfate and filtered under reduced pressure. An organic layer obtained therefrom was concentrated under reduced pressure, and the obtained solid was separated and purified by column chromatography to obtain Intermediate 1(b) (34 g, yield of 45%).

LC-Mass (calculated: 359.65 g/mol, found: 357.98 (M⁺¹))

### Synthesis of Intermediate 1(c)

Intermediate 1(c) (29.88 g, yield of 85%) was synthesized using Intermediate 1(b) (34.0 g, 94.54 mmol) and 2-(4,4,5,5-tetramethyl-1,3,2-dioxaborolan-2-yl)aniline) (13.06 g, 141.8 mmol) in the same manner as used to synthesize Intermediate 1(b) in Synthesis Example 1.

LC-Mass (calculated: 371.86 g/mol, found: 371.11 (M⁺¹))

### Synthesis of Intermediate 1(d)

Intermediate 1(c) (29 g, 77.99 mmol), S-phos (6.40 g, 15.6 mmol) and tris(dibenzylideneacetone)dipalladium(0) (Pd₂(dba)₃) (7.14 g, 7.8 mmol, 0.1 M in xylene) were mixed and stirred at 130° C. After completion of the reaction, a result which had been cooled to room temperature, was subjected to an extraction process using distilled water and dichloromethane, and the remaining water was removed therefrom with anhydrous magnesium sulfate and filtered under reduced pressure. An organic layer obtained therefrom was concentrated under reduced pressure, and the obtained solid was separated and purified by column chromatography to obtain Intermediate 1(d) (23 g, yield of 89%) as a yellow solid.

LC-Mass (calculated: 335.41 g/mol, found: 335.13 g/mol (M⁺¹))

### Synthesis of Intermediate 1(e)

9-(3,4,5-trichlorophenyl)-9H-carbazole (10.80 g, 31.17 mmol), Intermediate 1(d) (23.00 g, 68.57 mmol), Sphos (2.56 g, 6.23 mmol), and 0.1 M tris(dibenzylideneacetone)dipalladium(0) (Pd₂(dba)₃) (2.85 g, 3.12 mmol) in xylene were mixed and stirred at 130° C. After completion of the reaction and cooling the reaction mixture to room temperature, ethyl acetate and distilled water were added, the organic layer was separated and dried with anhydrous magnesium sulfate and filtered under reduced pressure. An organic layer obtained therefrom was concentrated under reduced pressure, and the obtained solid was separated and purified by column chromatography to obtain Intermediate 1(e) (11.76 g, yield of 40%).

LC-Mass (calculated: 944.53 g/mol, found: 943.30 (M⁺¹))

### Synthesis of Compound 10

Intermediate 1(e) (10 g, 10.59 mmol) was dissolved in 90 ml of t-butylbenzene under nitrogen, and cooled to −78° C., and then t-butyllithium (t-BuLi, 1.6 M in hexanes) (19.85 ml, 31.76 mmol) was added thereto, and the temperature was raised to 60° C. and stirred for 1 hour and 30 minutes. The resultant product was cooled to 0° C., and then, boron tribromide (3.0 ml, 31.76 mmol) was added thereto and stirred at room temperature for 1 hour and 30 minutes. The resultant product was cooled to 0° C., and then, N,N-diisopropylethyl acetate (5.55 ml, 31.76 mmol) was added thereto, and heated at 120° C. for 4 hours, and then the reaction was terminated using a sodium acetate solution (1.0 M). An organic layer was extracted and dried with MgSO₄, and a solvent was removed therefrom, and the obtained result was purified by column chromatography using methylene chloride (MC):hexane (1:4) to obtain 3.40 g of Compound 10 which was solid. (yield of 35%)

LC-Mass (calculated: 917.88 g/mol, found: 917.32 (M⁺¹))

### Synthesis Example 2: Synthesis of Compound 13

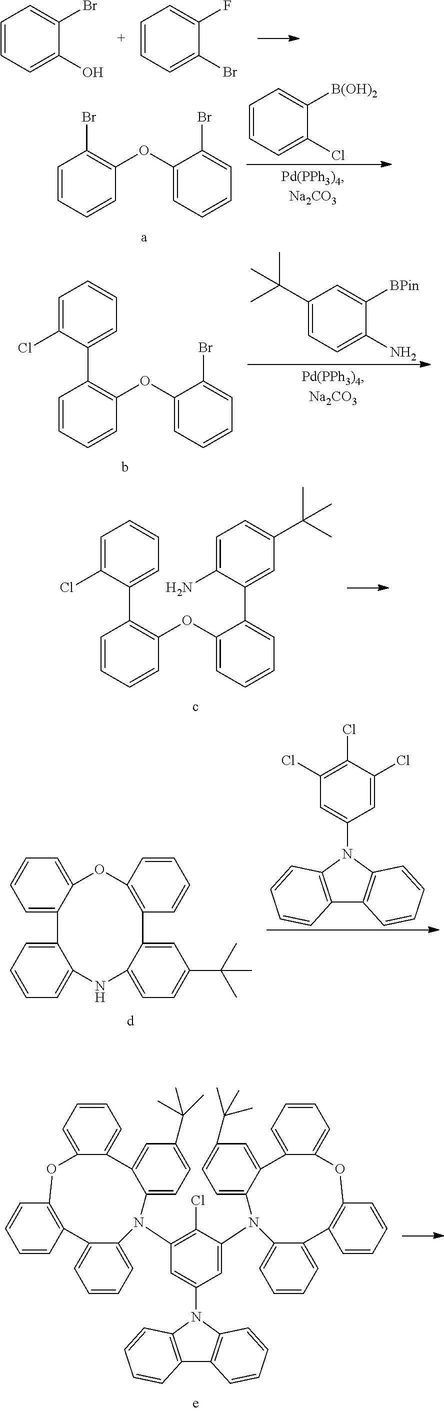

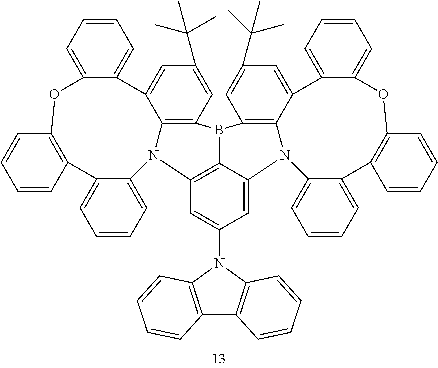 [SMILES: CC(C)(C)c1cc2c3c(c1)-c1ccccc1Oc1ccccc1-c1ccccc1N3c1cc(-n3c4ccccc4c4ccccc43)cc3c1B2c1cc(C(C)(C)C)cc2c1N3c1ccccc1-c1ccccc1Oc1ccccc1-2]

Compound 13 (3.41 g, yield of 35%) was synthesized in the same manner as used to synthesize Compound 10 of Synthesis Example 1, except that, in synthesizing Intermediate 2(c), 4-(tert-butyl)-2-(4,4,5,5-tetramethyl-1,3,2-dioxaborolan-2-yl)aniline was used instead of 2-(4,4,5,5-tetramethyl-1,3,2-dioxaborolan-2-yl)aniline.

LC-Mass (calculated: 1030.09 g/mol, found: 1029.45 (M⁺¹))

### Synthesis Example 3: Synthesis of Compound 11

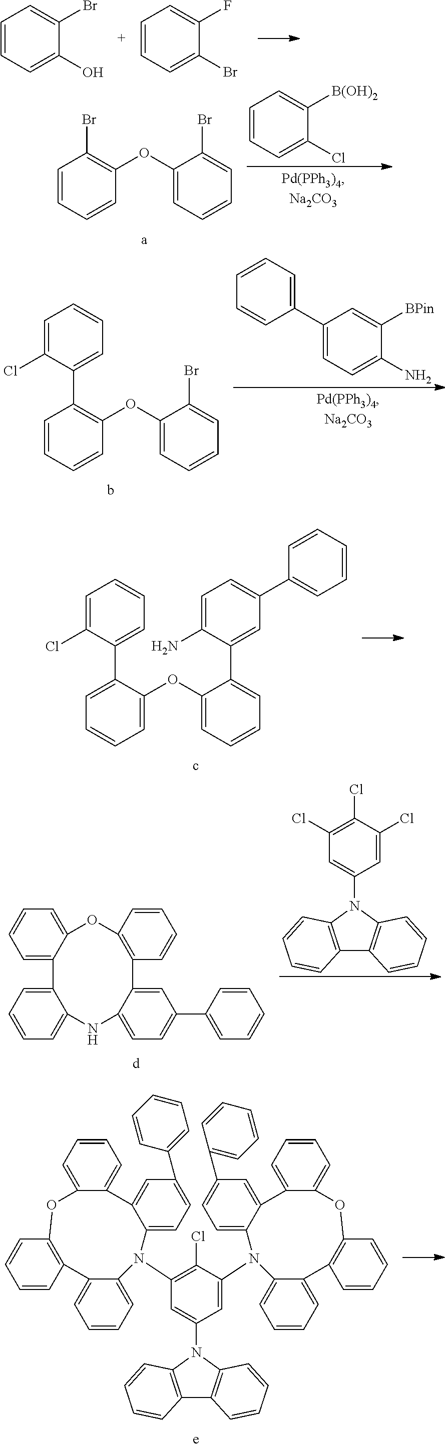

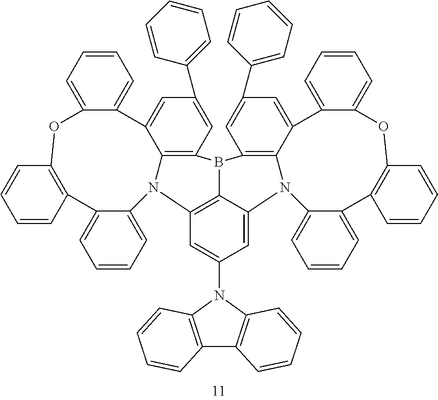 [SMILES: c1ccc(-c2cc3c4c(c2)-c2ccccc2Oc2ccccc2-c2ccccc2N4c2cc(-n4c5ccccc5c5ccccc54)cc4c2B3c2cc(-c3ccccc3)cc3c2N4c2ccccc2-c2ccccc2Oc2ccccc2-3)cc1]

Compound 11 (2.44 g, yield of 25%) was synthesized in the same manner as used to synthesize Compound 10 of Synthesis Example 1, except that, in synthesizing Intermediate 3(c), 3-(4,4,5,5-tetramethyl-1,3,2-dioxaborolan-2-yl)-[1,1′-biphenyl]-4-amine was used instead of 2-(4,4,5,5-tetramethyl-1,3,2-dioxaborolan-2-yl)aniline.

LC-Mass (calculated: 1070.07 g/mol, measured: 1069.38 (M⁺¹))

### Synthesis Example 4: Synthesis of Compound 181

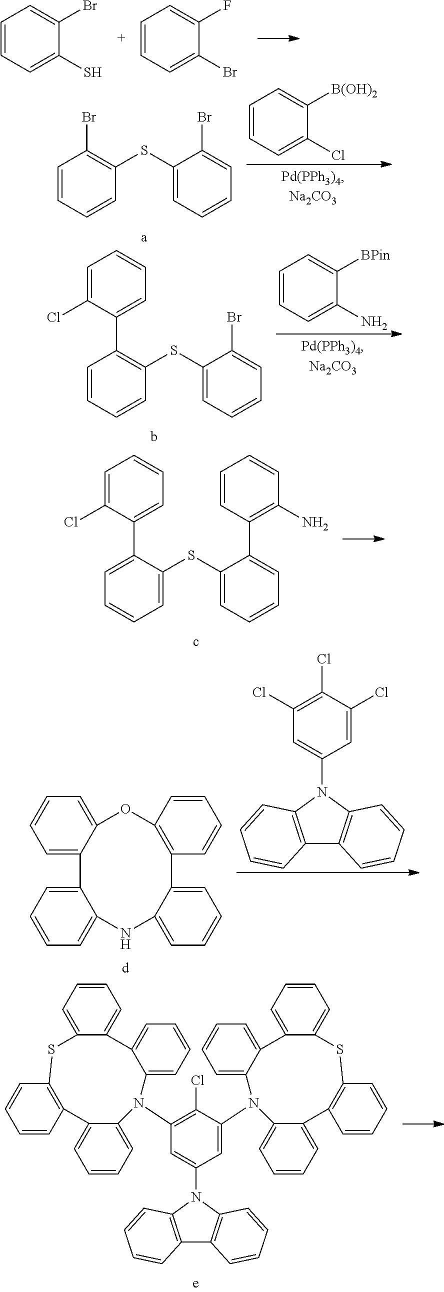

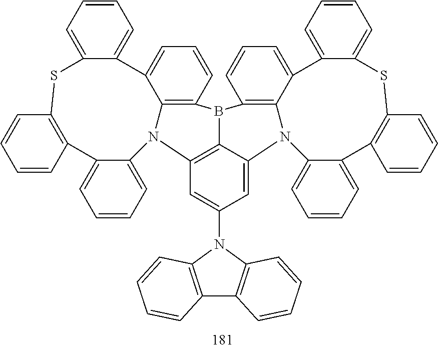 [SMILES: c1ccc2c(c1)Sc1ccccc1-c1cccc3c1N(c1ccccc1-2)c1cc(-n2c4ccccc4c4ccccc42)cc2c1B3c1cccc3c1N2c1ccccc1-c1ccccc1Sc1ccccc1-3]

### Synthesis of Compound 181

Compound 181 (1.94 g, yield of 20%) was synthesized in the same manner as used to synthesize Compound 10 of Synthesis Example 1, except that in synthesizing Intermediate 4(a), bromobenzenethiol was used instead of bromophenol.

LC-Mass (calculated: 950 g/mol, found: 949.28 (M⁺¹))

The condensed cyclic compound can have excellent thermal and electrical stability and a relatively small steric hindrance effect, due to the shielding effect, and emits a relatively small full-width-at-half-maximum (FWHM) and short-wavelength shifted blue light. Accordingly, an electronic device for example, a light-emitting device, using the condensed cyclic compound, may have improved driving voltage, improved external quantum efficiency, improved luminescence efficiency, and/or improved, e.g., longer, lifetime characteristics.

### Evaluation Example 1

After measuring the emission spectra of each of the compounds in Table 3 according to the method described in Table 2, the emission peak wavelength (PLₘₐₓ) of the peak with the maximum emission intensity, the half-width at half-maximum (FWHM) of the peak with the maximum emission intensity, and the triplet (T₁) energy of the peak with the maximum emission intensity of the emission spectrum of each compound were evaluated and are shown in Table 3.

TABLE 2

| | |
|---|---|
| The emission peak | Each compound was diluted to a |
| wavelength(PLₘₐₓ) | concentration of 1 ×10⁻⁵ M in |
| | toluene and photoluminescence |
| | (PL) spectra were measured |
| | for the compounds at room |
| | temperature using an ISC PC1 |
| | Spectrofluorometer equipped |
| | with a xenon lamp. |
| Ti energy level | T1 energy level was calculated |
| | from PLₘₐₓ value determined |
| | from the emission spectrum |
| | above and the following formula: |
| | T₁ (eV) = 1240/PLₘₐₓ |

TABLE 3

| Compound | PLₘₐₓ | FWHM | T₁ |
|---|---|---|---|
| No. | (nm) | (nm) | (eV) |
| 10 | 455 | 22 | 2.61 |
| 13 | 460 | 22 | 2.56 |
| 11 | 461 | 23 | 2.58 |
| 181 | 463 | 22 | 2.62 |

### Example 1

A glass substrate on which the 1500 Å thick ITO electrode was formed was cut into 50 mm×50 mm×0.5 mm dimensions and ultrasonically cleaned in acetone-isopropyl alcohol and pure water for 15 minutes each, followed by ultraviolet (UV) ozone cleaning for 30 minutes.

Next, m-MTDATA was deposited on the ITO electrode (anode) on the glass substrate to form a hole injection layer having a thickness of 600 Å, and α-NPD was deposited on the hole injection layer to form a hole transport layer having a thickness of 250 Å.

Compound 10 (emitter) and mCP (host) were co-deposited on the hole transport layer in a weight ratio of 10:90 to form an emission layer having a thickness of 400 Å.

BAlq was deposited on the emission layer to form a hole-blocking layer having a thickness of 50 Å, and then Alq₃ was deposited on the hole-blocking layer to form an electron transport layer having a thickness of 300 Å. Then, LiF was deposited on the electron transport layer to form an electron injection layer having a thickness of 10 Å, and then Al was vacuum-deposited on the electron injection layer to form a cathode having a thickness of 1200 Å, thereby completing the manufacture of an organic light-emitting device having the structure of ITO/m-MTDATA (600 Å)/α-NPD (250 Å)/mCP+Compound 10 (10 weight %) (400 Å)/BAlq(50 Å)/Alq₃(300 Å)/LiF(10 Å)/Al(1200 Å).

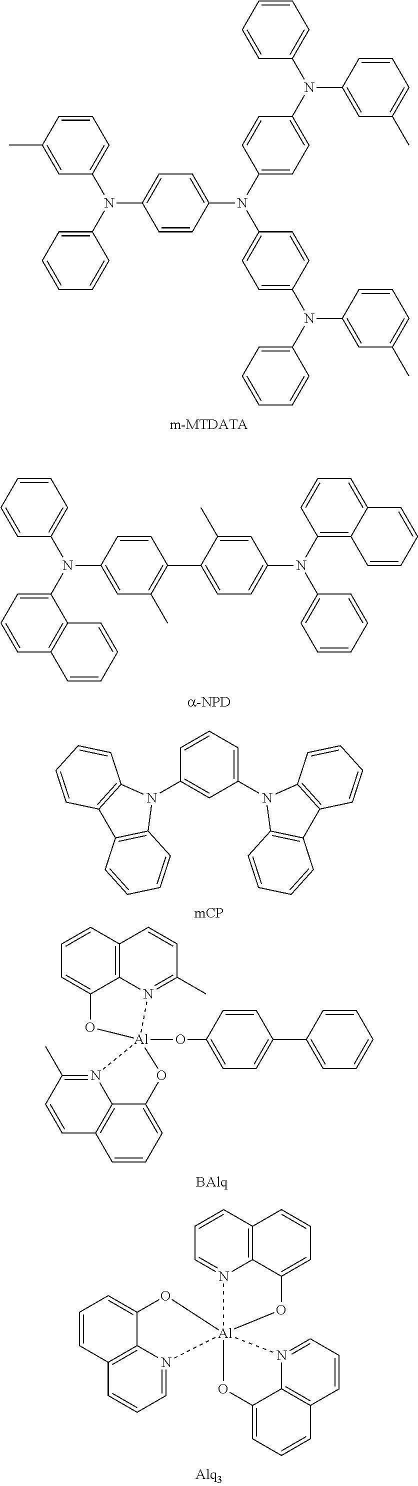

### Examples 2 to 4, Comparative Example A and Comparative Example B

The organic light-emitting devices of Examples 2 to 4, Comparative Example A and Comparative Example B were prepared using the same method as in Example 1, except that the compounds listed in Table 4 below were used in place of Compound 10.

### Evaluation Example 2

The emission peak wavelength (maximum emission peak wavelength), driving voltage, and external quantum efficiency (EQE) of the EL spectra were evaluated for each of the light-emitting devices fabricated in Examples 1 to 4, Comparative Example A and Comparative Example B above, and the results are shown in Table 4. The emission peak wavelengths of the EL spectra were evaluated from the EL spectra (at 1000 cd/m2) measured using a luminometer (Minolta Cs-1000A) for each organic light-emitting device. The driving voltage and external quantum efficiency were evaluated using a current-voltage meter (Keithley 2400) and a luminometer (Minolta Cs-1000A). The drive voltage and external quantum efficiency values in Table 4 are expressed as relative values (%).

TABLE 4

| | | | | External quantum |
|---|---|---|---|---|
| | | Emission | Drive | efficiency at |
| | | peak | voltage | 1000 cd/m²) |
| | Compound | wavelength | (relative | (relative value, |
| | No. | (nm) | value, %) | %) |
| Ex. 1 | 10 | 455 | 94.2 | 110 |
| Ex 2. | 13 | 460 | 95.4 | 120 |
| Ex. 3 | 11 | 461 | 97.0 | 115 |
| Ex. 4 | 181 | 463 | 97.1 | 105 |
| Comp. | A | 462 | 99.7 | 99 |
| Ex. A | | | | |
| Comp. | B | 460 | 97.6 | 100 |
| Ex. B | | | | |

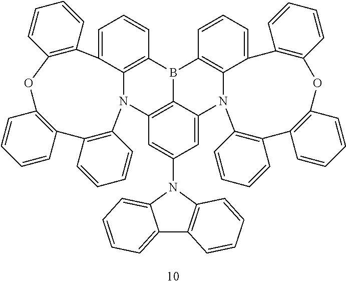 [SMILES: c1ccc2c(c1)Oc1ccccc1-c1cccc3c1N(c1ccccc1-2)c1cc(-n2c4ccccc4c4ccccc42)cc2c1B3c1cccc3c1N2c1ccccc1-c1ccccc1Oc1ccccc1-3]

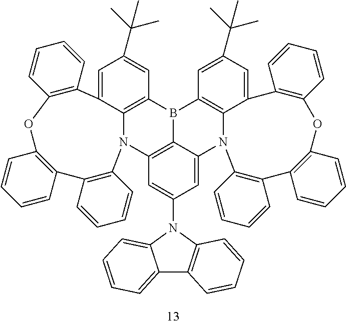 [SMILES: CC(C)(C)c1cc2c3c(c1)-c1ccccc1Oc1ccccc1-c1ccccc1N3c1cc(-n3c4ccccc4c4ccccc43)cc3c1B2c1cc(C(C)(C)C)cc2c1N3c1ccccc1-c1ccccc1Oc1ccccc1-2]

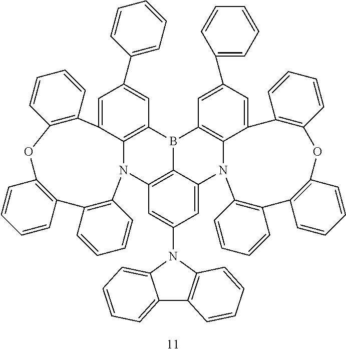 [SMILES: c1ccc(-c2cc3c4c(c2)-c2ccccc2Oc2ccccc2-c2ccccc2N4c2cc(-n4c5ccccc5c5ccccc54)cc4c2B3c2cc(-c3ccccc3)cc3c2N4c2ccccc2-c2ccccc2Oc2ccccc2-3)cc1]

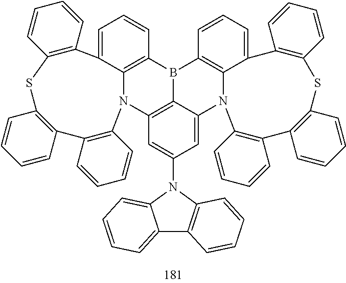 [SMILES: c1ccc2c(c1)Sc1ccccc1-c1cccc3c1N(c1ccccc1-2)c1cc(-n2c4ccccc4c4ccccc42)cc2c1B3c1cccc3c1N2c1ccccc1-c1ccccc1Sc1ccccc1-3]

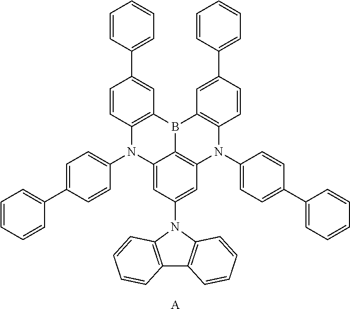

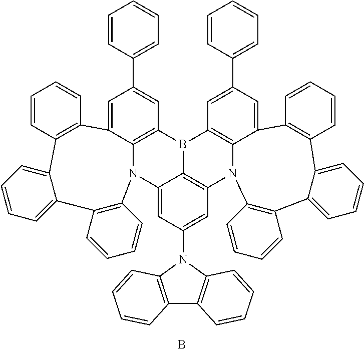

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A condensed cyclic compound which is free of metal and comprises a condensed cyclic core, the condensed cyclic core comprising a first condensed ring and a second condensed ring condensed with each other, wherein
the first condensed ring is a 10-membered ring, an 11-membered ring, a 12-membered ring, or a 13-membered ring, each comprising nitrogen and carbon as a first ring-forming atom, and at least one heteroatom selected from oxygen, sulfur, selenium, or nitrogen as a second ring-forming atom, in addition to the first ring-forming atom,
the second condensed ring is a 6-membered ring comprising nitrogen, carbon, and boron,
the first condensed ring and the second condensed ring are condensed with each other while sharing nitrogen and carbon,
the condensed cyclic core further comprises a third condensed ring that is condensed with the first condensed ring and is not condensed with the second condensed ring,
the third condensed ring is a C₅-C₆₀ carbocyclic group or a C₃-C₆₀ heterocyclic group, and
the number of third condensed rings in the condensed cyclic core is 3 or more.

2. The condensed cyclic compound of claim 1, wherein
the condensed cyclic core is represented by Formula 1(1): 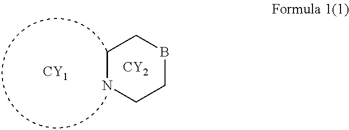
wherein, in Formula 1(1),
ring CY₁ is the first condensed ring, and
ring CY₂ is the second condensed ring.

3. The condensed cyclic compound of claim 1, wherein
the number of first condensed rings in the condensed cyclic compound is 1, 2, 3, or 4.

4. The condensed cyclic compound of claim 1, wherein
the condensed cyclic compound is a multiple resonance thermally activated delayed fluorescence material.

5. The condensed cyclic compound of claim 1, wherein
the condensed cyclic compound is represented by Formula 1, 2, or 3: 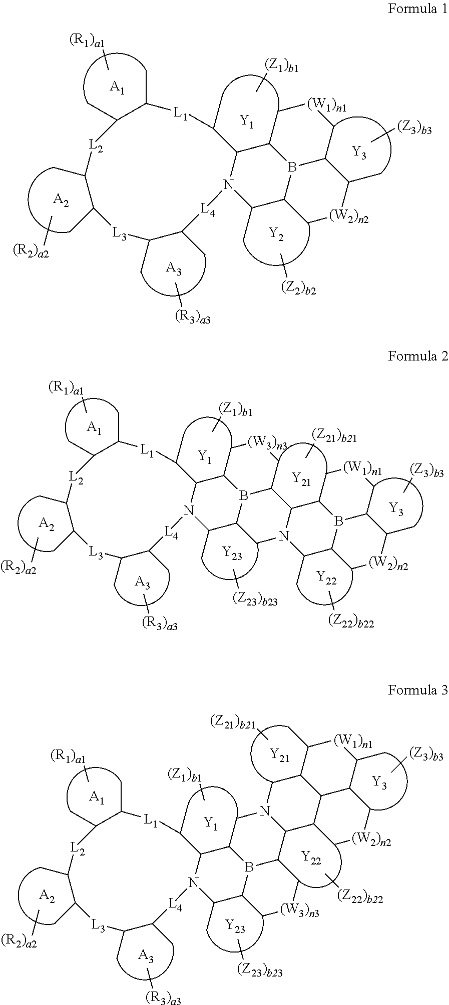
wherein, in Formulae 1, 2, and 3,
ring A₁ to ring A₃, ring Y₁ to ring Y₃ and ring Y₂₁ to ring Y₂₃ are each independently a C₅-C₆₀ carbocyclic group or a C₃-C₆₀ heterocyclic group,
W₁ is a single bond, O, S, N(T₁₁), C(T₁₁)(T₁₂), or Si(T₁₁)(T₁₂),
W₂ is a single bond, O, S, N(T₂₁), C(T₂₁)(T₂₂), or Si(T₂₁)(T₂₂),
W₃ is a single bond, O, S, N(T₃₁), C(T₃₁)(T₃₂), or Si(T₃₁)(T₃₂),
n1, n2, and n3 are each independently 0 or 1,
when n1 is 0, *—(W₁)ₙ₁—*′ does not exist,
when n2 is 0, *—(W₂)ₙ₂—*′ does not exist,
when n3 is 0, *—(W₃)ₙ₃—*′ does not exist,
the sum of n1 and n2 is 1 or more,
L₁ is a single bond, O, S, Se, or N(R₁₁),
L₂ is a single bond, O, S, Se, or N(R₂₁),
L₃ is a single bond, O, S, Se, or N(R₃₁),
L₄ is a single bond, O, S, Se, or N(R₄₁),
at least one of L₁ to L₄ is not a single bond,
R₁ to R₃, R₁₁, R₂₁, R₃₁, R₄₁, Z₁ to Z₃, and Z₂₁ to Z₂₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted non-aromatic condensed heteropolycyclic group, —N(Q₁)(Q₂), —Si(Q₃)(Q₄)(Q₅), —Ge(Q₃)(Q₄)(Q₅), —B(Q₆) (Q₇), —P(═O)(Q₈)(Q₉), or —P(Q₈)(Q₉),
a1 to a3, b1 to b3, and b21 to b23 are each independently an integer from 0 to 10,
each of T₁₁, T₁₂, T₂₁, T₂₂, T₃₁, and T₃₂ is i) the same as the definition for Z₁ above, or ii) connected to an adjacent substituent to form the first condensed ring,
two or more of R₁ to R₃, Z₁ to Z₃, Z₂₁ to Z₂₃, T₁₁, T₁₂, T₂₁, T₂₂, T₃₁, and T₃₂ are optionally connected to each other, forming a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, Q₁₁ to Q₁₉, Q₂₁ to Q₂₉ and Q₃₁ to Q₃₉ are each independently: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, a C₁-C₆₀ alkyl group, a C₆-C₆₀ aryl group, or a combination thereof.

6. The condensed cyclic compound of claim 5, wherein
ring A₁ to ring A₃, ring Y₁ to ring Y₃, and ring Y₂₁ to ring Y₂₃ are each independently a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

7. The condensed cyclic compound of claim 5, wherein
in Formula 1, n1 is 1, W₁ is N(T₁₁), and the condensed cyclic compound satisfies Condition 1A or Condition 1B:
Condition 1A
Z₁ is connected to T₁₁ to form the first condensed ring.
Condition 1B
Z₃ is connected to T₁₁ to form the first condensed ring.

8. The condensed cyclic compound of claim 5, wherein
in Formula 1, n2 is 1, W₂ is N(T₂₁), and the condensed cyclic compound satisfies Condition 1C or Condition 1D:
Condition 1C
Z₂ is connected to T₂₁ to form the first condensed ring.
Condition 1D
Z₃ is connected to T₂₁ to form the first condensed ring.

9. The condensed cyclic compound of claim 5, wherein
Formula 1 satisfies at least one of Condition 1E, Condition 1F, and Condition 1 G:
Condition 1E
ring Y₁ is a C₃-C₆₀ heteropolycyclic group comprising at least one boron as a ring-forming atom, and
the C₃-C₆₀ heteropolycyclic group is a condensed ring comprising
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, condensed with
ii) at least one boron-containing 6-membered ring,
Condition 1F
ring Y₂ is a C₃-C₆₀ heteropolycyclic group comprising at least one boron as a ring-forming atom, and
the C₃-C₆₀ heteropolycyclic group is a condensed ring comprising
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, condensed with
ii) at least one boron-containing 6-membered ring
are condensed with each other,
Condition 1G
ring Y₃ is a C₃-C₆₀ heteropolycyclic group comprising at least one boron as a ring-forming atom, and
the C₃-C₆₀ heteropolycyclic group is a condensed ring comprising
i) a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, an azadibenzosilole group, or a combination thereof, condensed with
ii) at least one boron-containing 6-membered ring.

10. The condensed cyclic compound of claim 5, wherein
R₁ to R₃, R₁₁, R₂₁, R₃₁, R₄₁, Z₁ to Z₃ and Z₂₁ to Z₂₃ are each independently:
hydrogen or deuterium;
a C₁-C₂₀ alkyl group unsubstituted or substituted with deuterium, a phenyl group, a biphenyl group, a carbazolyl group, or a combination thereof;
a phenyl group, a biphenyl group, or a carbazolyl group, unsubstituted or substituted with deuterium, a C₁-C₂₀ alkyl group, a phenyl group, a biphenyl group, a carbazolyl group, or a combination thereof; or
—N(Q₁)(Q₂), and
Q₁ and Q₂ are each independently a phenyl group, a biphenyl group, or a carbazolyl group, each unsubstituted or substituted with deuterium, a C₁-C₂₀ alkyl group, a phenyl group, a biphenyl group, a carbazolyl group, or a combination thereof.

11. The condensed cyclic compound of claim 5, wherein
T₁₁, T₁₂, T₂₁, T₂₂, T₃₁, and T₃₂ are each independently
i) hydrogen, deuterium, a C₁-C₁₀ alkyl group, or a deuterated C₁-C₁₀ alkyl group;
a phenyl group, a biphenyl group, or an N-carbazolyl group, each unsubstituted or substituted with deuterium, a C₁-C₁₀ alkyl group, a deuterated C₁-C₁₀ alkyl group, a phenyl group, a deuterated phenyl group, a (C₁-C₁₀ alkyl)phenyl group, a deuterated (C₁-C₁₀ alkyl)phenyl group, an N-carbazolyl group, a deuterated N-carbazolyl group, a (C₁-C₁₀ alkyl) N-carbazolyl group, a deuterated (C₁-C₁₀ alkyl) N-carbazolyl group, or a combination thereof; or
—N(Q₁)(Q₂),
or
ii) connected to an adjacent substituent to form the first condensed ring, and
Q₁ and Q₂ are each independently a phenyl group, a biphenyl group, or a carbazolyl group, each unsubstituted or substituted with deuterium, a C₁-C₂₀ alkyl group, a phenyl group, a biphenyl group, a carbazolyl group, or a combination thereof.

12. The condensed cyclic compound of claim 5, wherein
a moiety represented by 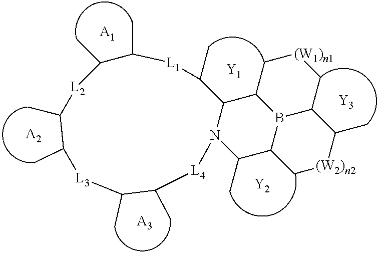
in Formula 1 is represented by one of Formulae 1A-1 to 1A-3, 1B-1, 1B-2, 1C-1 to 1C-5, 1 D-1 to 1 D-5, and 1E-1 to 1E-5: 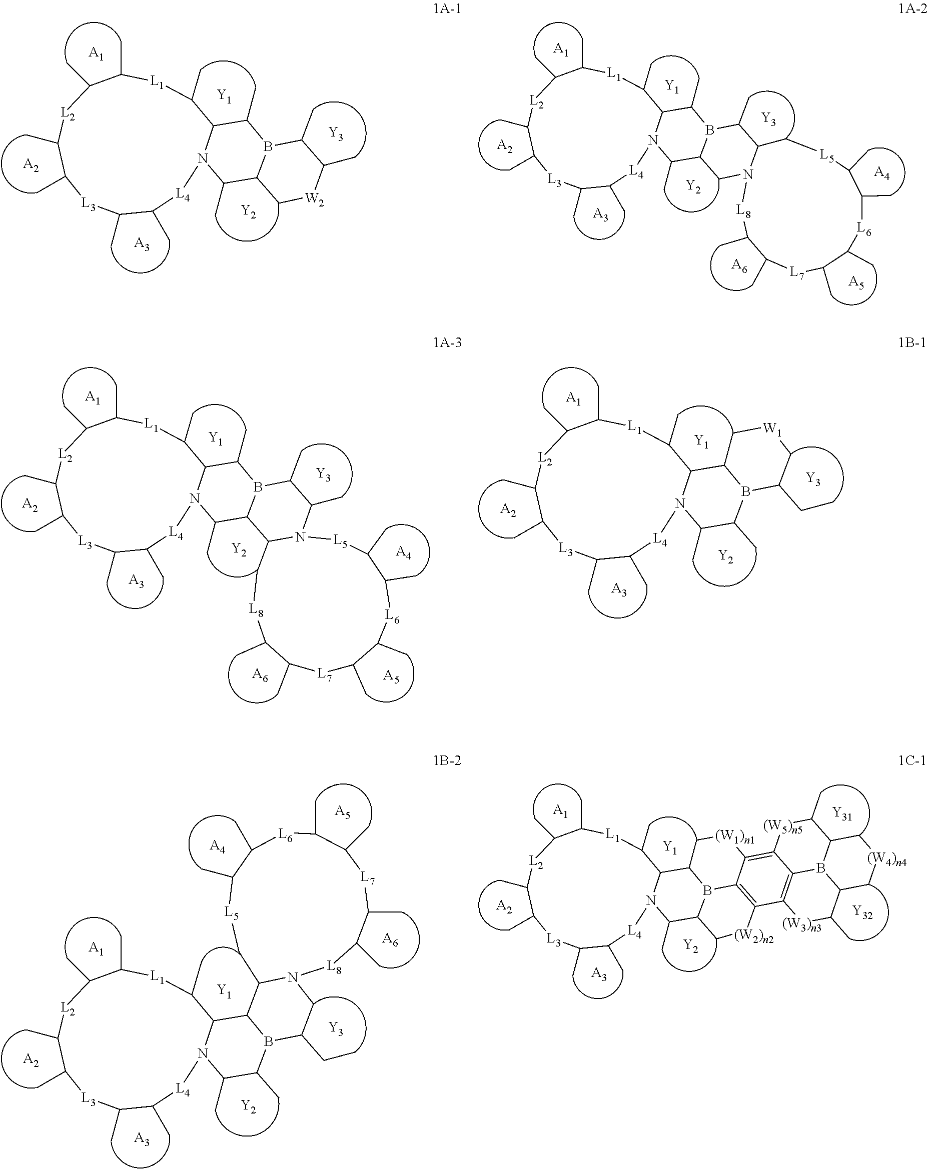 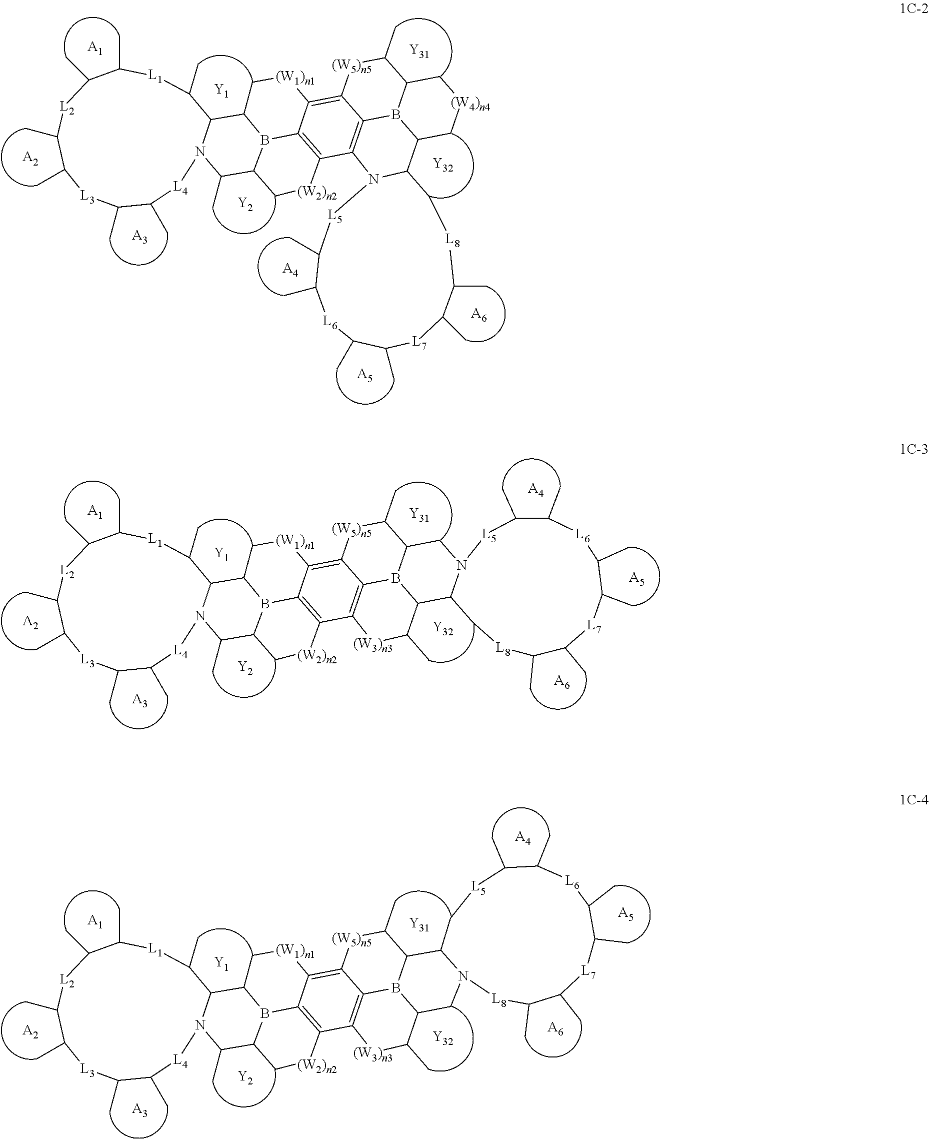 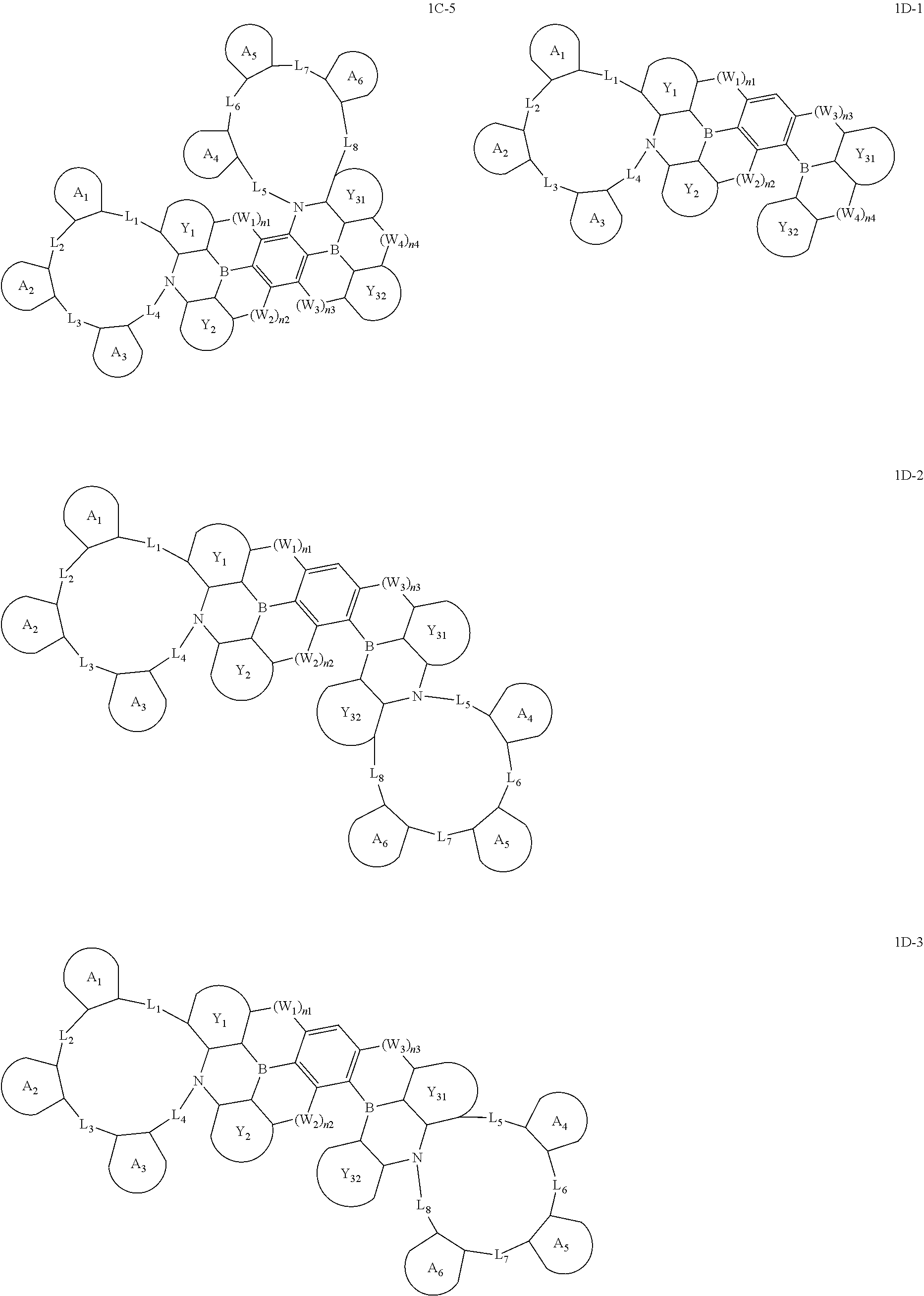 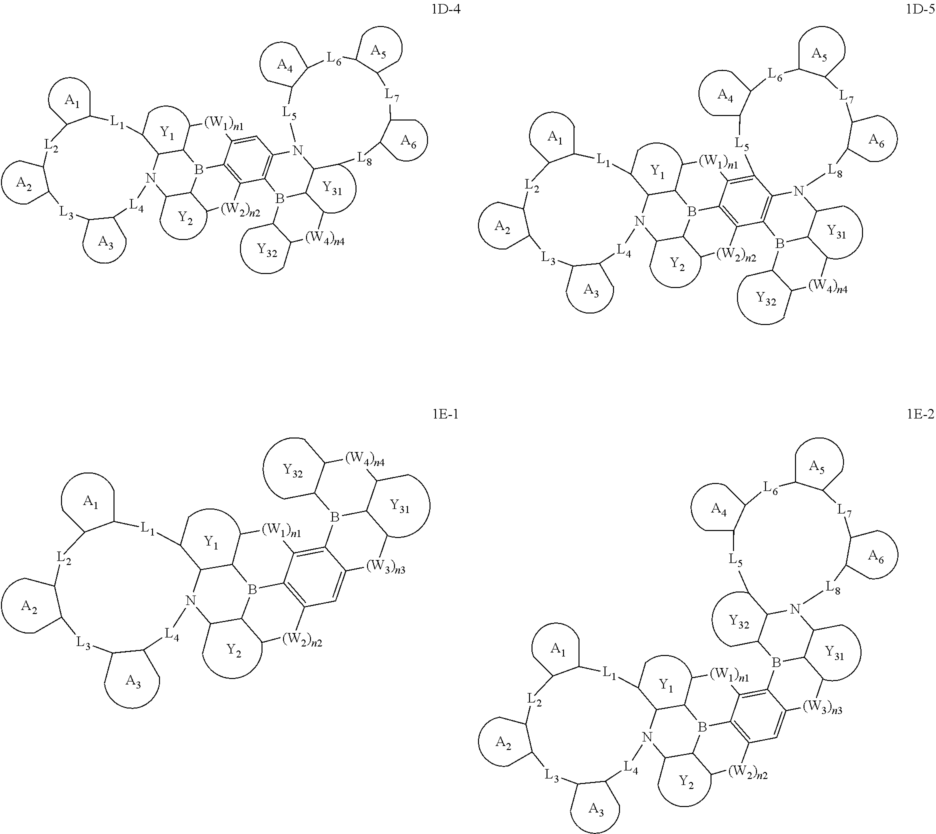 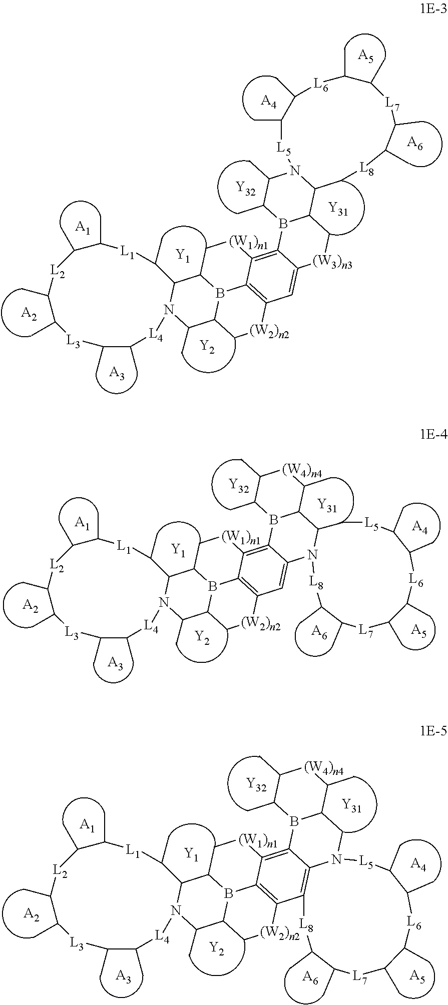
wherein, in Formulae 1A-1 to 1A-3, 1B-1, 1B-2, 1C-1 to 1C-5, 1D-1 to 1D-5, and 1E-1 to 1E-5,
the definition for each of ring A₄ to ring A₆ is the same as the definition for ring A₁,
the definition for each of L₅ to L₈ is the same as the definition for L₁, and at least one of L₅ to L₈ is not a single bond,
the definitions for each of ring Y₃₁ and ring Y₃₂ is the same as the definition for ring Y₃,
W₃ is a single bond, O, S, N(T₃₁), C(T₃₁)(T₃₂), or Si(T₃₁)(T₃₂),
W₄ is a single bond, O, S, N(T₄₁), C(T₄₁)(T₄₂), or Si(T₄₁)(T₄₂),
W₅ is a single bond, O, S, N(T₅₁), C(T₅₁)(T₅₂), or Si(T₅₁)(T₅₂),
each of T₃₁, T₃₂, T₄₁, T₄₂, T₅₁, and T₅₂ is i) the same as the definition for Z₁ above, or ii) connected to an adjacent substituent to form the first condensed ring,
n3 to n5 are each independently 0 or 1,
when n3 is 0, *—(W₃)ₙ₃—*′ does not exist,
when n4 is 0, *—(W₄)ₙ₄—*′ does not exist,
when n5 is 0, *—(W₅)ₙ₅—*′ does not exist,
the sum of n3, n4, and n5 in Formula 1C-1 is 2 or more,
the sum of n4 and n5 in Formula 1C-2 is 1 or more,
the sum of n3 and n5 in Formulae 1C-3 and 1C-4 is 1 or more,
the sum of n3 and n4 in Formulae 1C-5, 1 D-1 and 1E-1 is 1 or more,
n3 in Formulae 1 D-2, 1 D-3, 1E-2, and 1E-3 is 1, and
n4 in Formulae 1 D-4, 1 D-5, 1E-4 and 1E-5 is 1.

13. A light-emitting device comprising:
a first electrode;
a second electrode, and
an interlayer which is arranged between the first electrode and the second electrode and comprises an emission layer,
wherein the interlayer comprises at least one type of the condensed cyclic compound according to claim 1.

14. The light-emitting device of claim 13, wherein
the condensed cyclic compound is included in the emission layer.

15. The light-emitting device of claim 14, wherein
an emission peak wavelength of light emitted from the emission layer is about 440 nm to about 470 nm.

16. The light-emitting device of claim 14, wherein
the condensed cyclic compound included in the emission layer is an emitter.

17. The light-emitting device of claim 14, wherein
the emission layer further comprises a sensitizer, and the sensitizer and the condensed cyclic compound are different from each other.

18. The light-emitting device of claim 17, wherein
the sensitizer comprises an organometallic compound, a delayed fluorescence material, a prompt fluorescence material, or a combination thereof.

19. The light-emitting device of claim 18, wherein
the organometallic compound comprises platinum and a tetradentate ligand bonded to the platinum, and
the tetradentate ligand comprises a carbene moiety bonded to the platinum.

20. An electronic apparatus comprising the light-emitting device of claim 13.
